(19) United States
(12) Patent Application Publication
(10) Pub. No.: US 2026/0056467 A1
(43) Pub. Date: Feb. 26, 2026

(54) RESIST COMPOSITION AND PATTERNING PROCESS

(71) Applicant: Shin-Etsu Chemical Co., Ltd., Tokyo (JP)

(72) Inventors: Shun Kikuchi, Joetsu-shi (JP); Satoshi Kusama, Joetsu-shi (JP); Kousuke Ohyama, Joetsu-shi (JP); Masaki Ohashi, Joetsu-shi (JP)

(73) Assignee: Shin-Etsu Chemical Co., Ltd., Tokyo (JP)

(21) Appl. No.: 19/302,461

(22) Filed: Aug. 18, 2025

(30) Foreign Application Priority Data
Aug. 22, 2024 (JP) 2024-140591

(51) Int. Cl. G03F 7/004; C08F 20/22; G03F 7/00; G03F 7/038; G03F 7/039; G03F 7/09

(52) U.S. Cl. CPC G03F 7/0045; C08F 20/22; G03F 7/0046; G03F 7/0382; G03F 7/0388; G03F 7/0397; G03F 7/094; G03F 7/70033

(57) ABSTRACT

A resist composition comprising a hypervalent iodine compound, a carboxylic acid derivative, and a solvent is provided. When processed by photolithography using high-energy radiation, the resist composition exhibits a high sensitivity and improved maximum resolution. The non-chemically-amplified resist composition exhibits a high sensitivity and improved maximum resolution when processed by photolithography using high-energy radiation, typically EB and EUV lithography.

### CROSS-REFERENCE TO RELATED APPLICATION

This non-provisional application claims priority under 35 U.S.C. § 119(a) on Patent Application No. 2024-140591 filed in Japan on Aug. 22, 2024, the entire contents of which are hereby incorporated by reference.

### TECHNICAL FIELD

This invention relates to a resist composition and a pattern forming process.

### BACKGROUND ART

While a higher integration density, higher operating speed and lower power consumption of LSIs are demanded to comply with the expanding IoT market, the effort to reduce the pattern rule is in rapid progress. The wide-spreading logic device market drives forward the miniaturization technology. As the advanced miniaturization technology, microelectronic devices of 10-nm node are manufactured in a mass scale by the double, triple or quadro-patterning version of the immersion ArF lithography. Active research efforts have been made on the manufacture of 7-nm node devices by the next generation EUV lithography of wavelength 13.5 nm.

As the feature size is reduced, image blurs due to acid diffusion become a problem (see Non-Patent Document 1). To insure resolution for fine patterns with a feature size of 45 nm et seq., not only an improvement in dissolution contrast is requisite, but the control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

Addition of an acid generator capable of generating a bulky acid is effective for suppressing acid diffusion. It is then proposed to copolymerize a polymer with an acid generator in the form of an onium salt having a polymerizable olefin. With respect to the patterning of a resist film to a feature size of 16 nm et seq., it is believed impossible in the light of acid diffusion to form such a pattern from a chemically amplified resist composition. It would be desirable to have a non-chemically-amplified resist composition.

A typical non-chemically-amplified resist material is polymethyl methacrylate (PMMA). It is a positive resist material which increases solubility in organic solvent developer through the mechanism that the molecular weight becomes lower as a result of scission of the main chain upon EUV exposure.

Hydrogensilsesquioxane (HSQ) is a negative resist material which turns insoluble in alkaline developer through crosslinking by condensation reaction of silanol generated upon EUV exposure. Also chlorine-substituted calixarene functions as negative resist material. Since these negative resist materials have a small molecular size prior to crosslinking and avoid any blur caused by acid diffusion, they exhibit reduced edge roughness and very high resolution. They are thus used as a pattern transfer material for representing the resolution limit of the exposure tool. However, these materials are insufficient in sensitivity, with further improvements being needed.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV lithography is less than half the size by the ArF lithography. Therefore, the EUV lithography is quite sensitive to a variation of photon number. A variation in number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device. In view of their application to the resist at a practically acceptable sensitivity, resist compositions based on PMMA or HSQ are largely affected by stochastics, failing to gain the desired resolution.

As the means for reducing the influence of shot noise on the resist side, it is noteworthy to incorporate an element having high EUV absorption. Patent Document 1 discloses a chemically amplified resist composition containing highly EUV-absorbing iodine atoms. However, as mentioned above, the chemically amplified resist composition cannot reach the resolution desired in the EUV lithography where the pattern feature size becomes smaller than ever. Particularly in the case of line-and-space patterns, chances of collapse and disconnection of patterns increase outstandingly as the pattern size becomes smaller. Minimizing such chances leads to an improvement in maximum resolution.

Patent Document 2 discloses a negative resist composition comprising a tin compound. Based on tin element having high EUV absorption, this resist composition is improved in stochastics and achieves a high sensitivity and high resolution. The so-called metal resist compositions, however, suffer from many problems including low solubility in resist solvents, poor shelf stability, and defectiveness due to post-etching residues. Further, the metal resist compositions are of negative tone wherein the exposed region becomes a metal oxide which is insoluble in the developer. In their application to the patterning of contact holes, an additional reversal step is necessary, leaving an economical concern.

### CITATION LIST

Patent Document 1: JP-A 2018-005224 (U.S. Pat. No. 10,323,113)
Patent Document 2: JP-A 2021-503482
Non-Patent Document 1: SPIE Vol. 5039 p 1 (2003)
Non-Patent Document 2: SPIE Vol. 6520 p 65203L-1 (2007)

### SUMMARY OF THE INVENTION

An object of the invention is to provide a non-chemically-amplified resist composition which exhibits a high sensitivity and improved maximum resolution when processed by photolithography using high-energy radiation, typically EB and EUV lithography, and a patterning process using the same.

The inventors have found that a resist composition based on a hypervalent iodine compound and a carboxylic acid derivative forms a resist film exhibiting a reduced roughness and high resolution and is thus quite useful in precise micropatterning.

In one aspect, the invention provides a resist composition comprising a hypervalent iodine compound, a carboxylic acid derivative, and a solvent. The hypervalent iodine compound is at least one compound selected from hypervalent iodine compounds having the formulae (1) to (4).

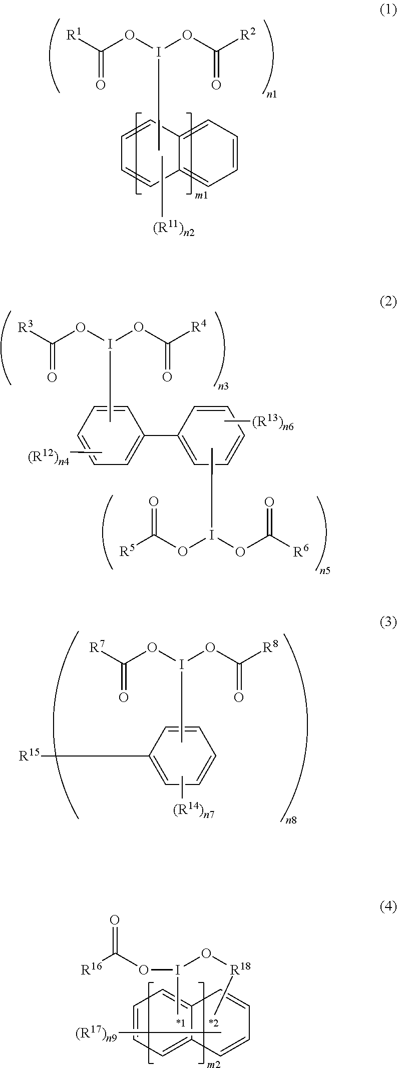

Herein m1 is 0, 1 or 2; when m1=0, n1 is 1, 2 or 3, n2 is 0, 1, 2, 3, 4 or 5 and 1≤n1+n2 K 6; when m1=1, n1 is 1, 2 or 3, n2 is 0, 1, 2, 3, 4, 5, 6 or 7 and 1≤n1+n2 K 8; when m1=2, n1 is 1, 2 or 3, n2 is 0, 1, 2, 3, 4, 5, 6, 7, 8 or 9 and 1 n1+n2≤10;
n3 is 1 or 2, n4 is 0, 1, 2, 3 or 4, 1≤n3+n4≤5, n5 is 1 or 2, n6 is 0, 1, 2, 3 or 4, 1≤n5+n6≤5, n7 is 0, 1, 2, 3 or 4, n8 is 1, 2, 3 or 4,
m2 is 0, 1 or 2; when m2=0, n9 is 0, 1, 2, 3 or 4; when m2=1, n9 is 0, 1, 2, 3, 4, 5 or 6;
R¹ to R⁸ are each independently halogen or a C₁-C₁₀ hydrocarbyl group which may contain a heteroatom, R¹ and R², R³ and R⁴, R⁵ and R⁶, or R⁷ and R¹ may bond together to form a ring with the carbon atoms to which they are attached and the intervenient atoms,
R¹¹ to R¹⁴ are each independently halogen or a C₁-C₄₀ hydrocarbyl group which may contain a heteroatom; when n2 is 2 or more, a plurality of R¹¹ may be identical or different and a plurality of R¹¹ may bond together to form a ring with the carbon atoms on the aromatic ring to which they are attached; when n4 is 2 or more, a plurality of R¹² may be identical or different and a plurality of R¹² may bond together to form a ring with the carbon atoms on the aromatic ring to which they are attached; when n6 is 2 or more, a plurality of R¹³ may be identical or different and a plurality of R¹³ may bond together to form a ring with the carbon atoms on the aromatic ring to which they are attached; when n7 is 2 or more, a plurality of R¹⁴ may be identical or different and a plurality of R¹⁴ may bond together to form a ring with the carbon atoms on the aromatic ring to which they are attached;
R¹⁵ is a C₁-C₄₀ (n8)-valent hydrocarbon group or C₂-C₄₀ (n8)-valent heterocyclic group; when n8=2, R¹⁵ may also be an ether bond, carbonyl group, azo group, thioether bond, carbonate bond, carbamate bond, sulfinyl group, sulfonyl group or thioketone bond; some or all of the hydrogen atoms in the (n8)-valent hydrocarbon group or (n8)-valent heterocyclic group may be substituted by a heteroatom-containing moiety, some —CH₂— in the (n8)-valent hydrocarbon group may be replaced by a heteroatom-containing moiety, R¹⁴ and R¹⁵ may bond together to form a ring with the carbon atoms to which they are attached and the intervenient atoms,
R¹⁶ is halogen or a C₁-C₁₀ hydrocarbyl group which may contain a heteroatom,
R¹⁷ is halogen or a C₁-C₄₀ hydrocarbyl group which may contain a heteroatom, when n9 is 2 or more, a plurality of R¹⁷ may be identical or different and a plurality of R¹⁷ may bond together to form a ring with the carbon atoms on the aromatic ring to which they are attached;
R¹⁸ is carbonyl or a C₁-C₁₀ hydrocarbylene group which may contain a heteroatom,
*1 and *2 each designate a point of attachment to a carbon atom on the aromatic ring in the formula, *1 and *2 being attached to adjoining carbon atoms on the aromatic ring,

The carboxylic acid derivative is a carboxylic acid derivative having the formula (5) or a polymer comprising carboxylic acid derivative repeat units having the formula (6).

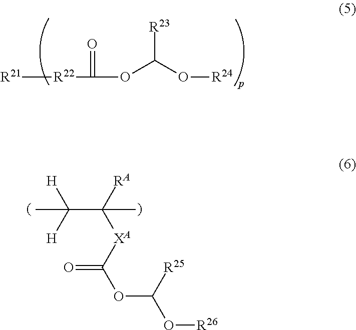

Herein p is 1, 2, 3 or 4,
R²¹ is a C₁-C₄₀ p-valent hydrocarbon group or C₂-C₄₀ p-valent heterocyclic group; when p=2, R²¹ may also be an ether bond, carbonyl group, azo group, thioether bond, carbonate bond, carbamate bond, sulfinyl group or sulfonyl group; some or all of the hydrogen atoms in the p-valent hydrocarbon group or p-valent heterocyclic group may be substituted by a heteroatom-containing moiety, some —CH₂— in the p-valent hydrocarbon group may be replaced by a heteroatom-containing moiety,
R²² is a single bond or C₁-C₁₀ hydrocarbylene group, some or all of the hydrogen atoms in the hydrocarbylene group may be substituted by a heteroatom-containing moiety, some —CH₂— in the hydrocarbylene group may be replaced by a heteroatom-containing moiety; when p is 2, 3 or 4, a plurality of R²² may be identical or different,
R²³ to R²⁶ are each independently halogen or a C₁-C₄₀ hydrocarbyl group which may contain a heteroatom, R²³ and R²⁴ may bond together to form a ring with the carbon and oxygen atoms to which they are attached, R²¹ and R²⁶ may bond together to form a ring with the carbon and oxygen atoms to which they are attached,
R^{A} is hydrogen, halogen, methyl or trifluoromethyl,
X^{A} is a single bond, phenylene, naphthylene, or *—C(═O)—O—X^{A1}—, X^{A1} is a C₁-C₁₀ saturated hydrocarbylene group, phenylene group or naphthylene group, the saturated hydrocarbylene group may contain a hydroxy moiety, ether bond, ester bond or lactone ring, * designates a point of attachment to the carbon atom in the backbone.

In one embodiment, the polymer comprising carboxylic acid derivative repeat units is free of acid labile group-containing repeat units other than the repeat units having formula (6).

In another aspect, the invention provides a laminate comprising a substrate and a resist film formed thereon from the resist composition defined herein.

The laminate may further comprise an underlying film between the substrate and the resist film.

Typically, the resist film is formed by a ligand exchange between the hypervalent iodine compound and the carboxylic acid derivative.

In a further aspect, the invention provides a pattern forming process comprising the steps of applying the resist composition defined herein onto a substrate or a substrate having an underlying film deposited thereon to form a resist film thereon, exposing the resist film to i-line, KrF excimer laser, ArF excimer laser, EB or EUV, and developing the exposed resist film in a developer.

### Advantageous Effects of the Invention

The resist composition forms a resist film which satisfies both reduced roughness and high resolution when processed by photolithography using i-line, KrF excimer laser, ArF excimer laser, EB or EUV and is quite useful in micropatterning.

### DESCRIPTION OF THE PREFERRED EMBODIMENT

The terms “a” and “an” herein do not denote a limitation of quantity, but rather denote the presence of at least one of the referenced item. As used herein, Me stands for methyl, Ac for acetyl, the notation (Cₙ-Cₘ) means a group containing from n to m carbon atoms per group. Both the broken line (- - -) and the asterisk (*) designate a point of attachment or valence bond.

The abbreviations and acronyms have the following meaning.
UV: ultraviolet radiation
EUV: extreme ultraviolet
EB: electron beam
Mw: weight average molecular weight
Mw/Mn: polydispersity index
GPC: gel permeation chromatography
PAB: post-apply bake
PEB: post-exposure bake
LWR: line width roughness
CDU: critical dimension uniformity

### [Resist Composition]

One embodiment of the invention is a resist composition based on a hypervalent iodine compound and a carboxylic acid derivative.

### [Hypervalent Iodine Compound]

The hypervalent iodine compound is a three-coordinate hypervalent iodine compound having the formula (1), (2), (3) or (4).

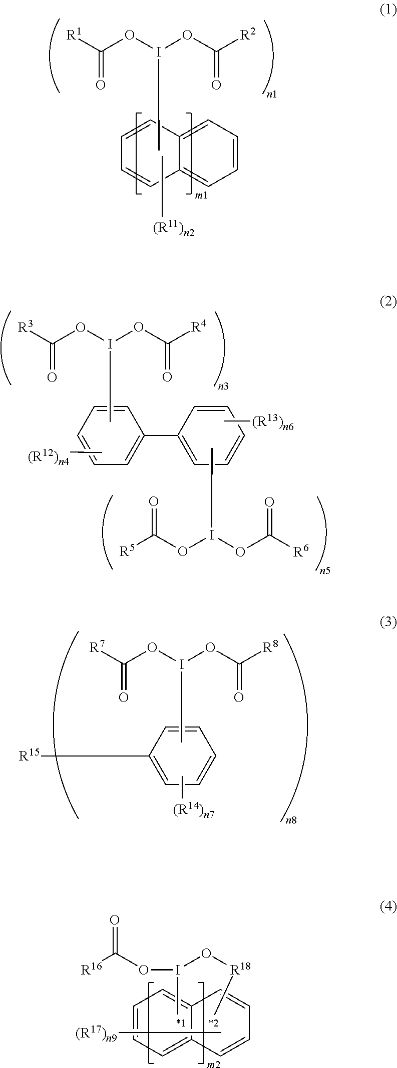

In formula (1), m1 is 0, 1 or 2. When m1=0, n1 is 1, 2 or 3, n2 is 0, 1, 2, 3, 4 or 5 and 1≤n1+n2≤56. When m1=1, n1 is 1, 2 or 3, n2 is 0, 1, 2, 3, 4, 5, 6 or 7 and 1≤n1+n2≤8. When m1=2, n1 is 1, 2 or 3, n2 is 0, 1, 2, 3, 4, 5, 6, 7, 8 or 9 and 1≤n1+n2≤10. In formulae (2) and (3), n3 is 1 or 2, n4 is 0, 1, 2, 3 or 4, 1≤3+n4≤5 n5 is 1 or 2, n6 is 0, 1, 2, 3 or 4, 1≤n5+n6≤5, n7 is 0, 1, 2, 3 or 4, and n8 is 1, 2, 3 or 4. In formula (4), m2 is 0, 1 or 2. When m2=0, n9 is, 1, 2, 3 or 4. When m2=1, n9 is 0, 1, 2, 3, 4, 5 or 6.

In formulae (1) to (3), R¹ to R⁸ are each independently halogen or a C₁-C₁₀ hydrocarbyl group which may contain a heteroatom. R¹ and R², R³ and R⁴, R⁵ and R⁶, or R⁷ and R⁸ may bond together to form a ring with the carbon atoms to which they are attached and the intervenient atoms.

Suitable halogen atoms represented by R¹ to R⁸ include fluorine, chlorine, bromine and iodine. The C₁-C₁₀ hydrocarbyl group represented by R¹ to R⁸ may be saturated or unsaturated and straight, branched or cyclic. Examples thereof include C₁-C₁₀ alkyl groups such as methyl, ethyl, propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₁₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, and adamantyl, C₂-C₁₀ alkenyl groups such as vinyl and allyl, C₆-C₁₀ aryl groups such as phenyl and naphthyl, and combinations thereof. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). R¹ to R⁸ are preferably C₁-C₄ hydrocarbyl groups.

In formulae (1) to (3), R¹¹ to R¹⁴ are each independently halogen or a C₁-C₄₀ hydrocarbyl group which may contain a heteroatom. When n2 is 2 or more, a plurality of R¹¹ may be identical or different and a plurality of R¹¹ may bond together to form a ring with the carbon atoms on the aromatic ring to which they are attached. When n4 is 2 or more, a plurality of R¹² may be identical or different and a plurality of R¹² may bond together to form a ring with the carbon atoms on the aromatic ring to which they are attached. When n6 is 2 or more, a plurality of R¹³ may be identical or different and a plurality of R¹³ may bond together to form a ring with the carbon atoms on the aromatic ring to which they are attached. When n7 is 2 or more, a plurality of R¹⁴ may be identical or different and a plurality of R¹⁴ may bond together to form a ring with the carbon atoms on the aromatic ring to which they are attached.

Suitable halogen atoms represented by R¹¹ to R¹⁴ include fluorine, chlorine, bromine and iodine. The C₁-C₄₀ hydrocarbyl group represented by R¹¹ to R¹⁴ may be saturated or unsaturated and straight, branched or cyclic. Examples thereof include C₁-C₄₀ alkyl groups such as methyl, ethyl, propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, adamantyl, and adamantylmethyl, and C₆-C₄₀ aryl groups such as phenyl, naphthyl, and anthracenyl. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—).

In formula (3), R¹⁵ is a C₁-C₄₀ (n8)-valent hydrocarbon group or C₂-C₄₀ (n8)-valent heterocyclic group. When n8=2, R¹⁵ may also be an ether bond, carbonyl group, azo group, thioether bond, carbonate bond, carbamate bond, sulfinyl group, sulfonyl group or thioketone bond. Some or all of the hydrogen atoms in the (n8)-valent hydrocarbon group or (n8)-valent heterocyclic group may be substituted by a heteroatom-containing moiety, some —CH₂— in the (n8)-valent hydrocarbon group may be replaced by a heteroatom-containing moiety. R¹⁴ and R¹⁵ may bond together to form a ring with the carbon atoms to which they are attached and the intervenient atoms.

The (n8)-valent hydrocarbon group represented by R¹⁵ may be saturated or unsaturated and straight, branched or cyclic. The (n8)-valent hydrocarbon group is obtained by eliminating “n8” number of hydrogen atoms from a hydrocarbon. Suitable hydrocarbons include C₁-C₄₀ alkanes, C₂-C₄₀ alkenes, C₂-C₄₀ alkynes, C₃-C₄₀ cyclic saturated hydrocarbons, C₃-C₄₀ cyclic unsaturated hydrocarbons, and C₆-C₄₀ aromatic hydrocarbons. Examples of the C₁-C₄₀ alkane include methane, ethane, propane, butane, pentane, hexane, heptane, octane, nonane, decane, and structural isomers thereof.

Examples of the C₂-C₄₀ alkene include ethylene, propylene, butene, pentene, hexene, heptene, octene, nonene, decene, and structural isomers thereof.

Examples of the C₂-C₄₀ alkyne include acetylene, propyne, butyne, pentyne, hexyne, heptyne, octyne, nonyne, decyne, and structural isomers thereof.

Examples of the C₃-C₄₀ cyclic saturated hydrocarbon include cyclopropane, cyclobutane, cyclohexane, cycloheptane, cyclooctane, adamantane, and norbornane.

Examples of the C₃-C₄₀ cyclic unsaturated hydrocarbon include cyclopropene, cyclobutene, cyclopentene, cyclohexene, cycloheptene, cyclooctene, and norbornene.

Examples of the C₆-C₄₀ aromatic hydrocarbon include benzene, naphthalene and biphenyl.

The (n8)-valent heterocyclic group represented by R¹⁵ is obtained by eliminating “n8” number of hydrogen atoms from a heterocyclic compound. Suitable heterocyclic compounds include furane, pyridine, pyrazole, and thiazolidine.

Also included are the (n8)-valent hydrocarbon groups or (n8)-valent heterocyclic groups in which some or all of the hydrogen atoms are substituted by a moiety containing a heteroatom such as oxygen, sulfur, nitrogen or halogen so that the group may contain a hydroxy moiety, cyano moiety, fluorine, chlorine, bromine, or iodine; and the (n8)-valent hydrocarbon group in which some —CH₂— is replaced by a moiety containing a heteroatom such as oxygen, sulfur or nitrogen so that the group may contain a carbonyl moiety, ether bond, thioether bond, ester bond, sulfonate ester bond, carbonate bond, carbamate bond, lactone ring, sultone ring, or carboxylic anhydride (—C(═O)—O—C(═O)—).

In formula (4), R¹⁶ is halogen or a C₁-C₁₀ hydrocarbyl group which may contain a heteroatom. Examples of the halogen and hydrocarbyl group represented by R¹⁶ are the same as exemplified above for the halogen and hydrocarbyl groups R¹ to R⁸.

In formula (4), R¹⁷ is halogen or a C₁-C₄₀ hydrocarbyl group which may contain a heteroatom. When n9 is 2 or more, a plurality of R¹⁷ may be identical or different and a plurality of R¹⁷ may bond together to form a ring with the carbon atoms on the aromatic ring to which they are attached. Examples of the halogen and hydrocarbyl group represented by R¹⁷ are the same as exemplified above for the halogen and hydrocarbyl groups R¹¹ to R¹⁴.

In formula (4), R¹¹ is carbonyl or a C₁-C₁₀ hydrocarbylene group which may contain a heteroatom. The C₁-C₁₀ hydrocarbylene group may be saturated or unsaturated and straight, branched or cyclic. Examples thereof include C₁-C₁₀ alkylene groups such as methanediyl, ethane-1,1-diyl, ethane-1,2-diyl, propane-1,1-diyl, propane-1,2-diyl, propane-1,3-diyl, propane-2,2-diyl, butane-2,3-diyl, butane-1,4-diyl, 2-methylpropane-1,2-diyl, pentane-1,5-diyl, hexane-1,6-diyl, heptane-1,7-diyl, octane-1,8-diyl, nonane-1,9-diyl, and decane-1,10-diyl; C₃-C₁₀ cyclic saturated hydrocarbylene groups such as cyclopentanediyl, cyclohexanediyl, norbornanediyl, adamantanediyl and tricyclo[5.2.1.0^{2,6}]decanediyl; C₂-C₁₀ alkenylene groups such as vinylene and propynylene; C₆-C₁₀ arylene groups such as phenylene, methylphenylene, ethylphenylene, n-propylphenylene, isopropylphenylene, n-butylphenylene and naphthylene; and combinations thereof. In these hydrocarbylene groups, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, cyano, halogenated alkyl, halogen, carbonyl, ether bond, thioether bond, ester bond, sulfonate ester bond, carbonate bond, carbamate bond, lactone ring, sultone ring, carboxylic anhydride (—C(═O)—O—C(═O)—). R¹⁸ is preferably carbonyl, a C₁-C₄ hydrocarbylene group or C₁-C₄ fluorinated hydrocarbylene group.

In formula (4), *1 and *2 each designate a point of attachment to a carbon atom on the aromatic ring in the formula, with the proviso that *1 and *2 are attached to adjoining carbon atoms on the aromatic ring. As the combination of *1, *2 and m2, the following seven patterns are contemplated.

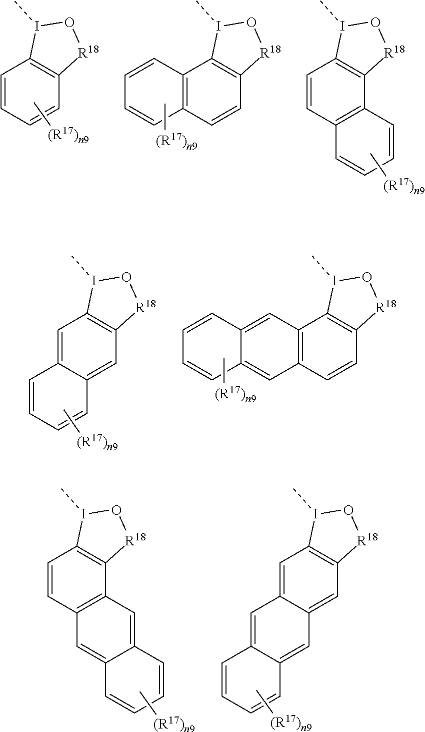

Herein n9, R¹⁷ and R¹⁸ are as defined above, the broken line designates a point of attachment to R¹⁶—C(═O)—O—.

Examples of the hypervalent iodine compound having formula (1) are shown below, but not limited thereto.

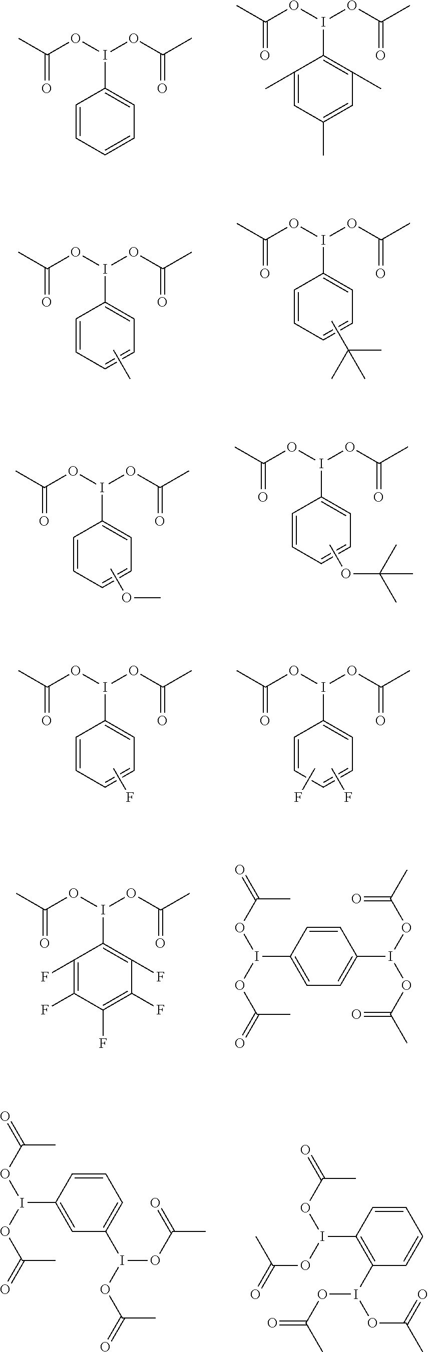

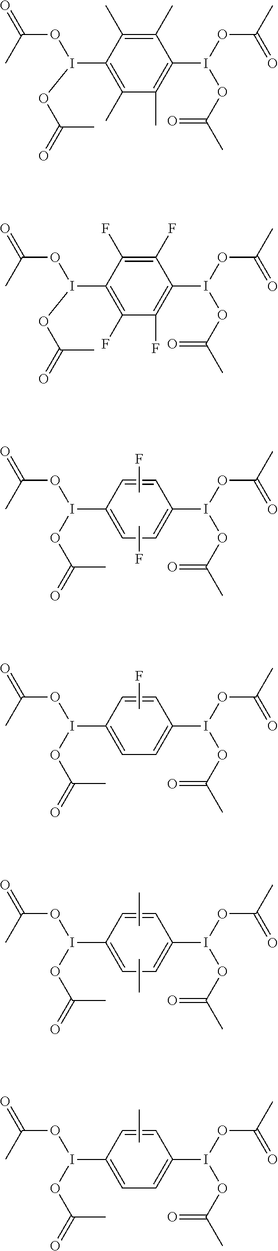

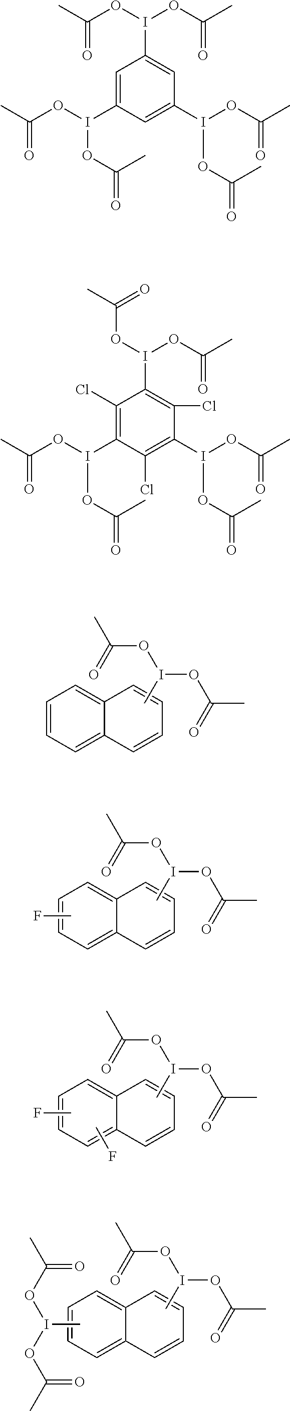

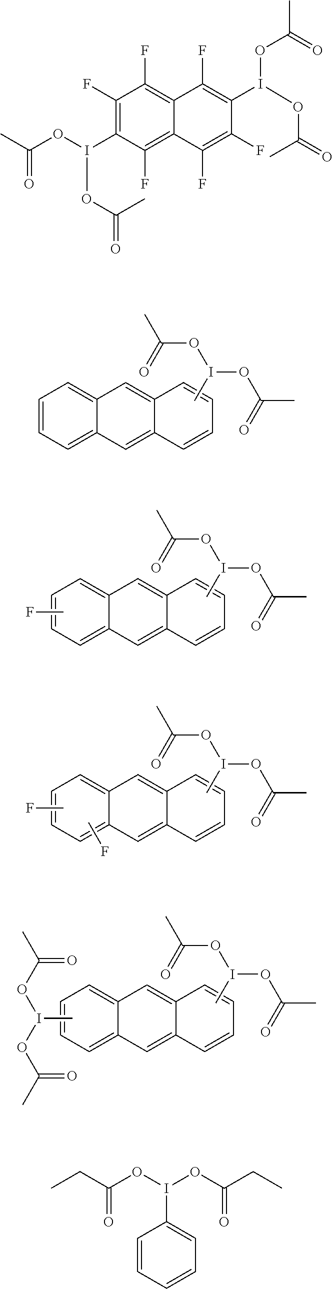

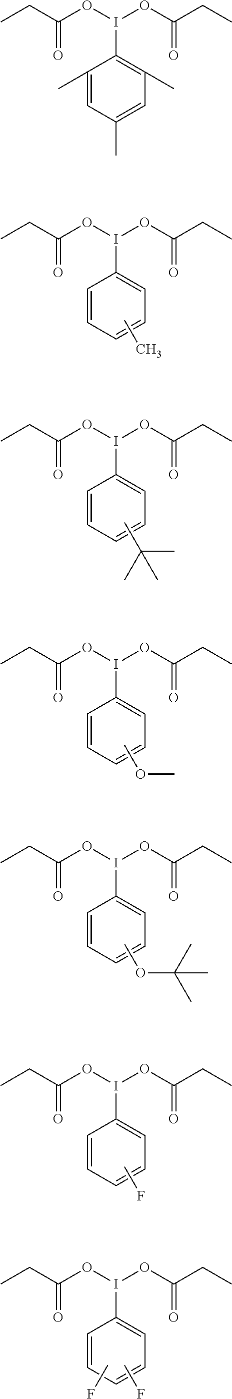

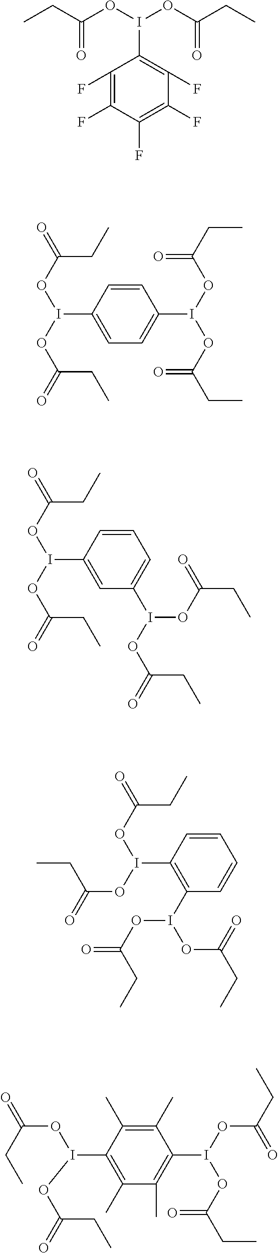

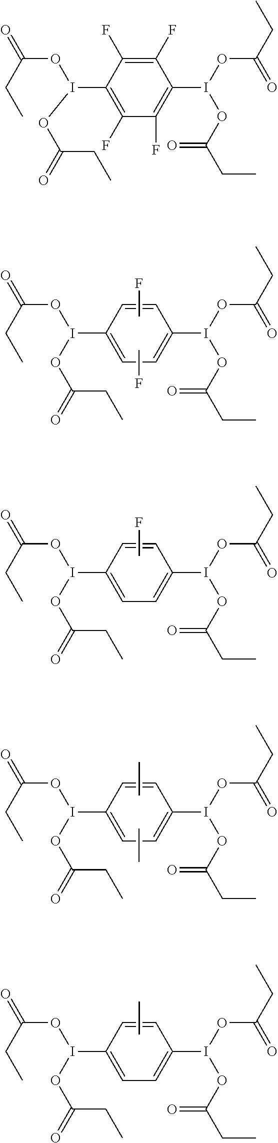

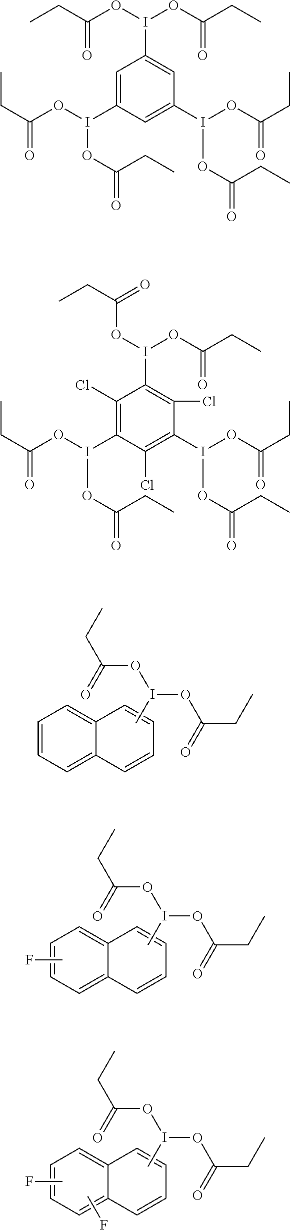

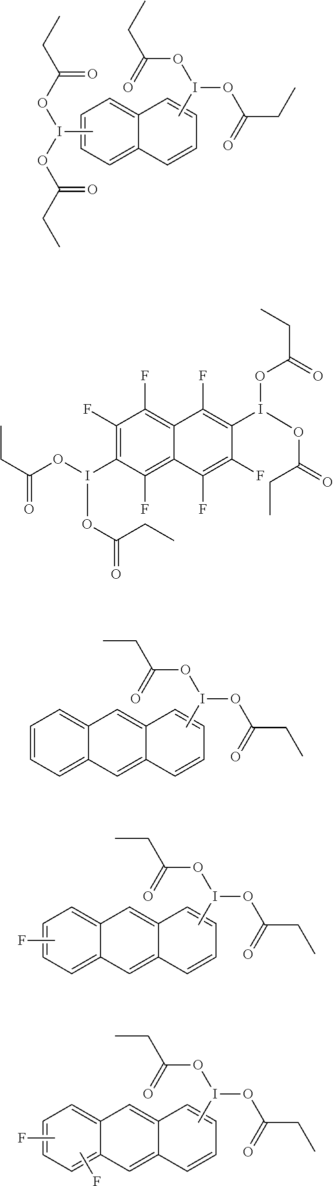

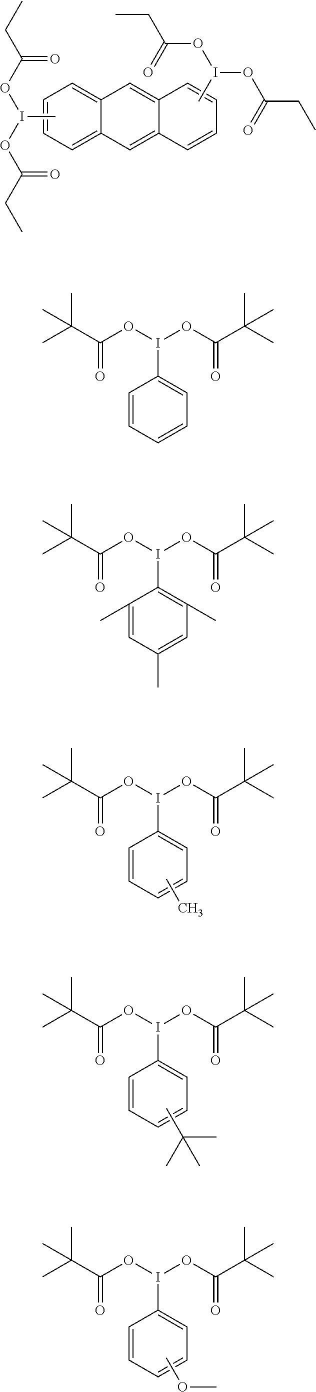

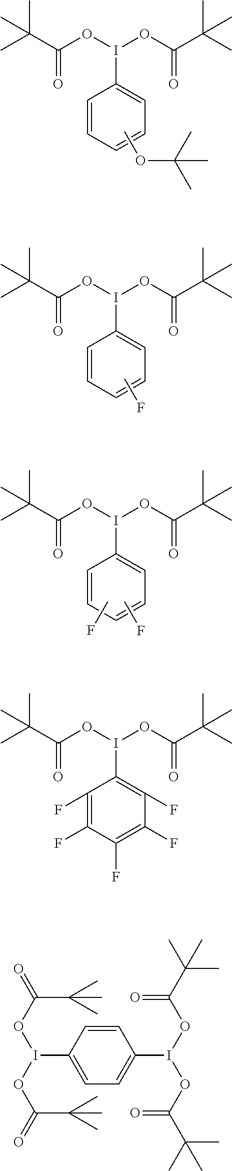

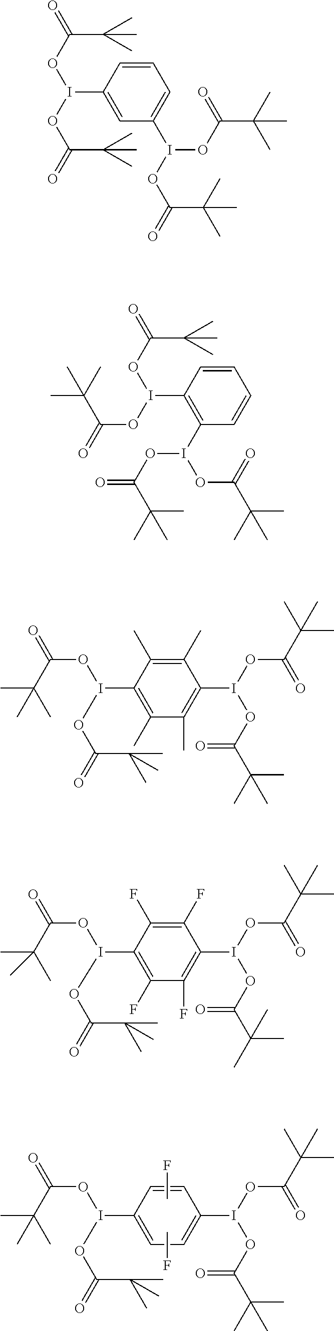

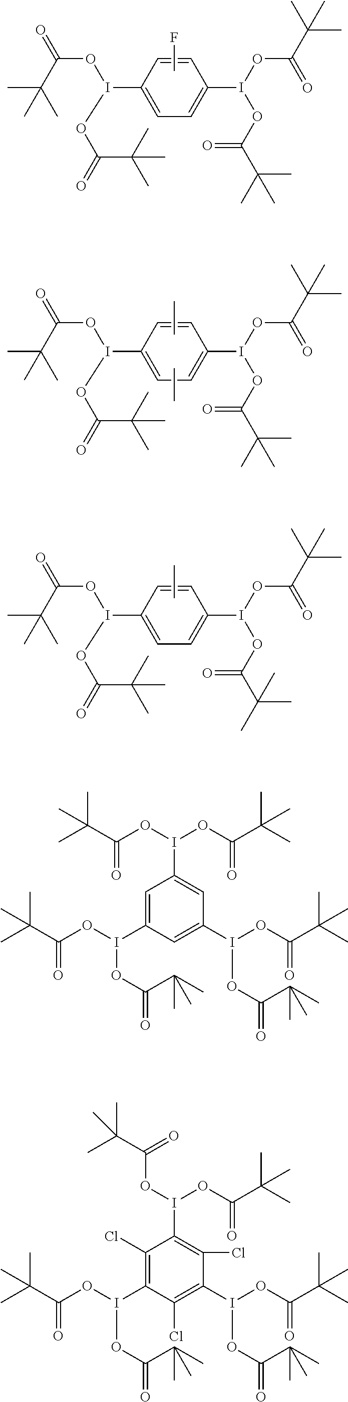

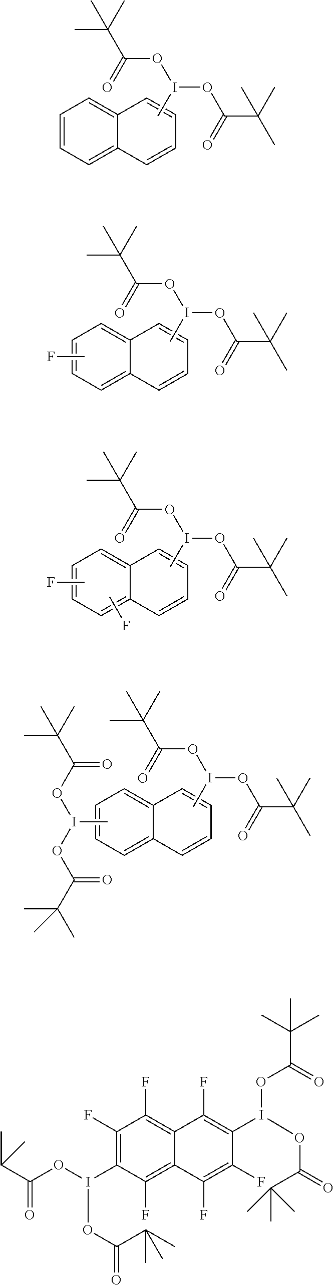

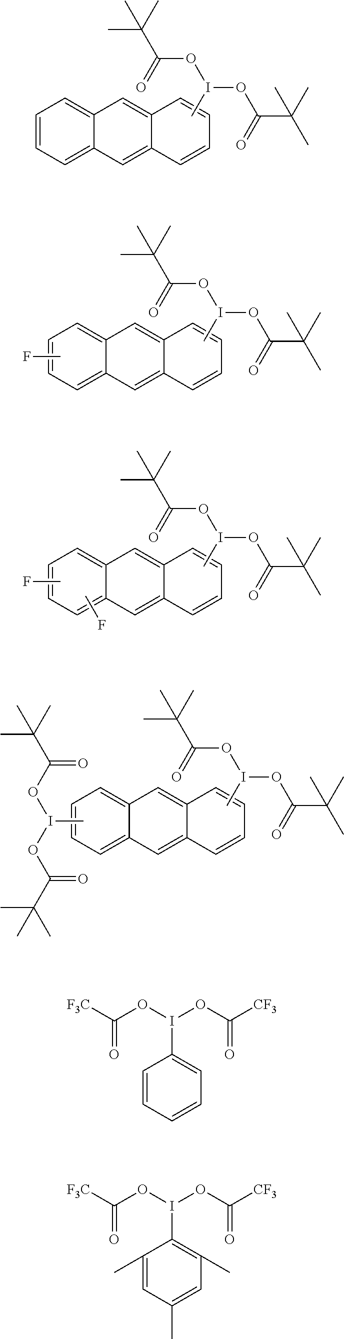

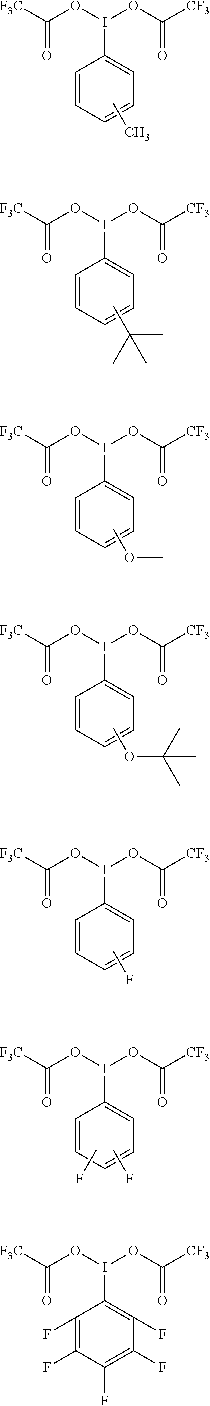

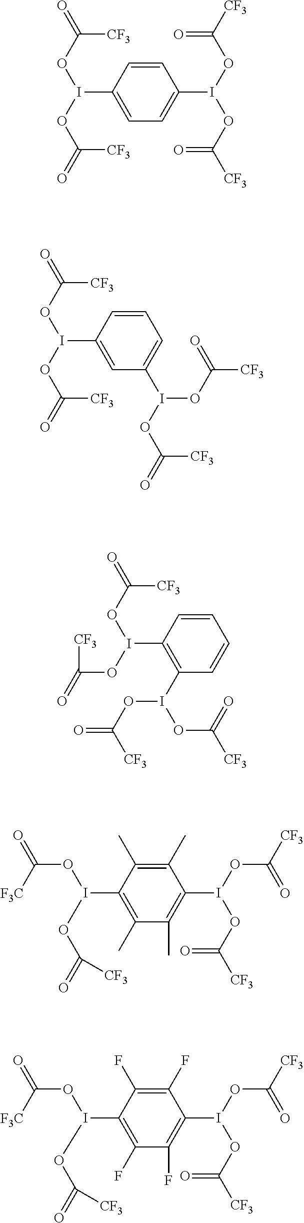 [SMILES: O=C(OI(OC(=O)C(F)(F)F)c1ccc(I(OC(=O)C(F)(F)F)OC(=O)C(F)(F)F)cc1)C(F)(F)F ; O=C(OI(OC(=O)C(F)(F)F)c1cccc(I(OC(=O)C(F)(F)F)OC(=O)C(F)(F)F)c1)C(F)(F)F ; O=C(OI(OC(=O)C(F)(F)F)c1ccccc1I(OC(=O)C(F)(F)F)OC(=O)C(F)(F)F)C(F)(F)F ; Cc1c(C)c(I(OC(=O)C(F)(F)F)OC(=O)C(F)(F)F)c(C)c(C)c1I(OC(=O)C(F)(F)F)OC(=O)C(F)(F)F ; O=C(OI(OC(=O)C(F)(F)F)c1c(F)c(F)c(I(OC(=O)C(F)(F)F)OC(=O)C(F)(F)F)c(F)c1F)C(F)(F)F]

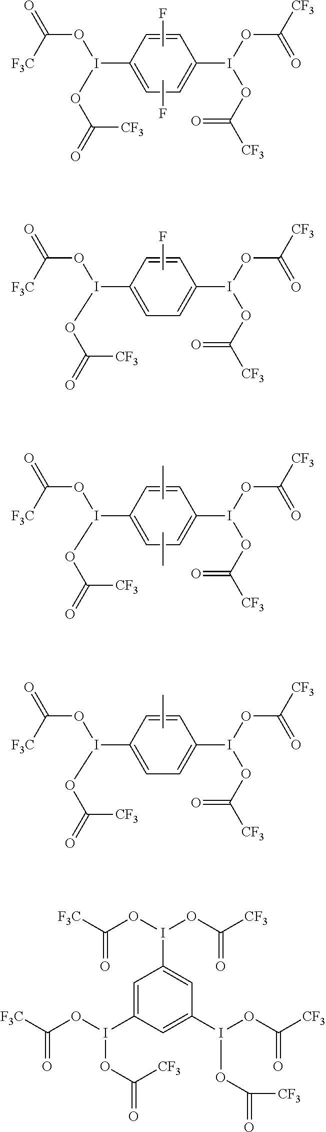

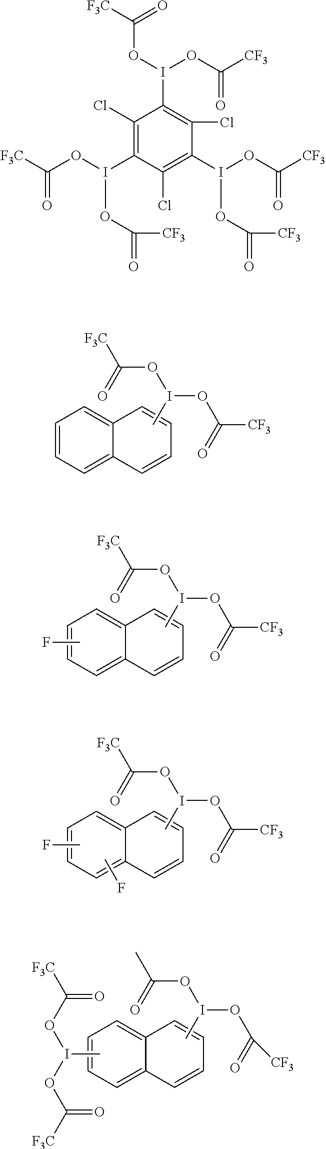

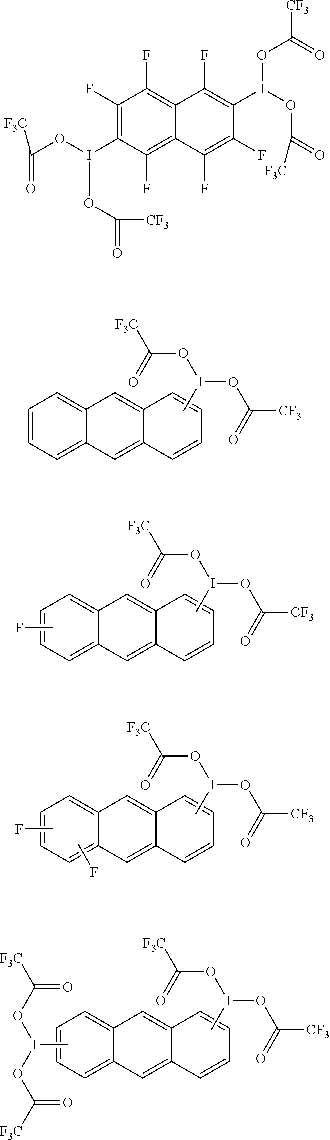

Examples of the hypervalent iodine compound having formula (2) are shown below, but not limited thereto.

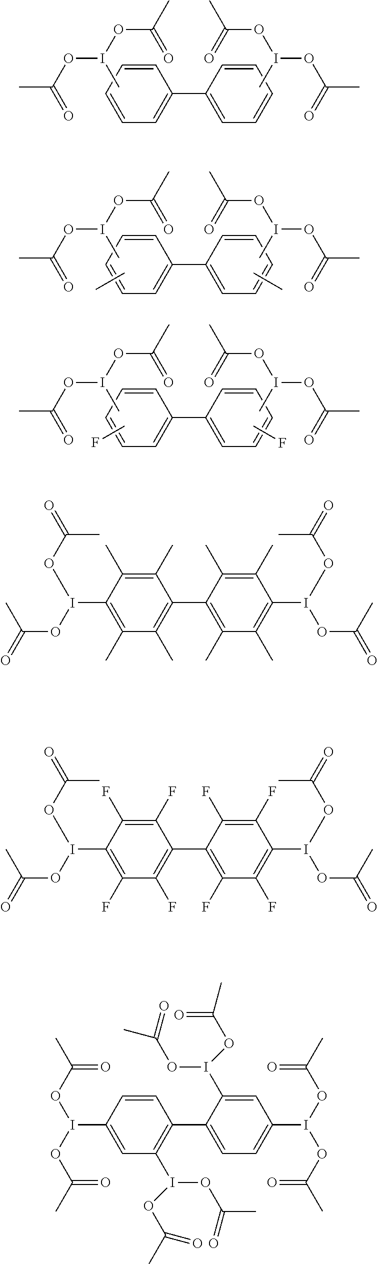

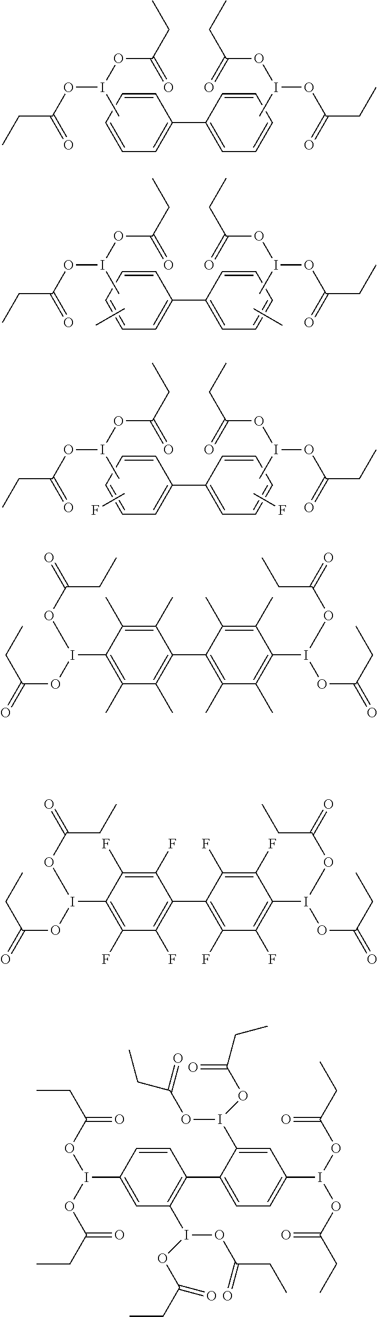

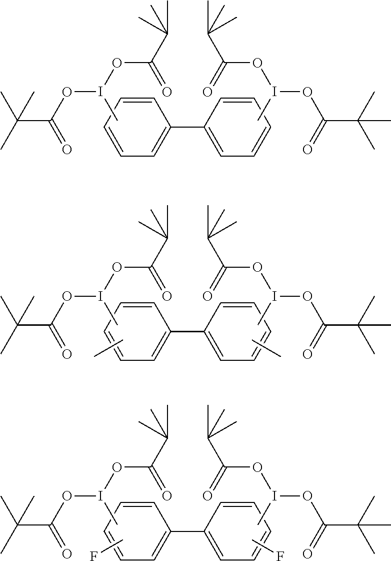

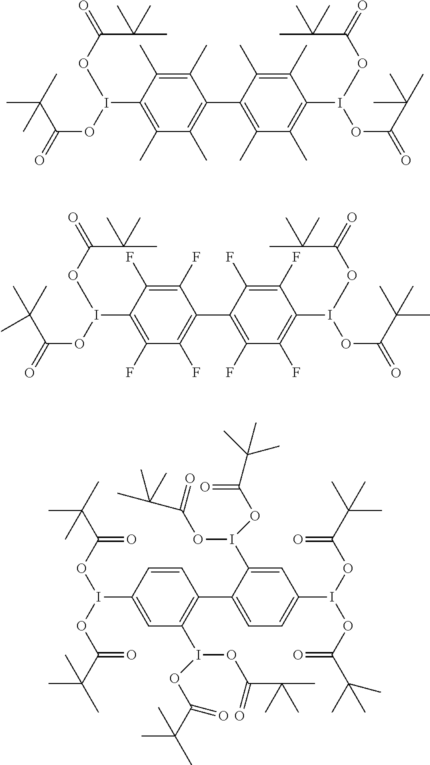

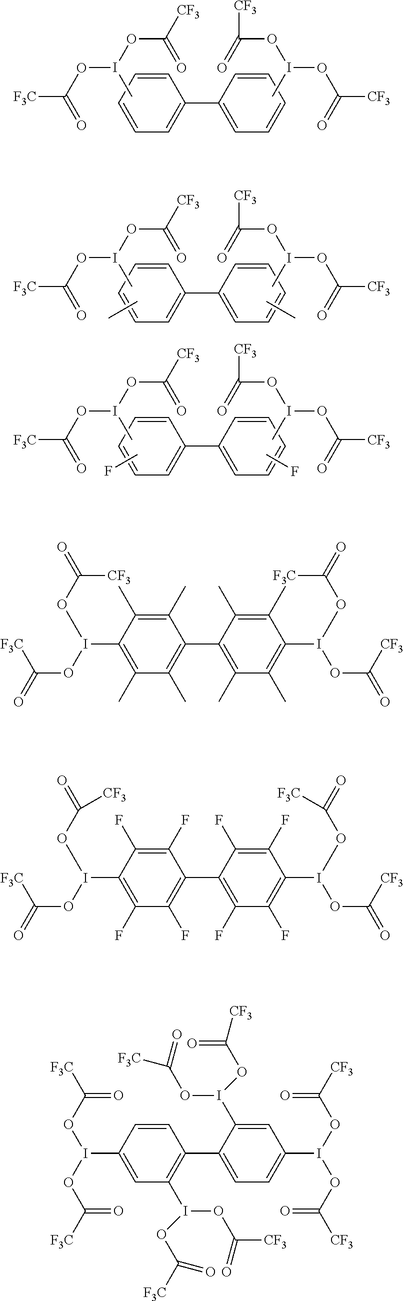

Examples of the hypervalent iodine compound having formula (3) are shown below, but not limited thereto.

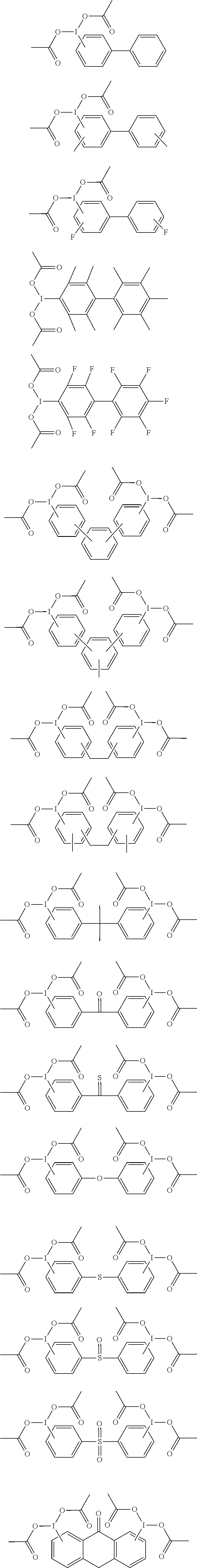

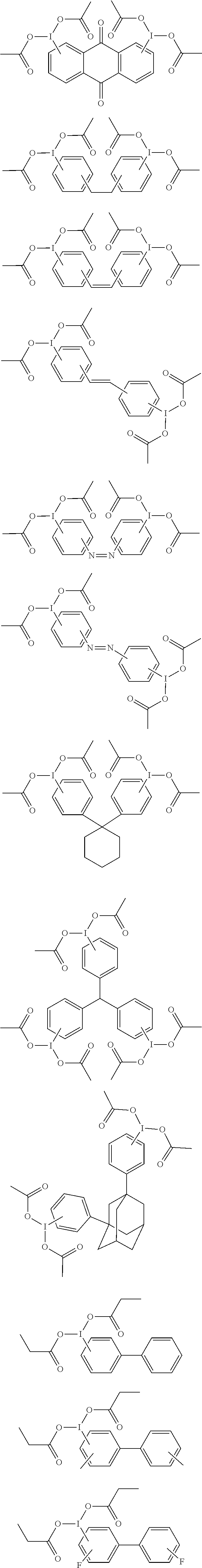

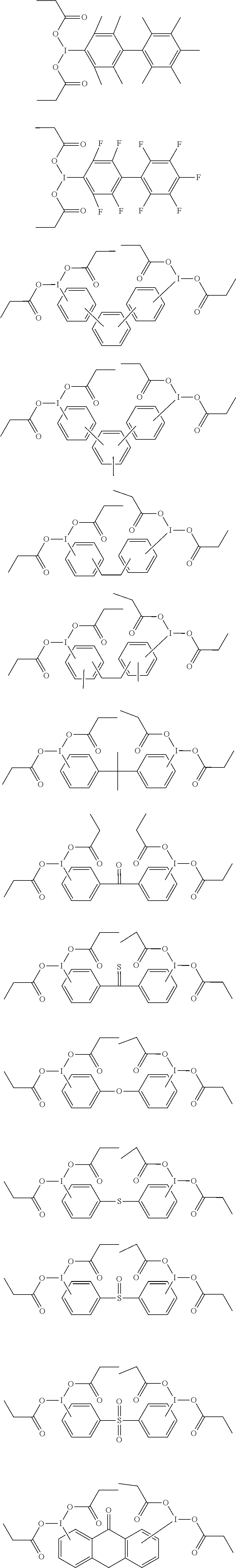

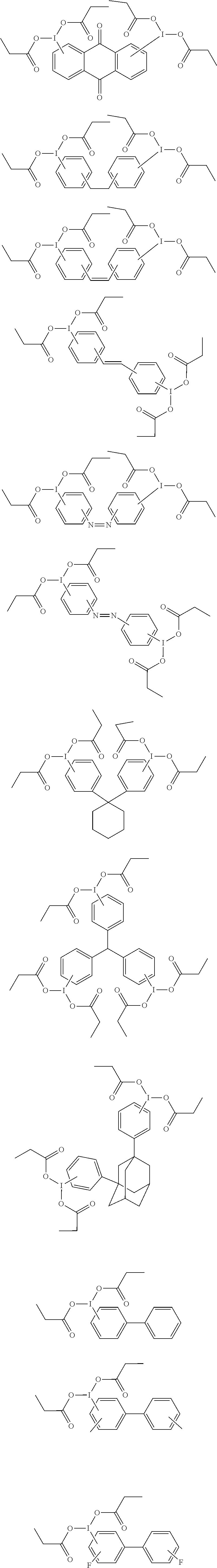

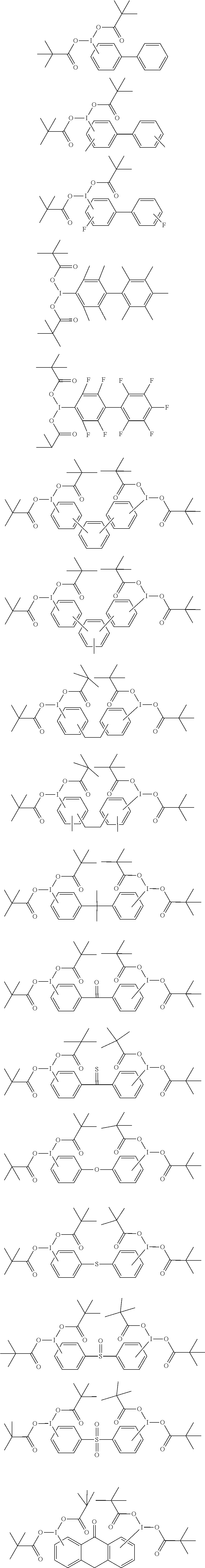

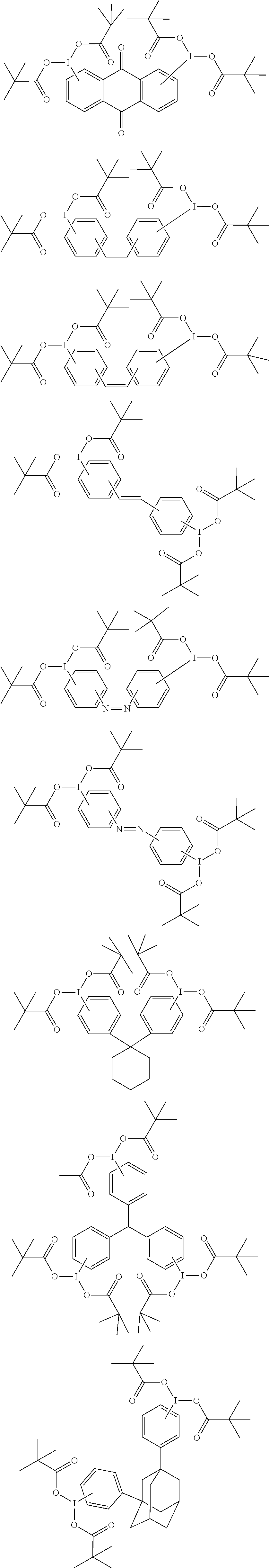

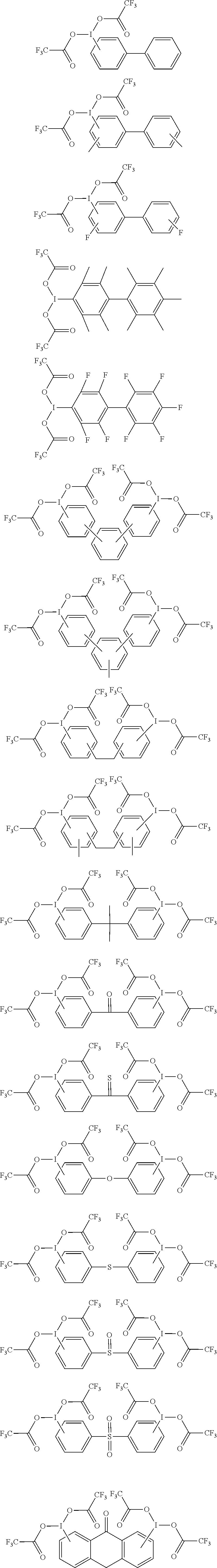

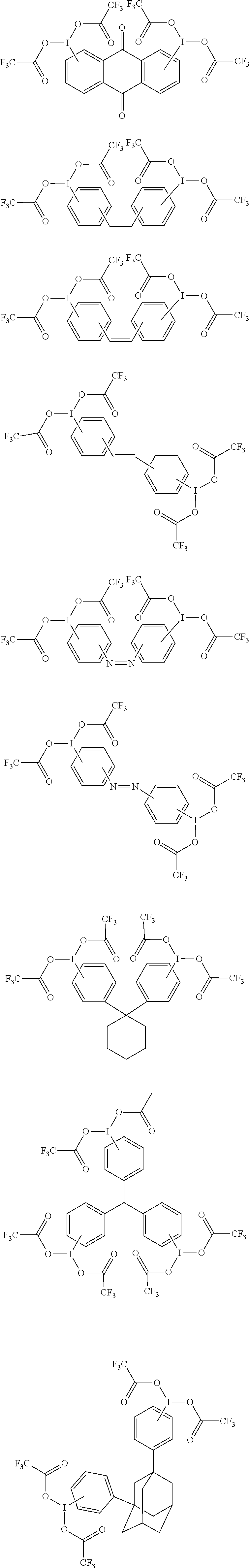

Examples of the hypervalent iodine compound having formula (4) are shown below, but not limited thereto.

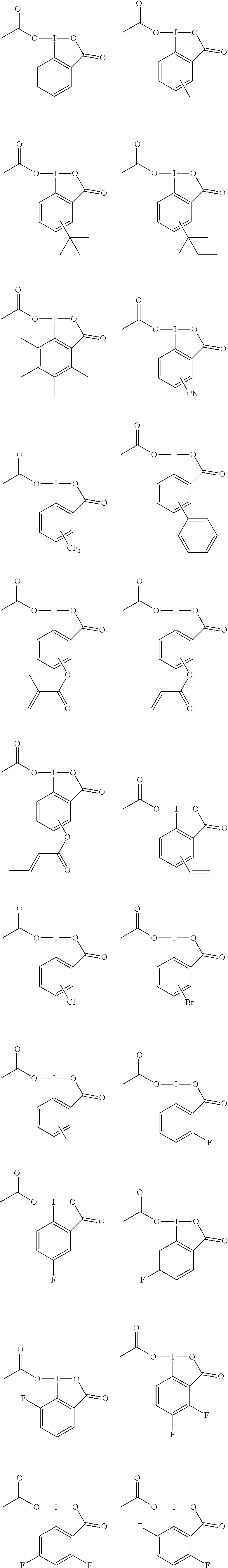

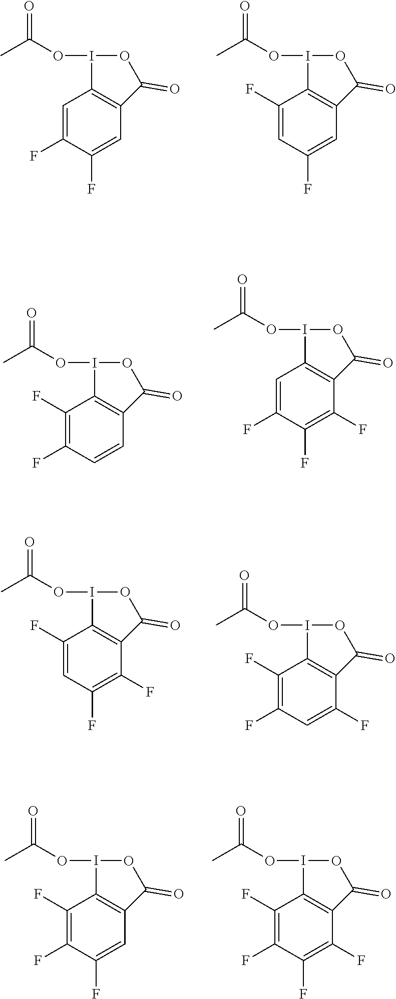

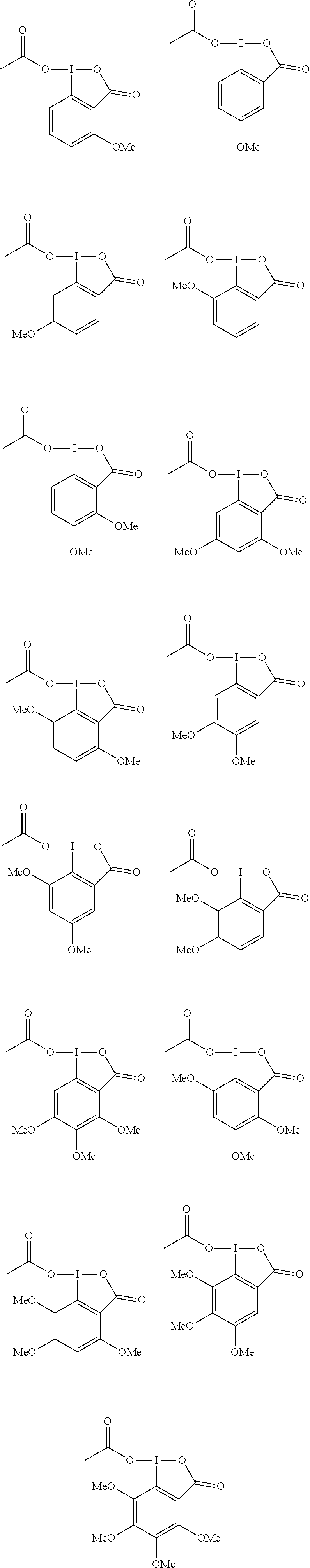

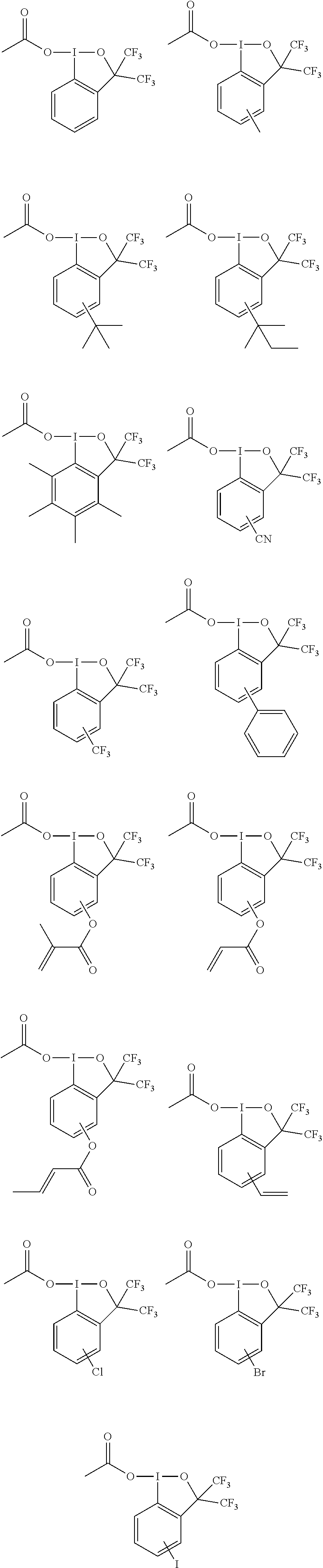

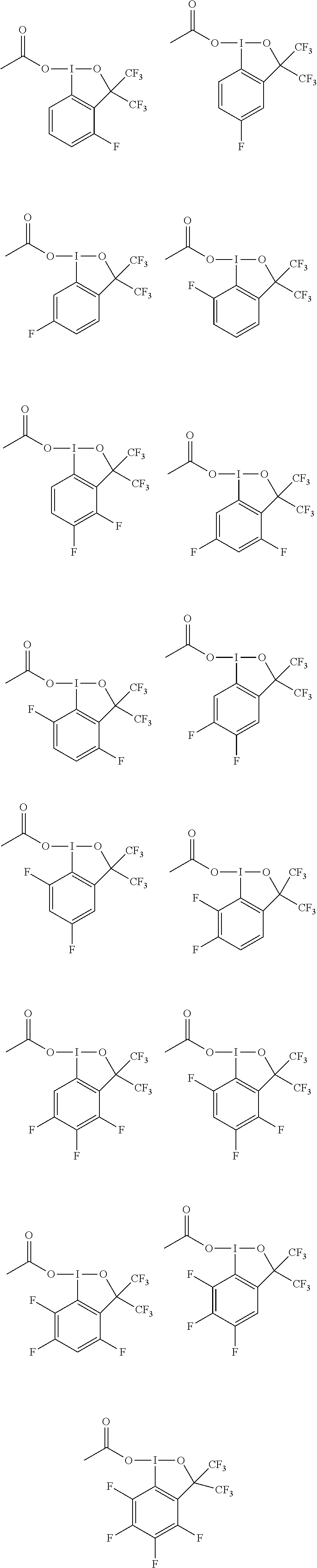

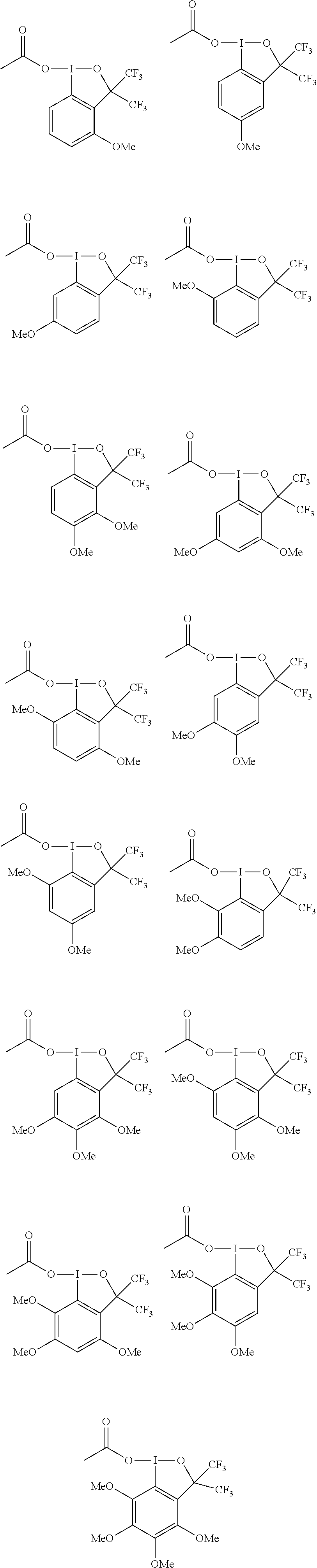

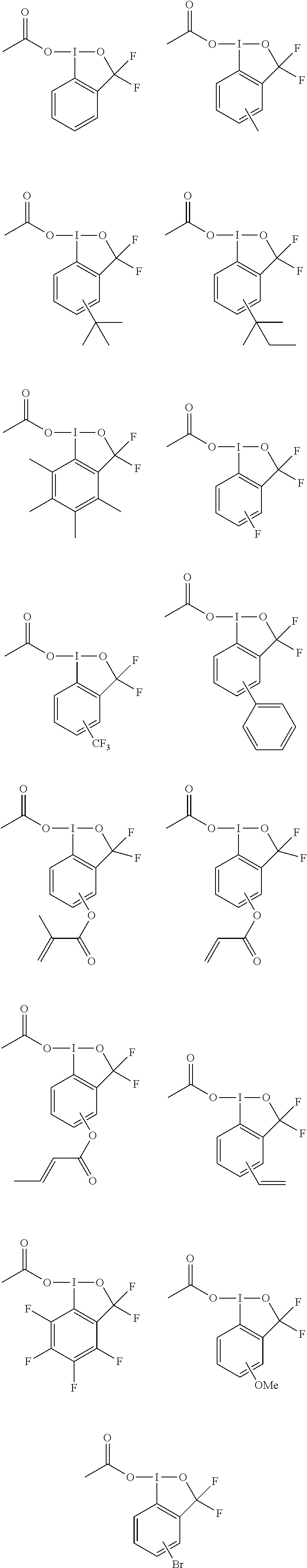

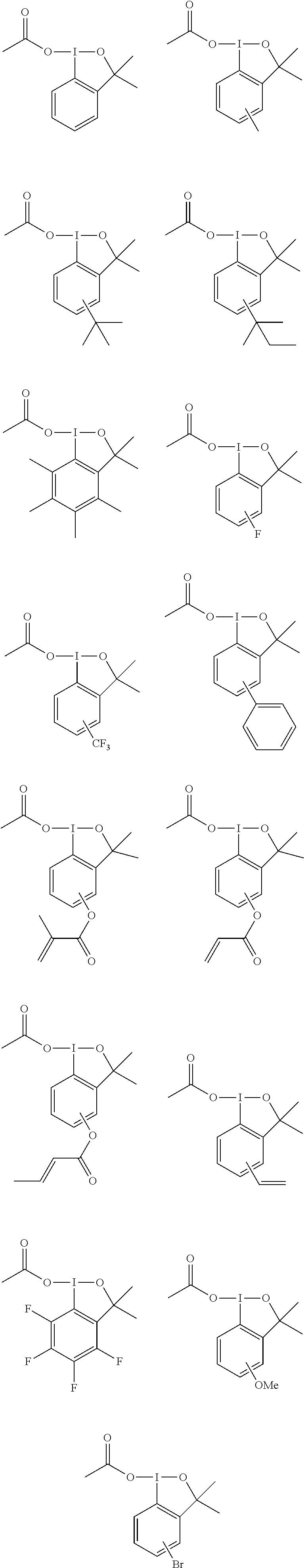

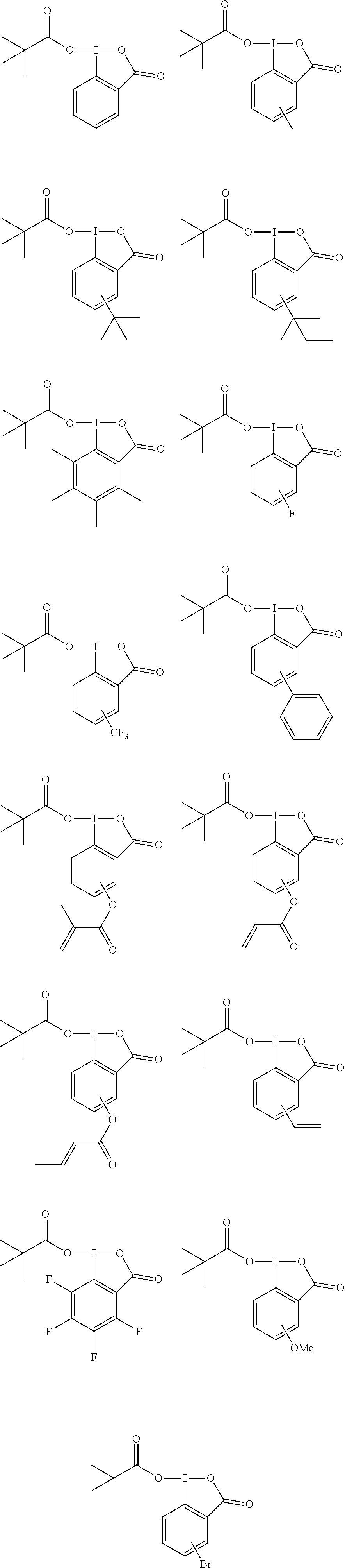

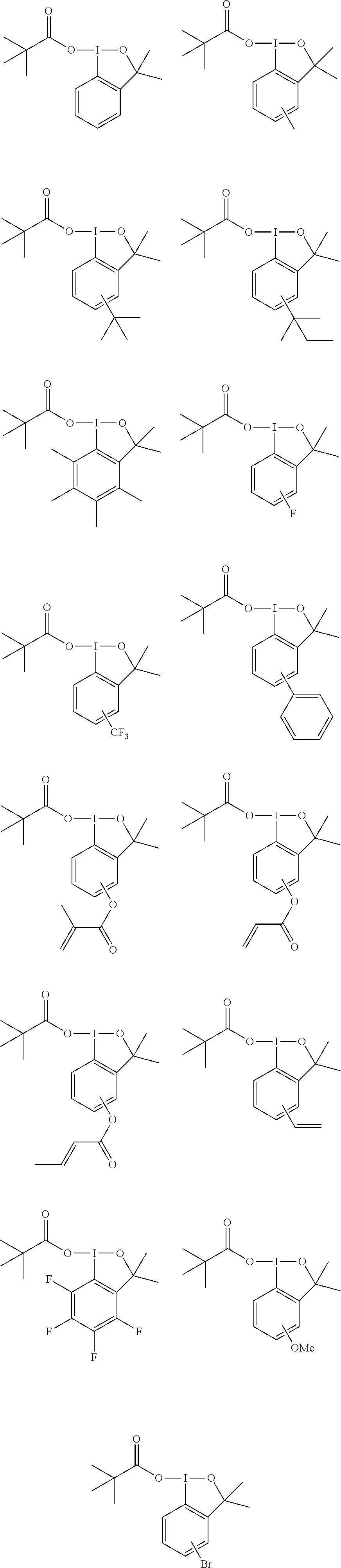

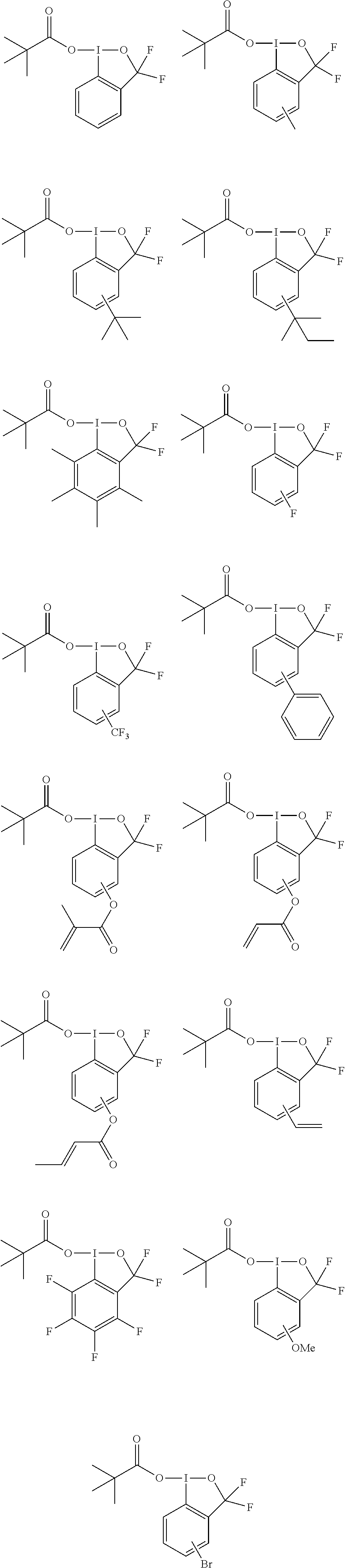

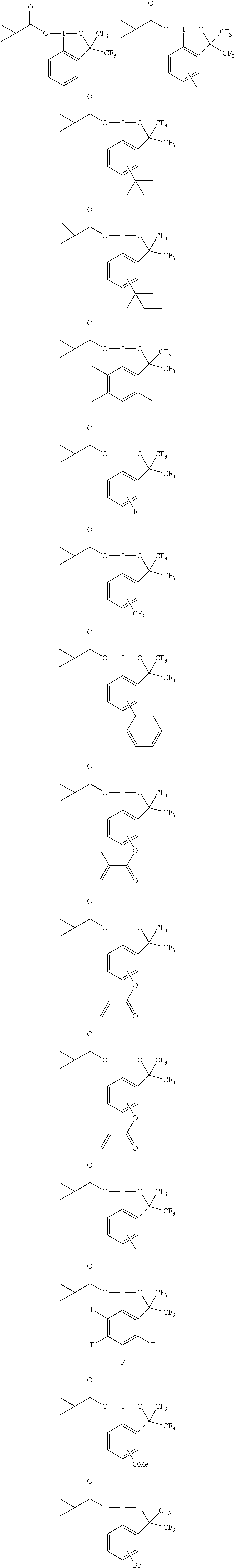

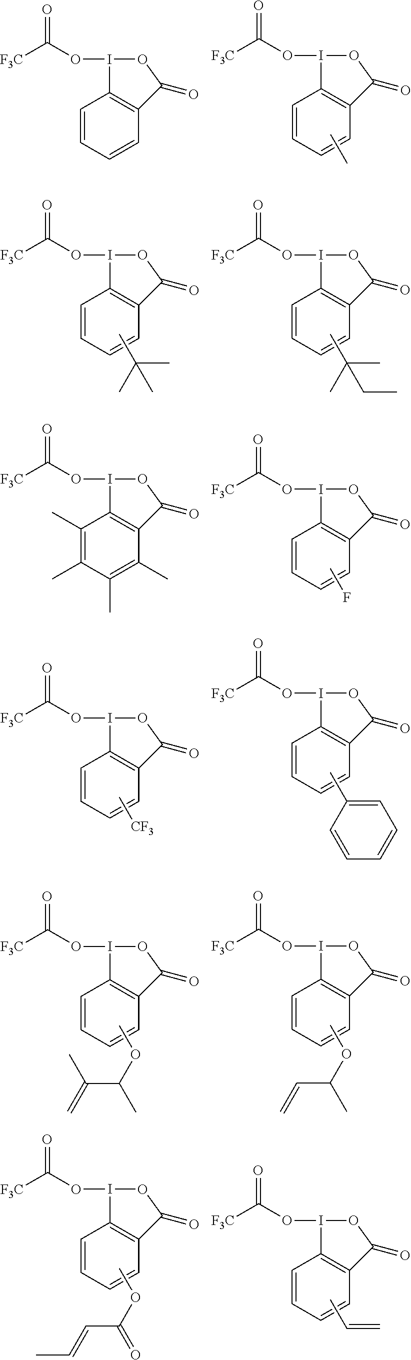

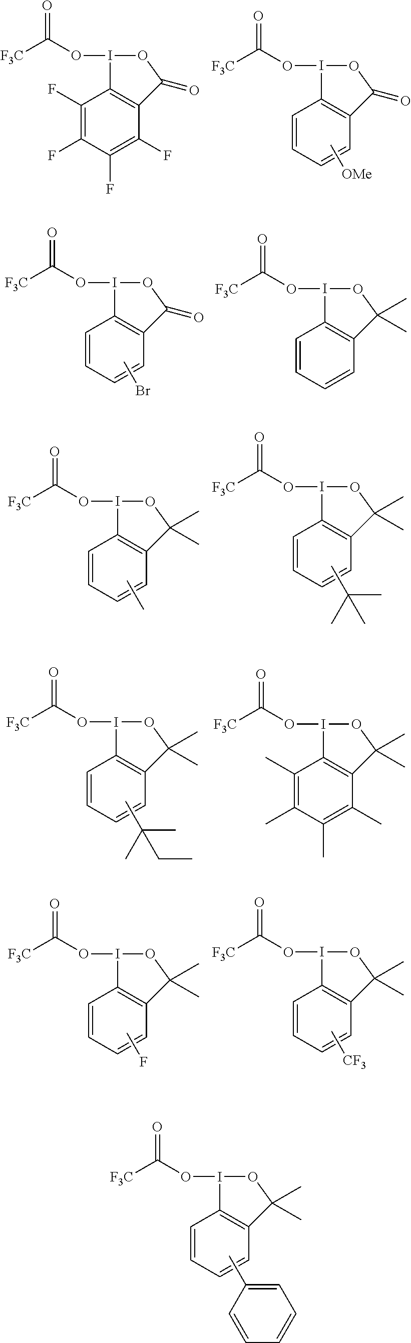

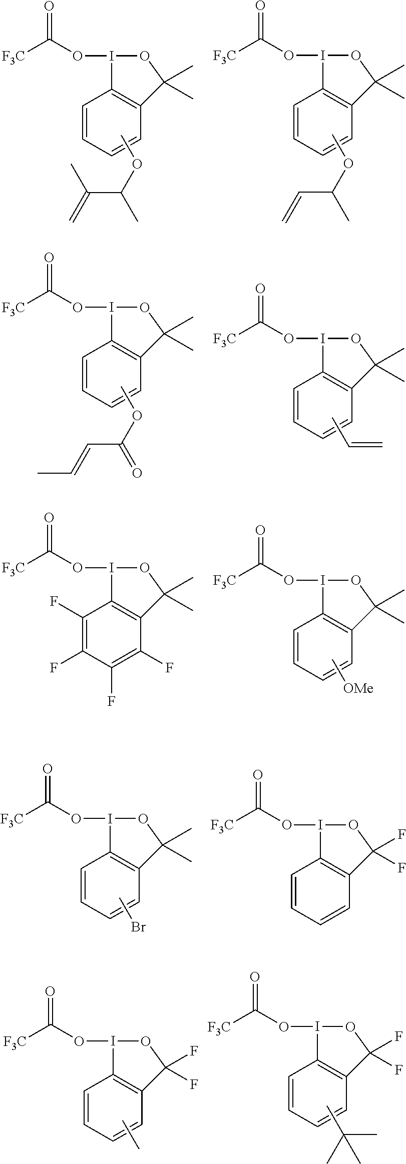

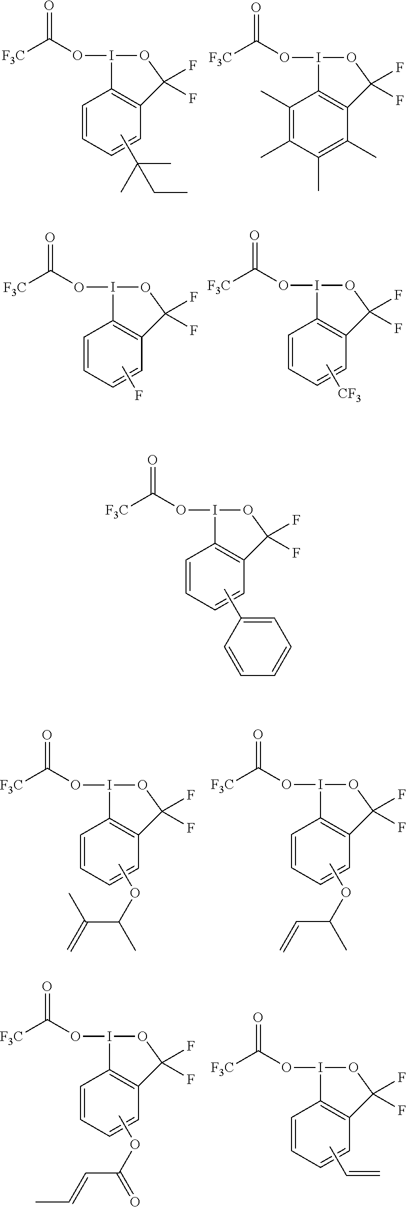

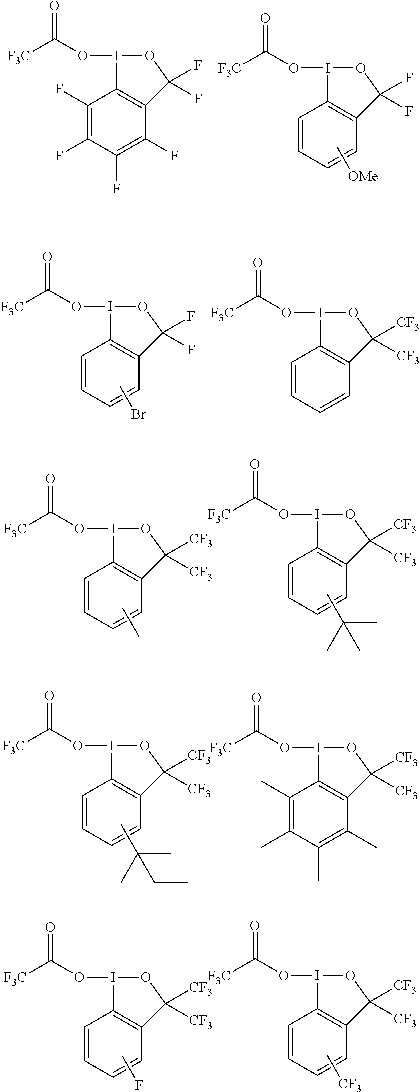

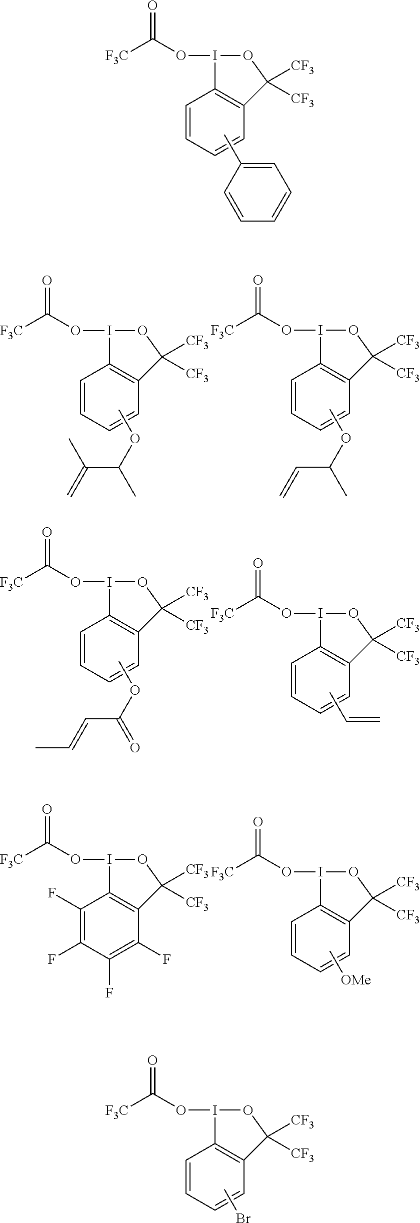

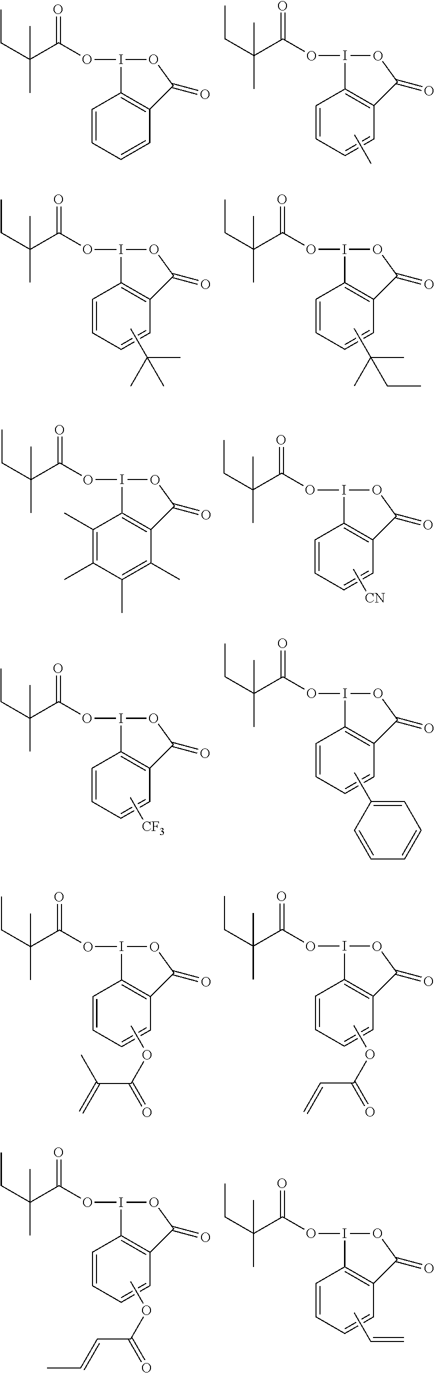

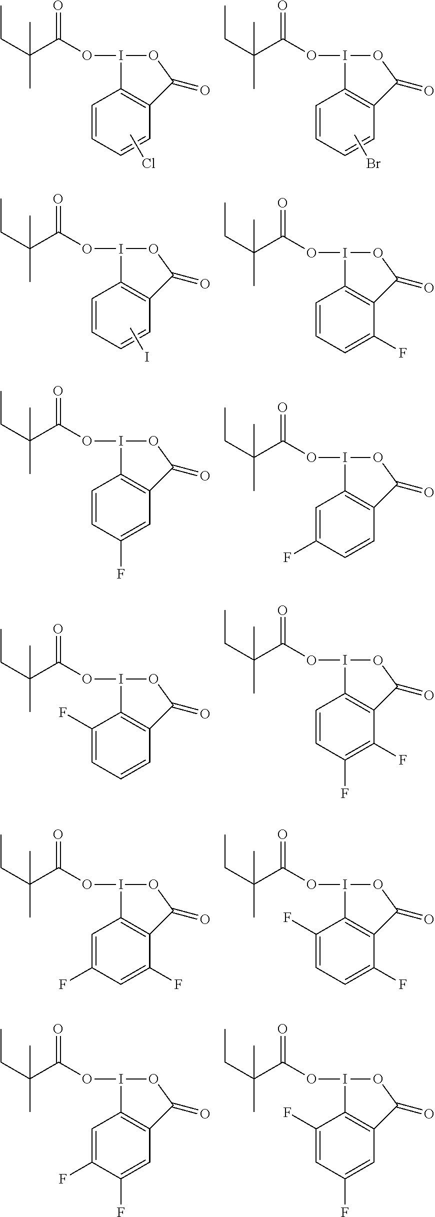

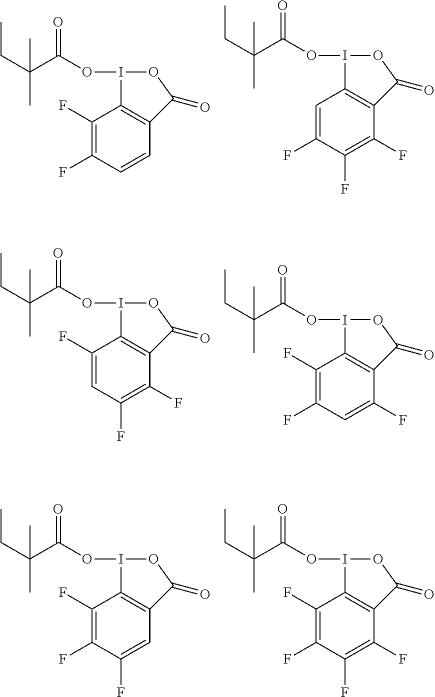

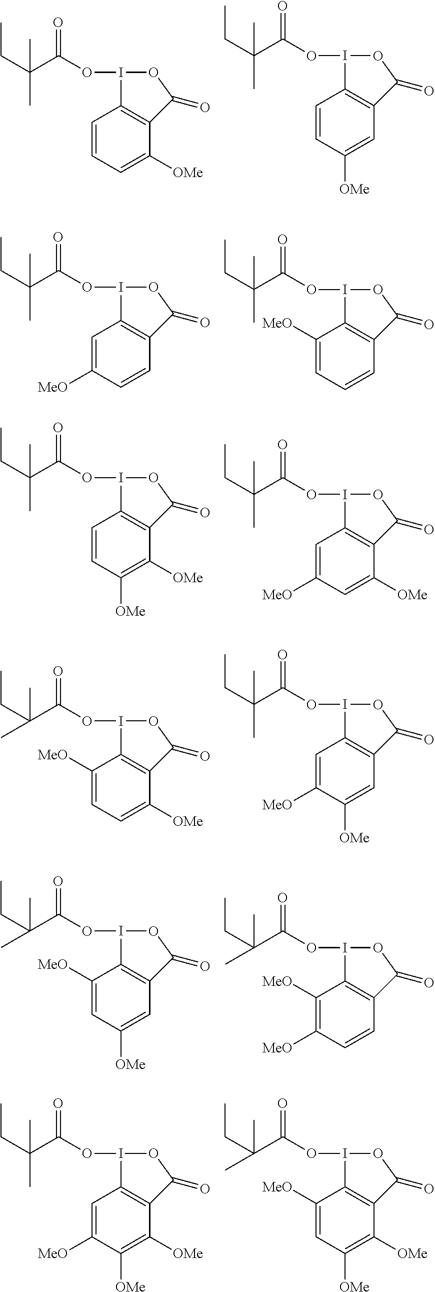

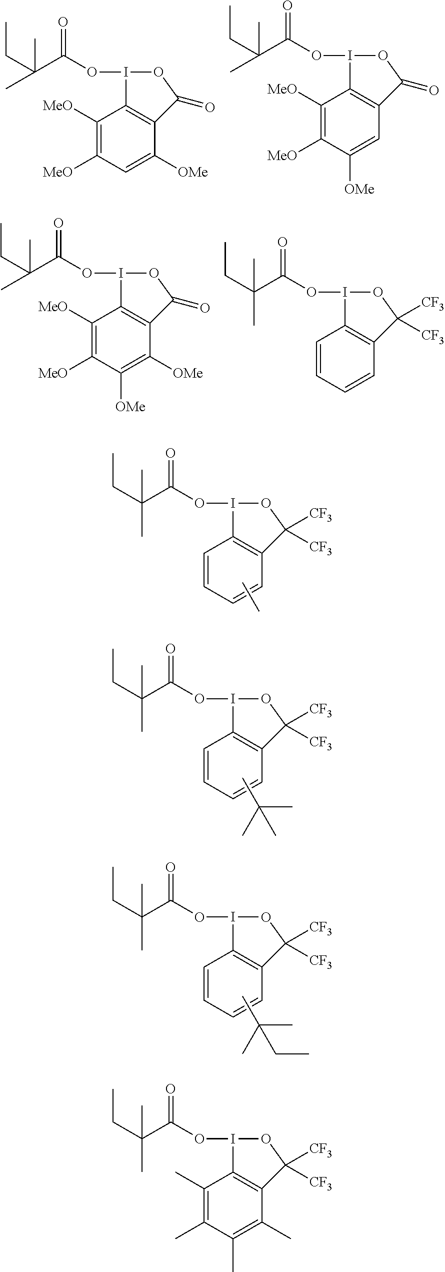

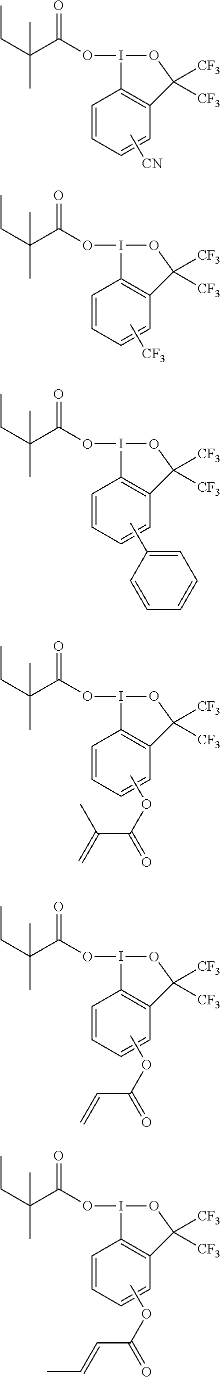

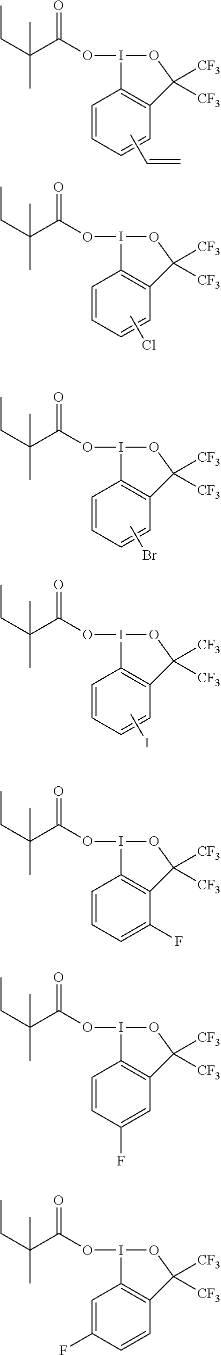

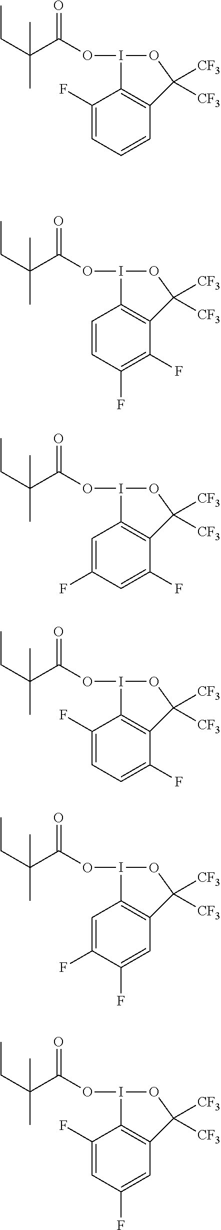

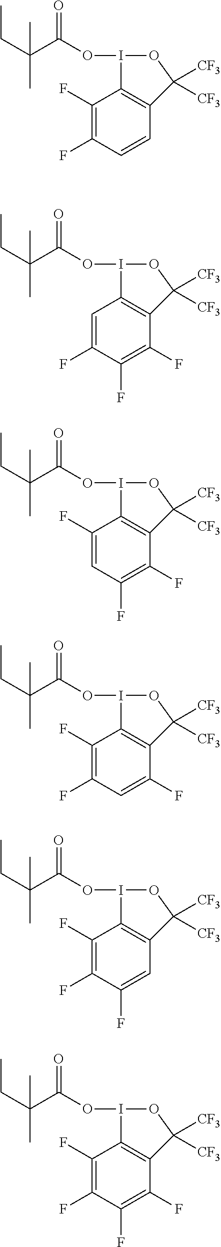

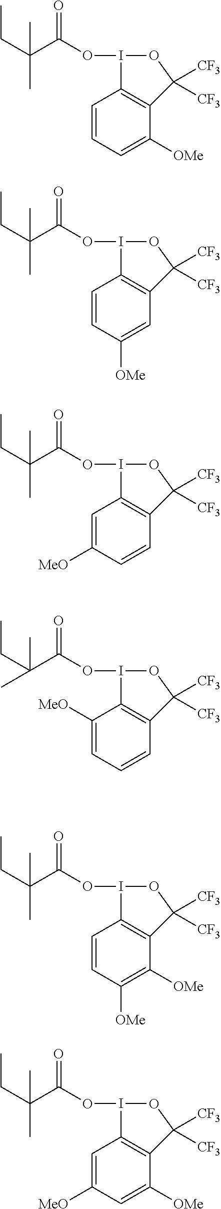 [SMILES: CCC(C)(C)C(=O)OI1OC(C(F)(F)F)(C(F)(F)F)c2c(OC)cccc21 ; CCC(C)(C)C(=O)OI1OC(C(F)(F)F)(C(F)(F)F)c2cc(OC)ccc21 ; CCC(C)(C)C(=O)OI1OC(C(F)(F)F)(C(F)(F)F)c2ccc(OC)cc21 ; CCC(C)(C)C(=O)OI1OC(C(F)(F)F)(C(F)(F)F)c2cccc(OC)c21 ; CCC(C)(C)C(=O)OI1OC(C(F)(F)F)(C(F)(F)F)c2c1ccc(OC)c2OC ; CCC(C)(C)C(=O)OI1OC(C(F)(F)F)(C(F)(F)F)c2c(OC)cc(OC)cc21]

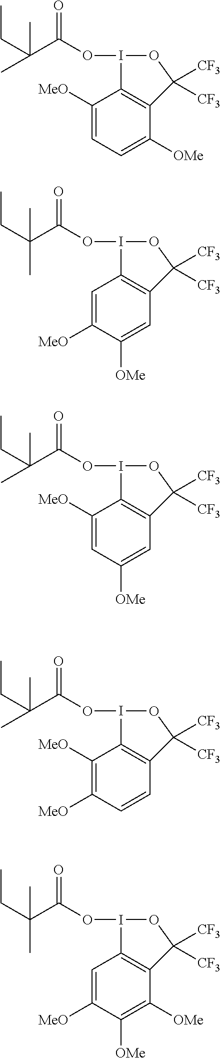 [SMILES: CCC(C)(C)C(=O)OI1OC(C(F)(F)F)(C(F)(F)F)c2c(OC)ccc(OC)c21 ; CCC(C)(C)C(=O)OI1OC(C(F)(F)F)(C(F)(F)F)c2cc(OC)c(OC)cc21 ; CCC(C)(C)C(=O)OI1OC(C(F)(F)F)(C(F)(F)F)c2cc(OC)cc(OC)c21 ; CCC(C)(C)C(=O)OI1OC(C(F)(F)F)(C(F)(F)F)c2ccc(OC)c(OC)c21 ; CCC(C)(C)C(=O)OI1OC(C(F)(F)F)(C(F)(F)F)c2c1cc(OC)c(OC)c2OC]

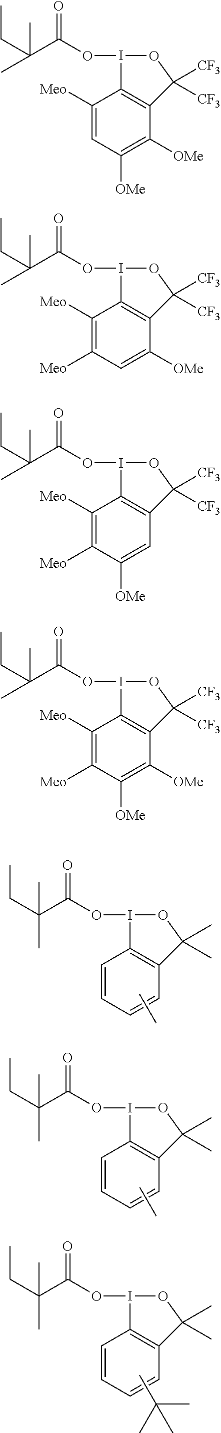

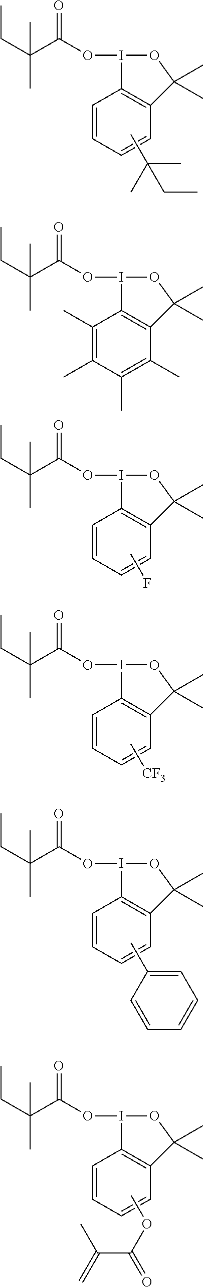

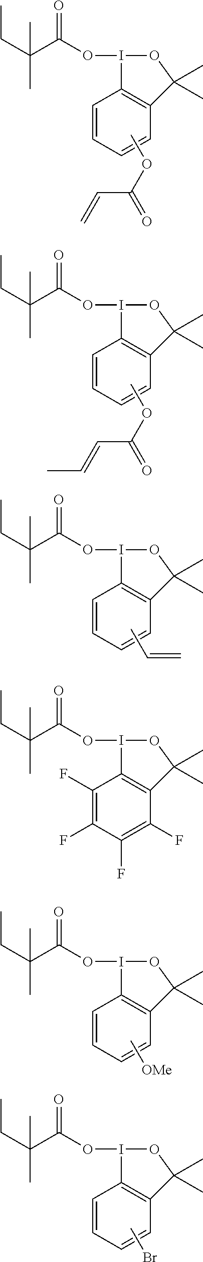

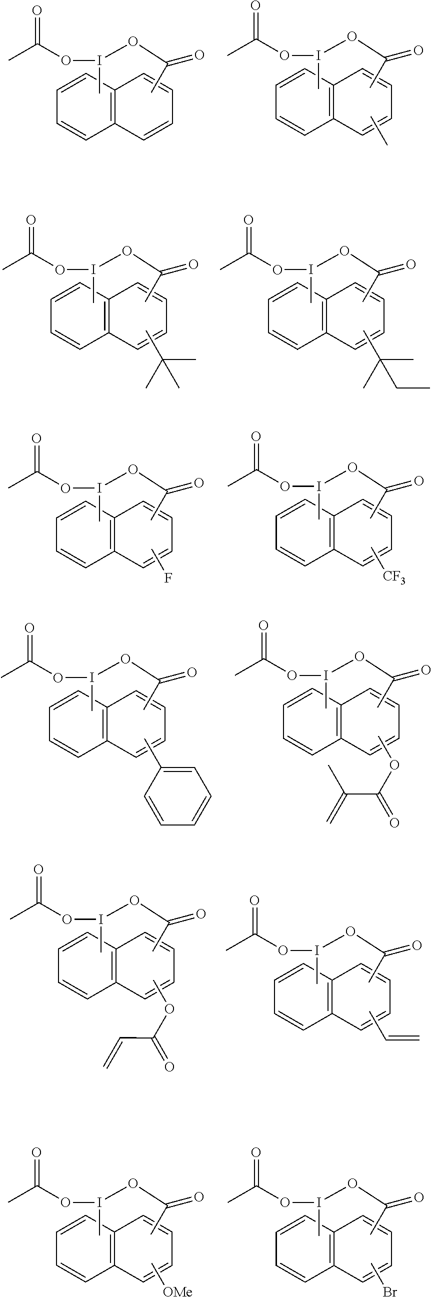

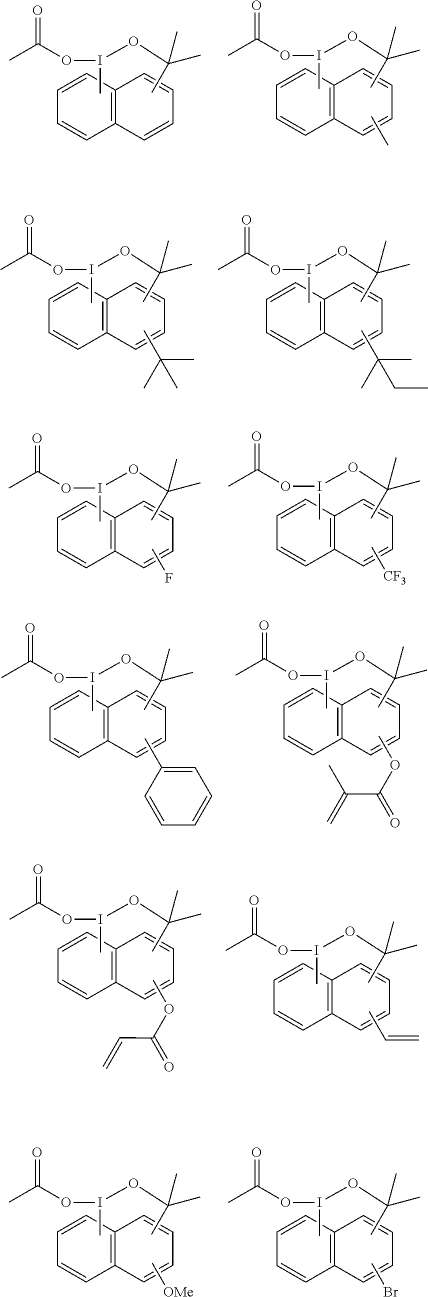

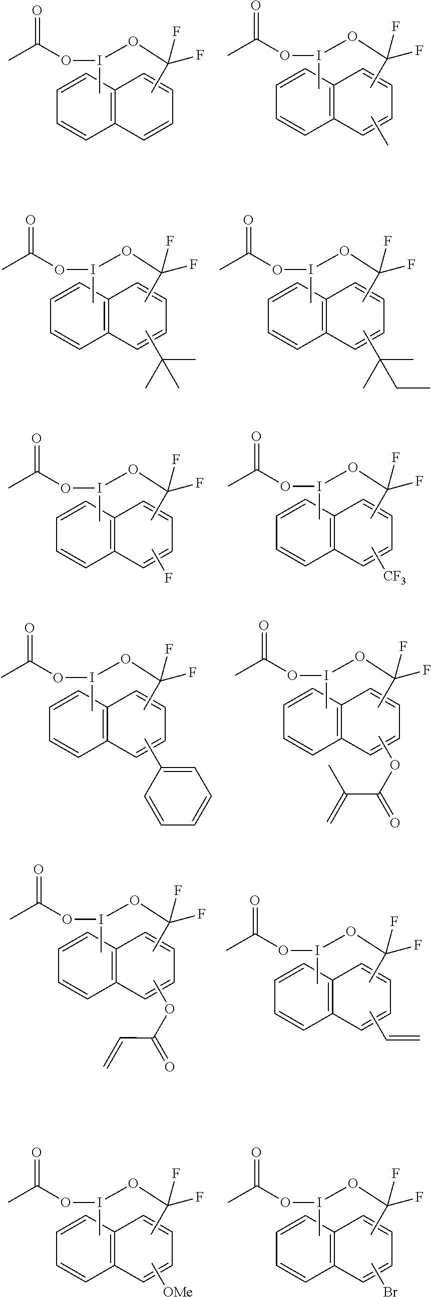

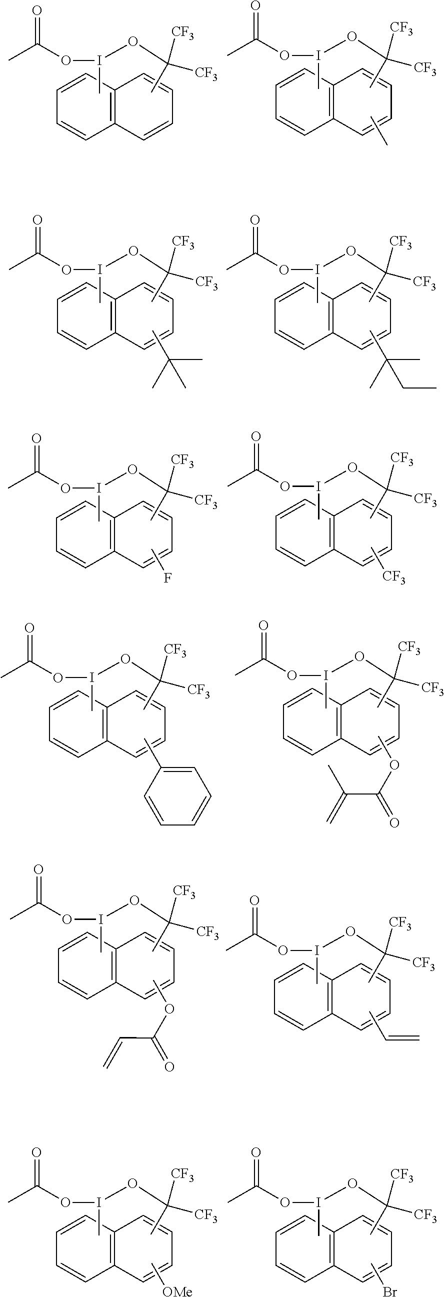

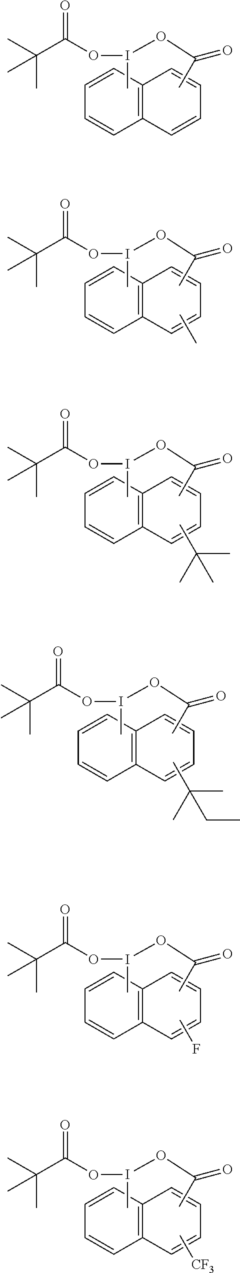

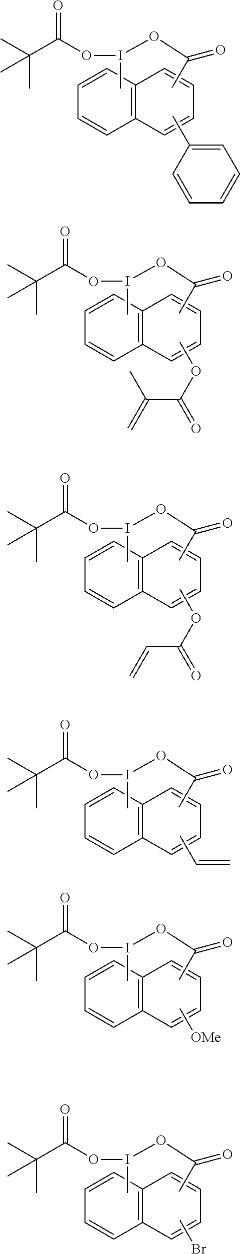

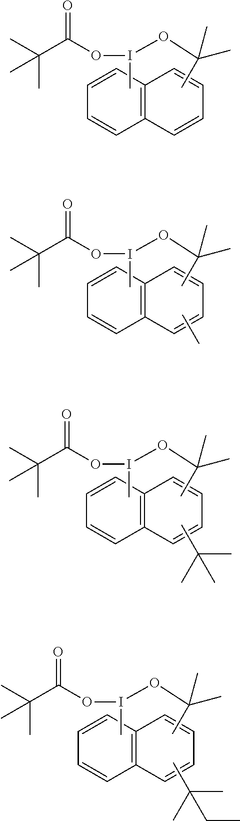

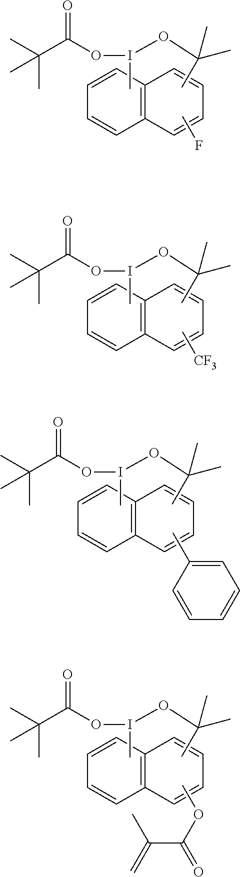

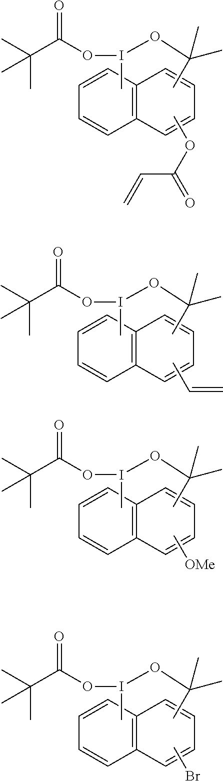

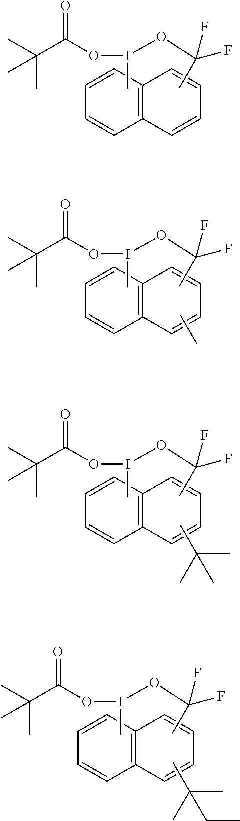

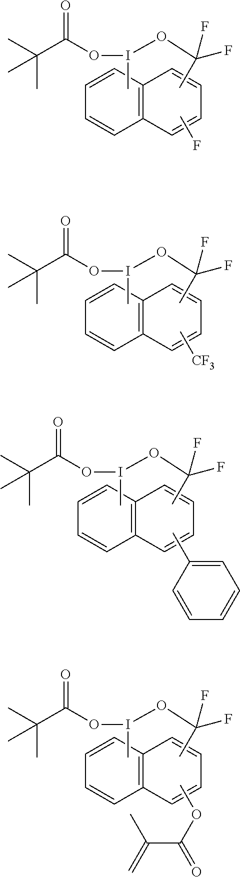

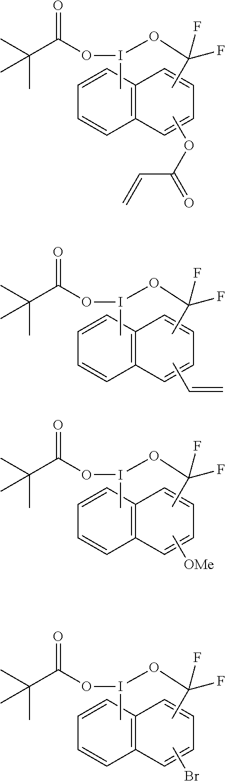

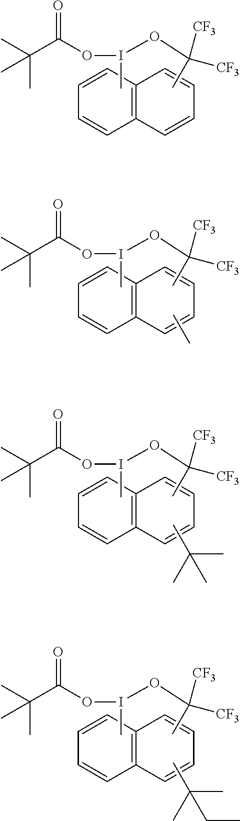

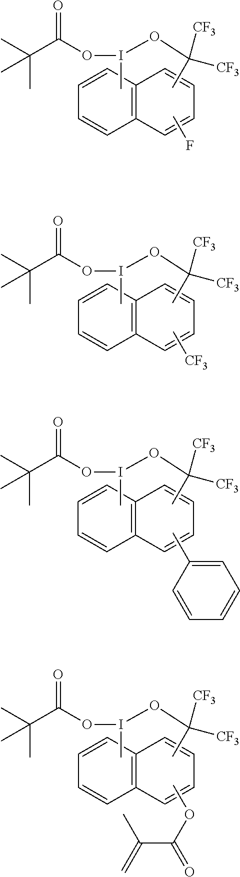

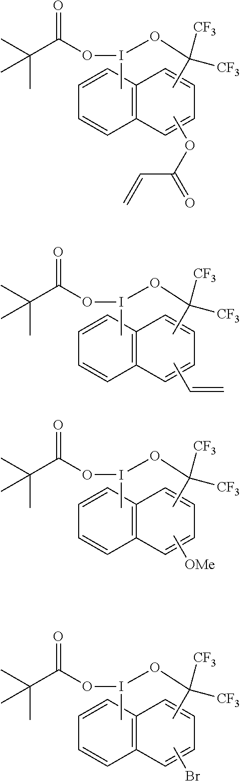

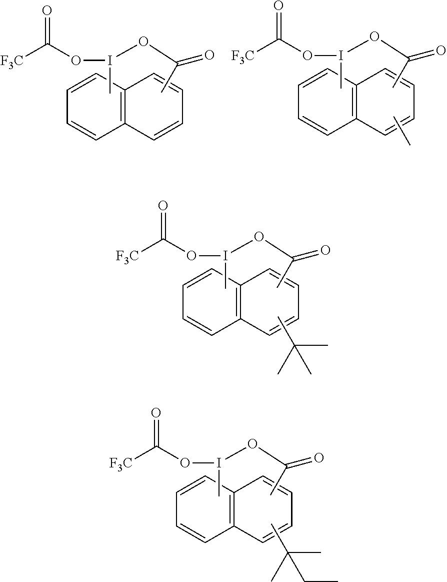

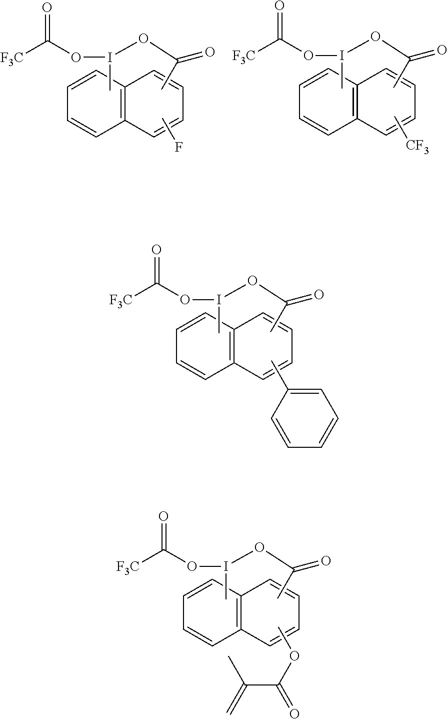

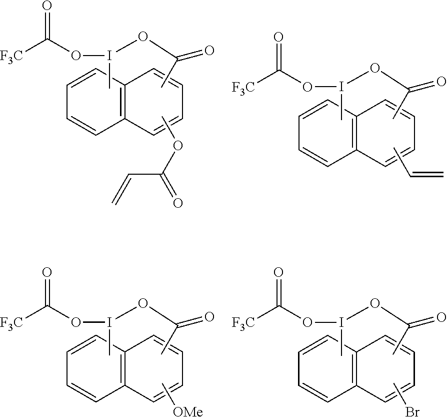

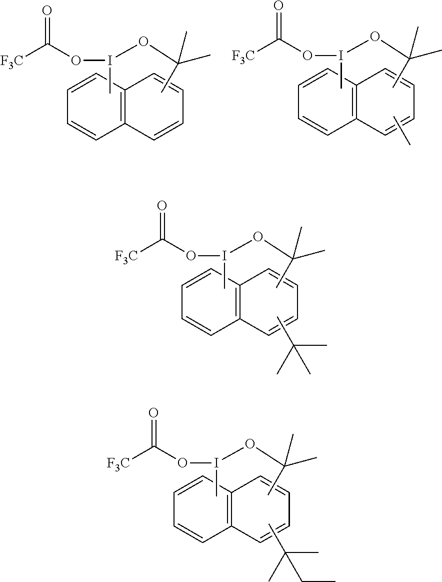

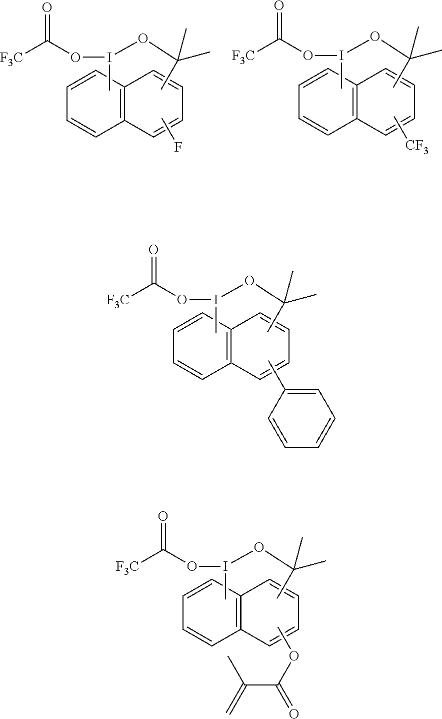

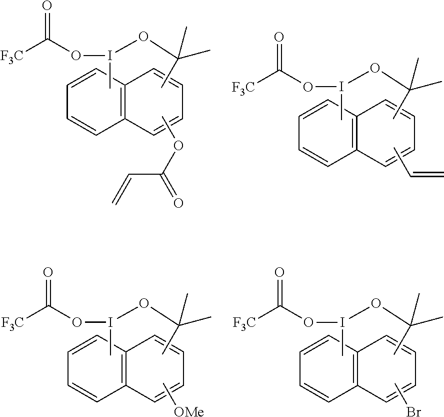

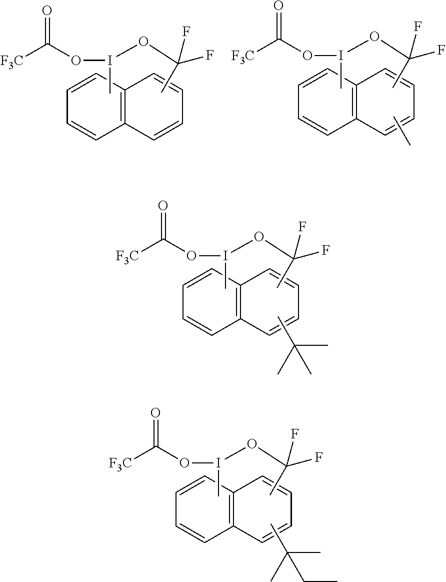

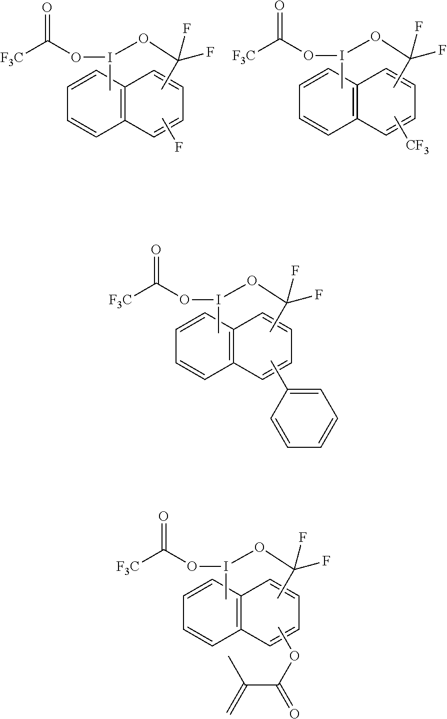

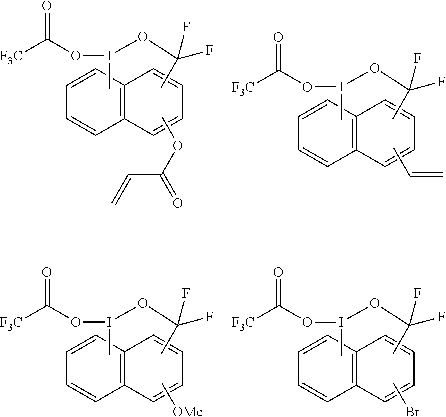

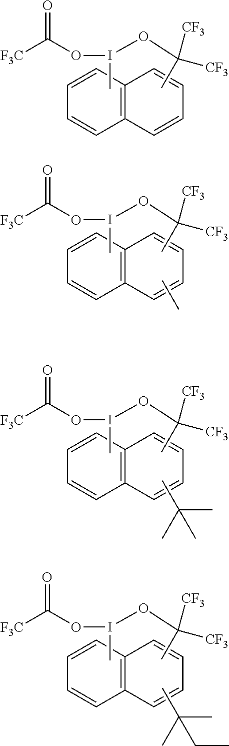

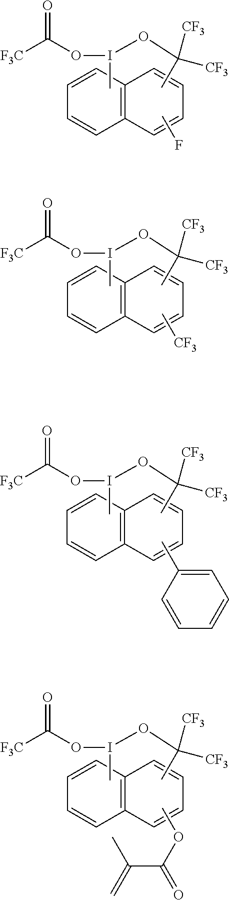

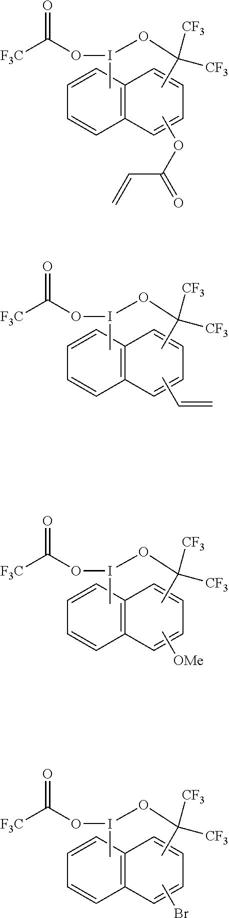

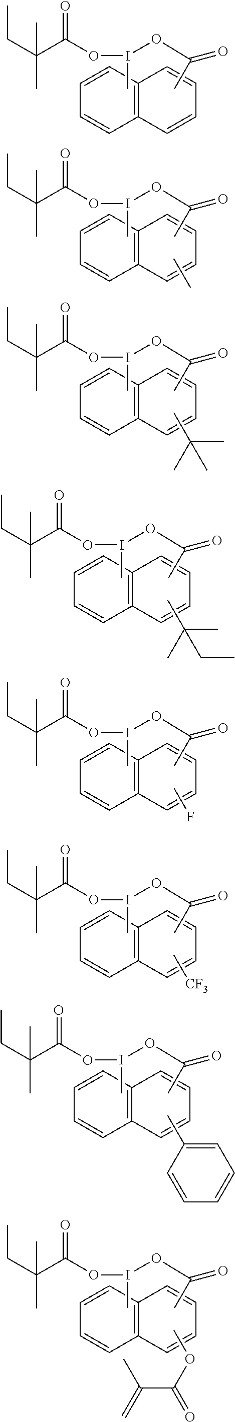

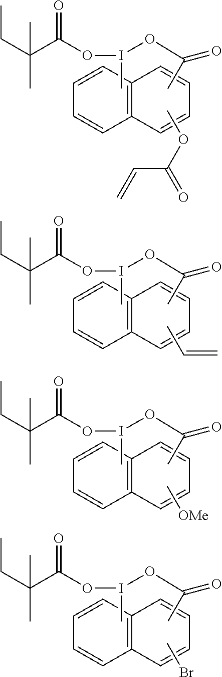

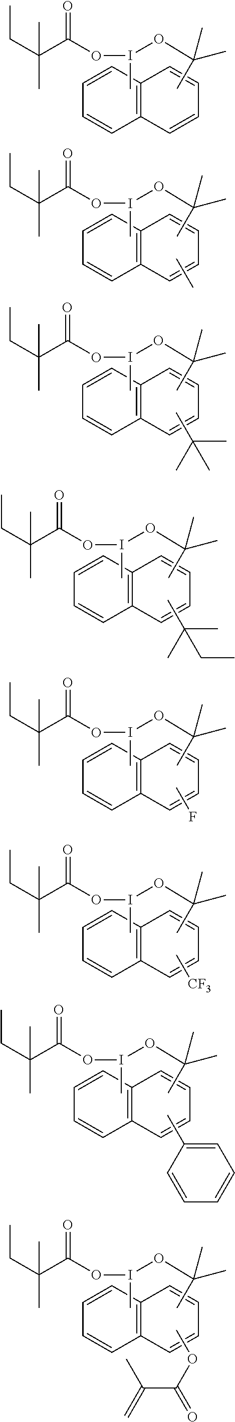

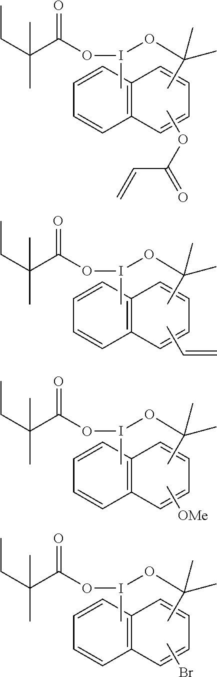

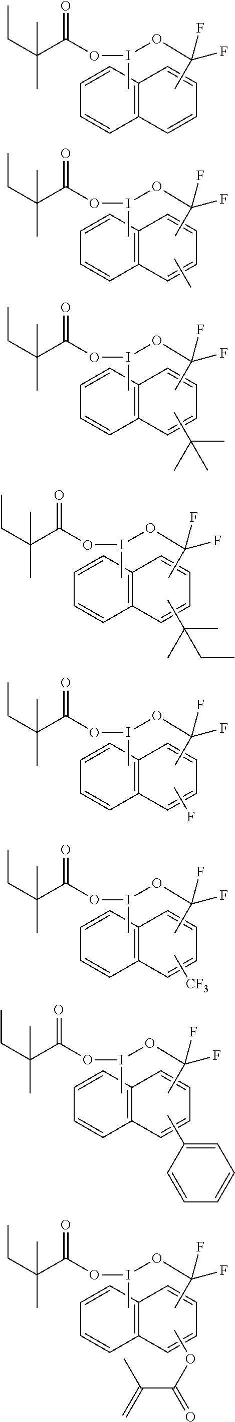

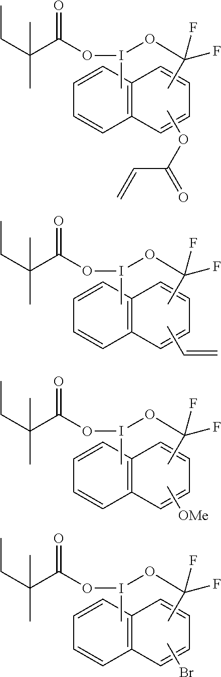

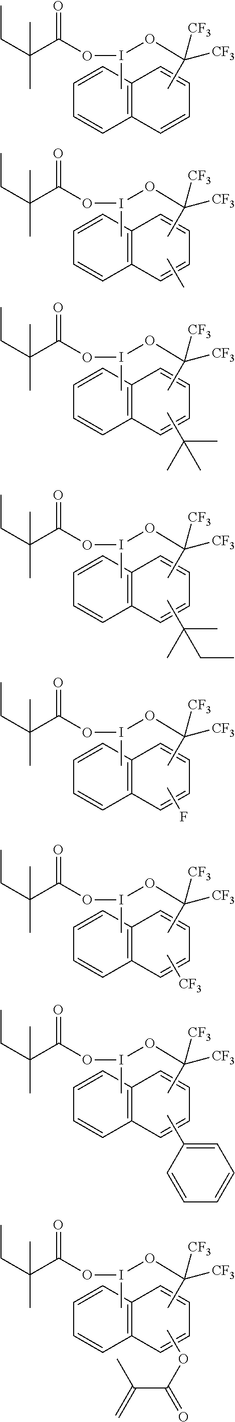

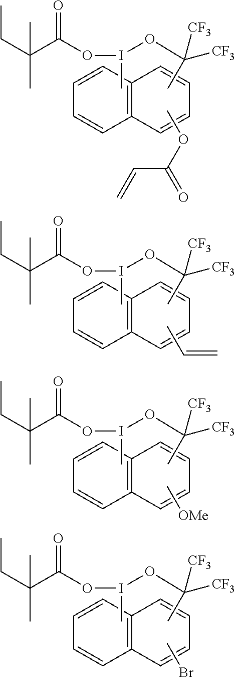

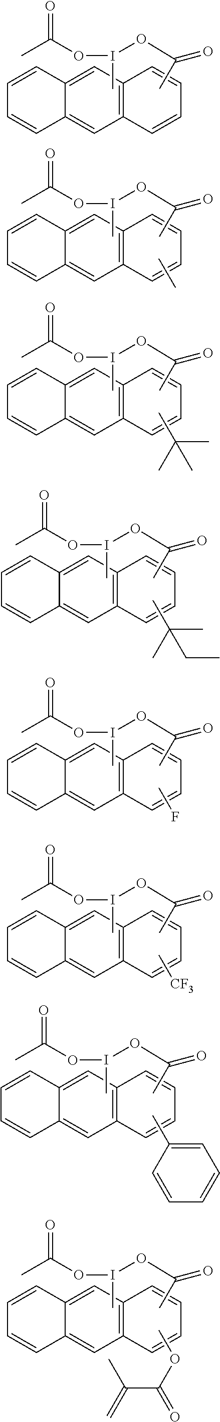

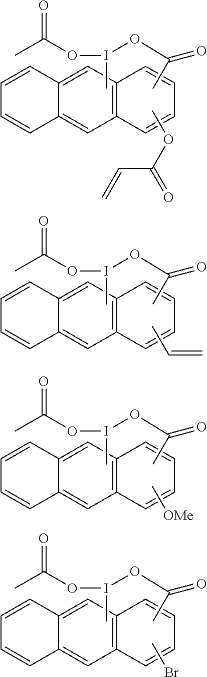

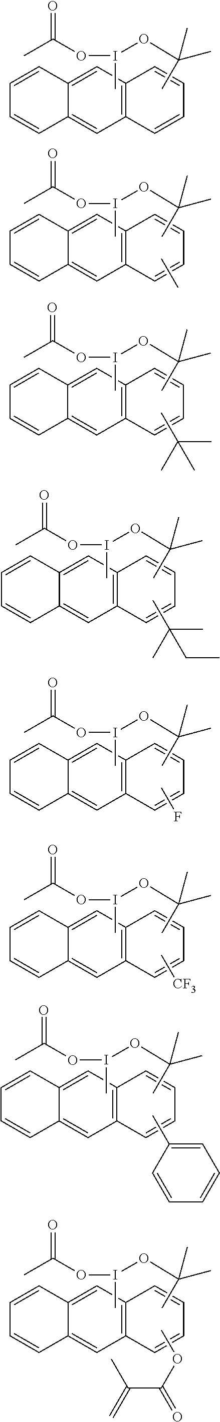

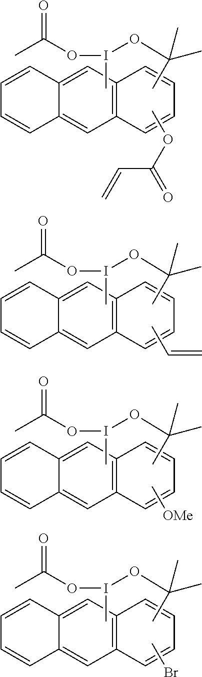

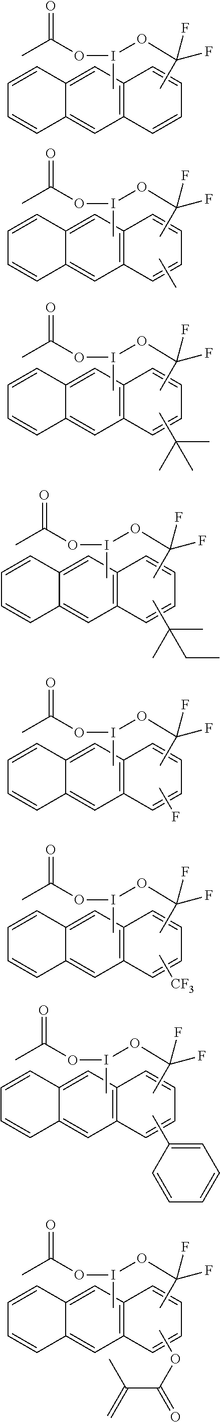

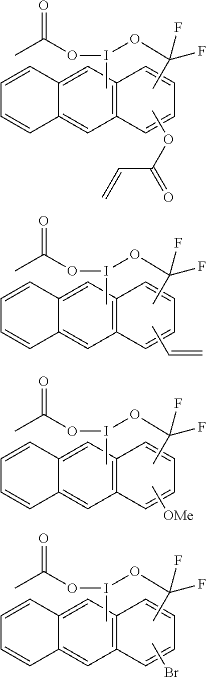

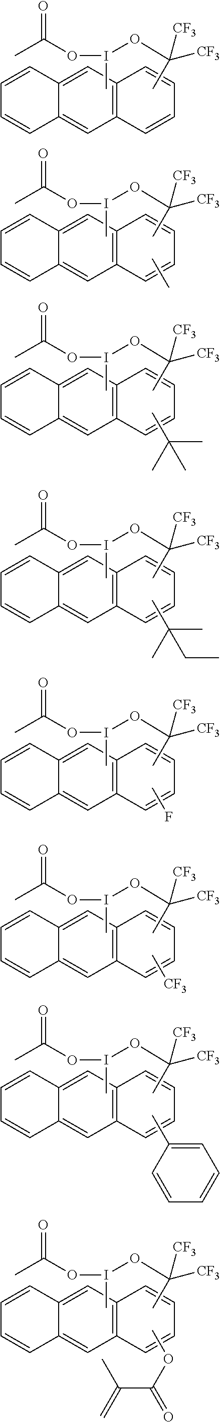

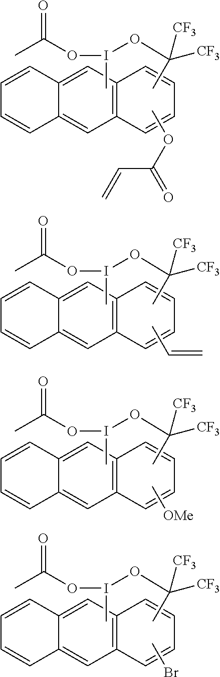

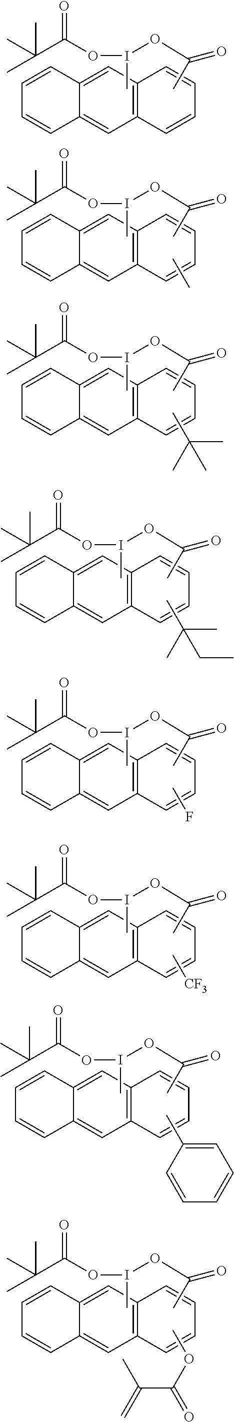

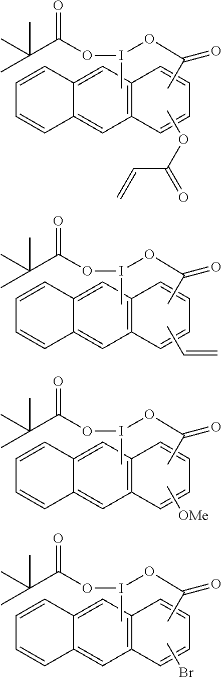

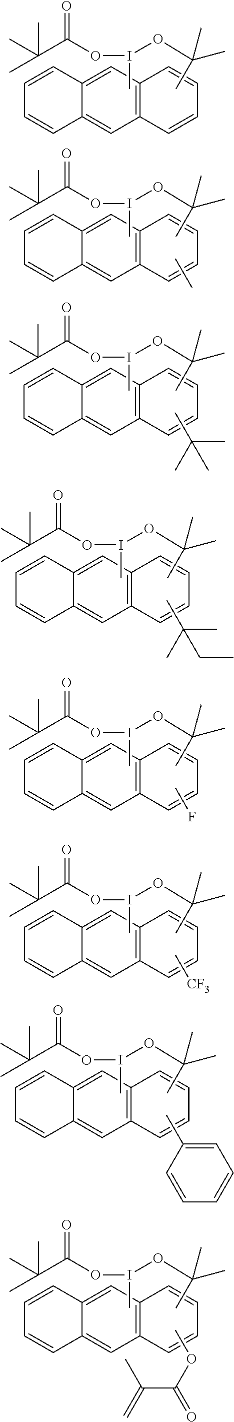

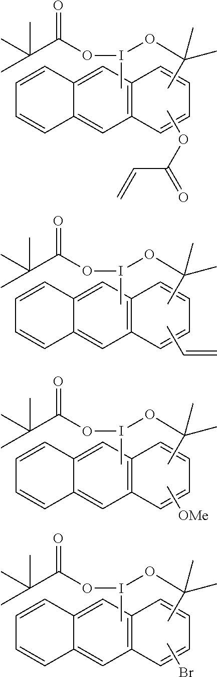

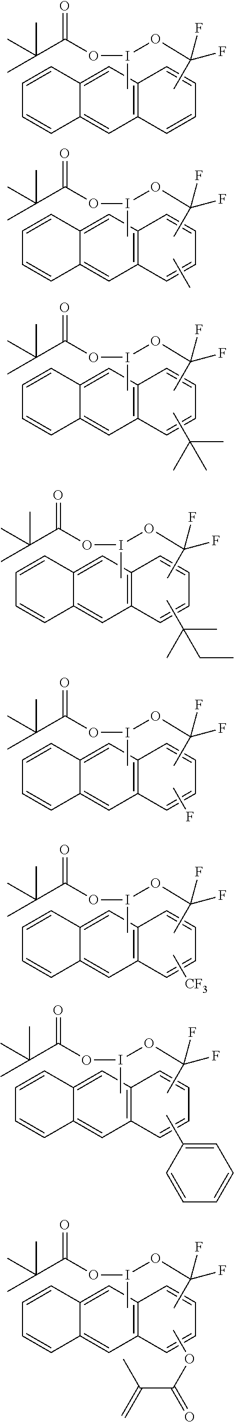

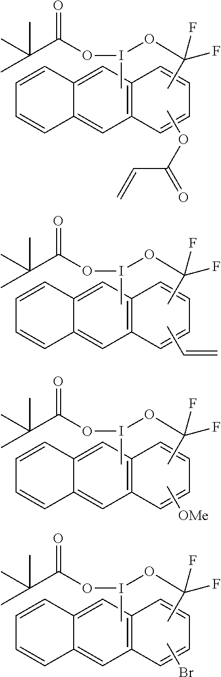

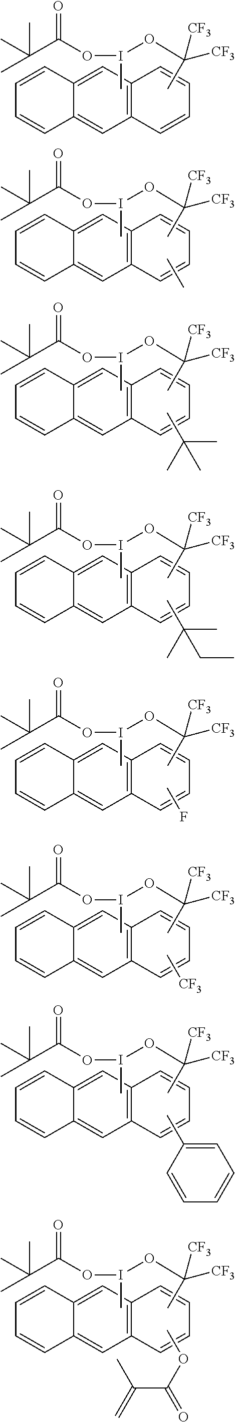

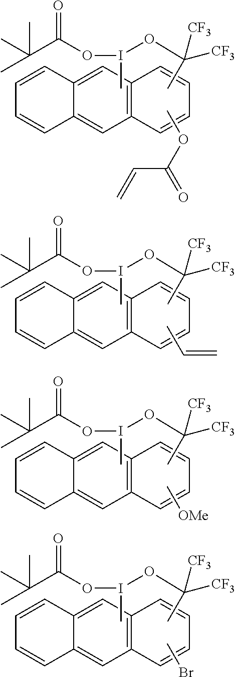

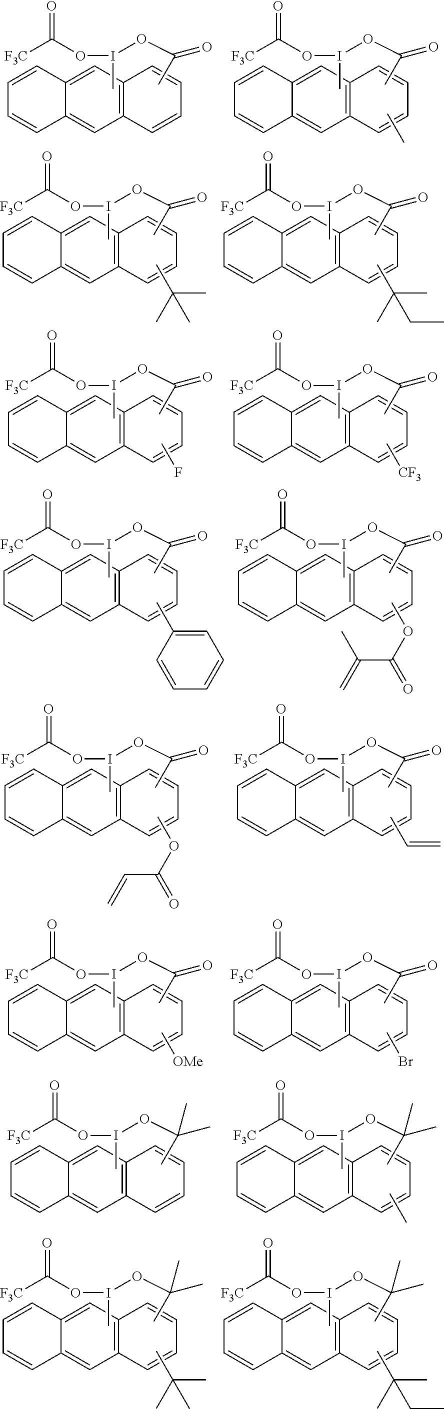

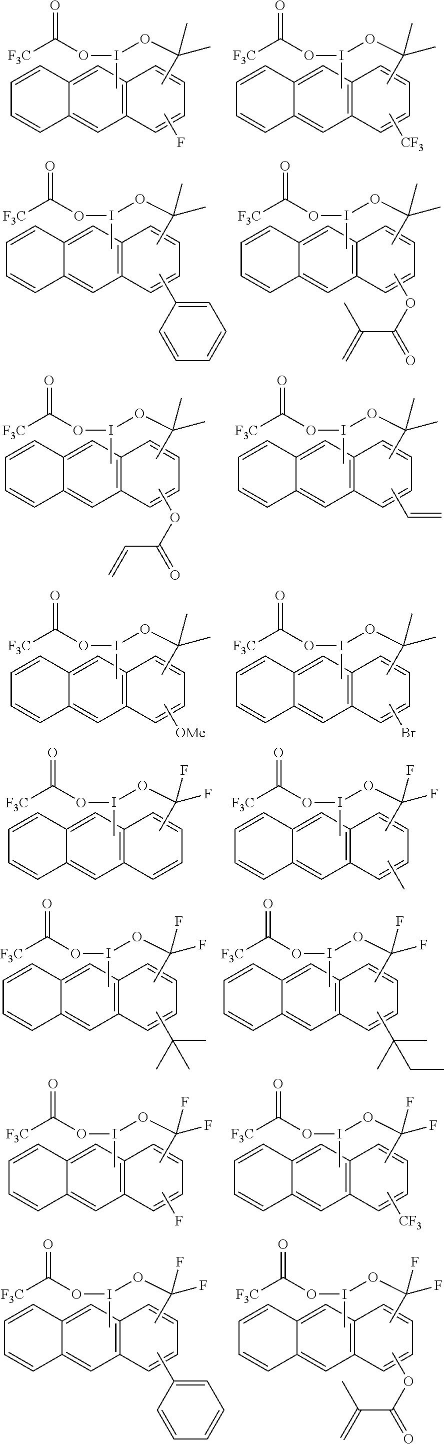

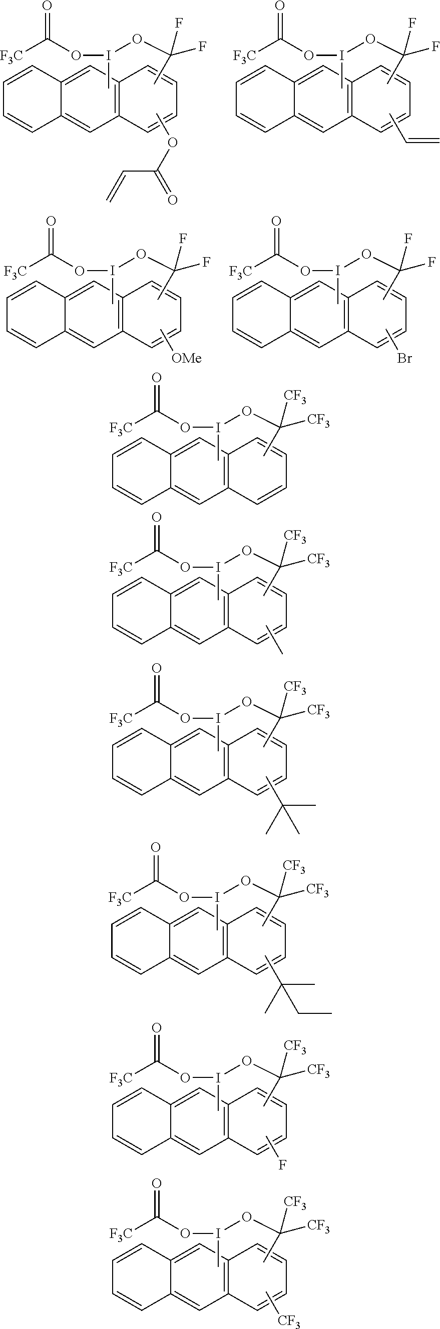

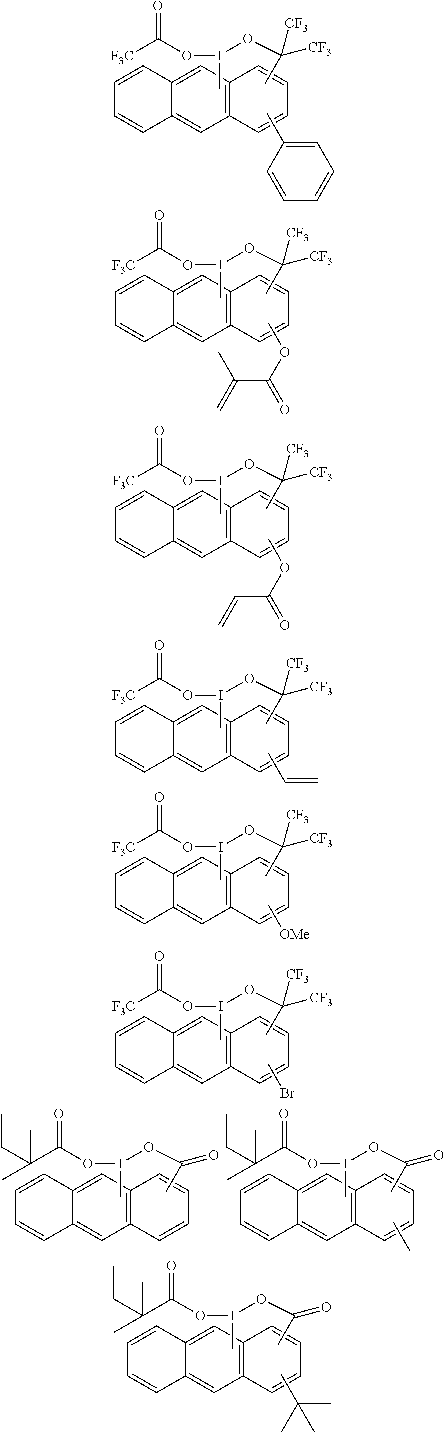

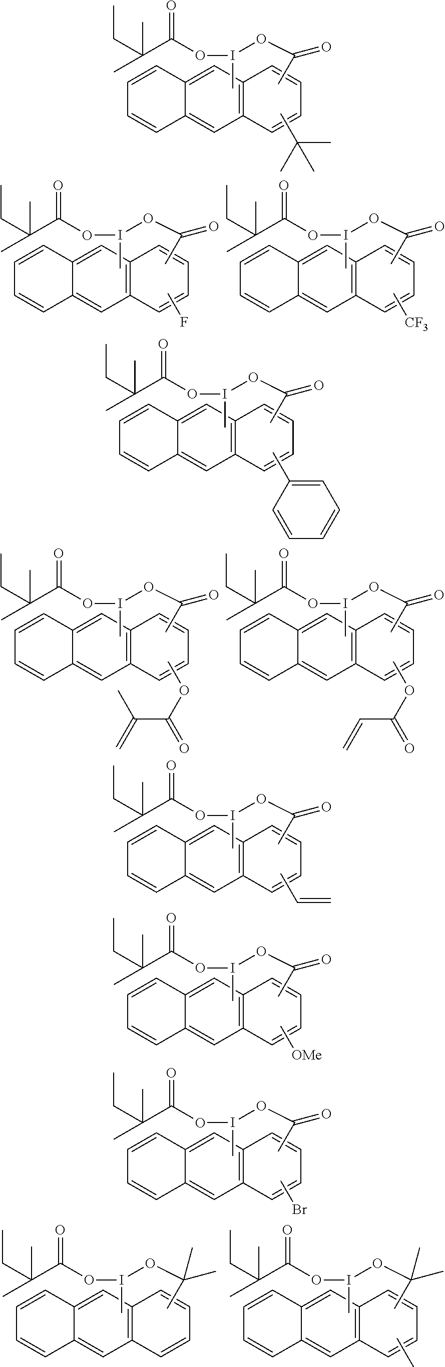

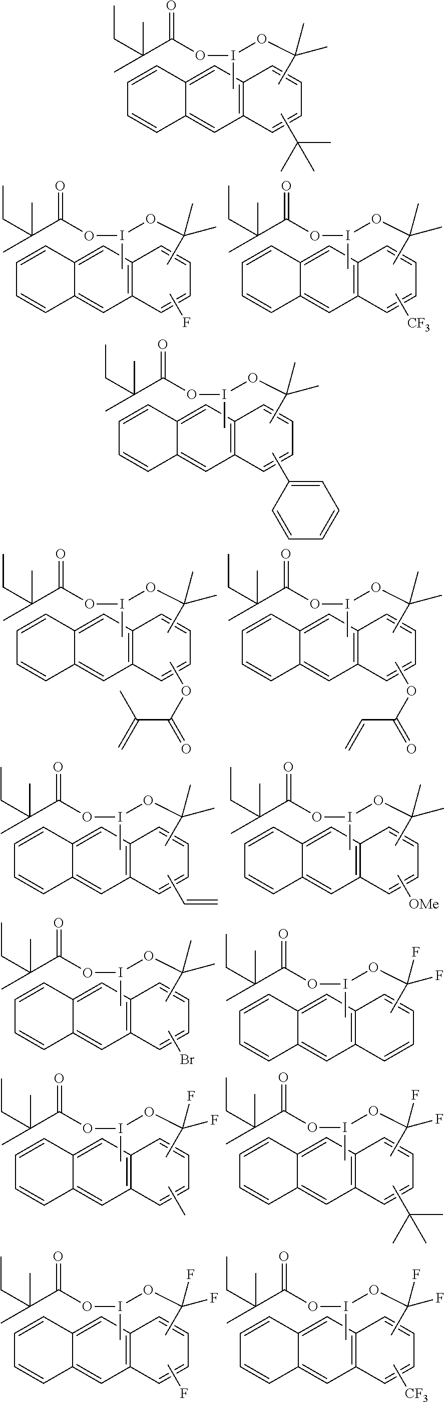

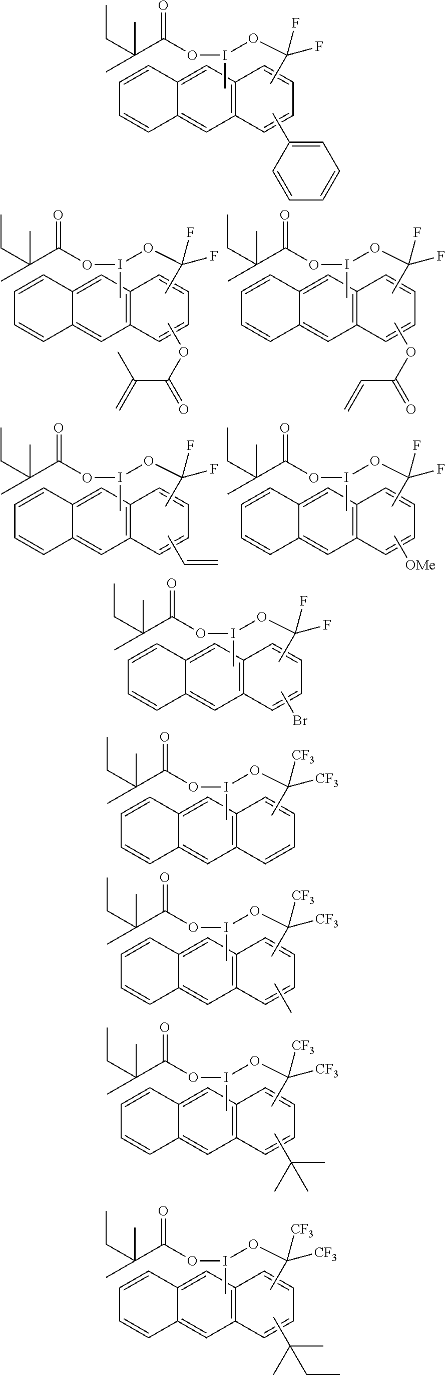

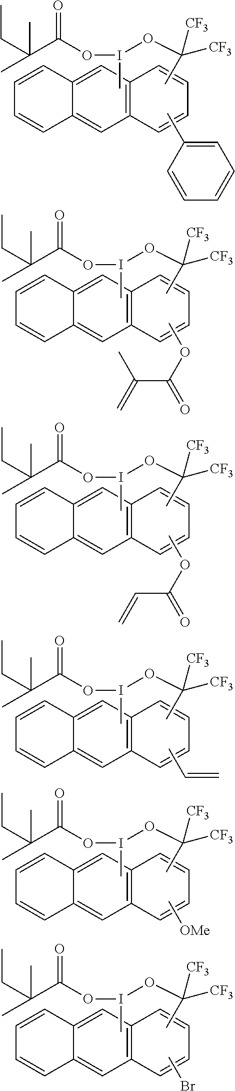

### [Carboxylic Acid Derivative]

The carboxylic acid derivative is a carboxylic acid derivative having the formula (5) or a polymer comprising carboxylic acid derivative repeat units having the formula (6), which is also referred to as carboxylic acid derivative-containing polymer, hereinafter.

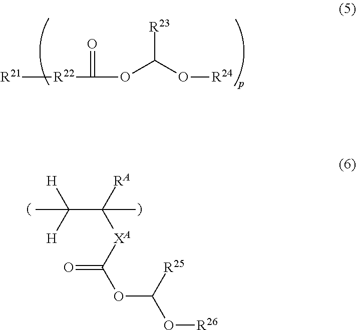

In formula (5), p is 1, 2, 3 or 4.

In formula (5), R²¹ is a C₁-C₄₀ p-valent hydrocarbon group or C₂-C₄₀ p-valent heterocyclic group. When p=2, R²¹ may also be an ether bond, carbonyl group, azo group, thioether bond, carbonate bond, carbamate bond, sulfinyl group or sulfonyl group.

Some or all of the hydrogen atoms in the p-valent hydrocarbon group or p-valent heterocyclic group may be substituted by a heteroatom-containing moiety, and some —CH₂— in the p-valent hydrocarbon group may be replaced by a heteroatom-containing moiety.

The p-valent hydrocarbon group represented by R²¹ may be saturated or unsaturated and straight, branched or cyclic. The p-valent hydrocarbon group is obtained by eliminating “p” number of hydrogen atoms from a hydrocarbon. Suitable hydrocarbons include C₁-C₄₀ alkanes, C₂-C₄₀ alkenes, C₂-C₄₀ alkynes, C₃-C₄₀ cyclic saturated hydrocarbons, C₃-C₄₀ cyclic unsaturated hydrocarbons, and C₆-C₄₀ aromatic hydrocarbons.

Examples of the C₁-C₄₀ alkane include methane, ethane, propane, butane, pentane, hexane, heptane, octane, nonane, decane, and structural isomers thereof.

Examples of the C₂-C₄₀ alkene include ethylene, propylene, butene, pentene, hexene, heptene, octene, nonene, decene, and structural isomers thereof.

Examples of the C₂-C₄₀ alkyne include acetylene, propyne, butyne, pentyne, hexyne, heptyne, octyne, nonyne, decyne, and structural isomers thereof.

Examples of the C₃-C₄₀ cyclic saturated hydrocarbon include cyclopropane, cyclobutane, cyclohexane, cycloheptane, cyclooctane, adamantane, and norbornane.

Examples of the C₃-C₄₀ cyclic unsaturated hydrocarbon include cyclopropene, cyclobutene, cyclopentene, cyclohexene, cycloheptene, cyclooctene, and norbornene.

Examples of the C₆-C₄₀ aromatic hydrocarbon include benzene, naphthalene and biphenyl.

The p-valent heterocyclic group represented by R²¹ is obtained by eliminating “p” number of hydrogen atoms from a heterocyclic compound. Suitable heterocyclic compounds include furane, pyridine, pyrazole, and thiazolidine.

Also included are the p-valent hydrocarbon groups or p-valent heterocyclic groups in which some or all of the hydrogen atoms are substituted by a moiety containing a heteroatom such as oxygen, sulfur, nitrogen or halogen so that the group may contain a hydroxy moiety, cyano moiety, fluorine, chlorine, bromine, or iodine; and the p-valent hydrocarbon group in which some —CH₂— is replaced by a moiety containing a heteroatom such as oxygen, sulfur or nitrogen so that the group may contain a carbonyl moiety, ether bond, thioether bond, ester bond, sulfonate ester bond, carbonate bond, carbamate bond, lactone ring, sultone ring, or carboxylic anhydride (—C(═O)—O—C(═O)—).

In formula (5), R²² is a single bond or C₁-C₁₀ hydrocarbylene group, some or all of the hydrogen atoms in the hydrocarbylene group may be substituted by a heteroatom-containing moiety, some —CH₂— in the hydrocarbylene group may be replaced by a heteroatom-containing moiety. When p is 2, 3 or 4, a plurality of R²² may be identical or different.

The hydrocarbylene group represented by R²² may be saturated or unsaturated and straight, branched or cyclic. Examples thereof include C₁-C₂₀ alkanediyl groups such as methanediyl, ethane-1,1-diyl, ethane-1,2-diyl, propane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, and dodecane-1,12-diyl; C₃-C₂₀ cyclic saturated hydrocarbylene groups such as cyclopentanediyl, cyclohexanediyl, norbornanediyl and adamantanediyl; C₂-C₂₀ unsaturated aliphatic hydrocarbylene groups such as vinylene and propene-1,3-diyl; C₆-C₂₀ arylene groups such as phenylene and naphthylene; and combinations thereof. In these hydrocarbylene groups, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, cyano, fluorine, chlorine, bromine, iodine, carbonyl, ether bond, thioether bond, ester bond, sulfonate ester bond, carbonate bond, carbamate bond, lactone ring, sultone ring, carboxylic anhydride (—C(═O)—O—C(═O)—).

In formula (6), R^{A} is hydrogen, halogen, methyl or trifluoromethyl. X^{A} is a single bond, phenylene, naphthylene, or *—C(═O)—O—X^{A1}—. X^{A1} is a C₁-C₁₀ saturated hydrocarbylene group, phenylene group or naphthylene group, the saturated hydrocarbylene group may contain a hydroxy moiety, ether bond, ester bond or lactone ring, * designates a point of attachment to the carbon atom in the backbone.

In formulae (5) and (6), R²³ to R²⁶ are each independently halogen or a C₁-C₄₀ hydrocarbyl group which may contain a heteroatom. R²³ and R²⁴ may bond together to form a ring with the carbon and oxygen atoms to which they are attached. R²¹ and R²⁶ may bond together to form a ring with the carbon and oxygen atoms to which they are attached.

Suitable halogen atoms represented by R²³ to R²⁶ include fluorine, chlorine, bromine and iodine. The C₁-C₄₀ hydrocarbyl group represented by R²³ to R²⁶ may be saturated or unsaturated and straight, branched or cyclic. Examples thereof include C₁-C₄₀ alkyl groups such as methyl, ethyl, propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, adamantyl and adamantylmethyl, C₆-C₄₀ aryl groups such as phenyl, naphthyl and anthracenyl, and combinations thereof. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—).

Of the carboxylic acid derivatives having formula (5), those wherein p is 2, 3 or 4 are preferred.

Examples of the carboxylic acid derivative having formula (5) are shown below, but not limited thereto. Herein R^{B} is methyl, ethyl, propyl, isopropyl, n-butyl, isobutyl, sec-butyl, tert-butyl, n-pentyl, tert-pentyl, n-hexyl, n-octyl, 2-ethylhexyl, n-nonyl, n-decyl, cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, adamantyl, adamantylmethyl, phenyl, naphthyl, anthracenyl, or a group having any of the formulae (AL-1) to (AL-9).

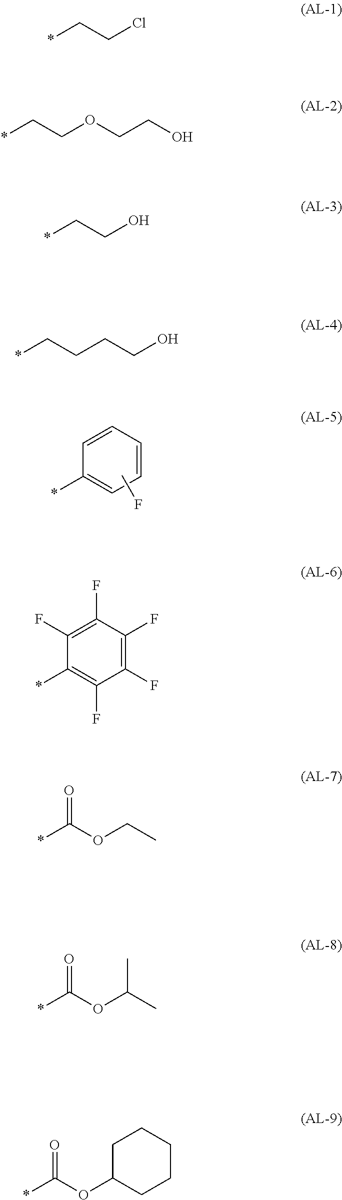

In the formula, * designates a point of attachment

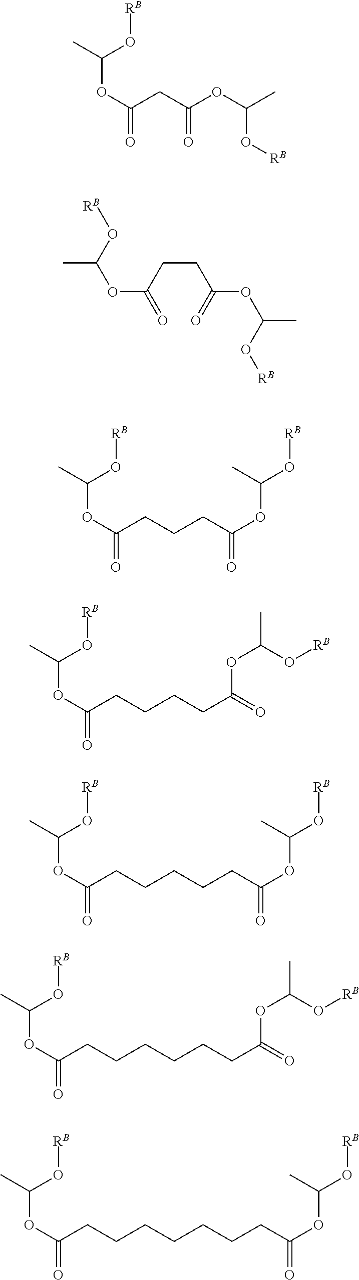

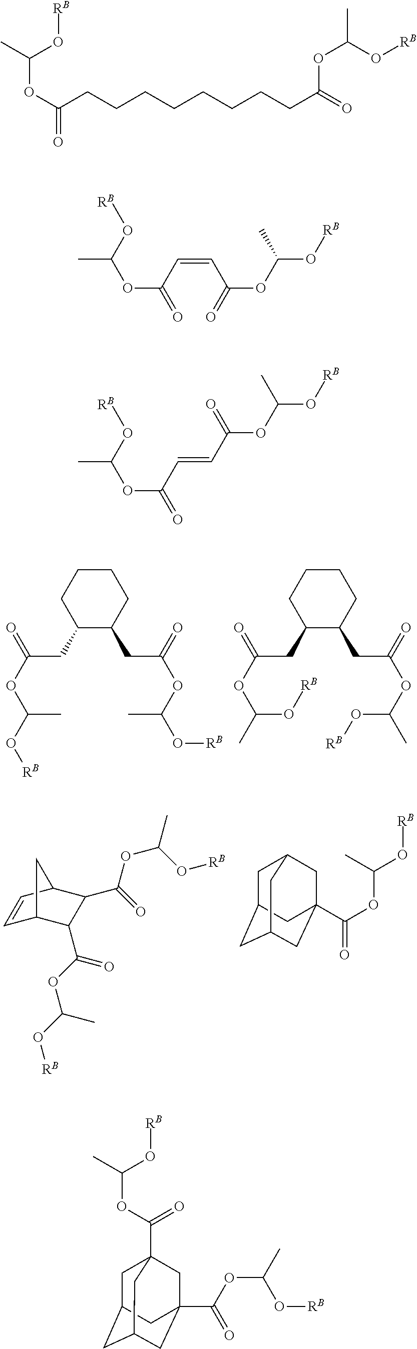

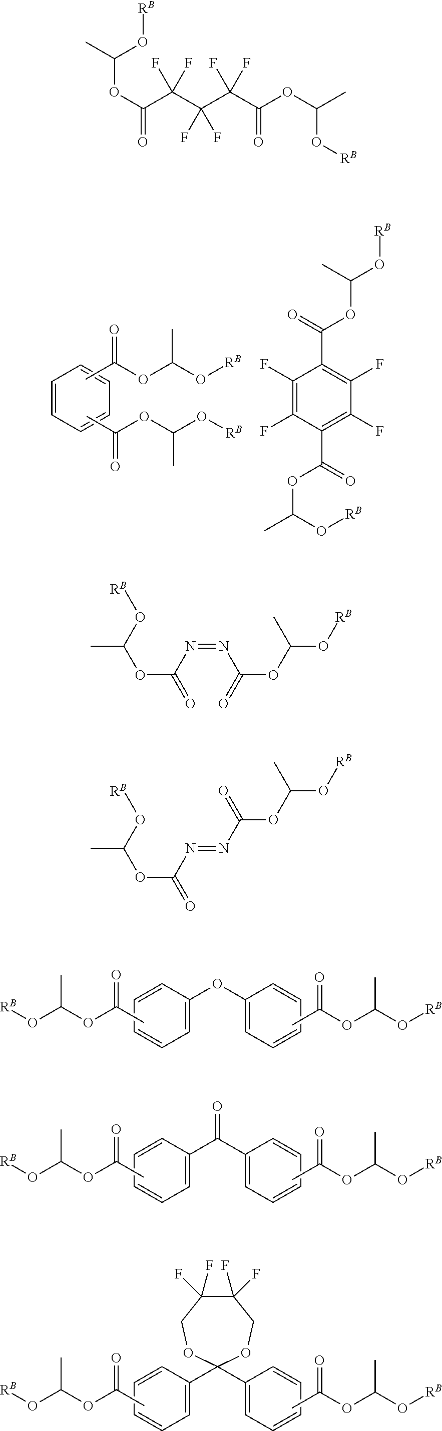

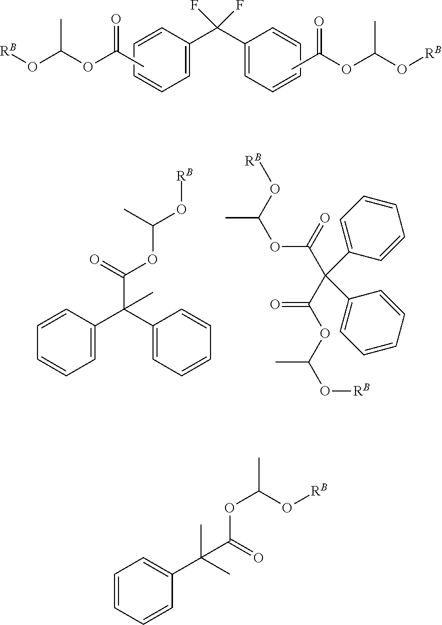

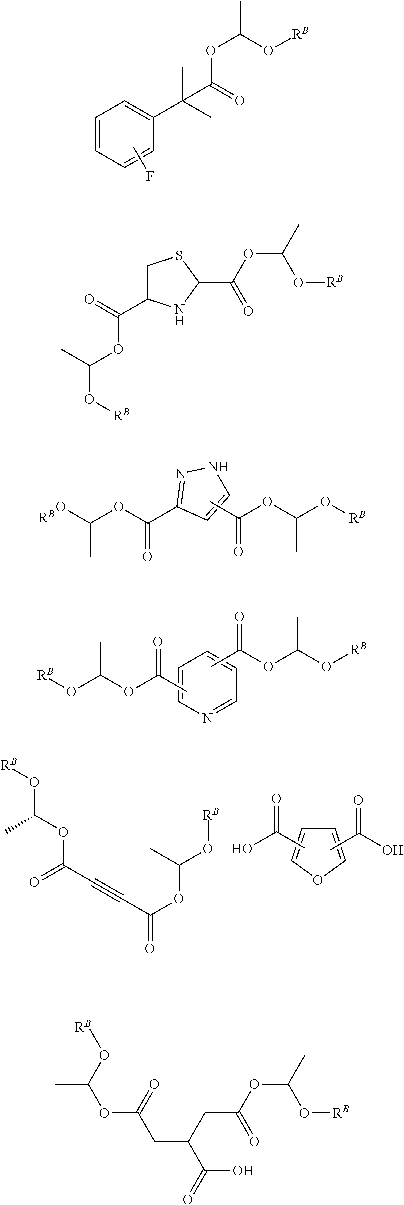

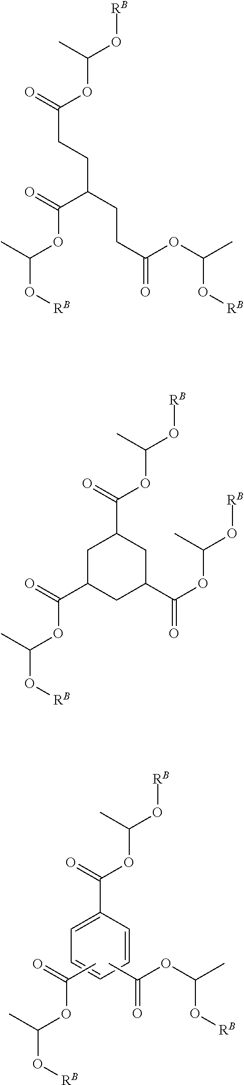

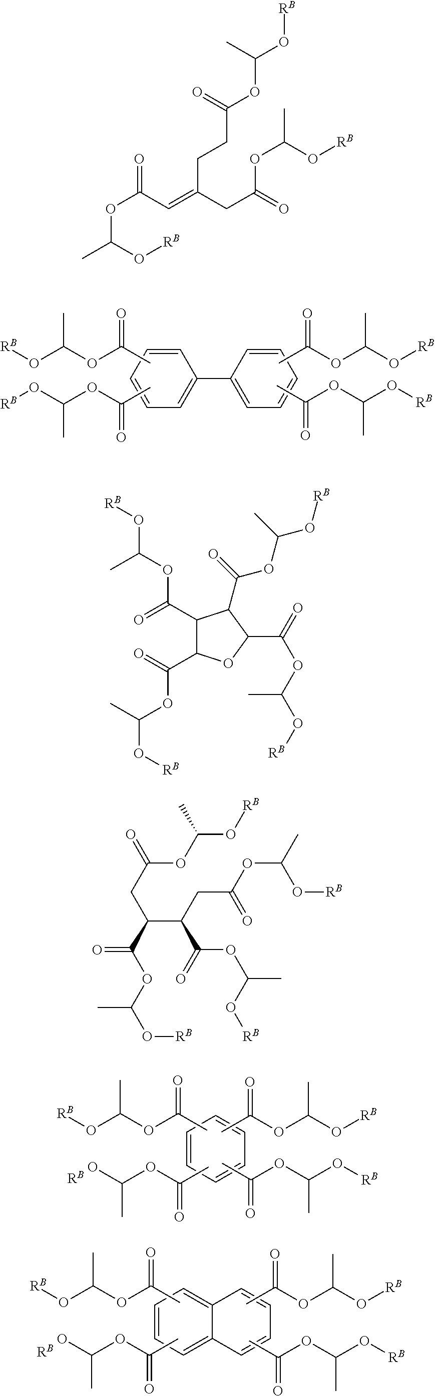

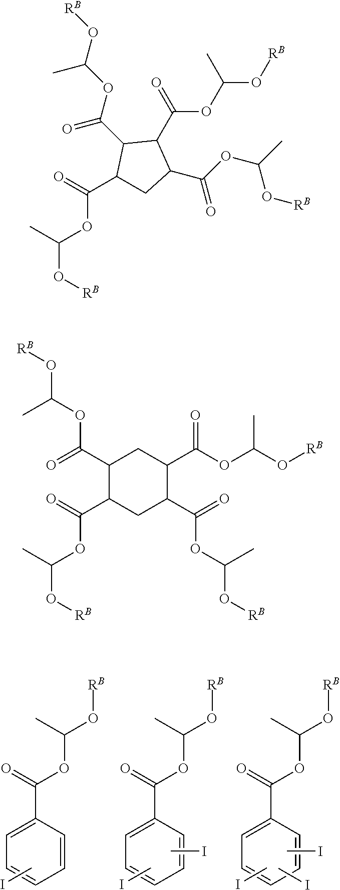

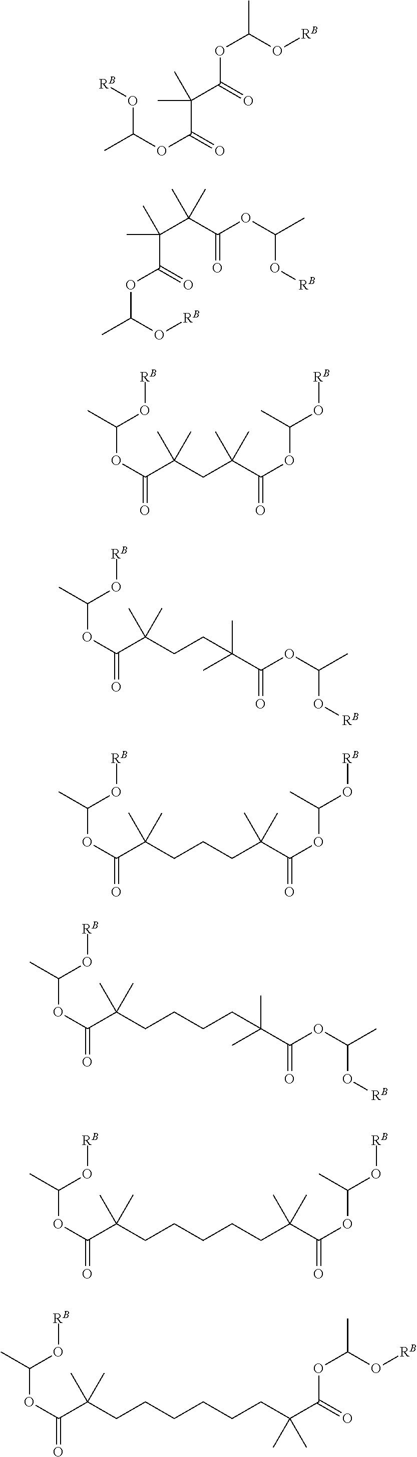

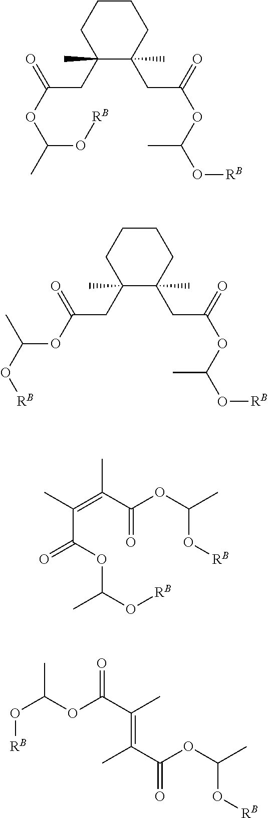

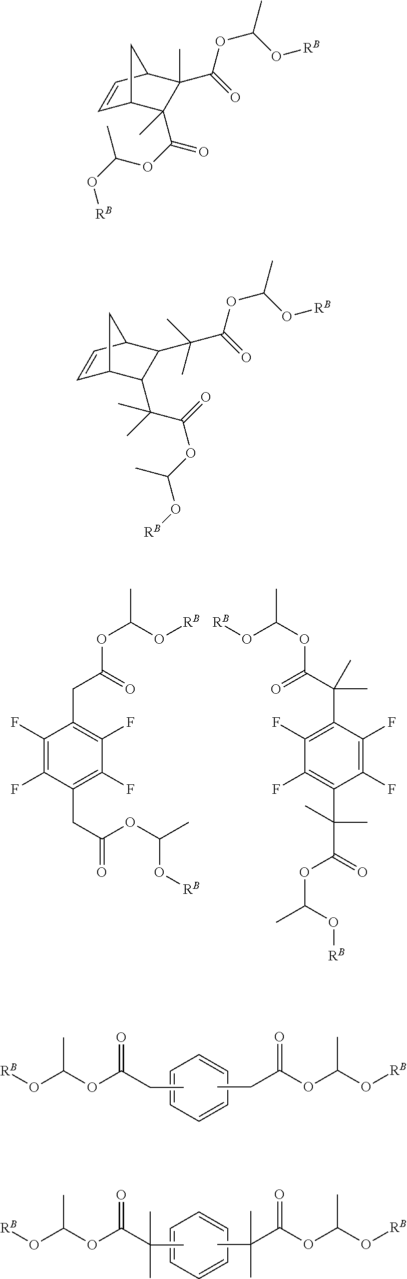

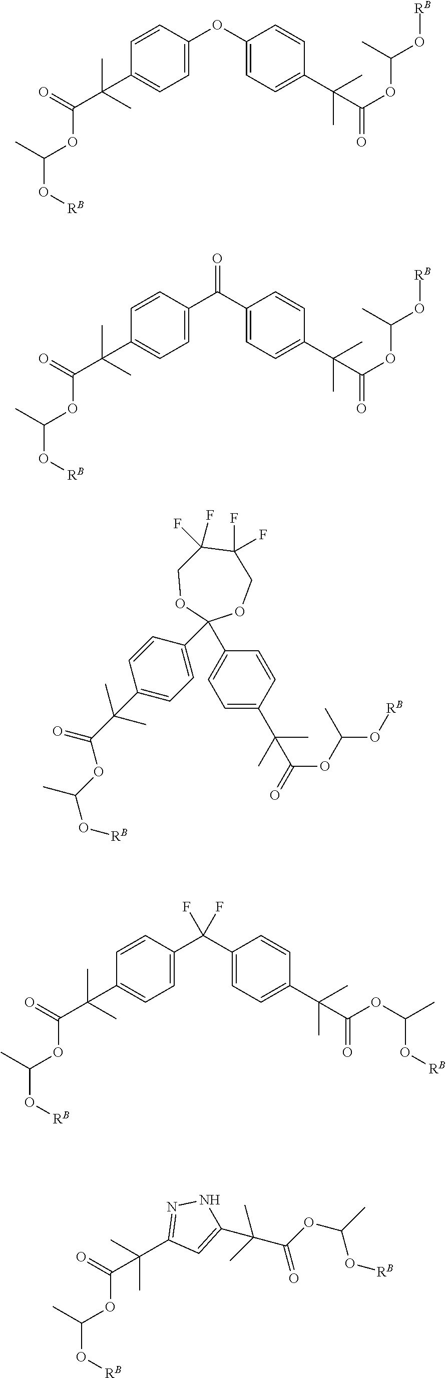

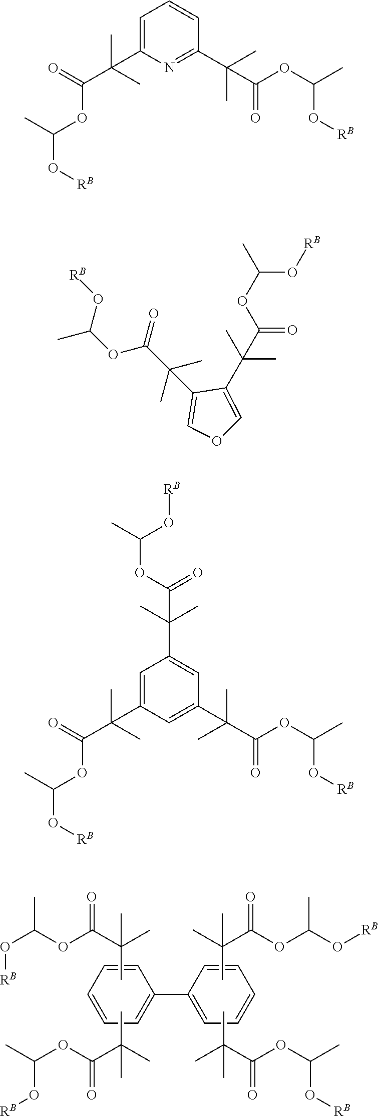

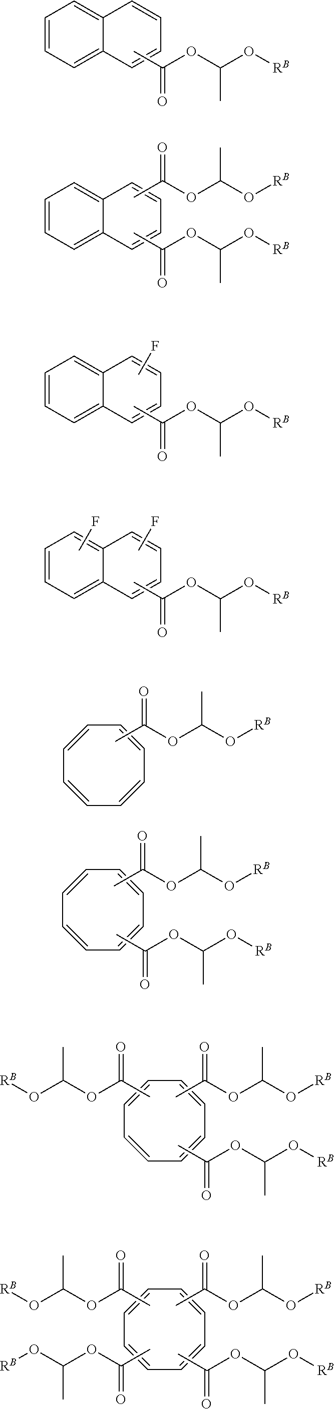

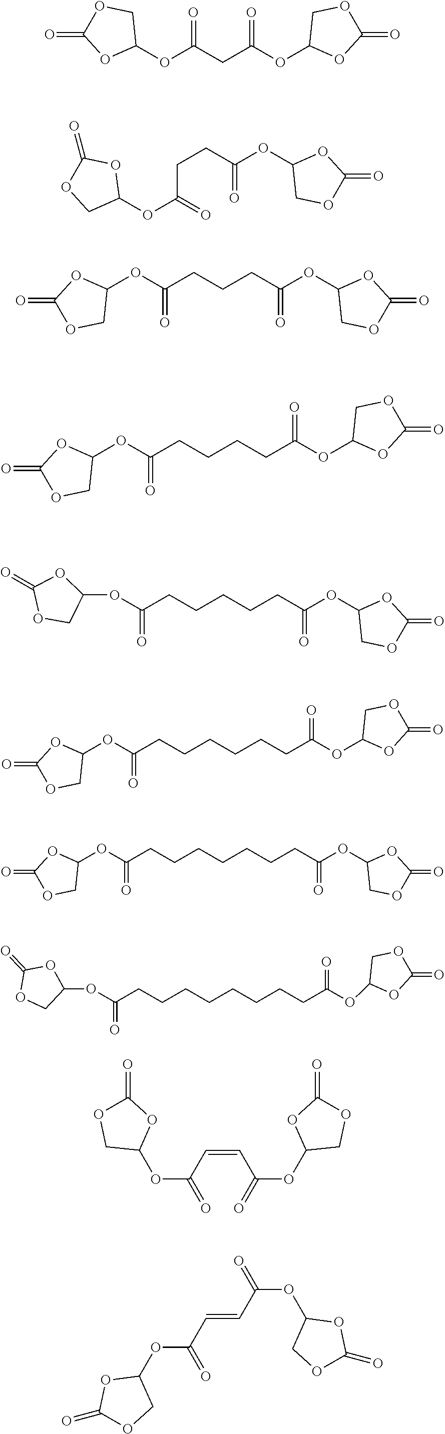

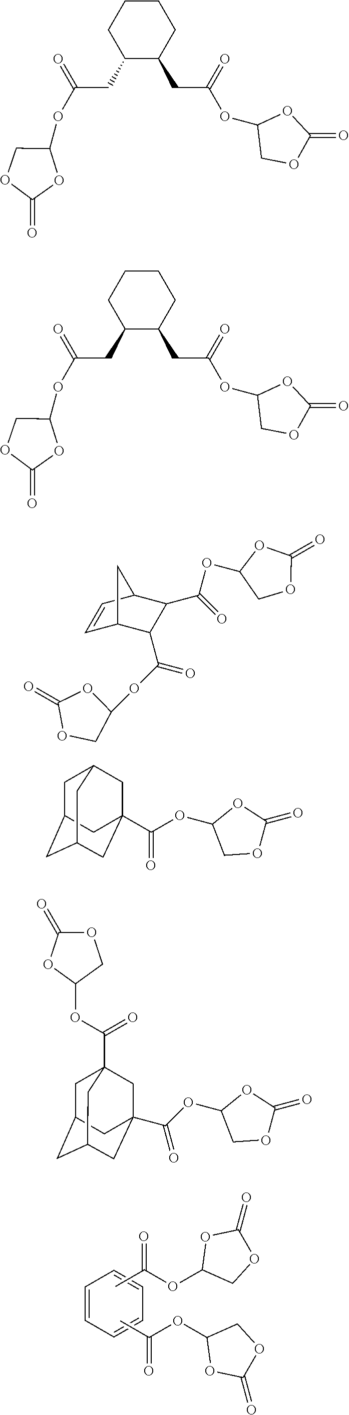

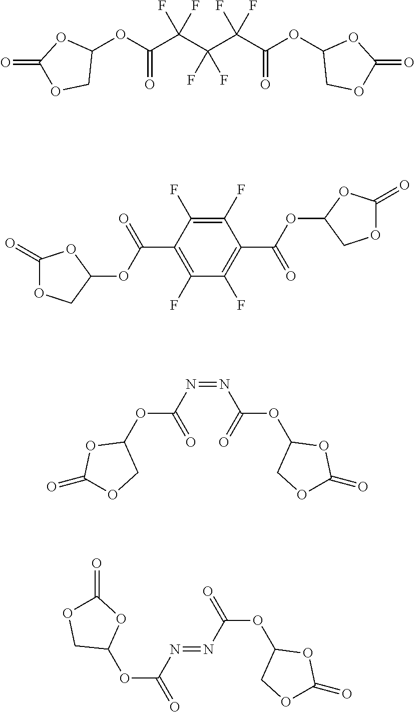 [SMILES: O=C1OCC(OC(=O)C(F)(F)C(F)(F)C(F)(F)C(=O)OC2COC(=O)O2)O1 ; O=C1OCC(OC(=O)c2c(F)c(F)c(C(=O)OC3COC(=O)O3)c(F)c2F)O1 ; O=C(/N=N\C(=O)OC1COC(=O)O1)OC1COC(=O)O1 ; O=C(/N=N/C(=O)OC1COC(=O)O1)OC1COC(=O)O1]

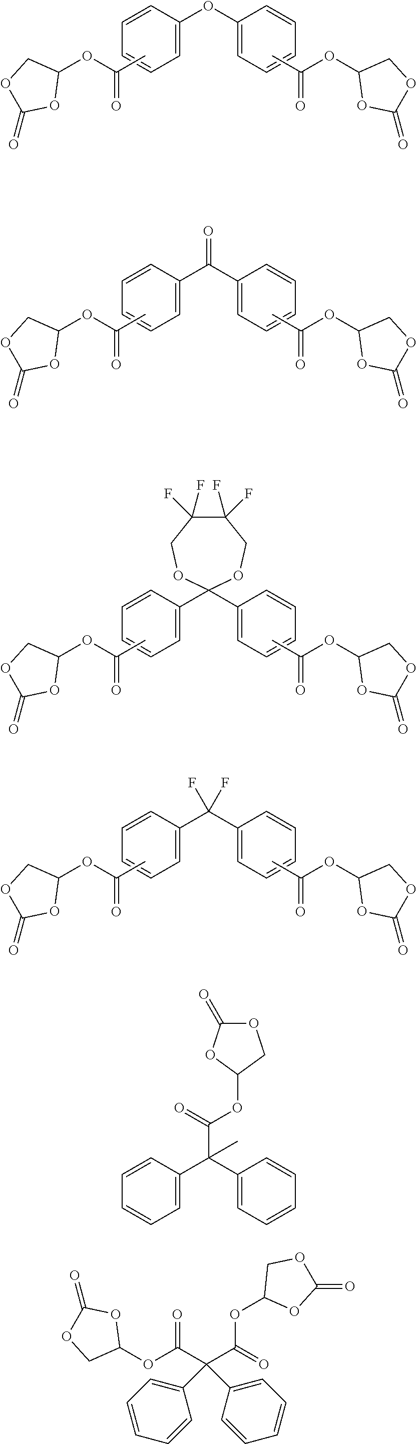

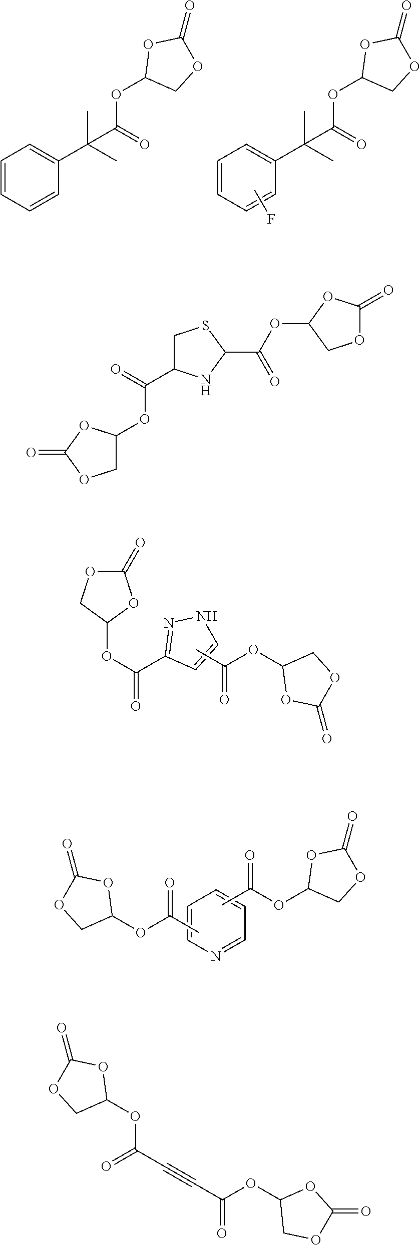

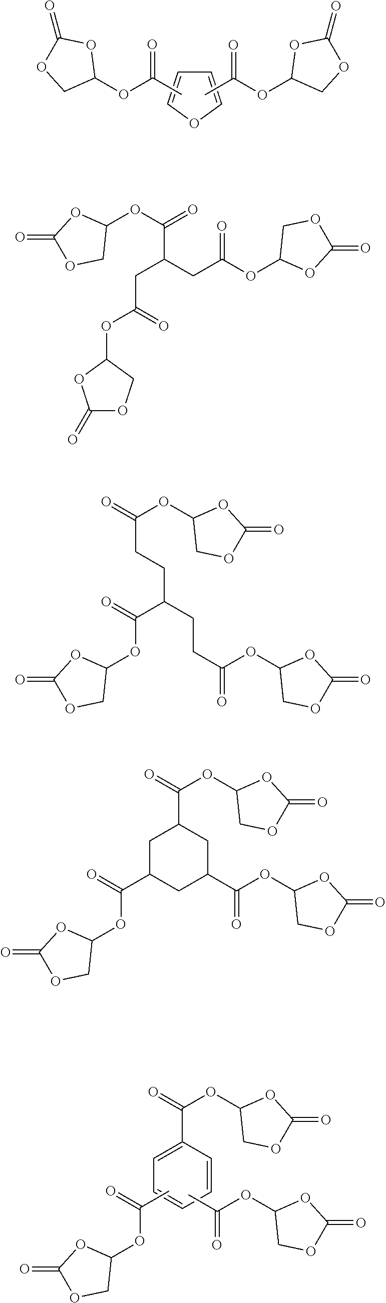

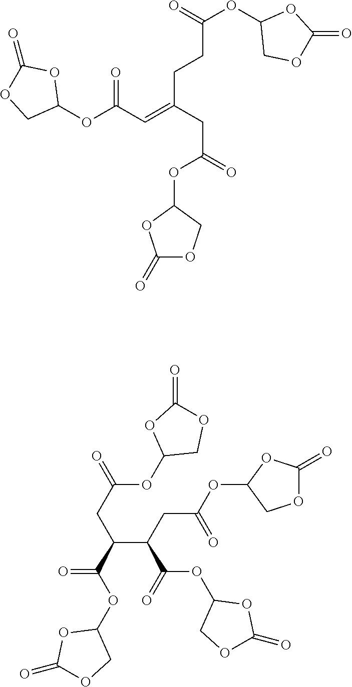 [SMILES: O=C(/C=C(\CCC(=O)OC1COC(=O)O1)CC(=O)OC1COC(=O)O1)OC1COC(=O)O1 ; O=C(C[C@H](C(=O)OC1COC(=O)O1)[C@@H](CC(=O)OC1COC(=O)O1)C(=O)OC1COC(=O)O1)OC1COC(=O)O1]

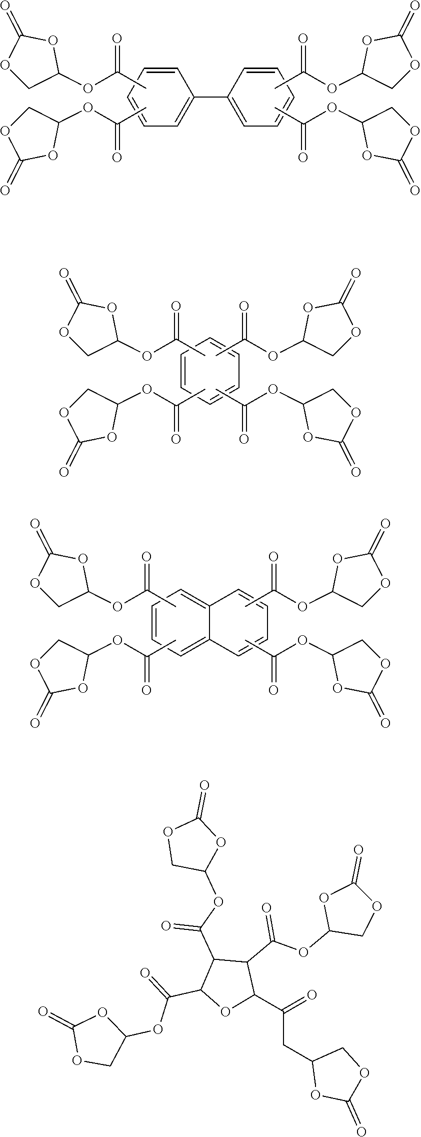

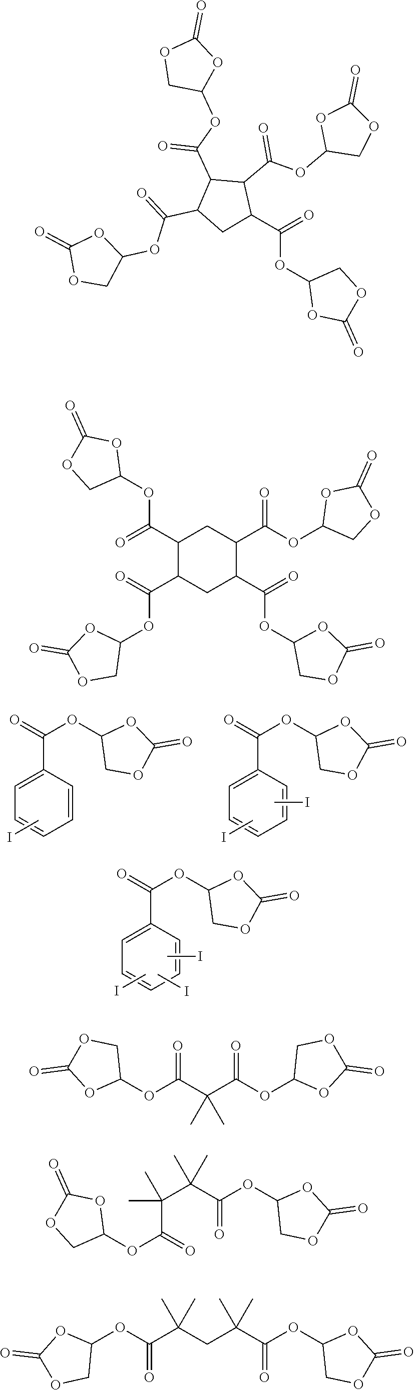

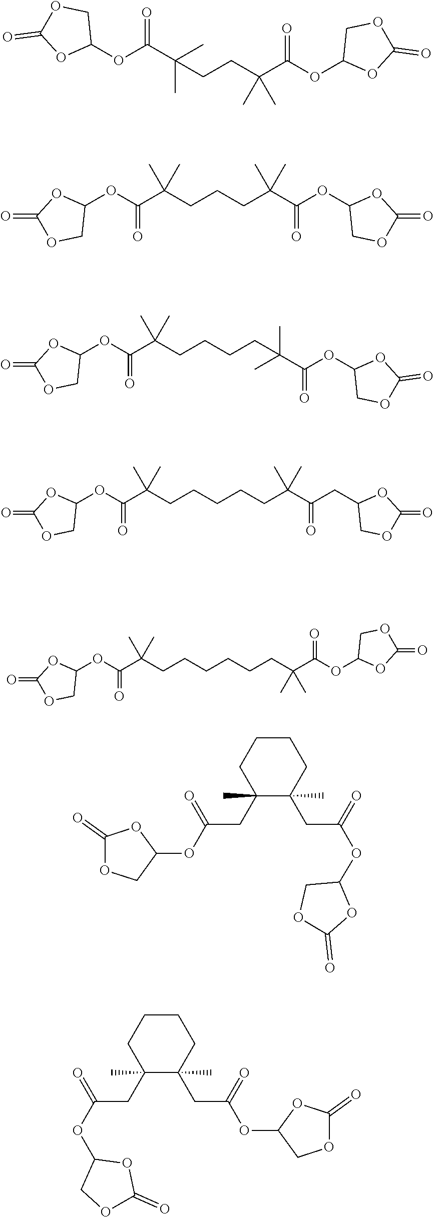

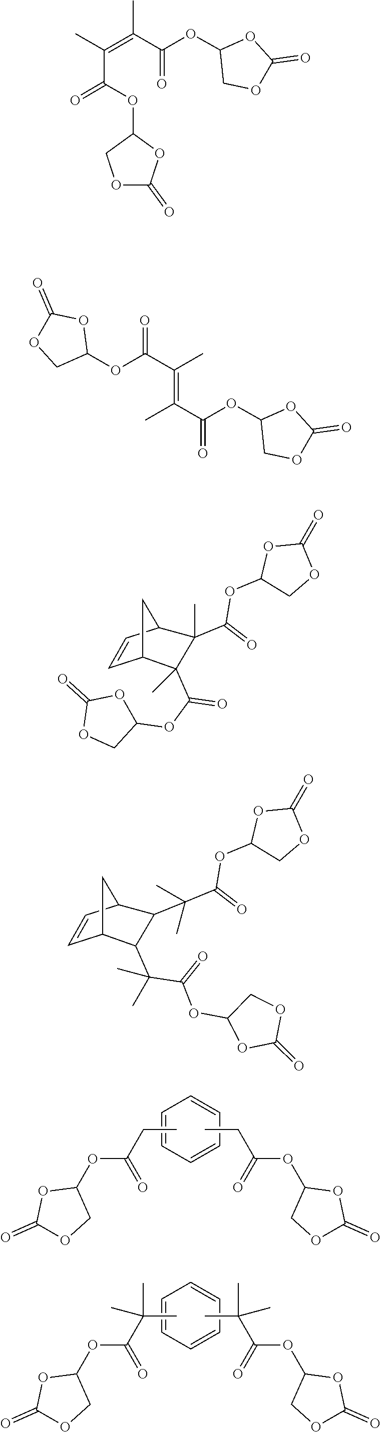

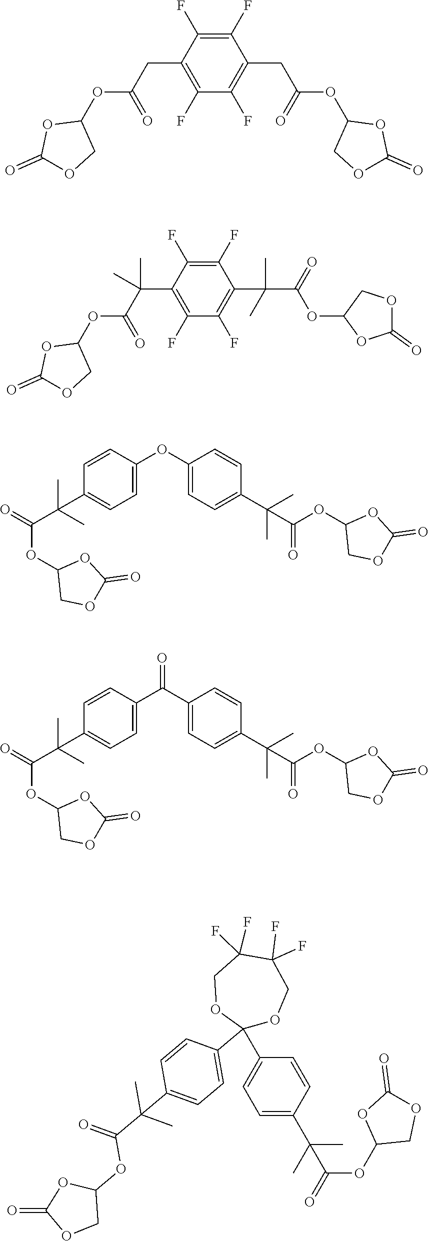 [SMILES: O=C(Cc1c(F)c(F)c(CC(=O)OC2COC(=O)O2)c(F)c1F)OC1COC(=O)O1 ; CC(C)(C(=O)OC1COC(=O)O1)c1c(F)c(F)c(C(C)(C)C(=O)OC2COC(=O)O2)c(F)c1F ; CC(C)(C(=O)OC1COC(=O)O1)c1ccc(Oc2ccc(C(C)(C)C(=O)OC3COC(=O)O3)cc2)cc1 ; CC(C)(C(=O)OC1COC(=O)O1)c1ccc(C(=O)c2ccc(C(C)(C)C(=O)OC3COC(=O)O3)cc2)cc1 ; CC(C)(C(=O)OC1COC(=O)O1)c1ccc(C2(c3ccc(C(C)(C)C(=O)OC4COC(=O)O4)cc3)OCC(F)(F)C(F)(F)CO2)cc1]

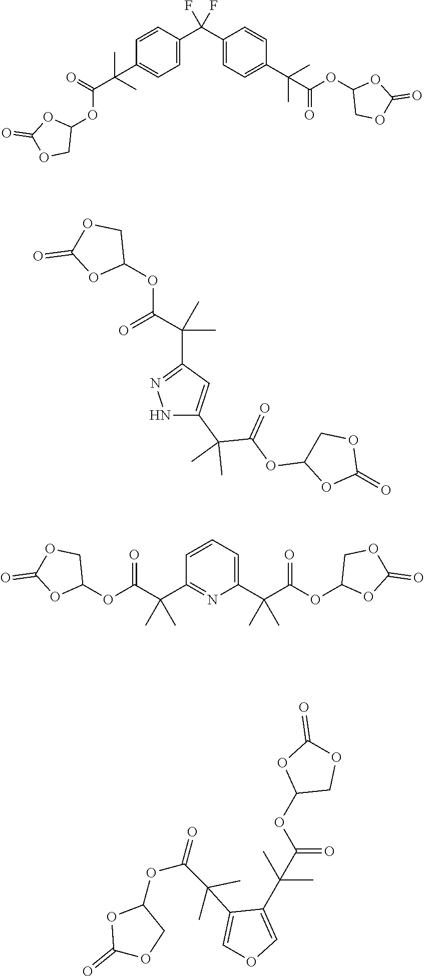 [SMILES: CC(C)(C(=O)OC1COC(=O)O1)c1ccc(C(F)(F)c2ccc(C(C)(C)C(=O)OC3COC(=O)O3)cc2)cc1 ; CC(C)(C(=O)OC1COC(=O)O1)c1cc(C(C)(C)C(=O)OC2COC(=O)O2)[nH]n1 ; CC(C)(C(=O)OC1COC(=O)O1)c1cccc(C(C)(C)C(=O)OC2COC(=O)O2)n1 ; CC(C)(C(=O)OC1COC(=O)O1)c1cocc1C(C)(C)C(=O)OC1COC(=O)O1]

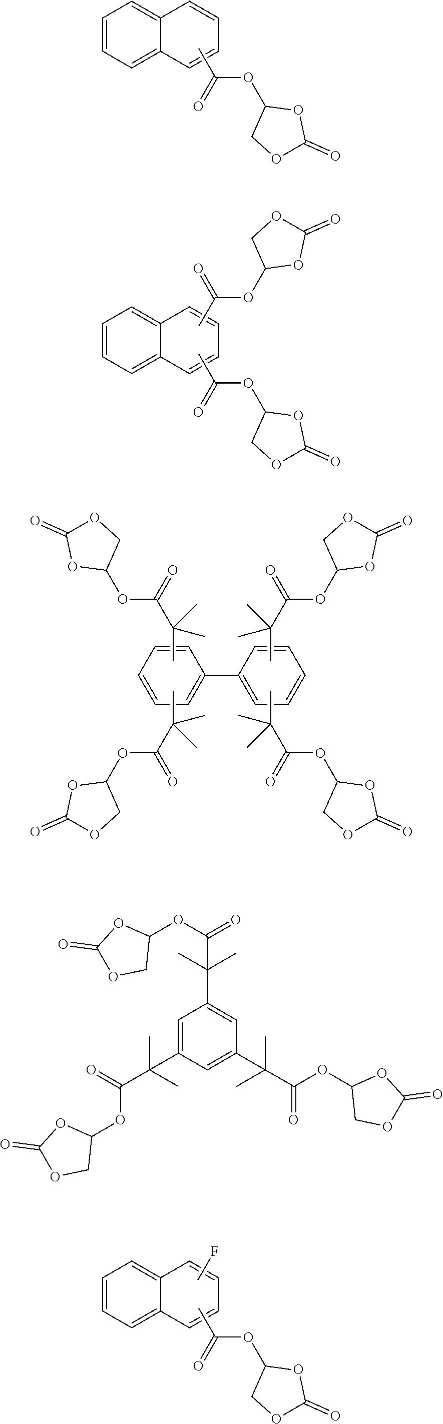

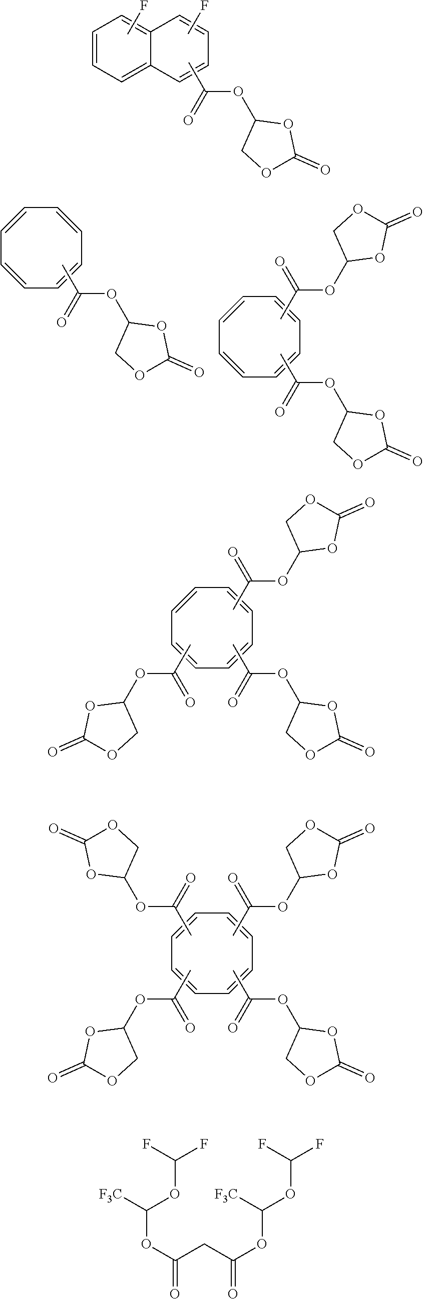

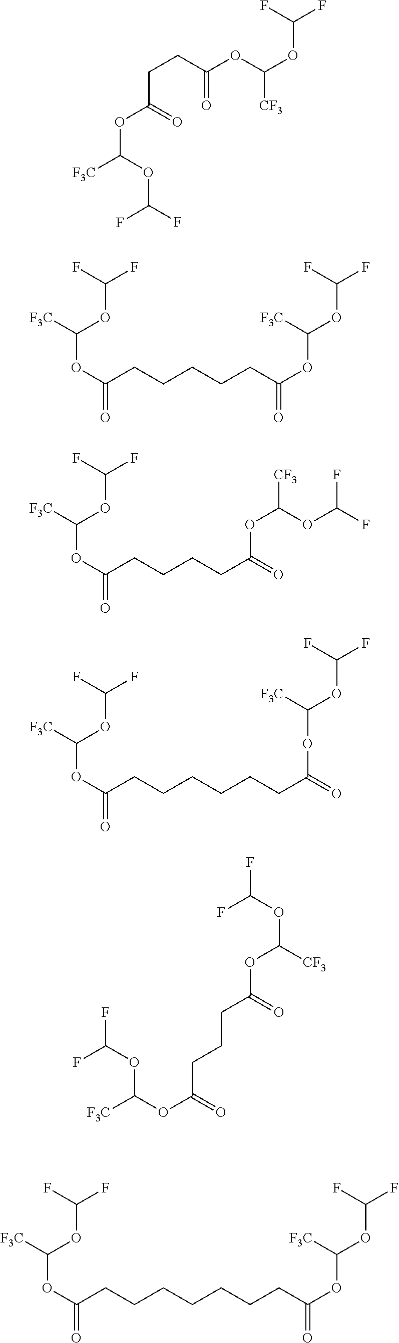 [SMILES: O=C(CCC(=O)OC(OC(F)F)C(F)(F)F)OC(OC(F)F)C(F)(F)F ; O=C(CCCCCC(=O)OC(OC(F)F)C(F)(F)F)OC(OC(F)F)C(F)(F)F ; O=C(CCCCC(=O)OC(OC(F)F)C(F)(F)F)OC(OC(F)F)C(F)(F)F ; O=C(CCCCCCC(=O)OC(OC(F)F)C(F)(F)F)OC(OC(F)F)C(F)(F)F ; O=C(CCCC(=O)OC(OC(F)F)C(F)(F)F)OC(OC(F)F)C(F)(F)F ; O=C(CCCCCCCC(=O)OC(OC(F)F)C(F)(F)F)OC(OC(F)F)C(F)(F)F]

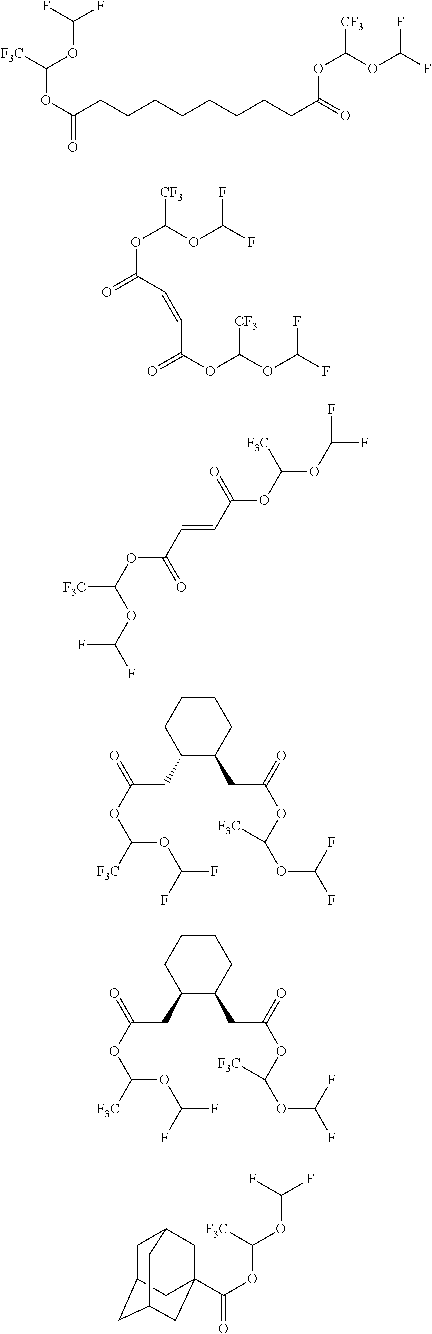

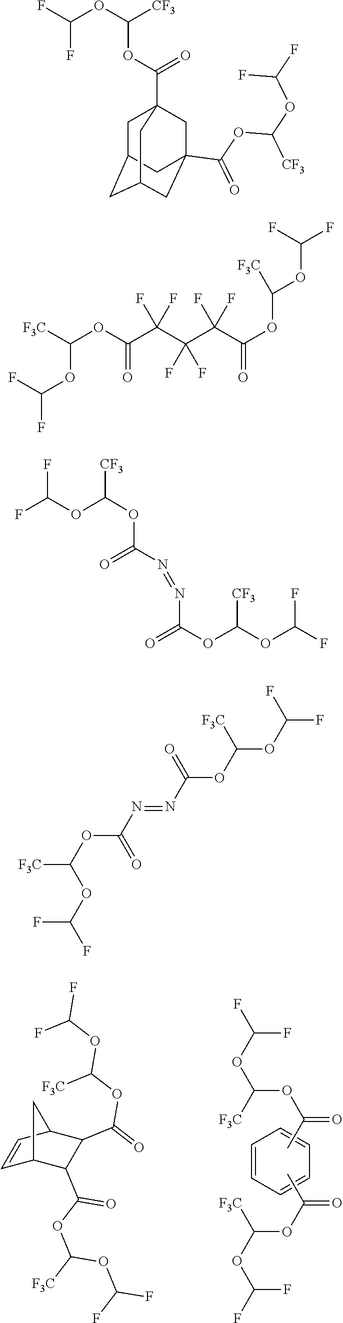

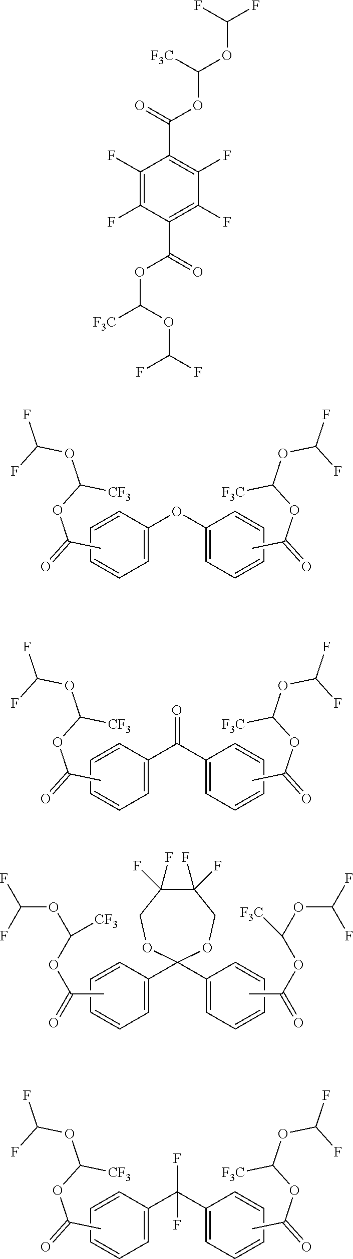

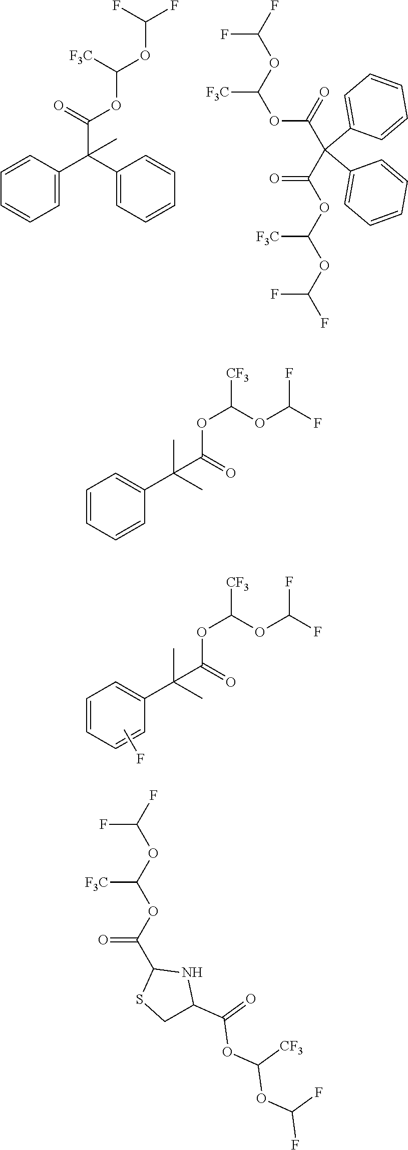

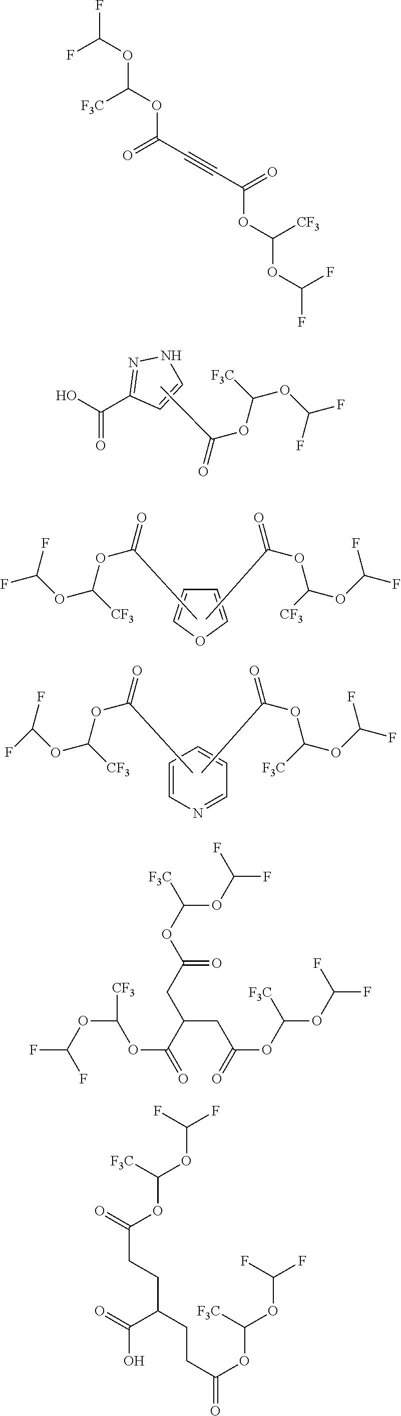

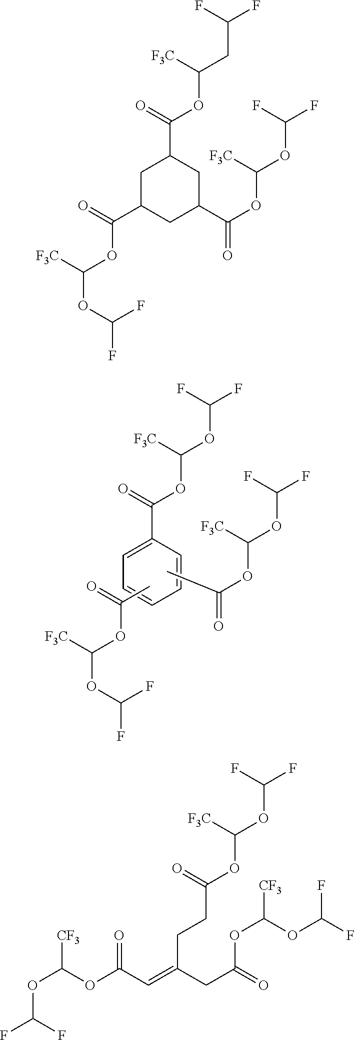

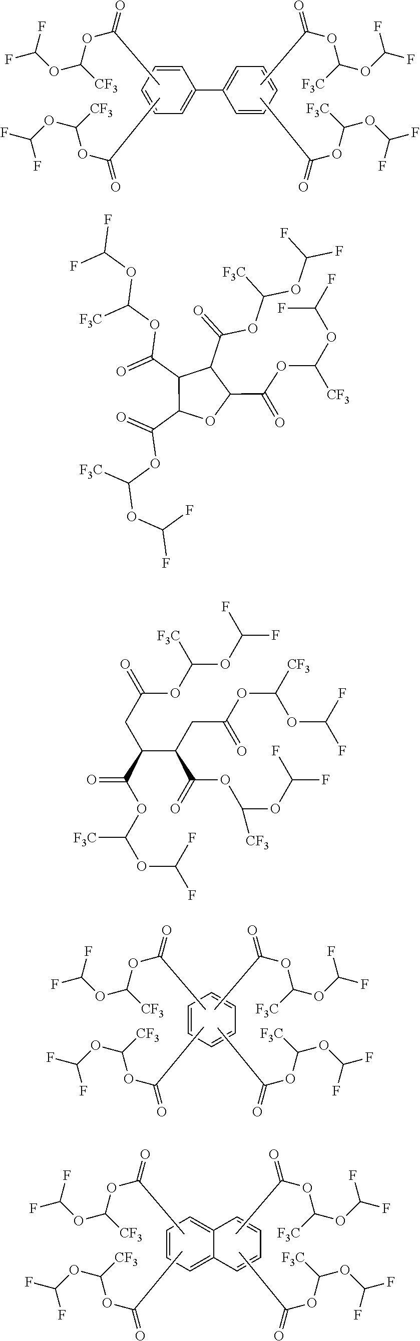

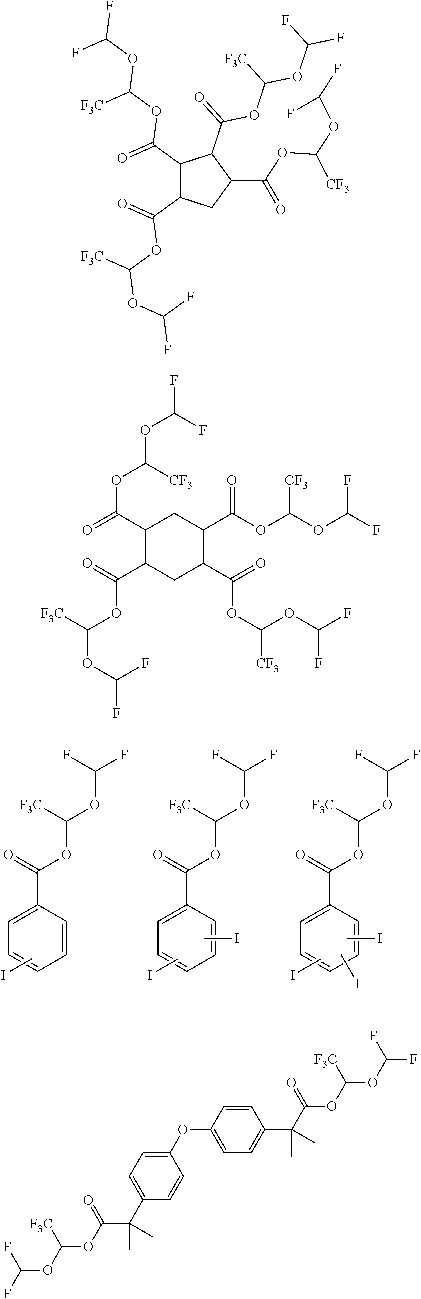

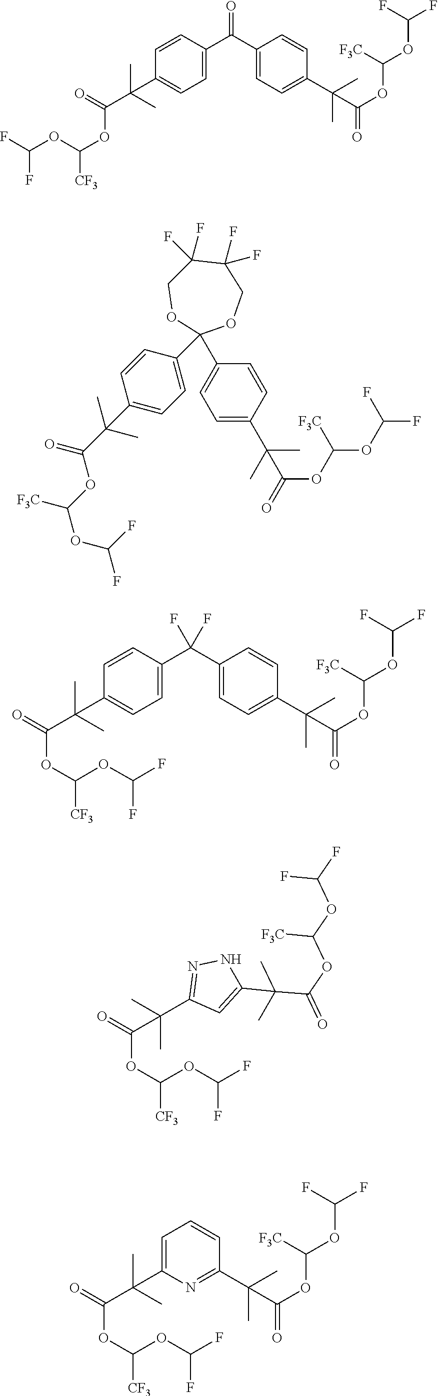 [SMILES: CC(C)(C(=O)OC(OC(F)F)C(F)(F)F)c1ccc(C(=O)c2ccc(C(C)(C)C(=O)OC(OC(F)F)C(F)(F)F)cc2)cc1 ; CC(C)(C(=O)OC(OC(F)F)C(F)(F)F)c1ccc(C2(c3ccc(C(C)(C)C(=O)OC(OC(F)F)C(F)(F)F)cc3)OCC(F)(F)C(F)(F)CO2)cc1 ; CC(C)(C(=O)OC(OC(F)F)C(F)(F)F)c1ccc(C(F)(F)c2ccc(C(C)(C)C(=O)OC(OC(F)F)C(F)(F)F)cc2)cc1 ; CC(C)(C(=O)OC(OC(F)F)C(F)(F)F)c1cc(C(C)(C)C(=O)OC(OC(F)F)C(F)(F)F)[nH]n1 ; CC(C)(C(=O)OC(OC(F)F)C(F)(F)F)c1cccc(C(C)(C)C(=O)OC(OC(F)F)C(F)(F)F)n1]

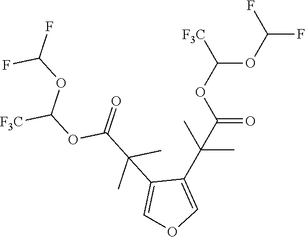 [SMILES: CC(C)(C(=O)OC(OC(F)F)C(F)(F)F)c1cocc1C(C)(C)C(=O)OC(OC(F)F)C(F)(F)F]

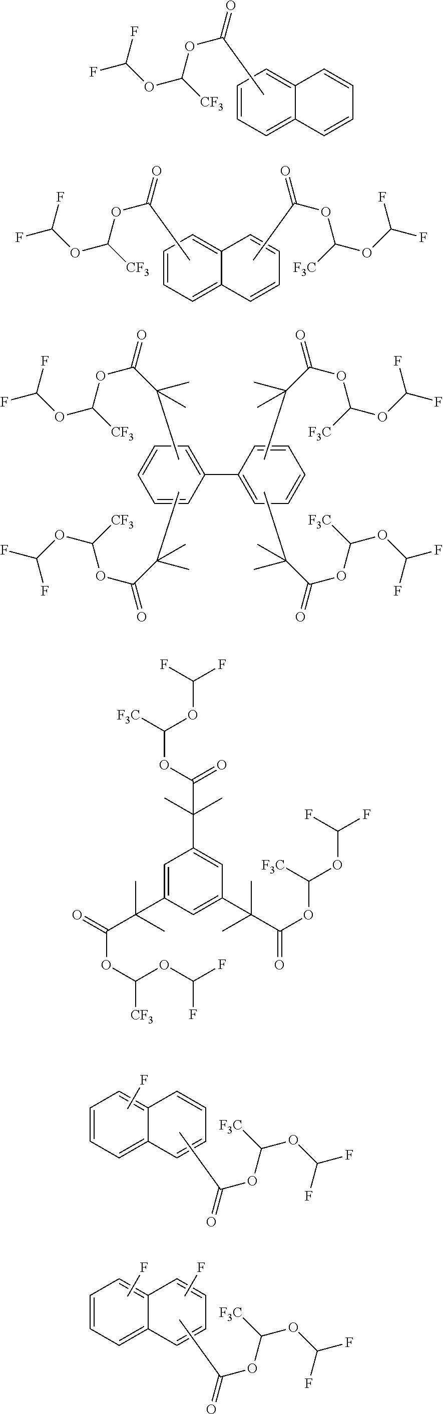

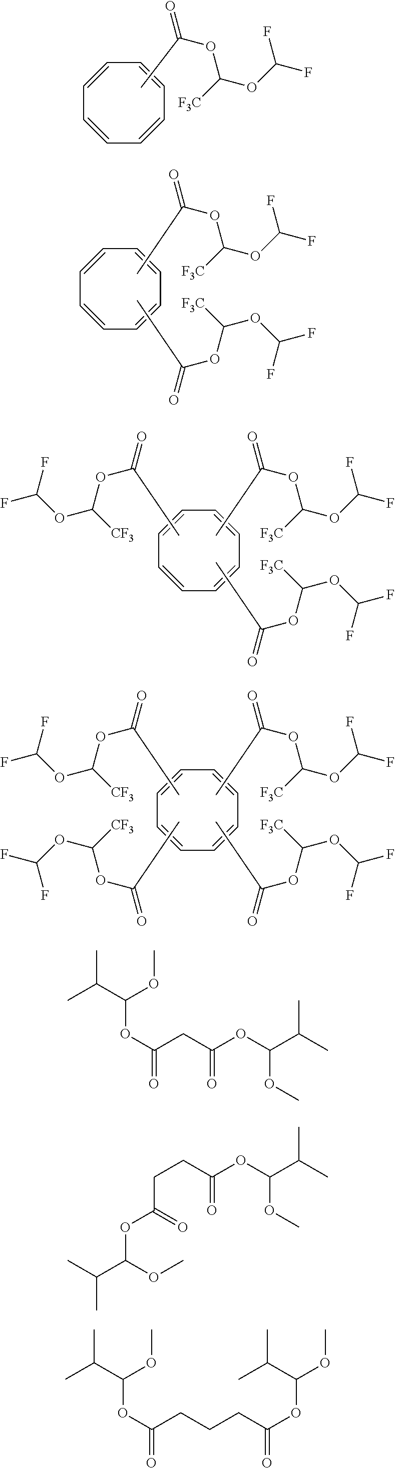

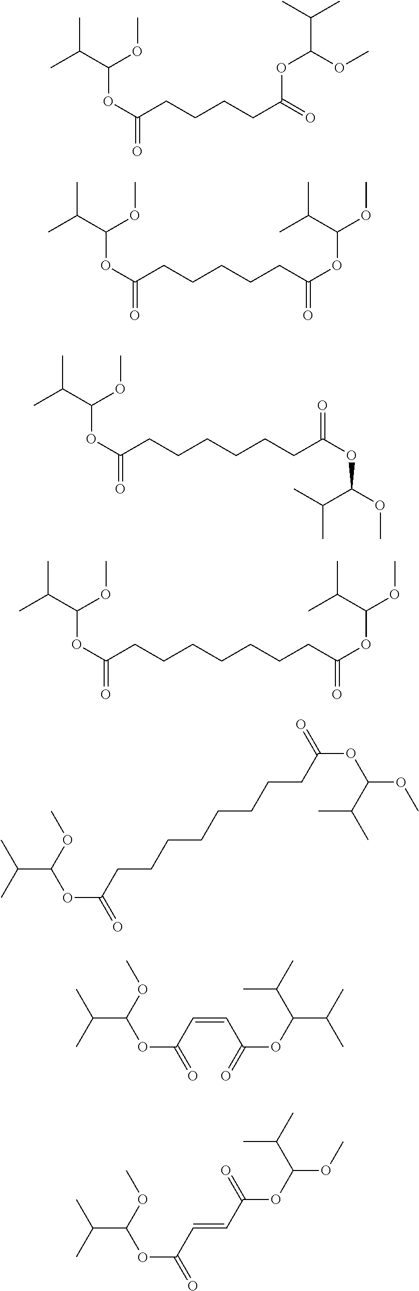

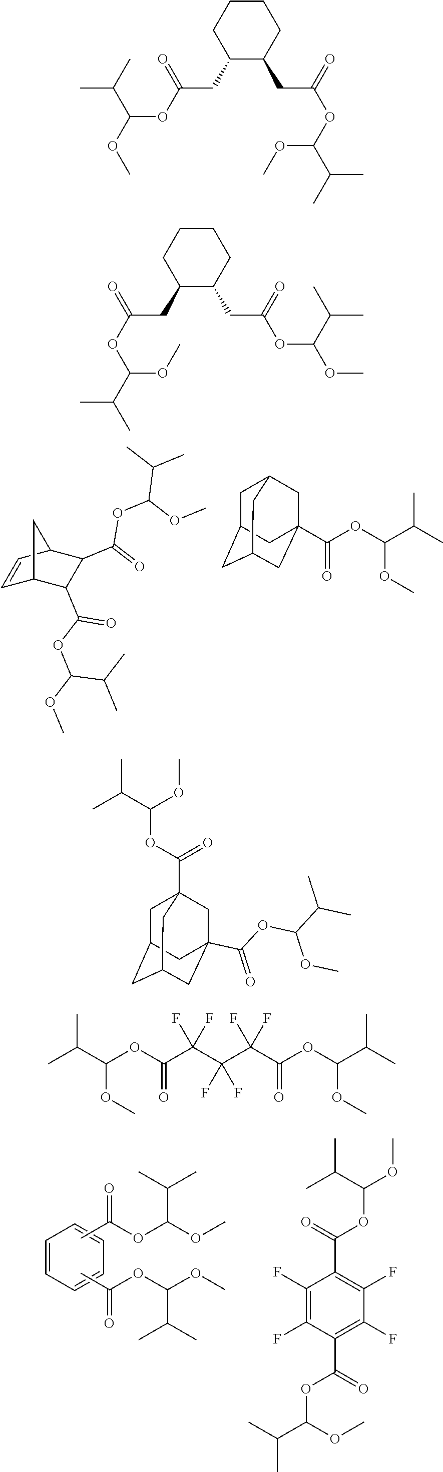

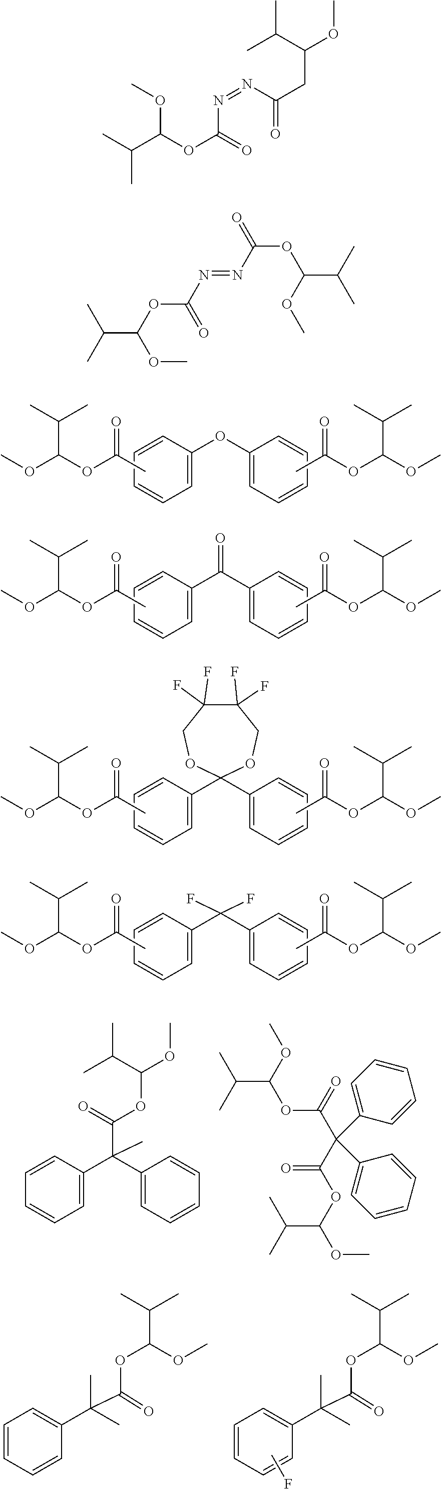

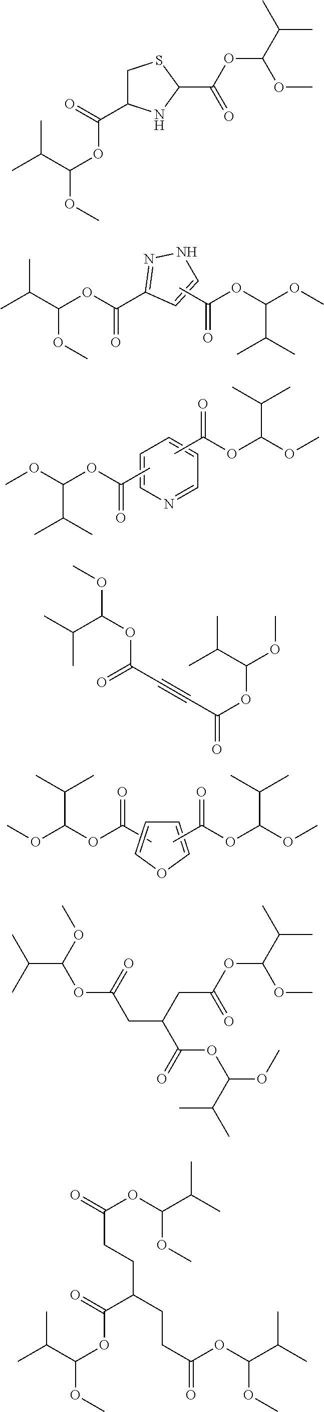

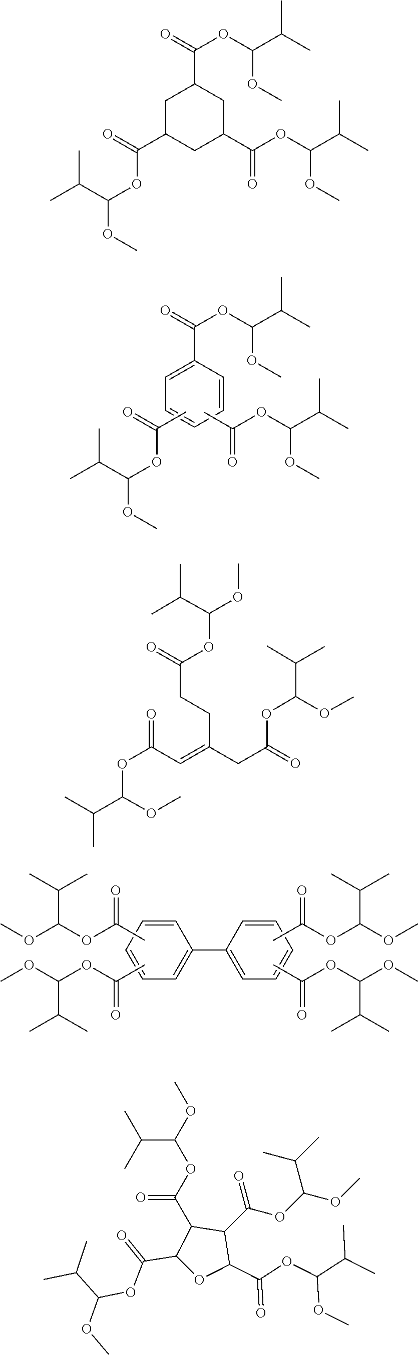

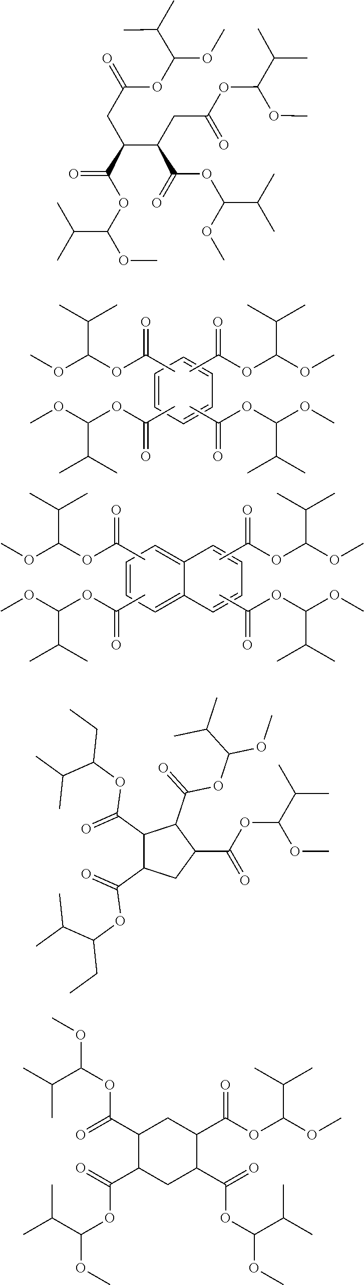

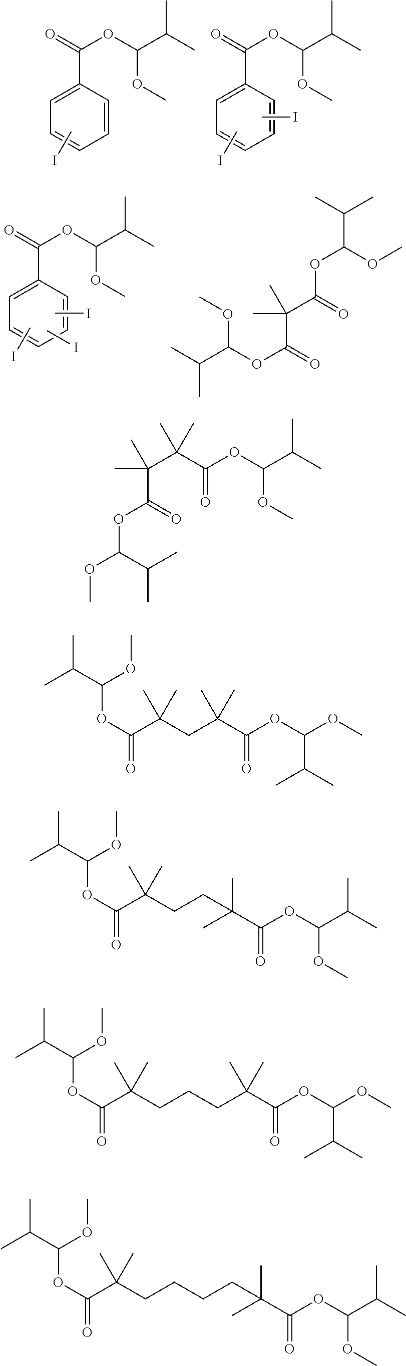

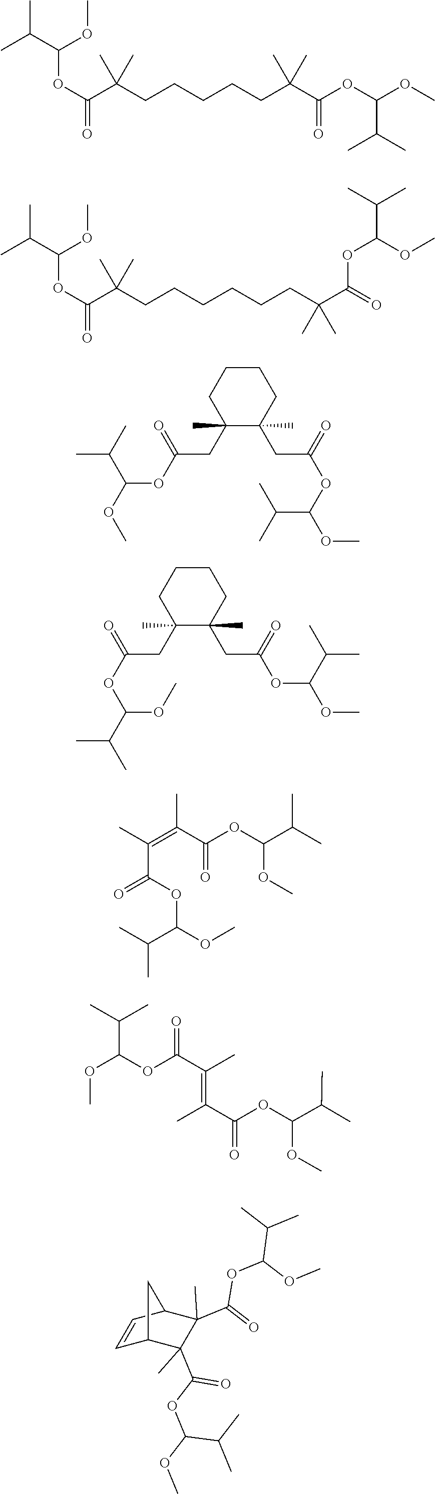

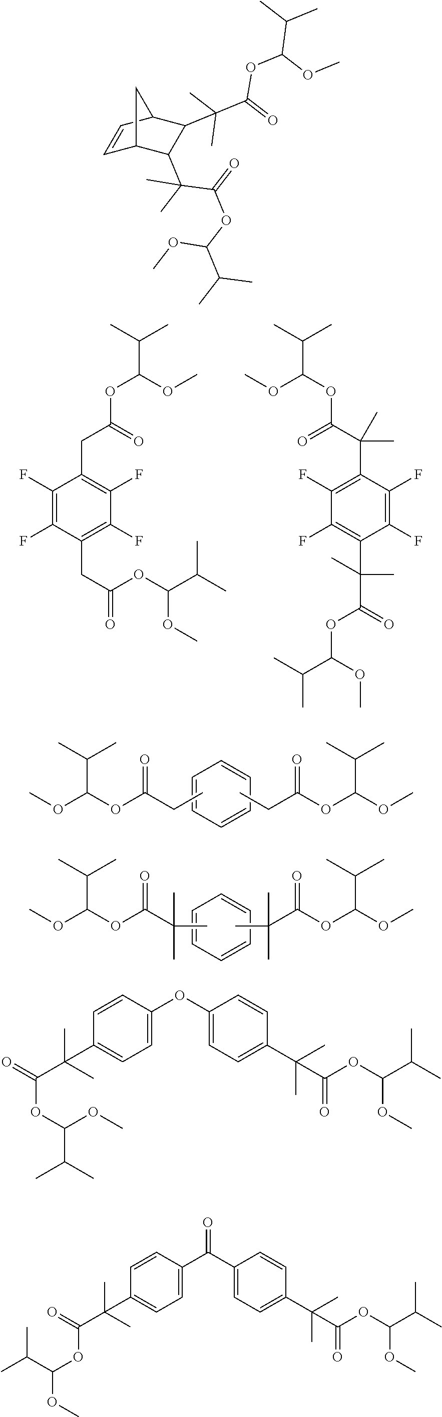

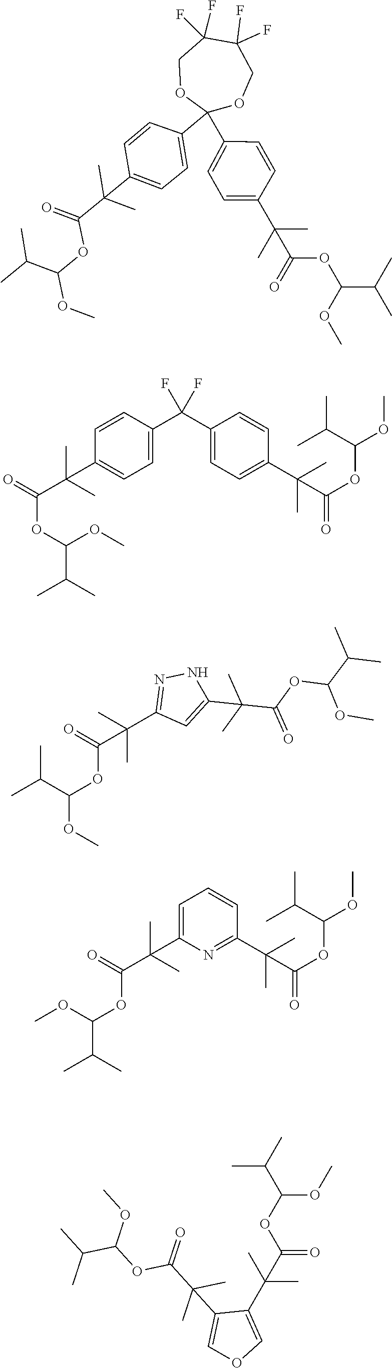

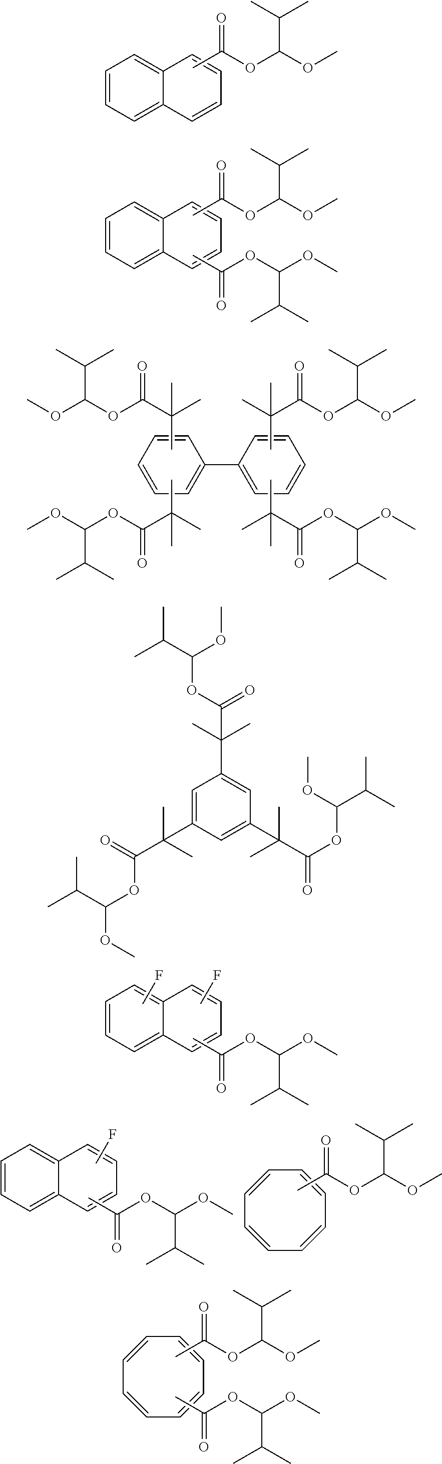

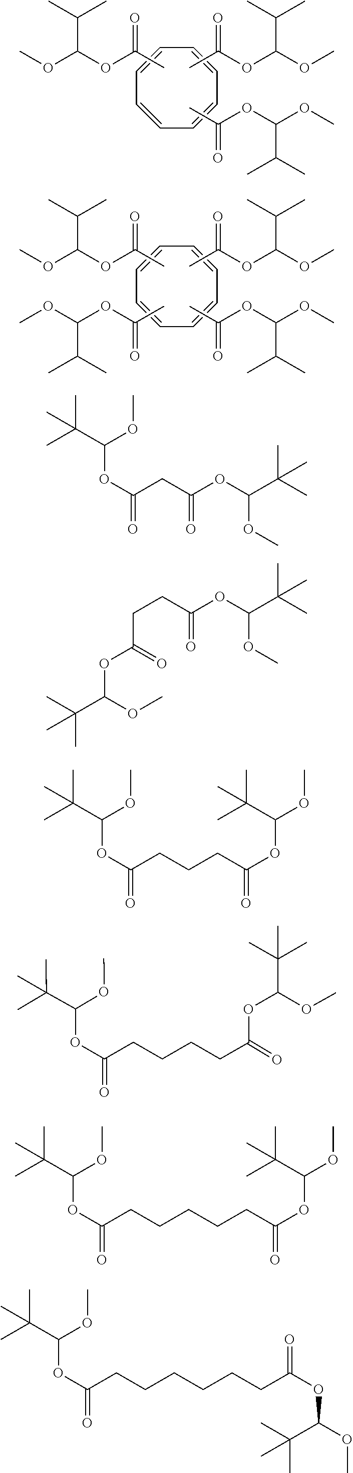

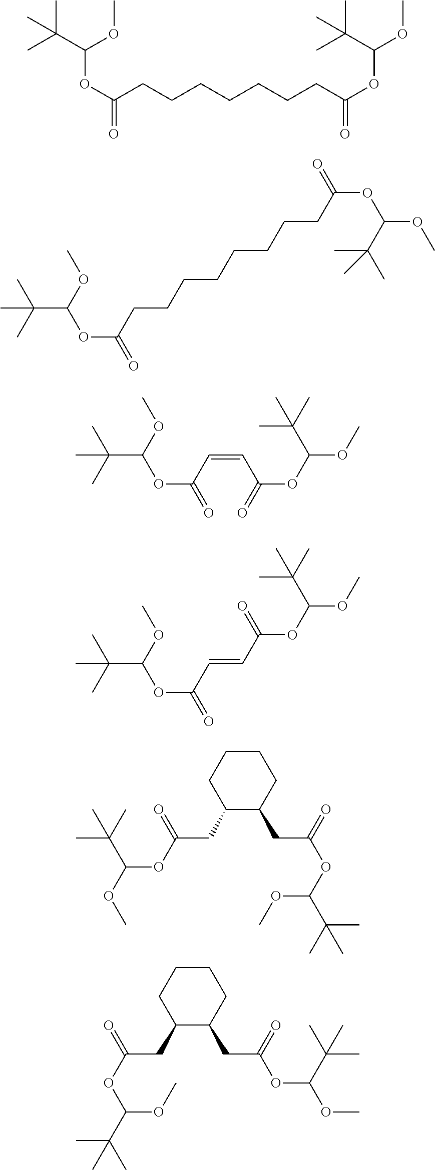

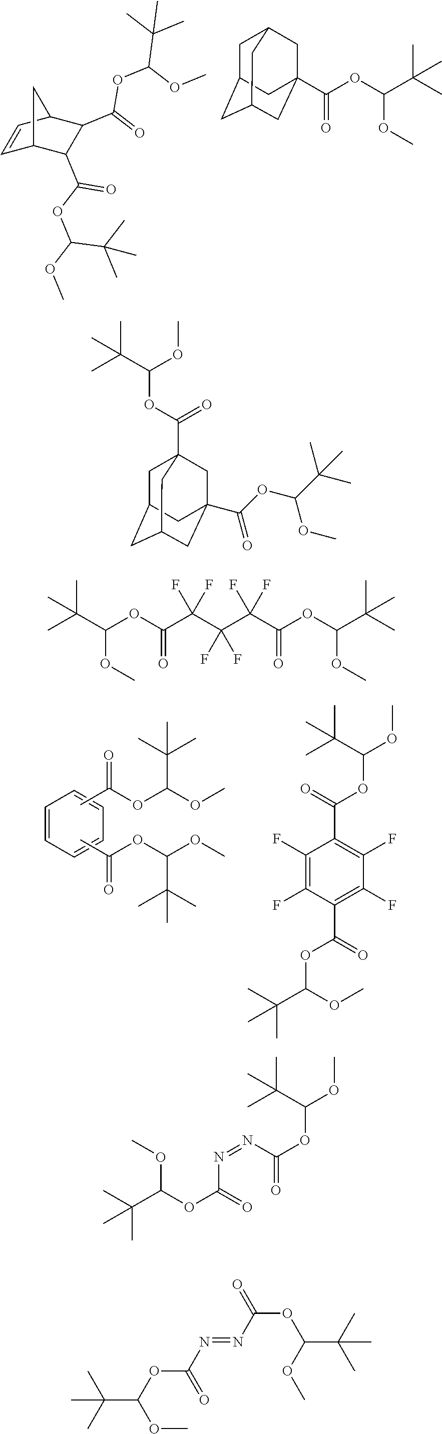

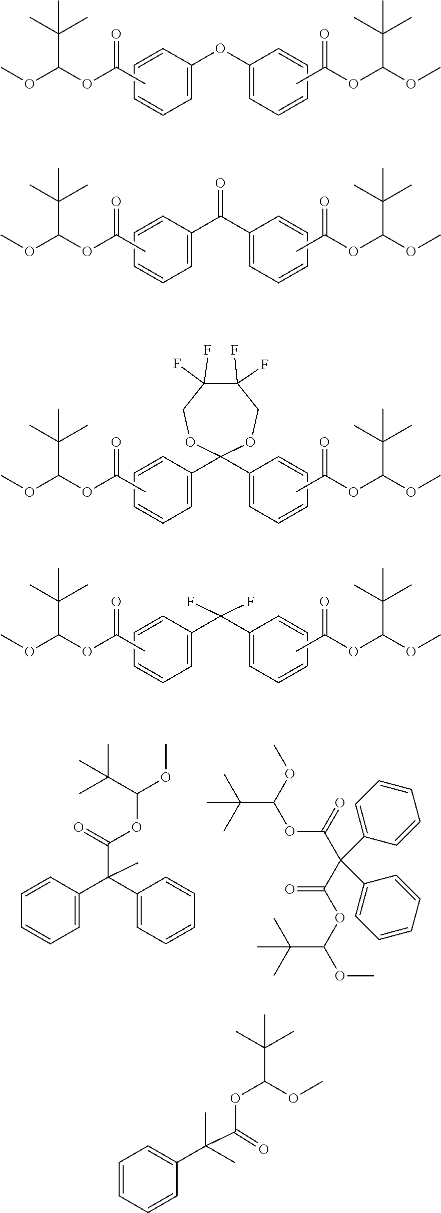

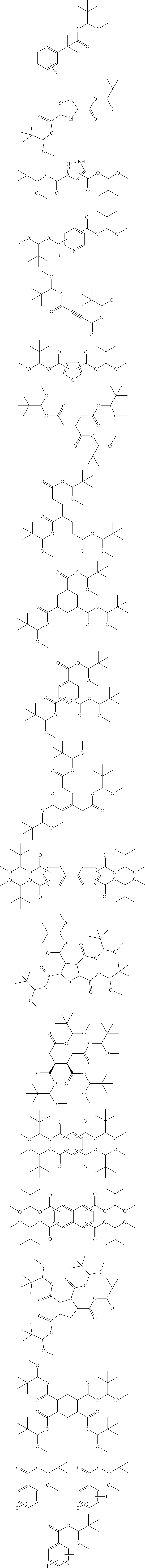

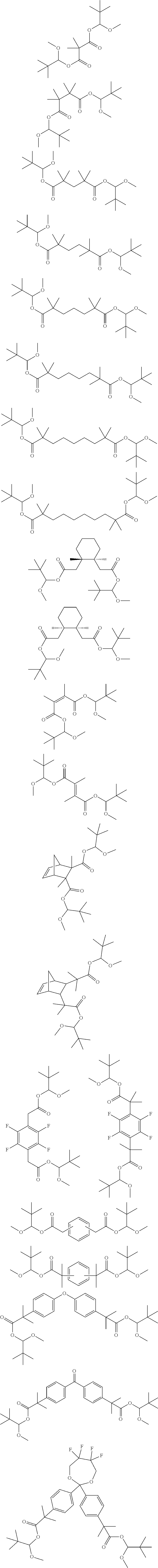

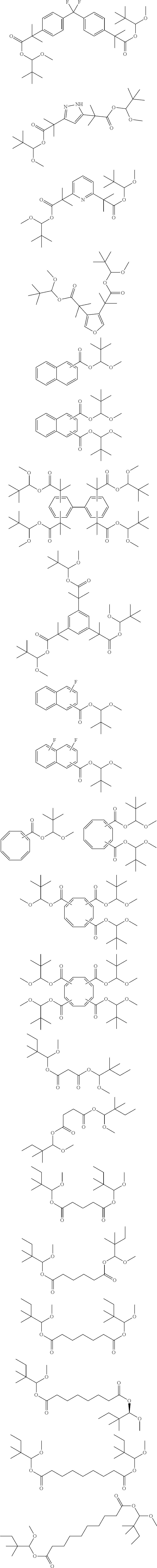

[chemical structure]

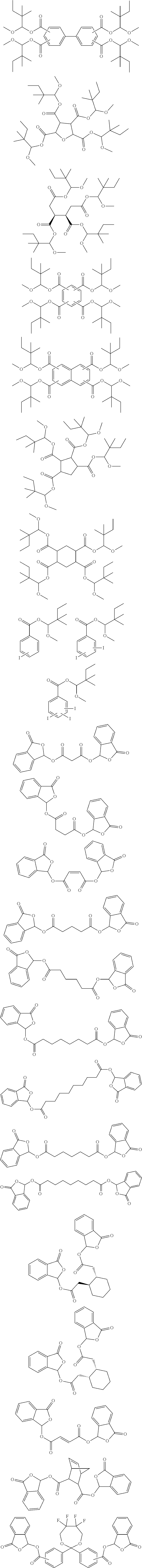

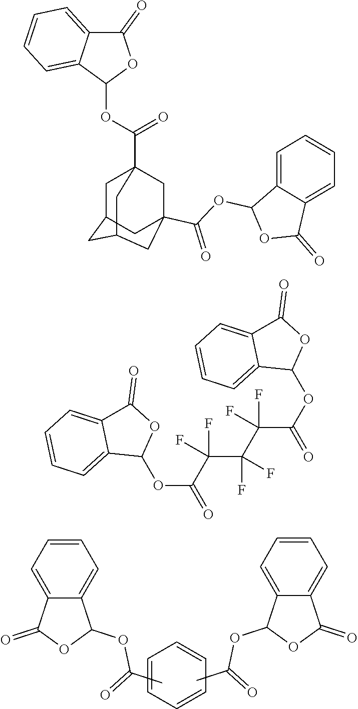

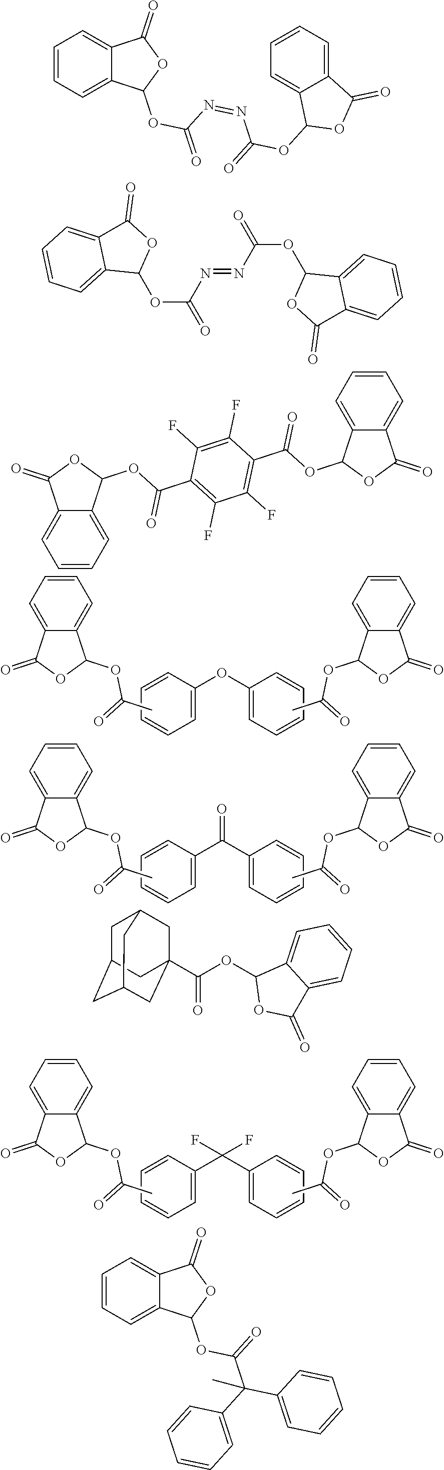

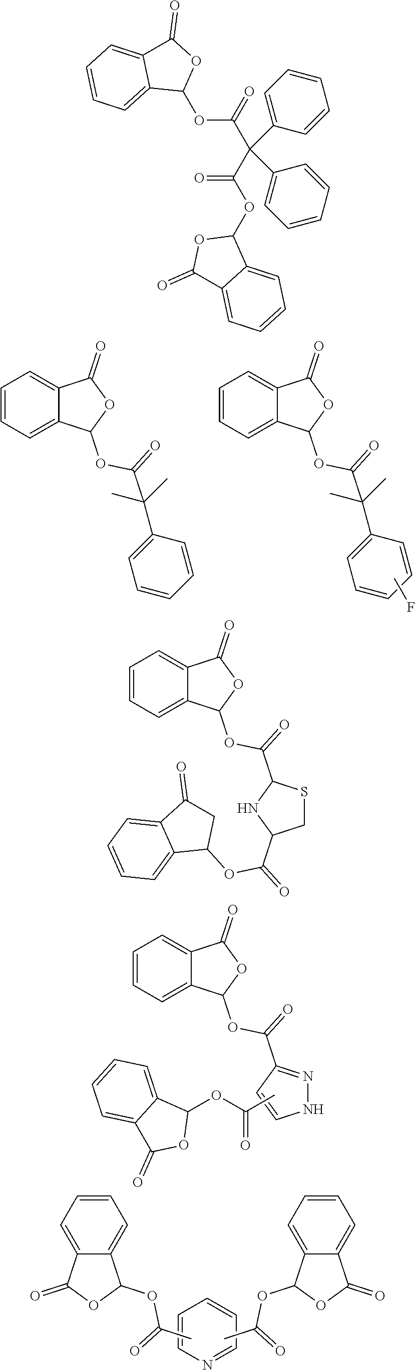

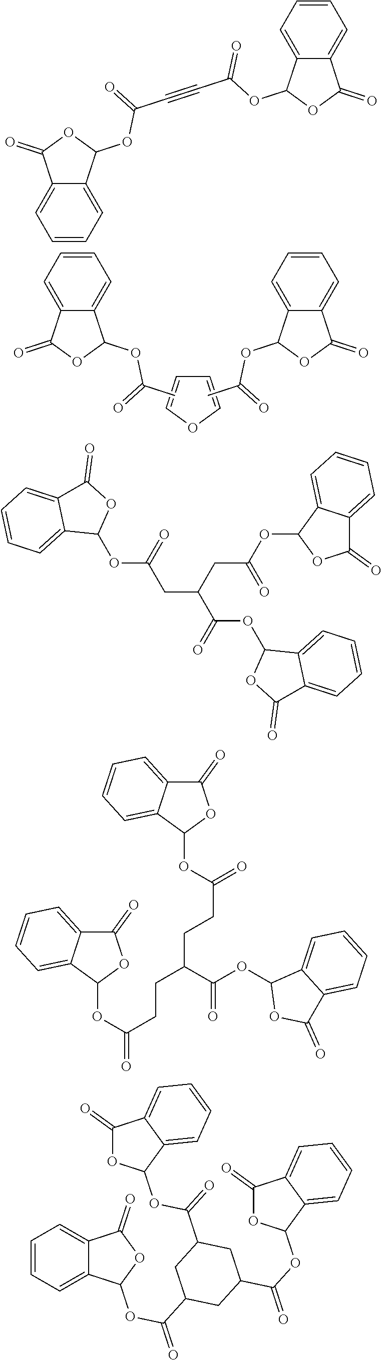

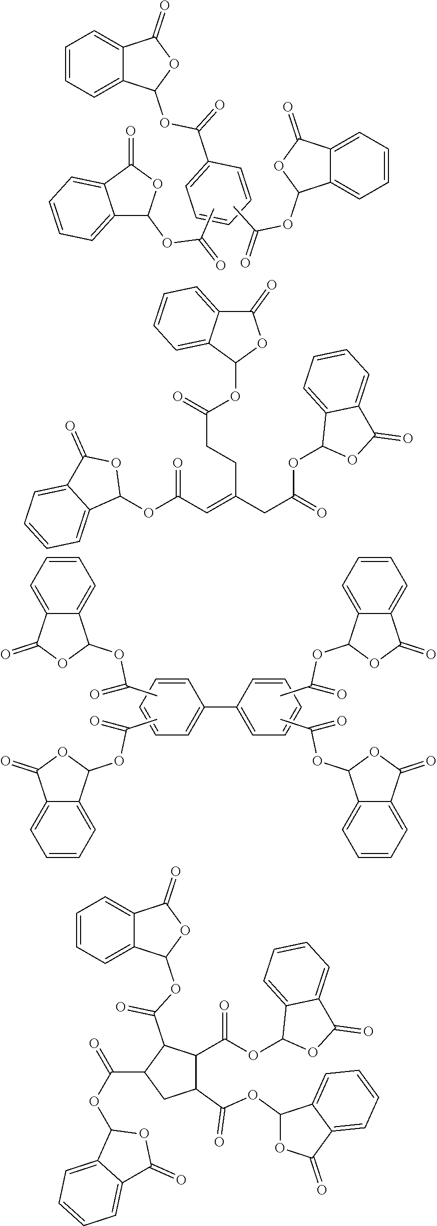

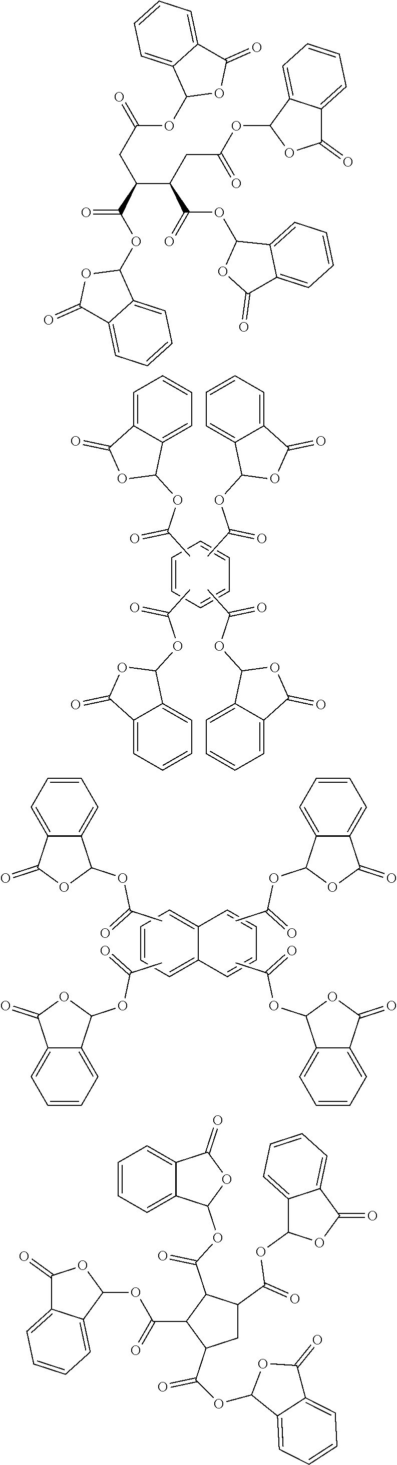

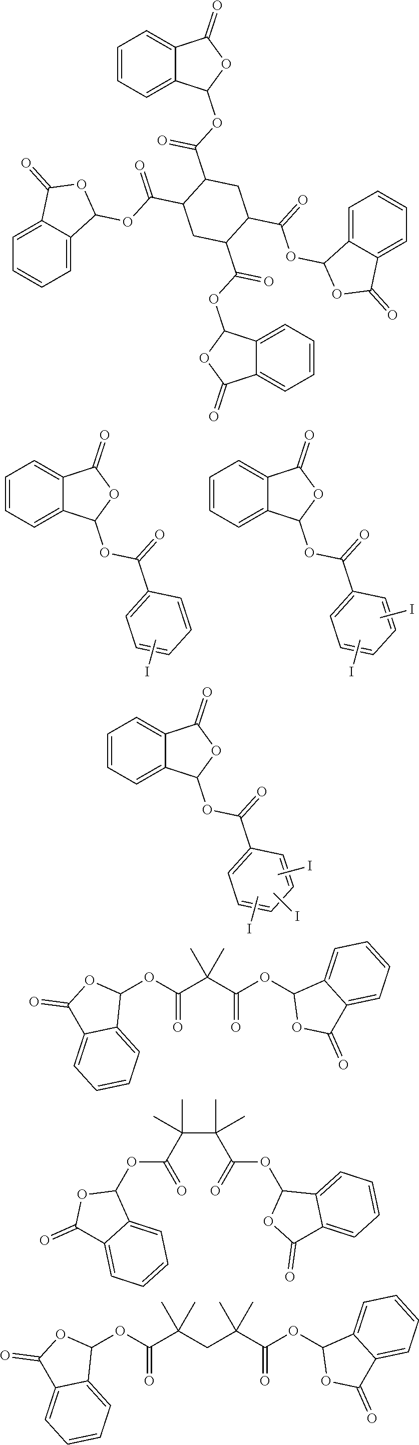

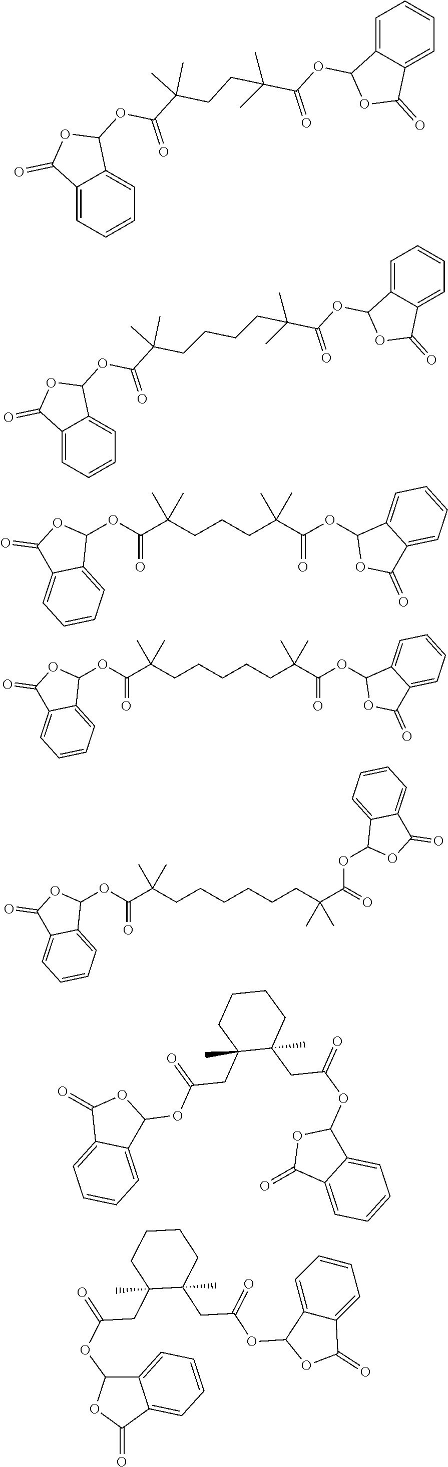

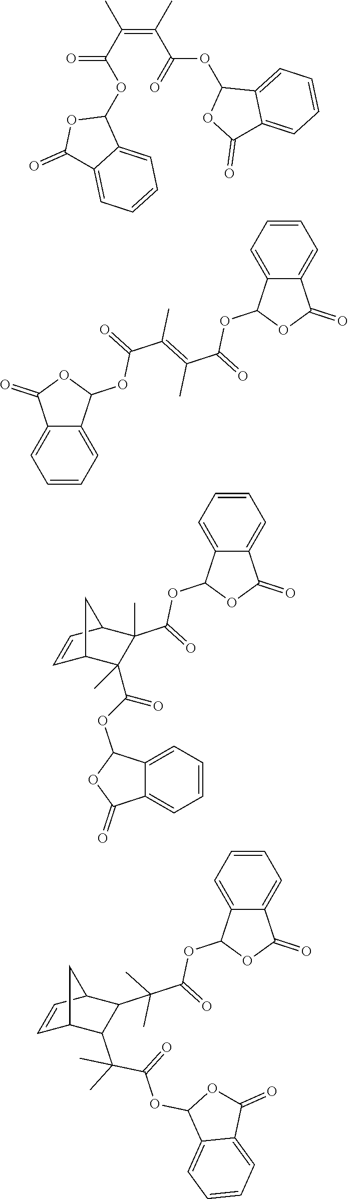 [SMILES: C/C(C(=O)OC1OC(=O)c2ccccc21)=C(\C)C(=O)OC1OC(=O)c2ccccc21 ; C/C(C(=O)OC1OC(=O)c2ccccc21)=C(/C)C(=O)OC1OC(=O)c2ccccc21 ; CC1(C(=O)OC2OC(=O)c3ccccc32)C2C=CC(C2)C1(C)C(=O)OC1OC(=O)c2ccccc21 ; CC(C)(C(=O)OC1OC(=O)c2ccccc21)C1C2C=CC(C2)C1C(C)(C)C(=O)OC1OC(=O)c2ccccc21]

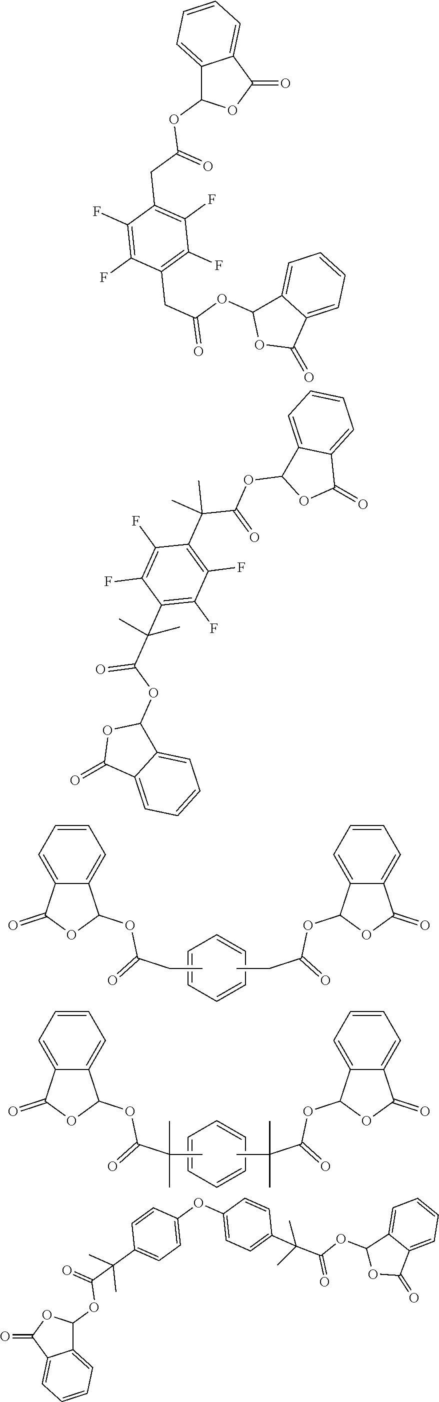

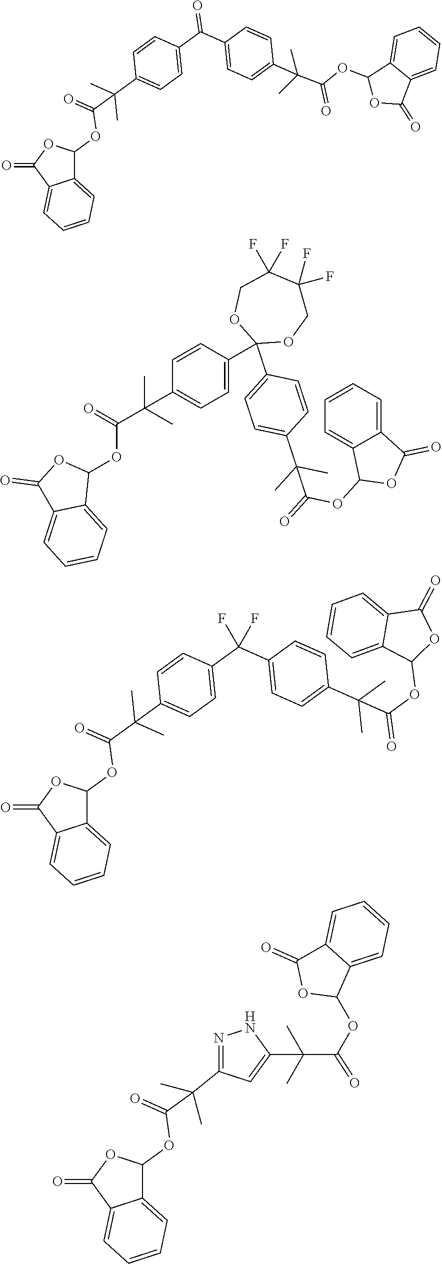 [SMILES: CC(C)(C(=O)OC1OC(=O)c2ccccc21)c1ccc(C(=O)c2ccc(C(C)(C)C(=O)OC3OC(=O)c4ccccc43)cc2)cc1 ; CC(C)(C(=O)OC1OC(=O)c2ccccc21)c1ccc(C2(c3ccc(C(C)(C)C(=O)OC4OC(=O)c5ccccc54)cc3)OCC(F)(F)C(F)(F)CO2)cc1 ; CC(C)(C(=O)OC1OC(=O)c2ccccc21)c1ccc(C(F)(F)c2ccc(C(C)(C)C(=O)OC3OC(=O)c4ccccc43)cc2)cc1 ; CC(C)(C(=O)OC1OC(=O)c2ccccc21)c1cc(C(C)(C)C(=O)OC2OC(=O)c3ccccc32)[nH]n1]

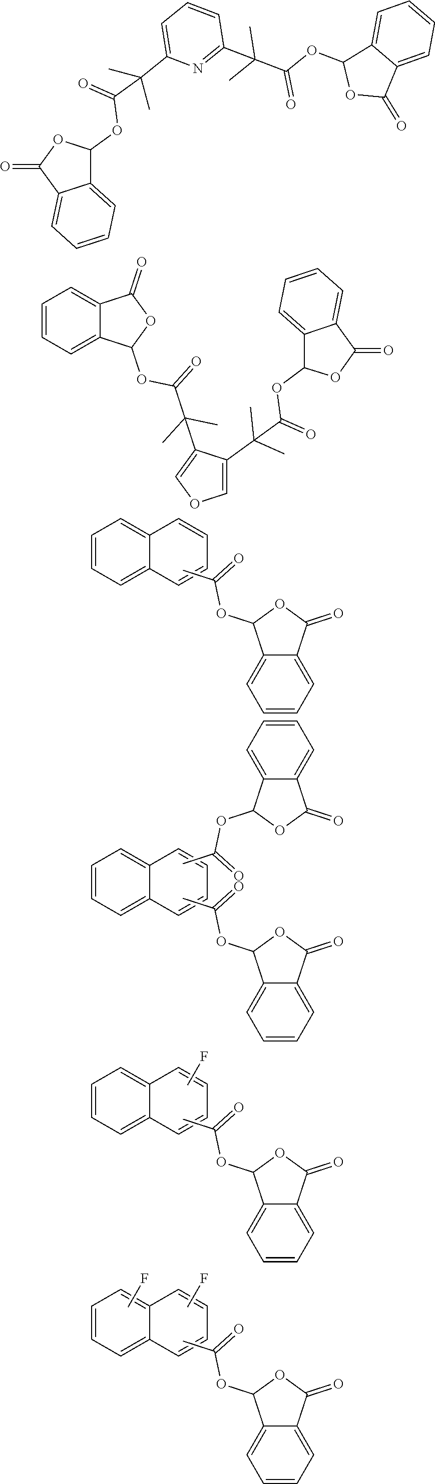

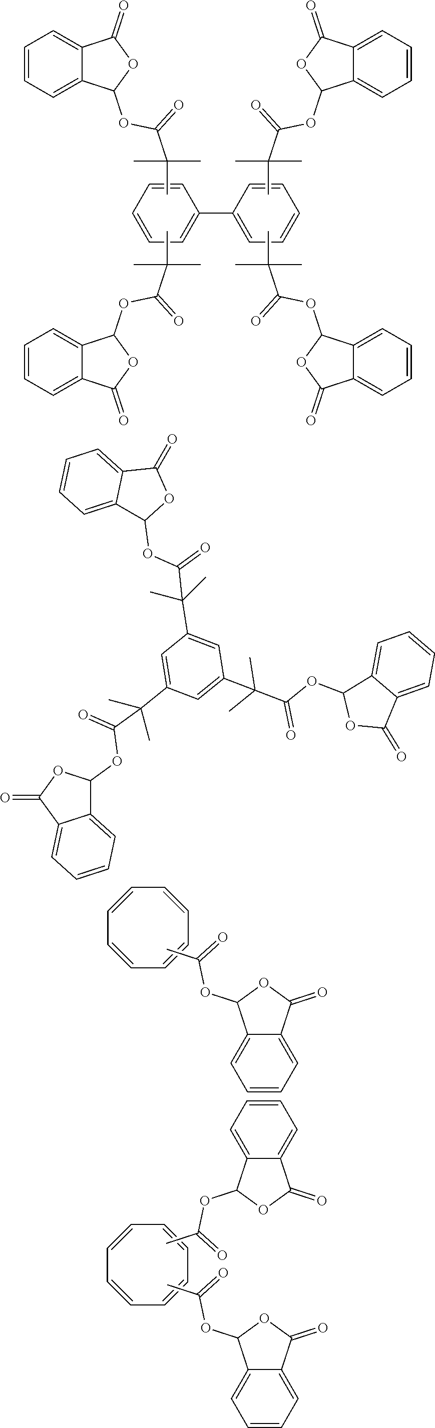

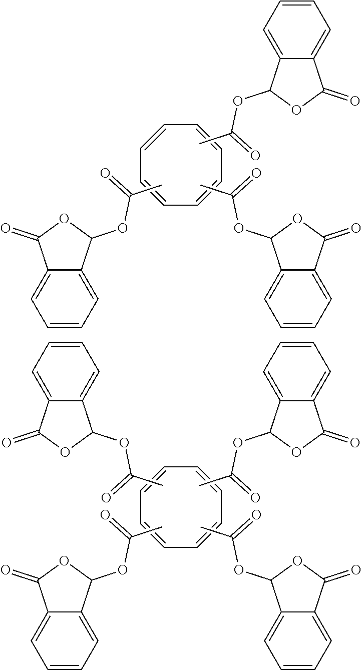

Examples of the carboxylic acid derivative-containing repeat unit having formula (6) are shown below, but not limited thereto. Herein R^{A} and R^{B} are as defined above.

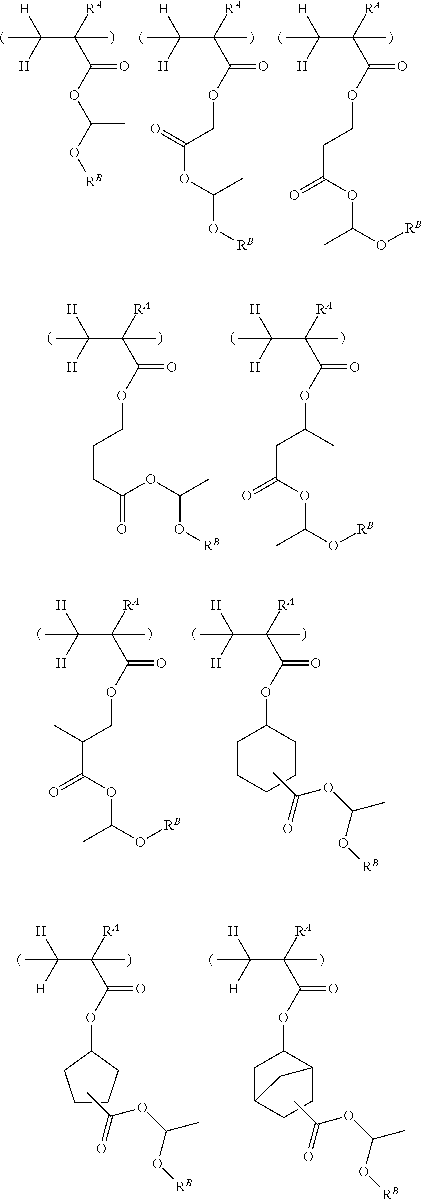

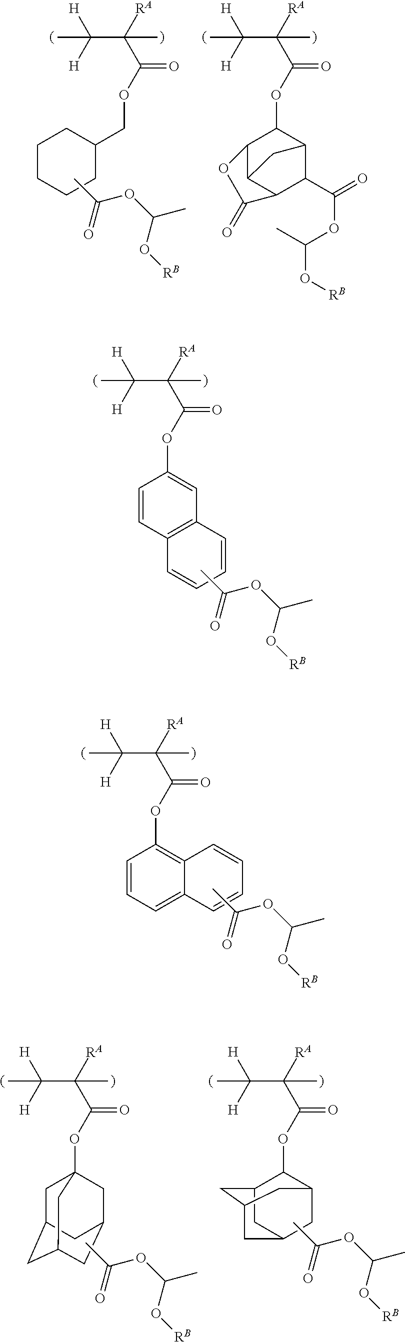

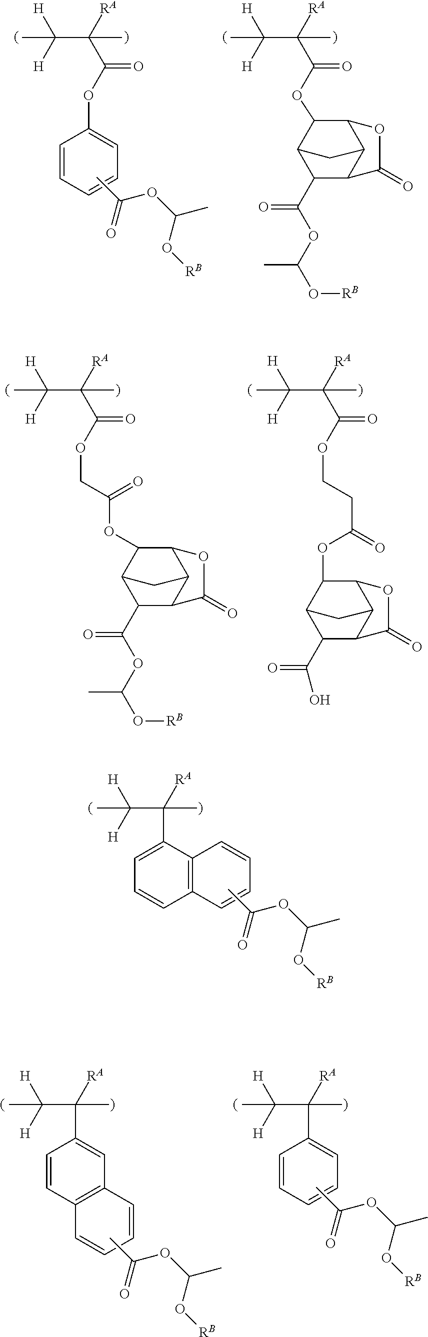

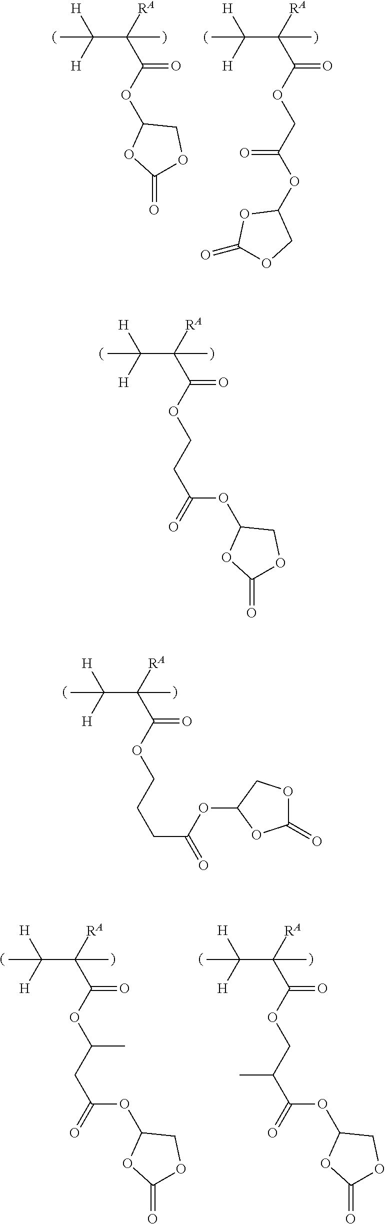

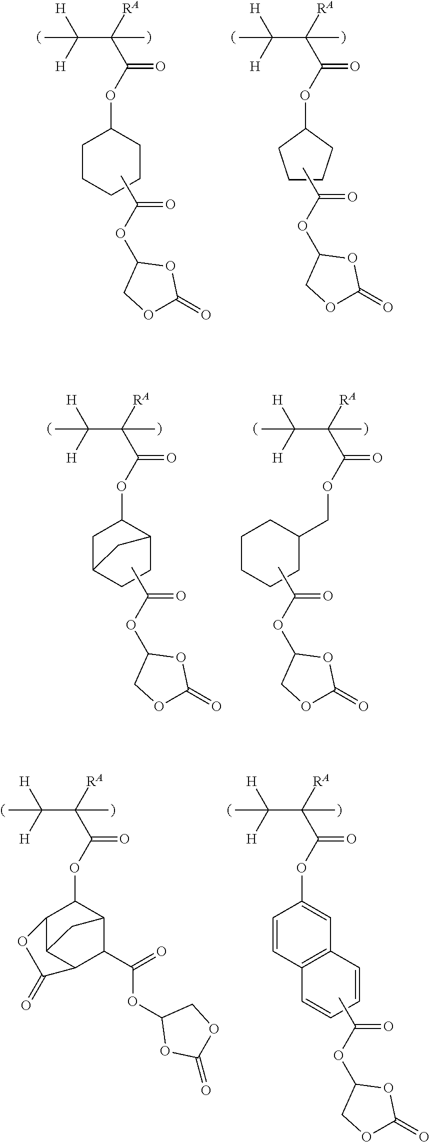

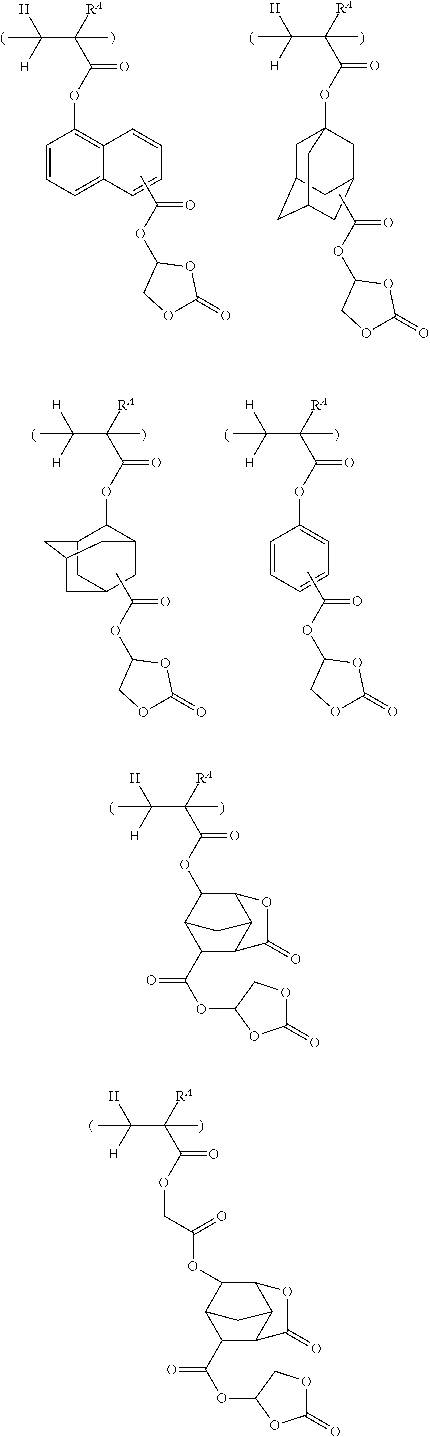

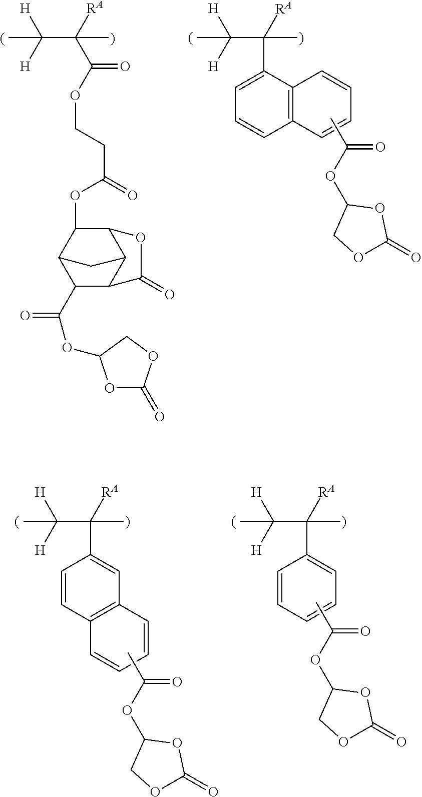

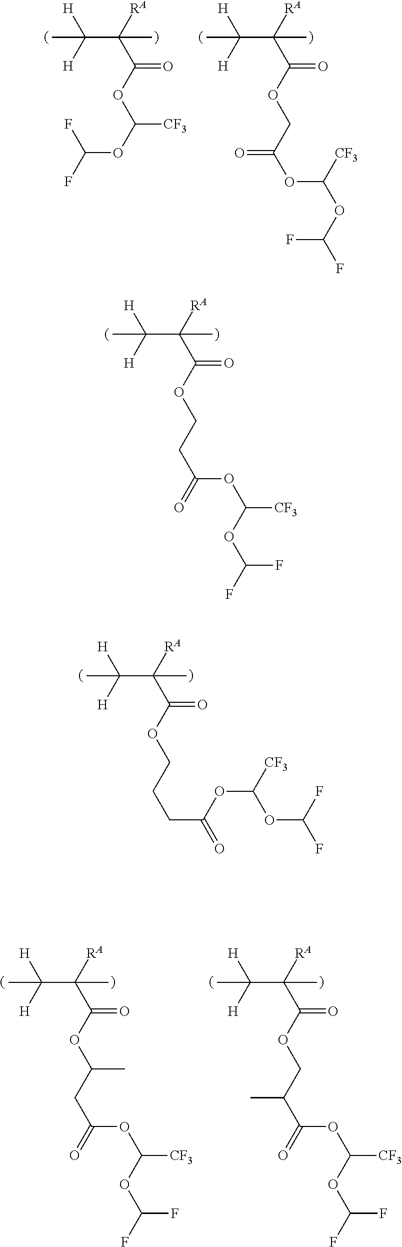

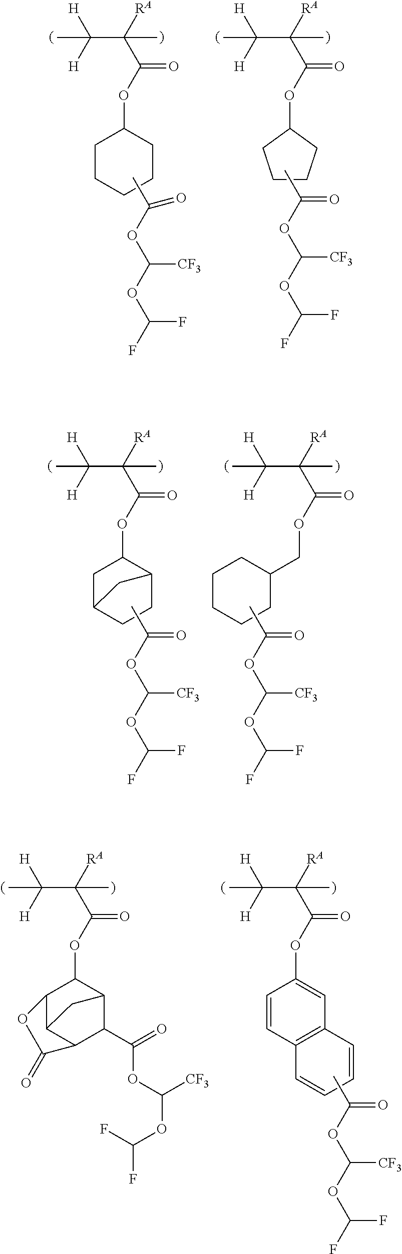

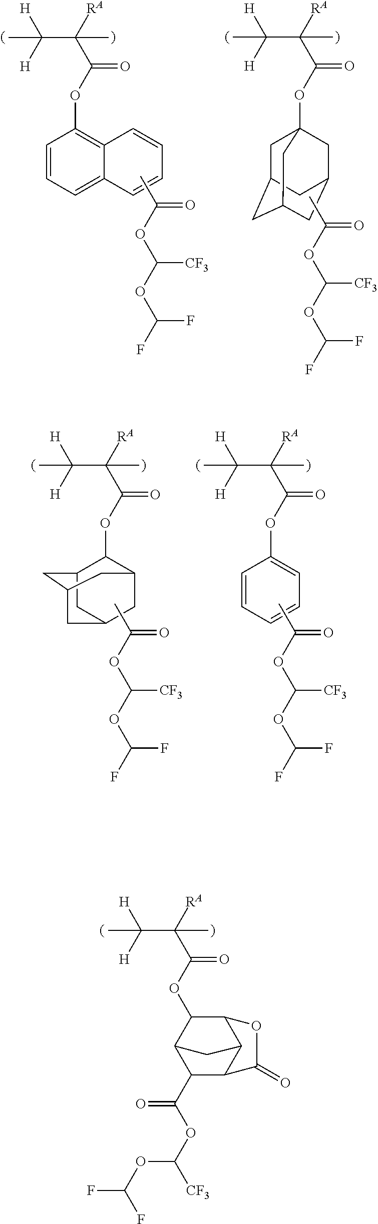

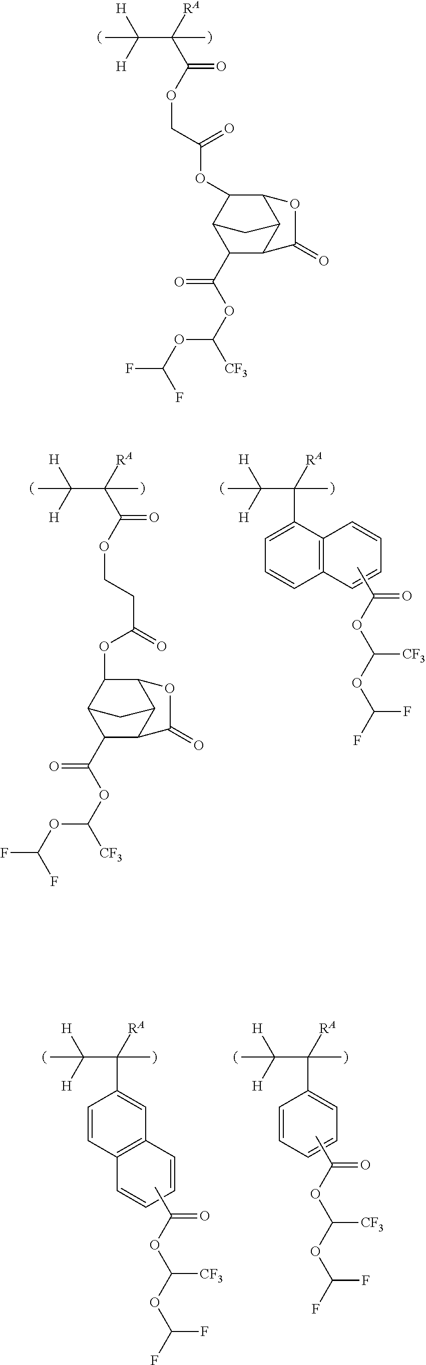

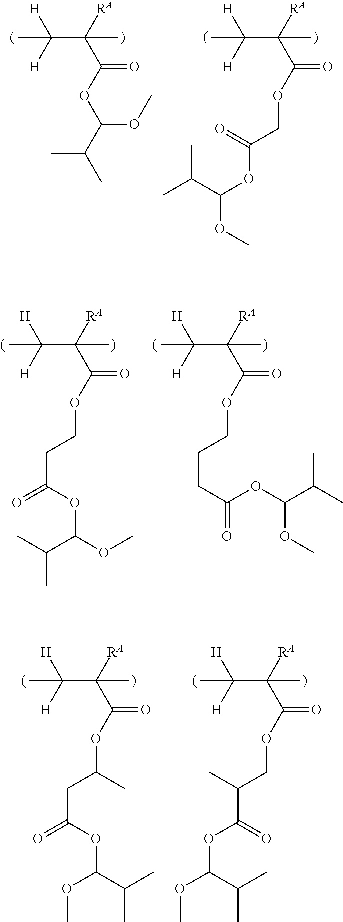

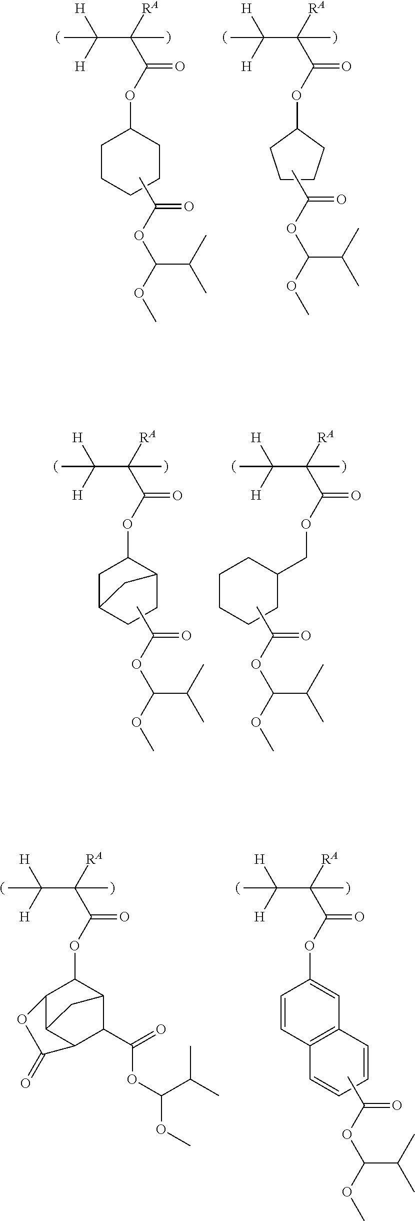

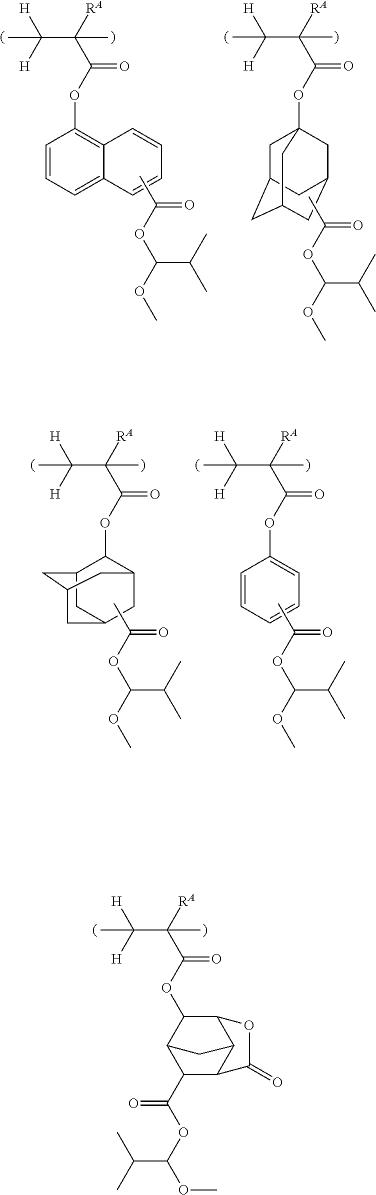

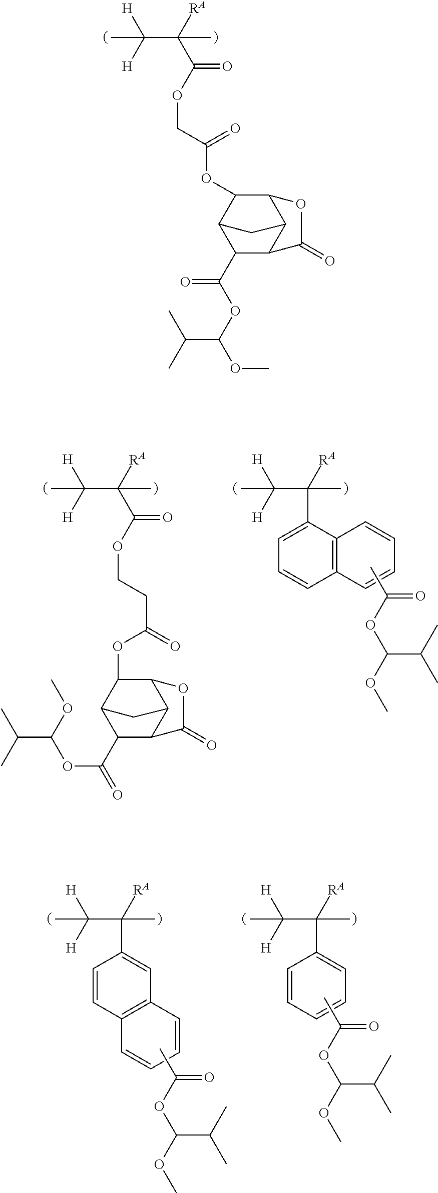

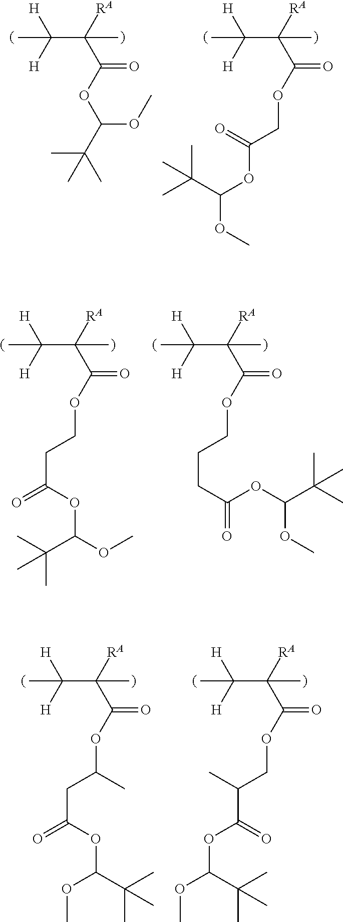

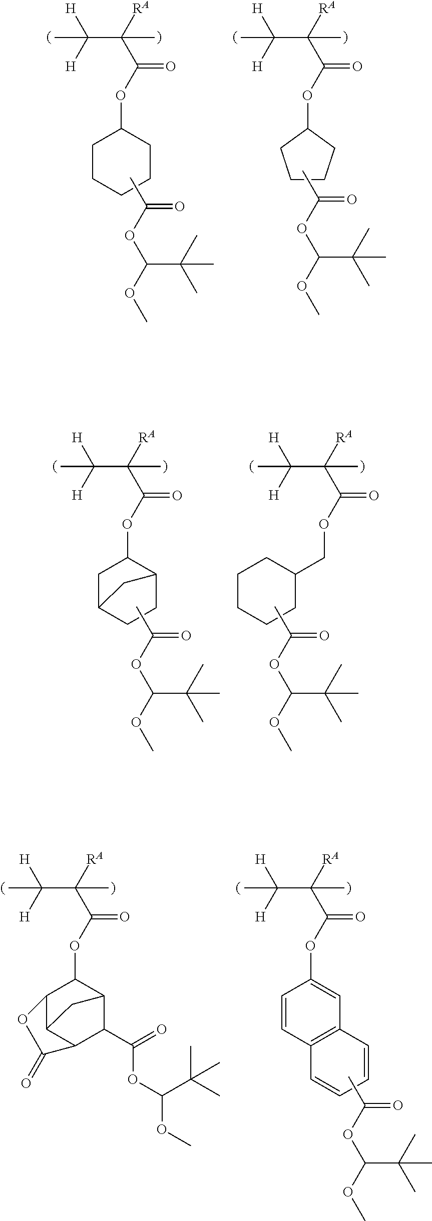

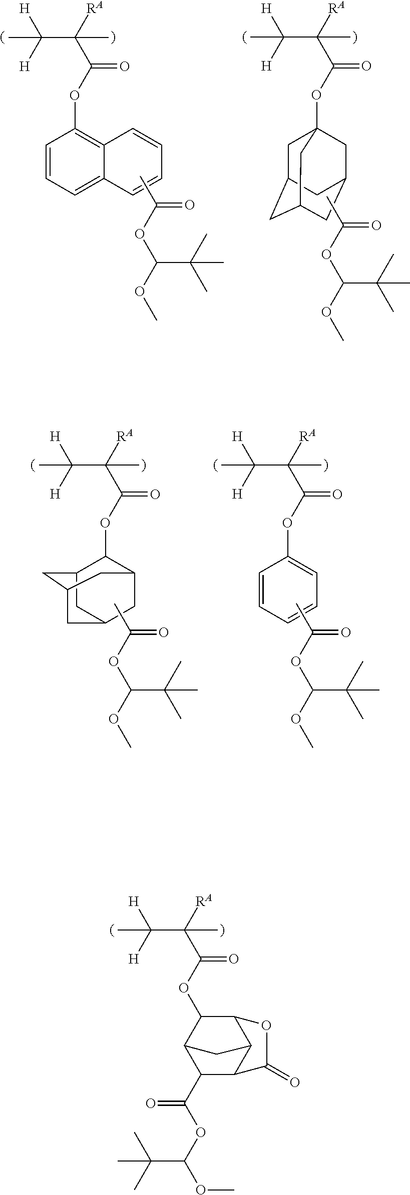

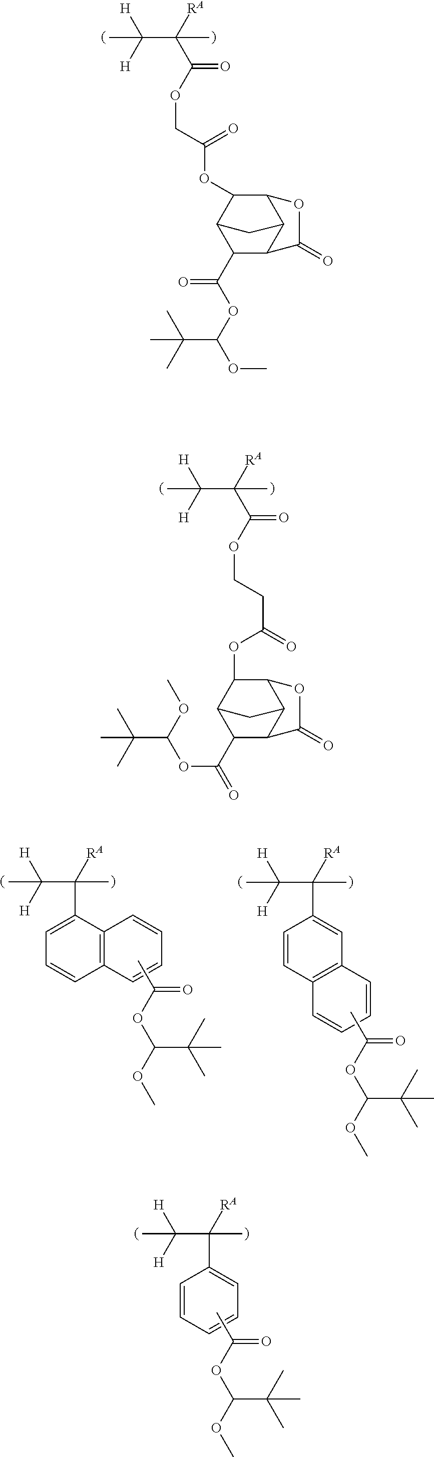

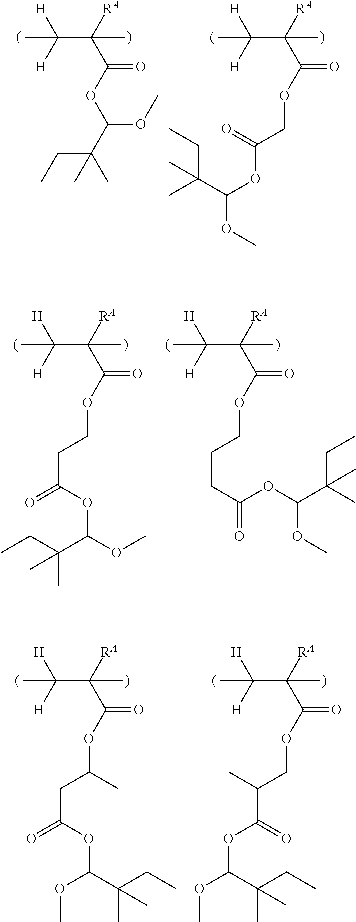

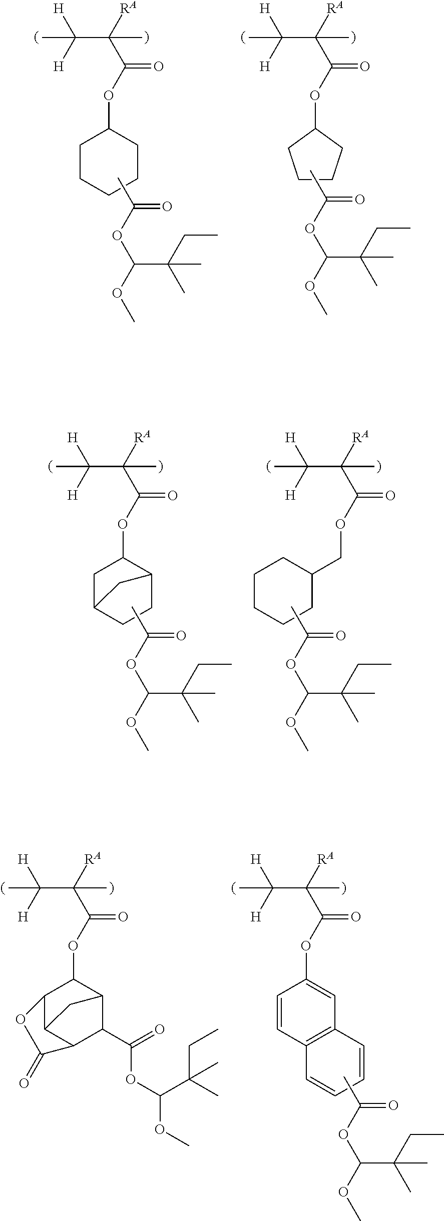

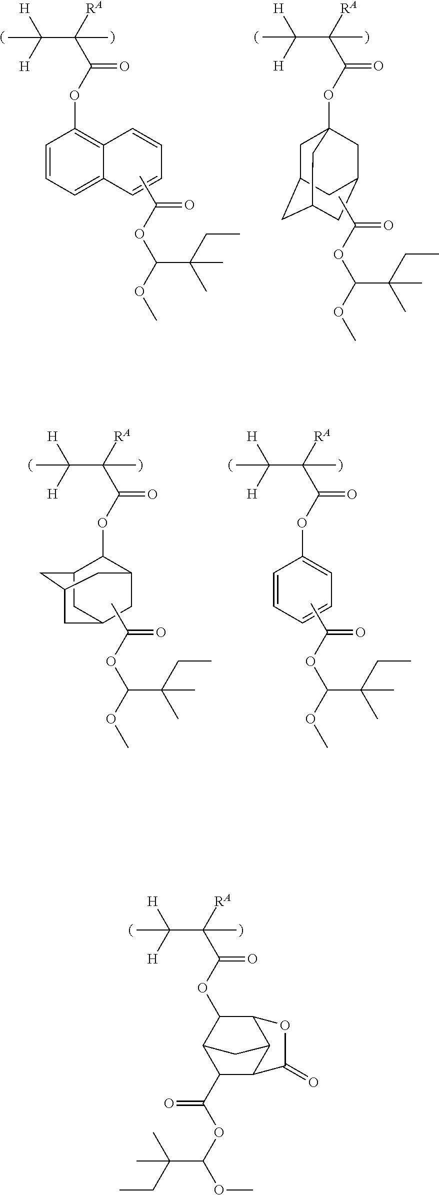

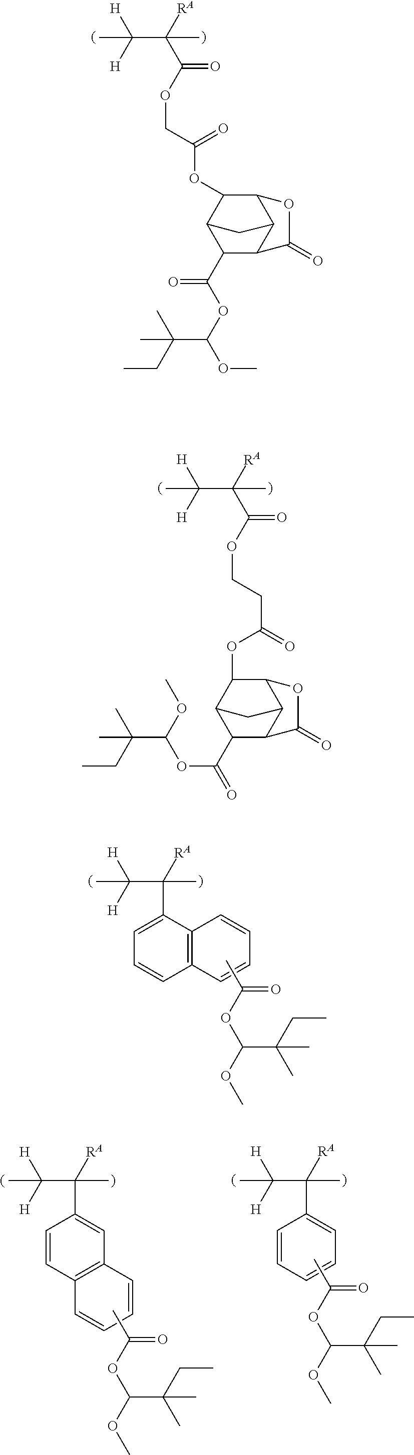

The carboxylic acid derivative-containing polymer may further comprise repeat units other than the repeat units having formula (6). Although the other repeat units are not particularly limited, preference is given to repeat units having a robust skeleton, typically repeat units having a cyclic structure from which high etch resistance is expectable and repeat units having a styrene skeleton.

Examples of the other repeat unit are shown below, but not limited thereto. Herein R^{A} is as defined above, and X^{B} is each independently —CH₂— or —O—.

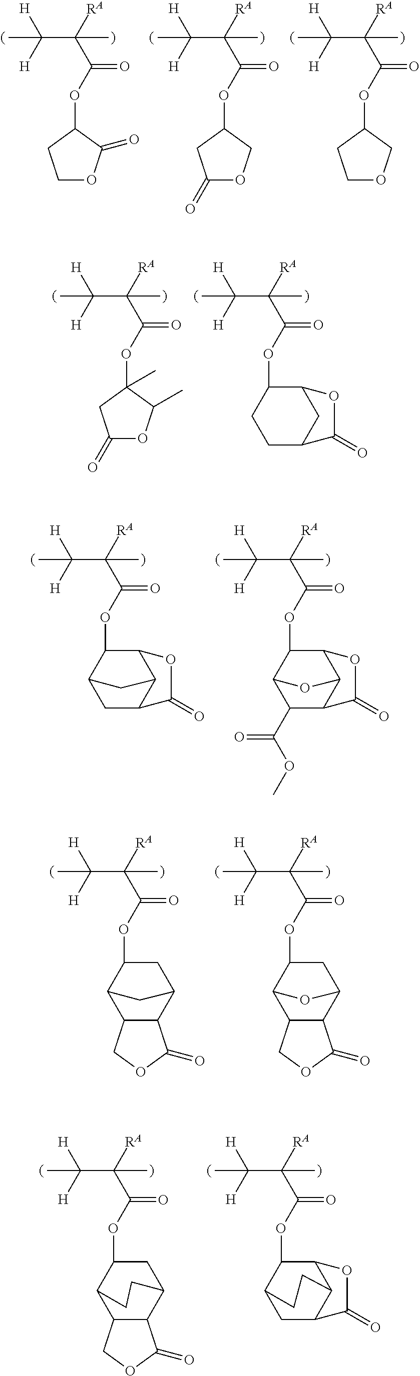

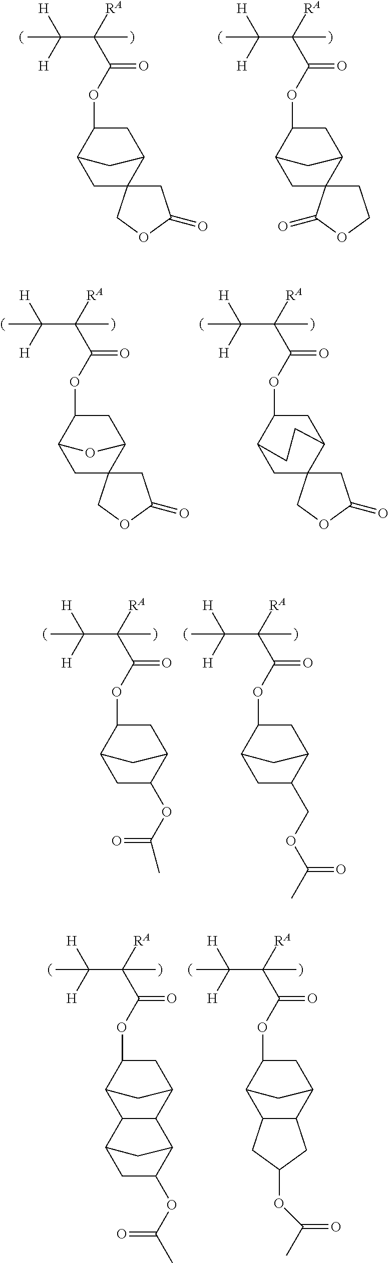

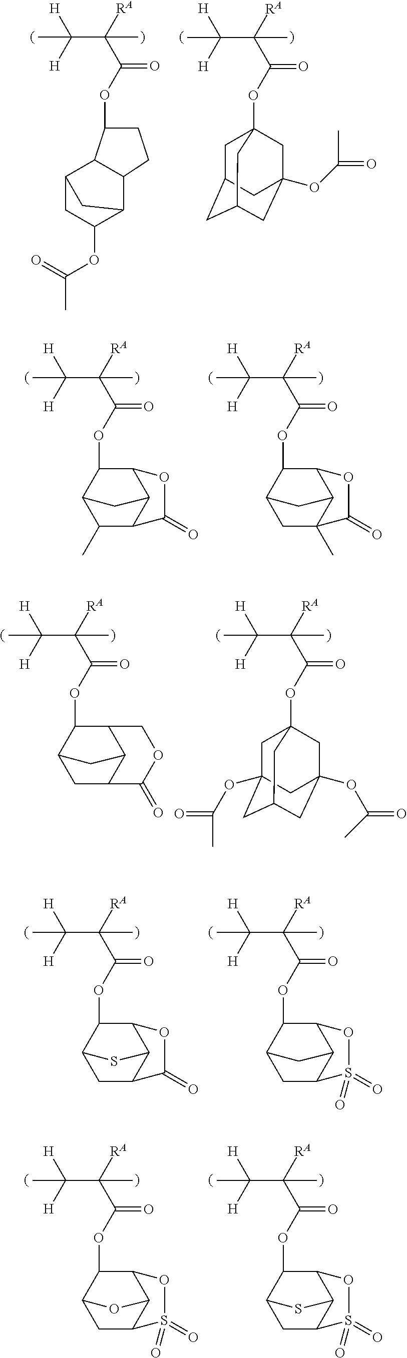

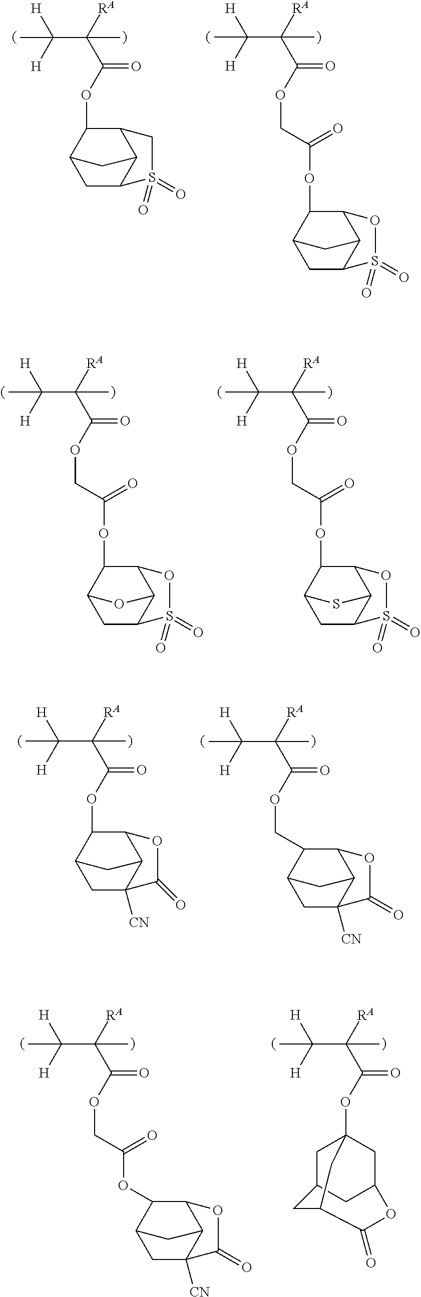

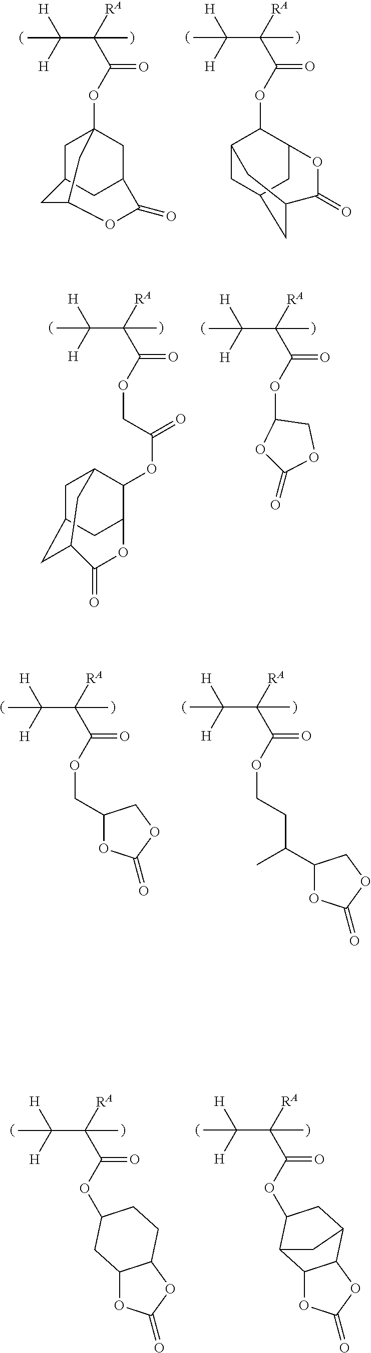

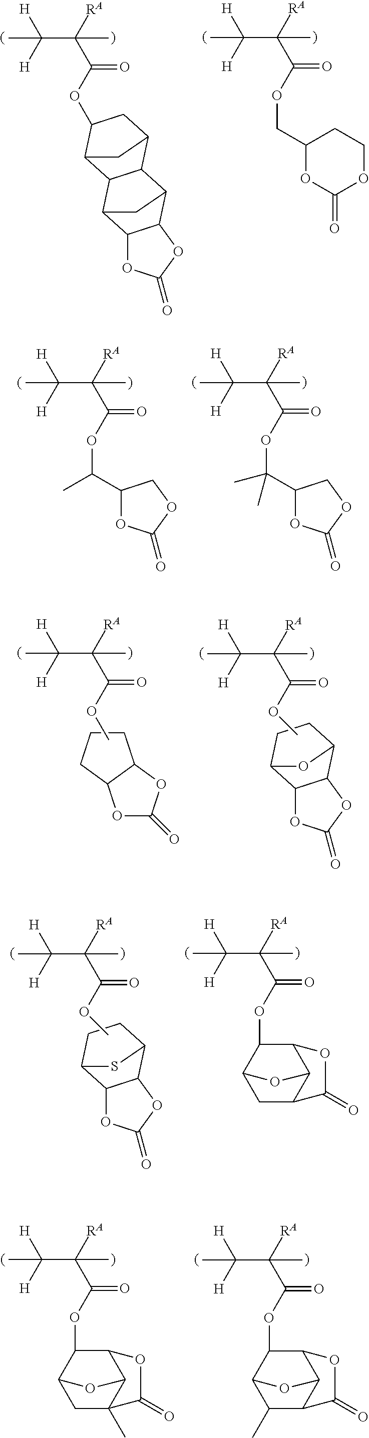

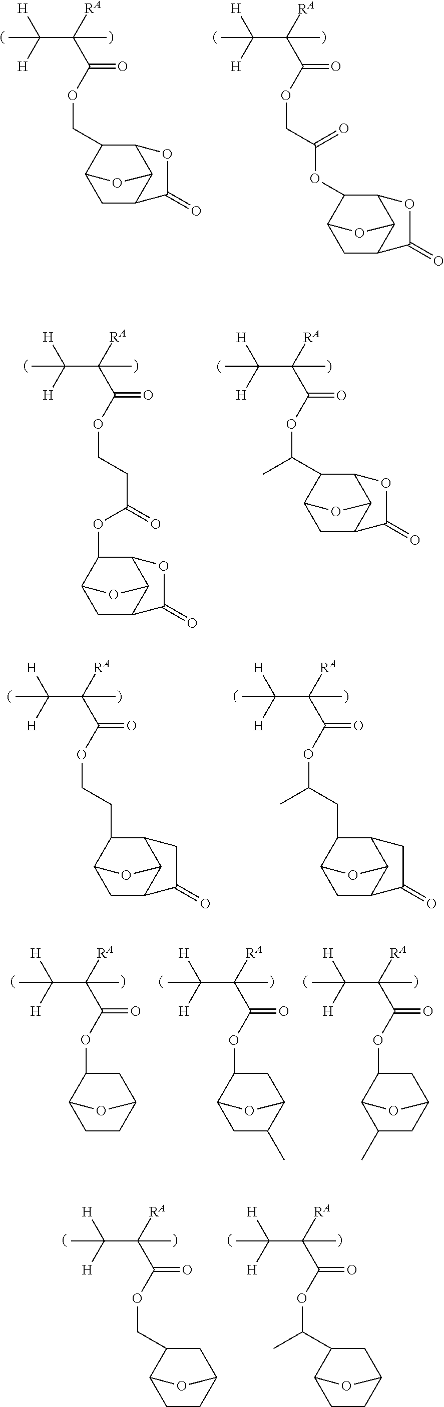

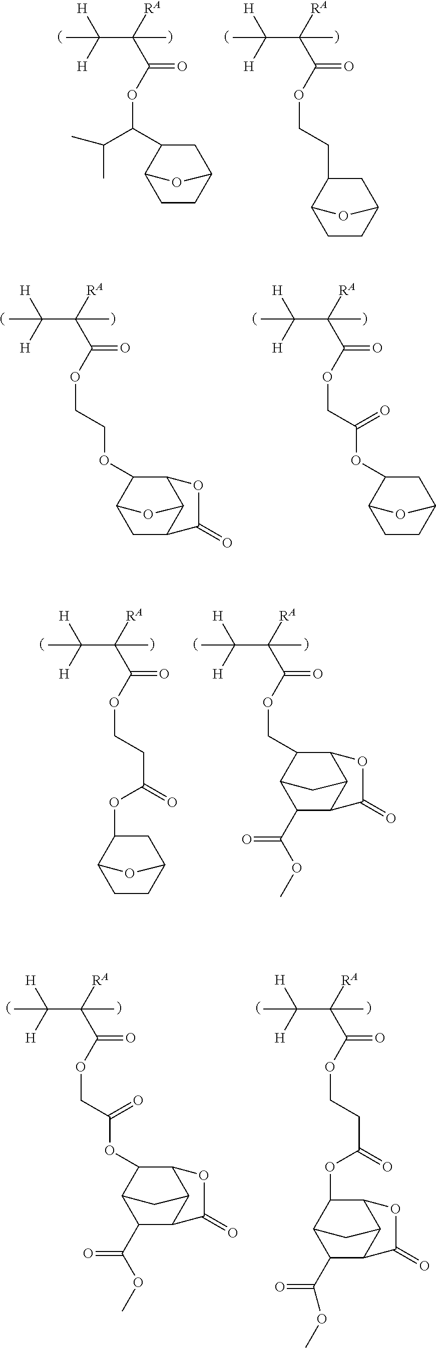

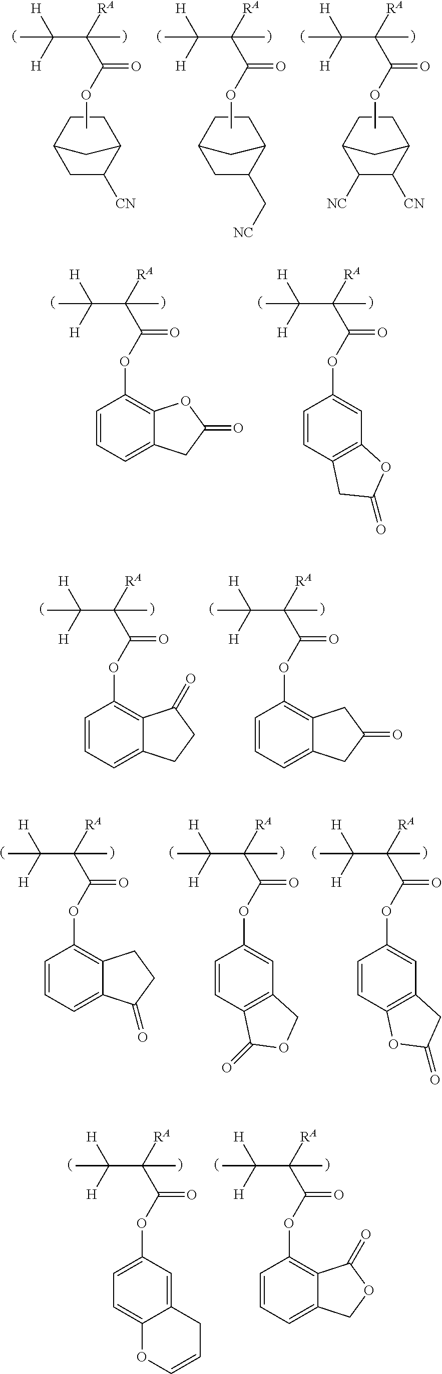

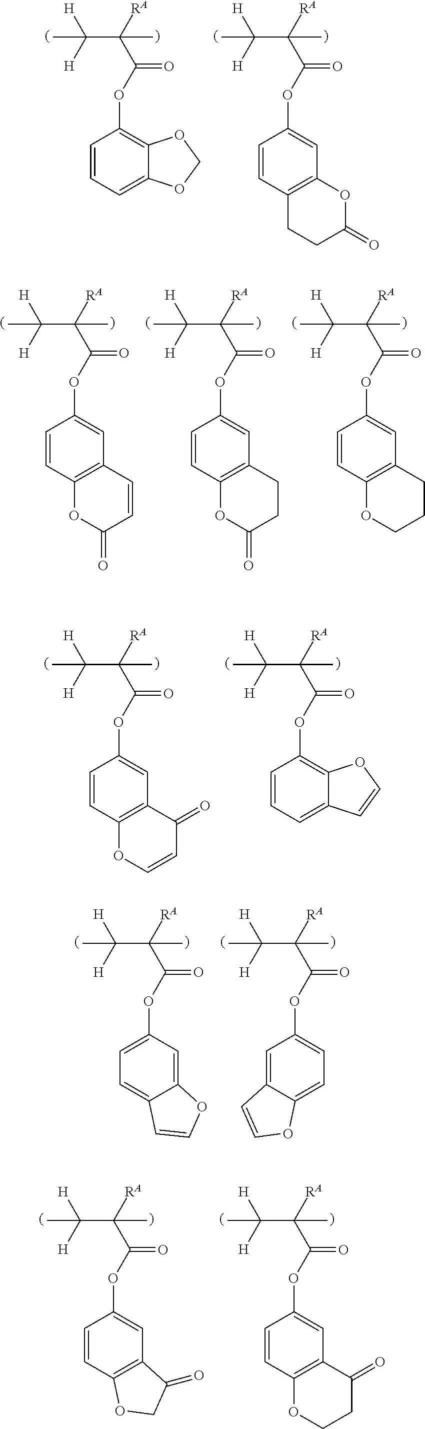

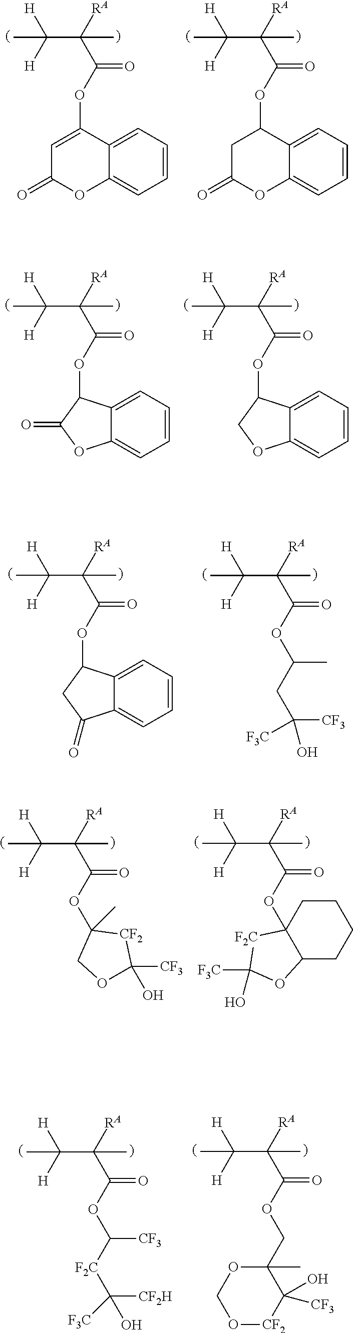

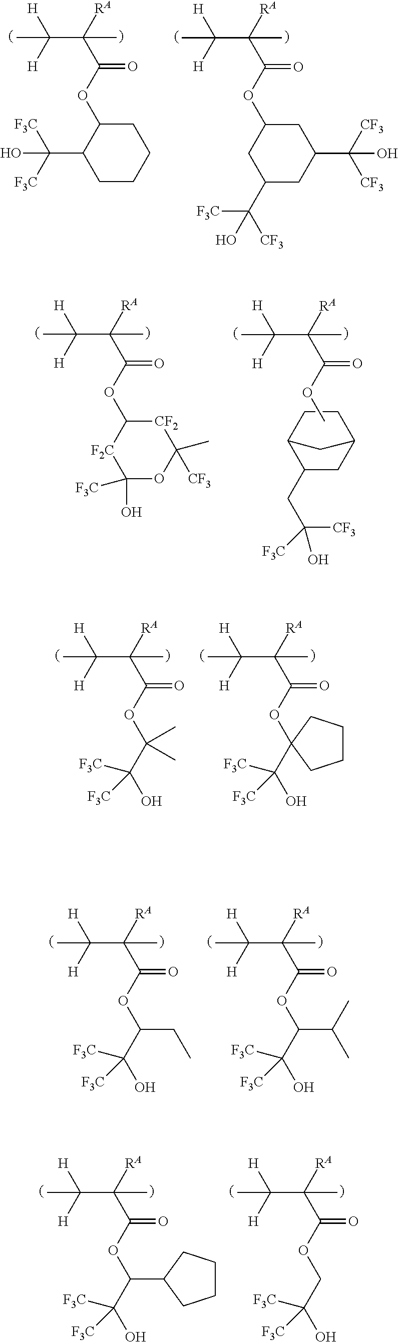

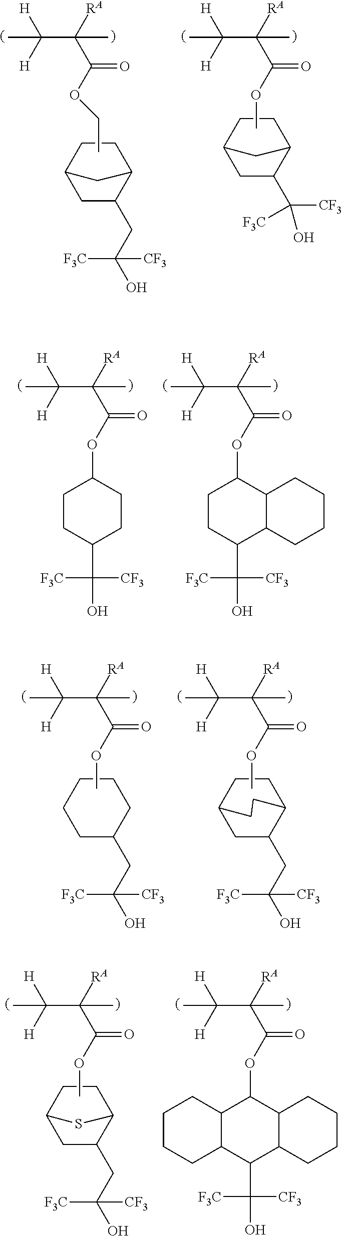

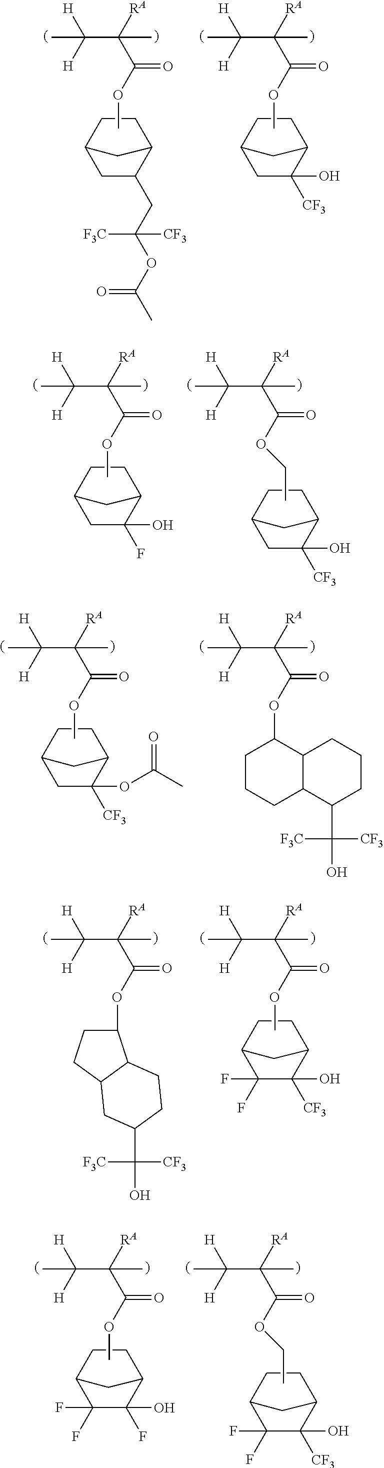

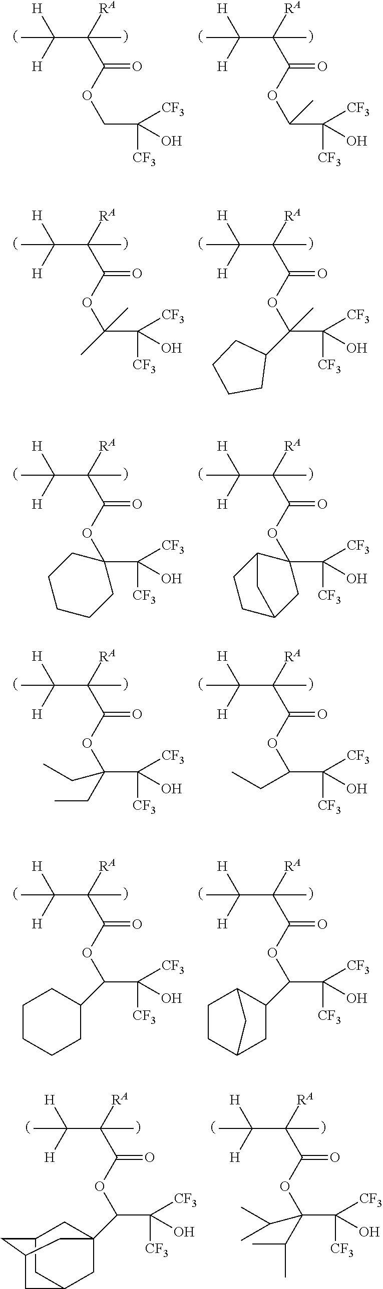

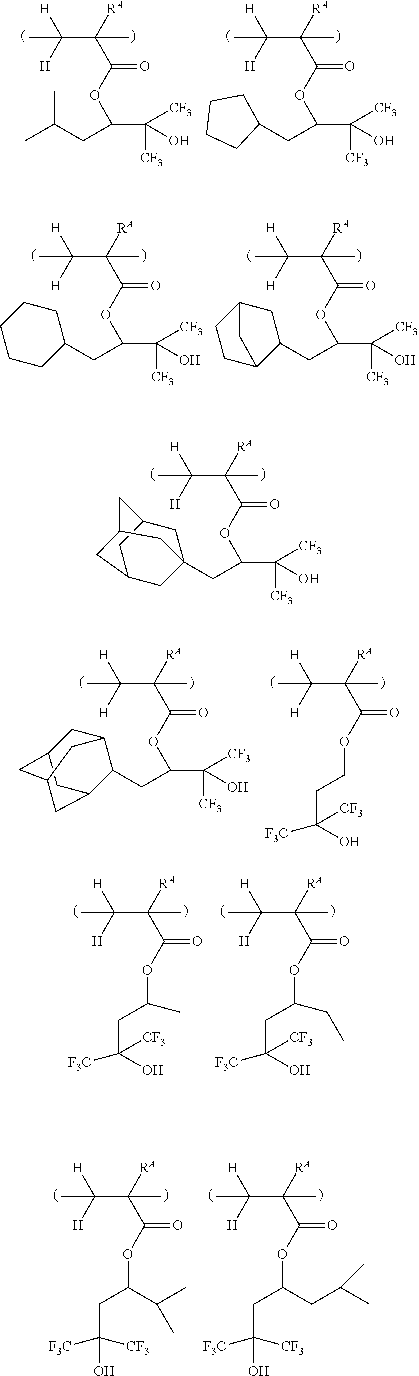

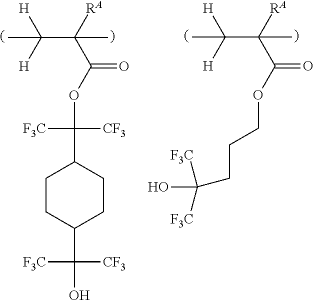

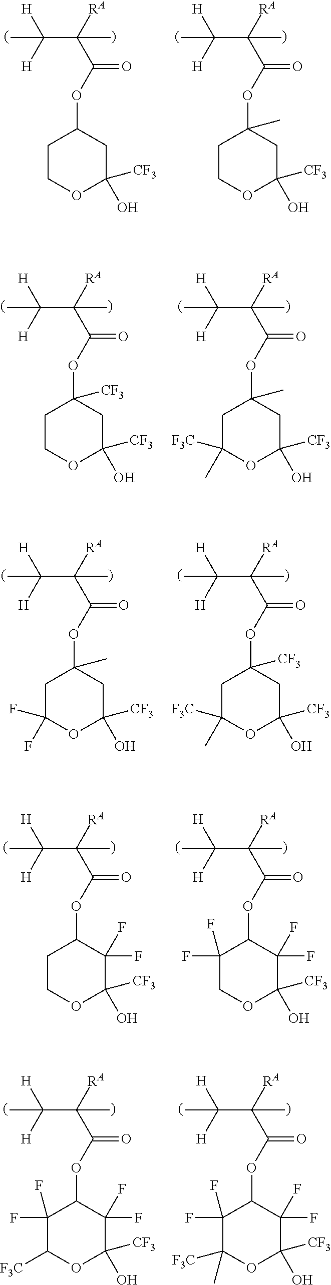

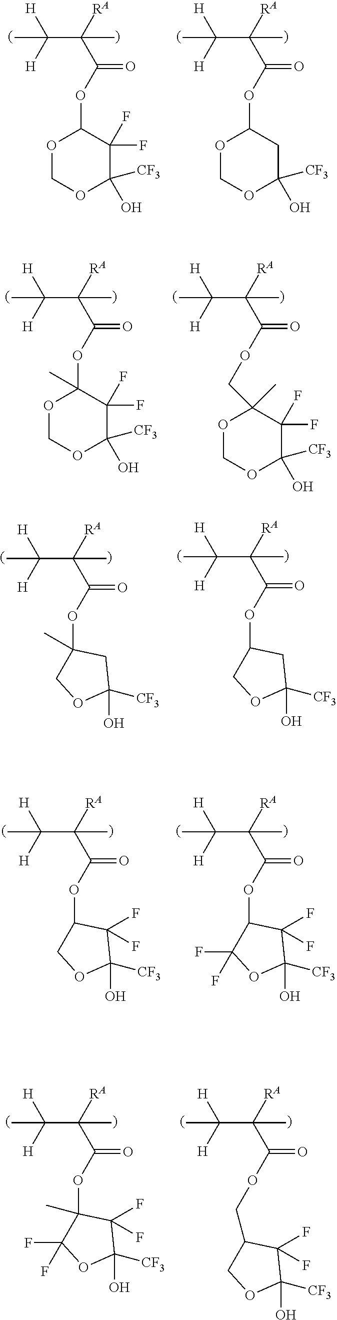

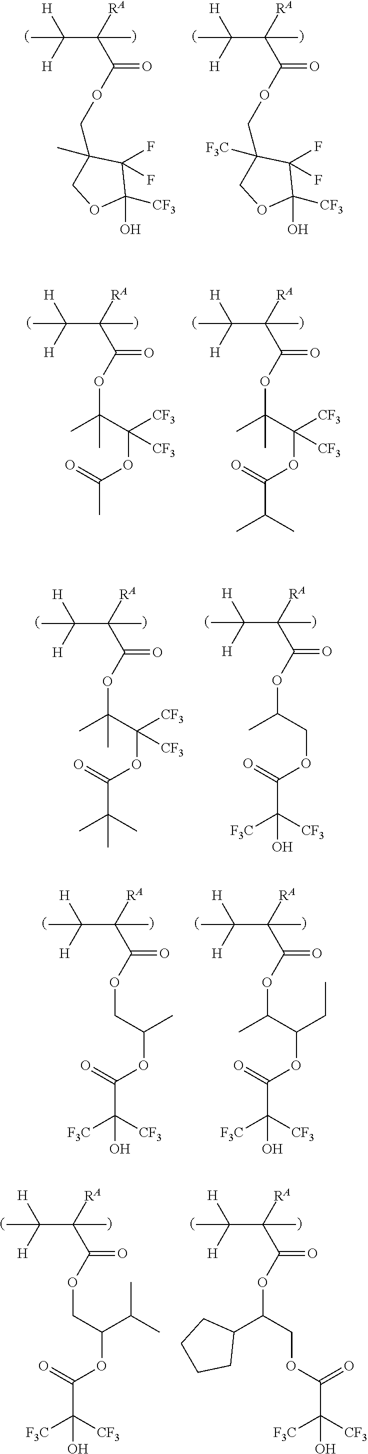

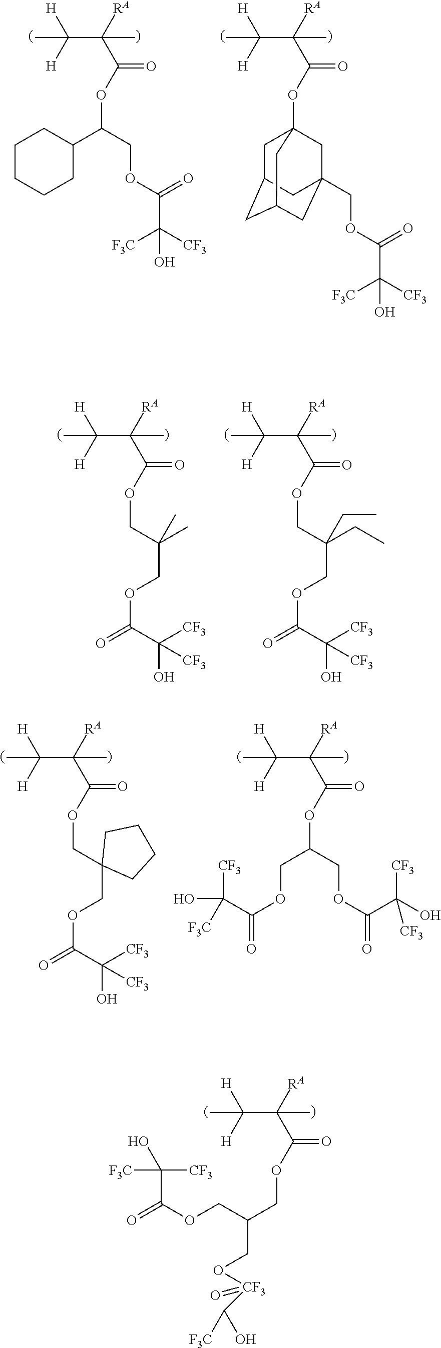

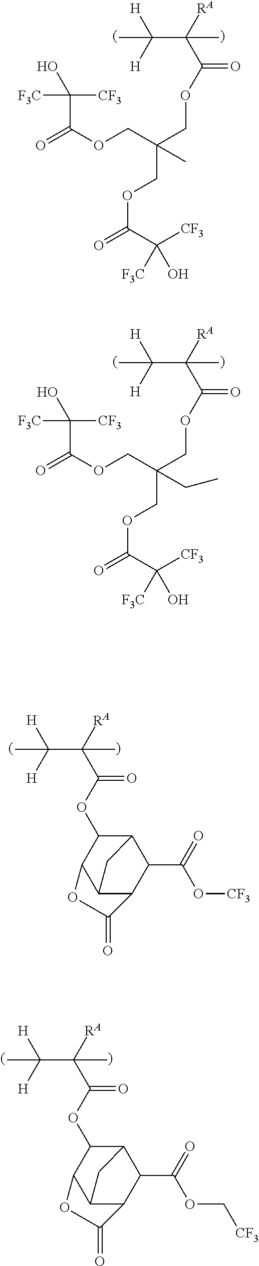

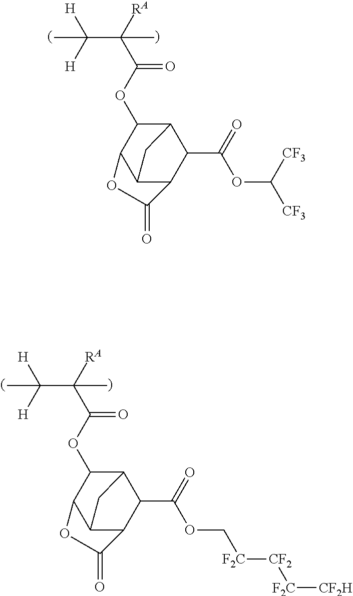

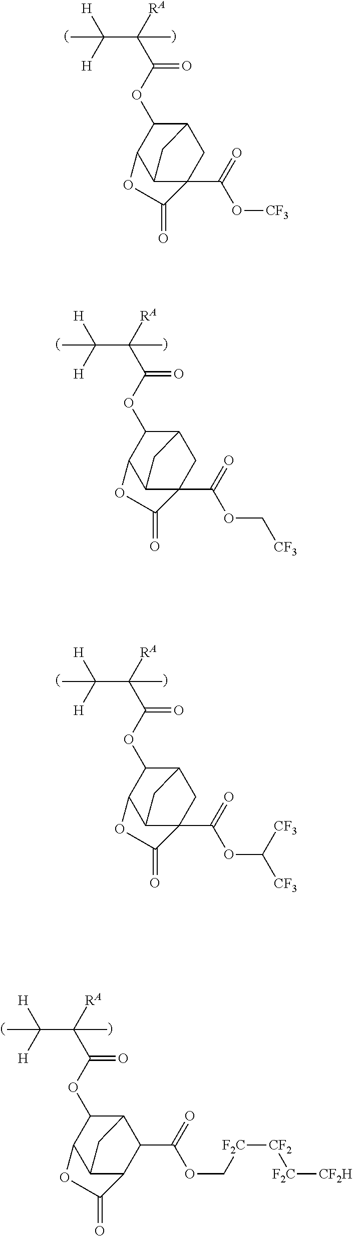

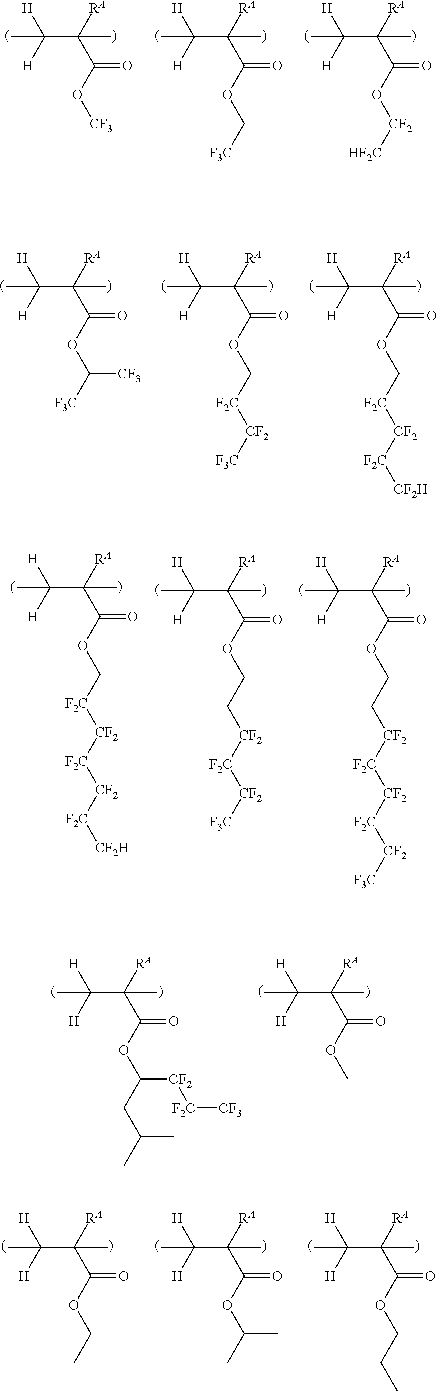

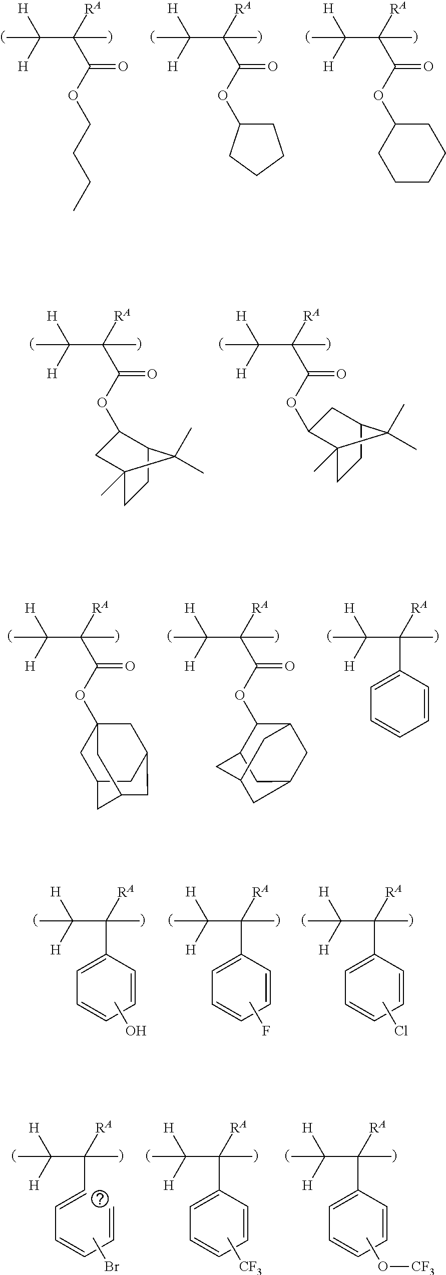

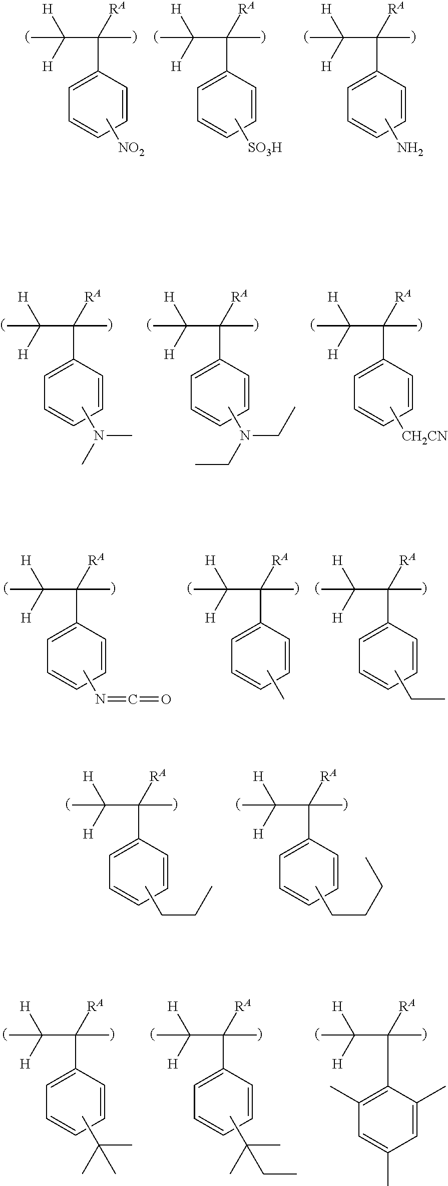

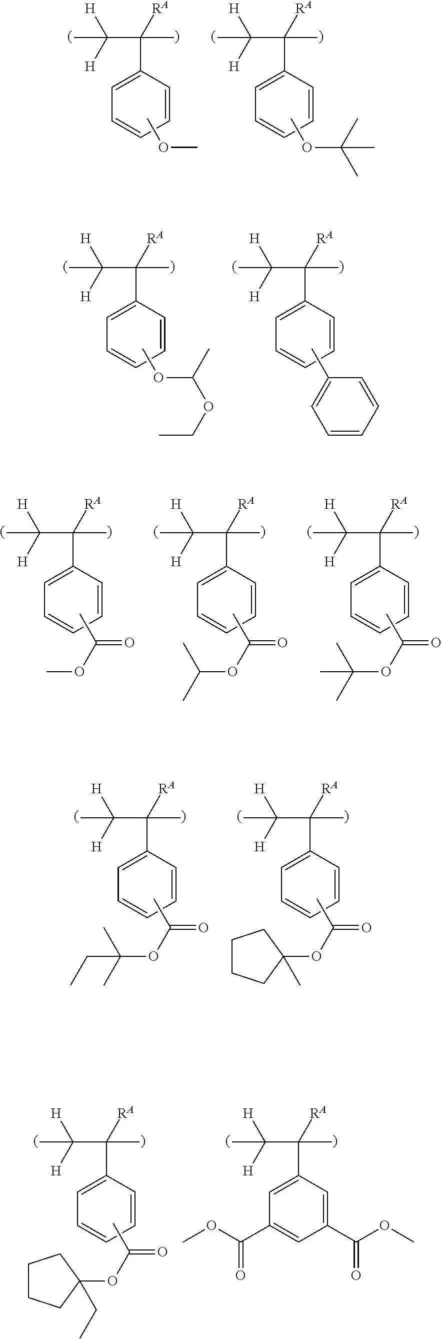

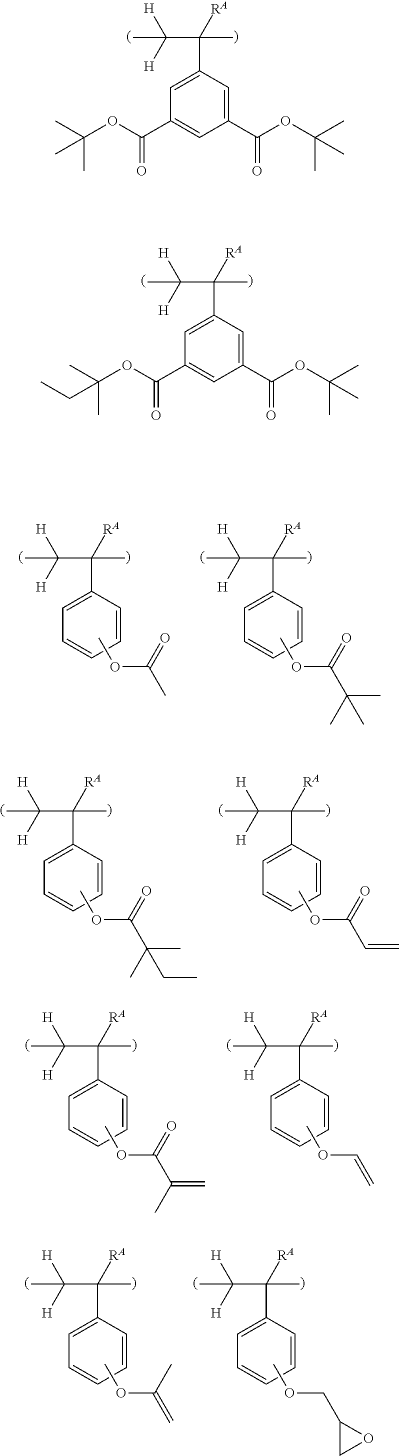

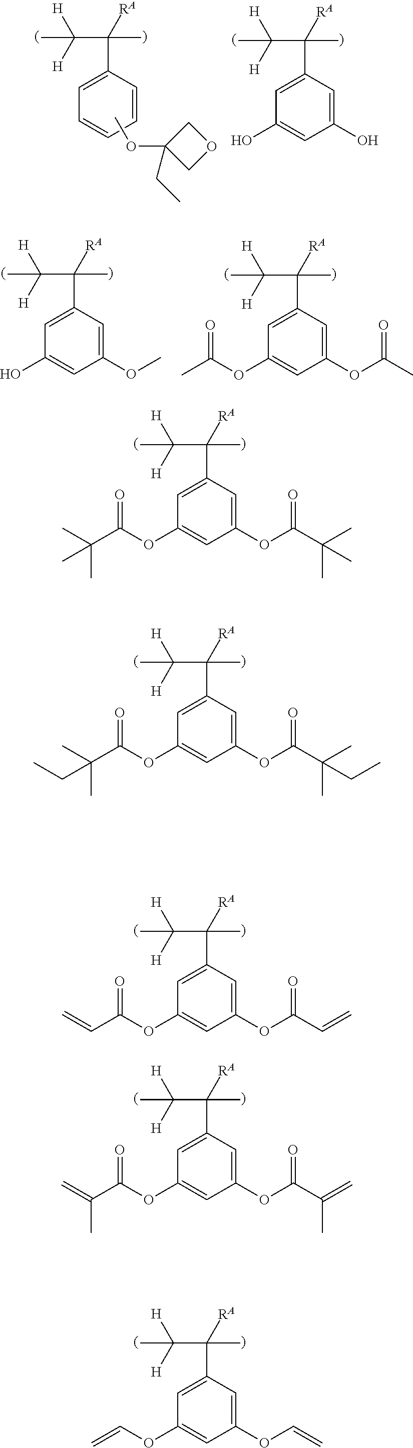

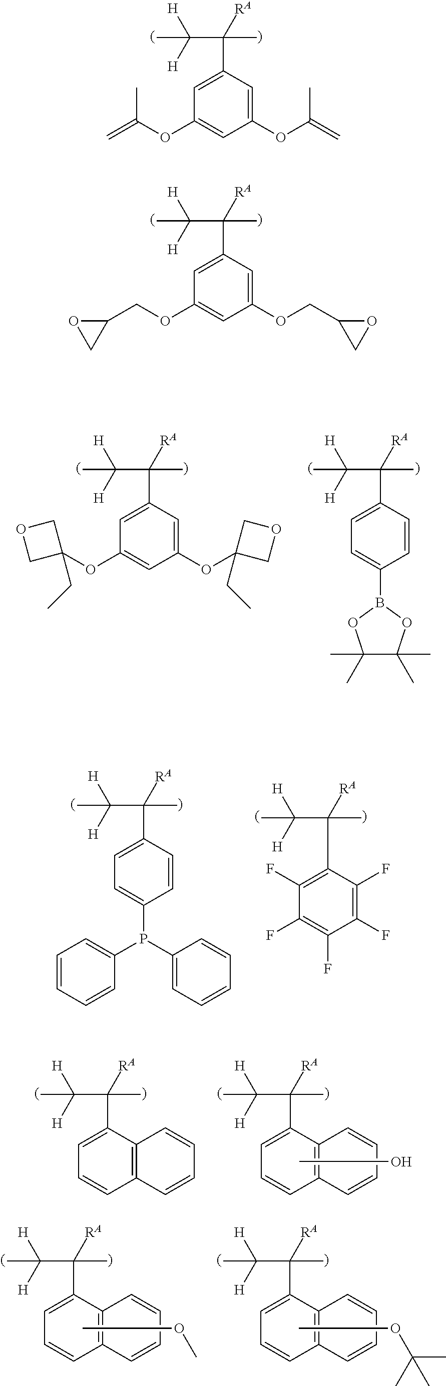

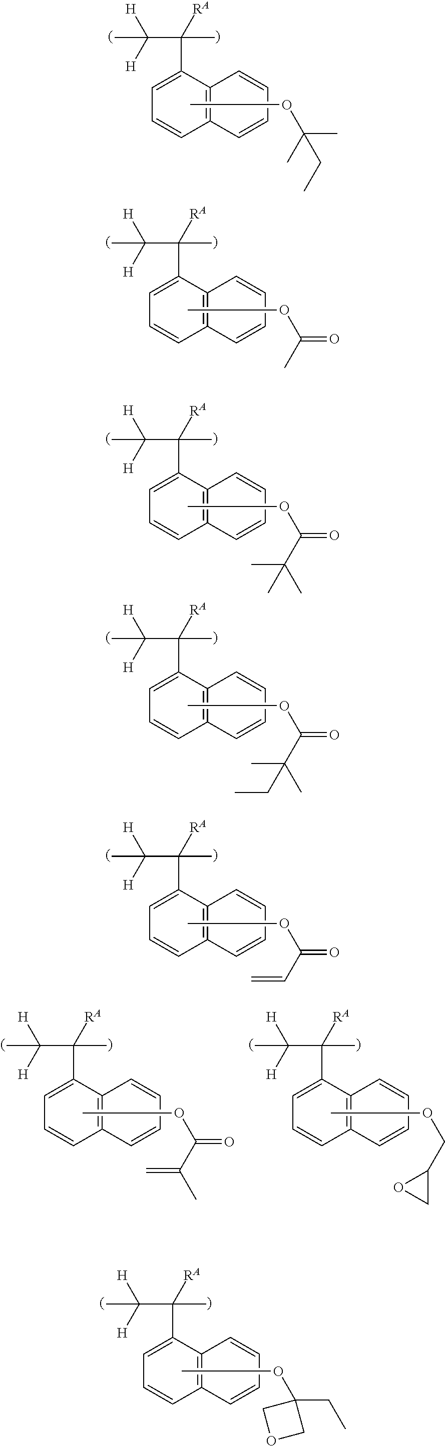

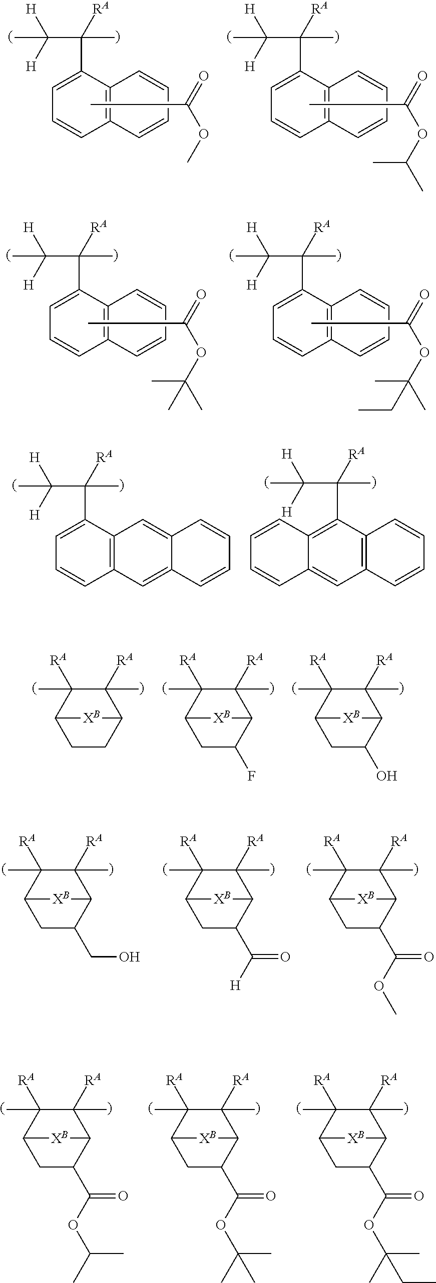

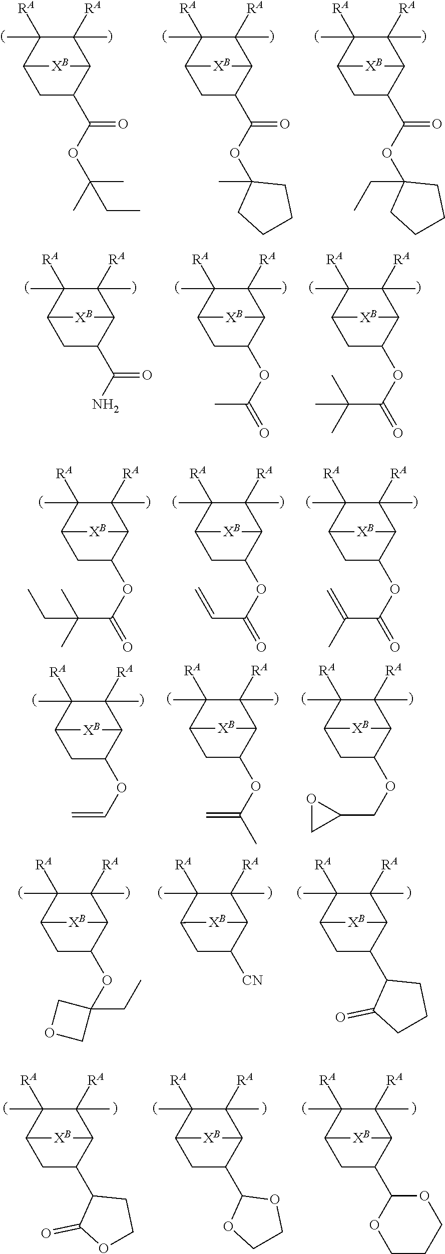

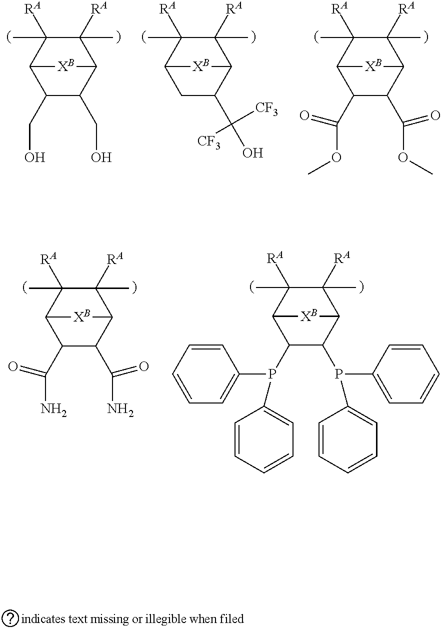

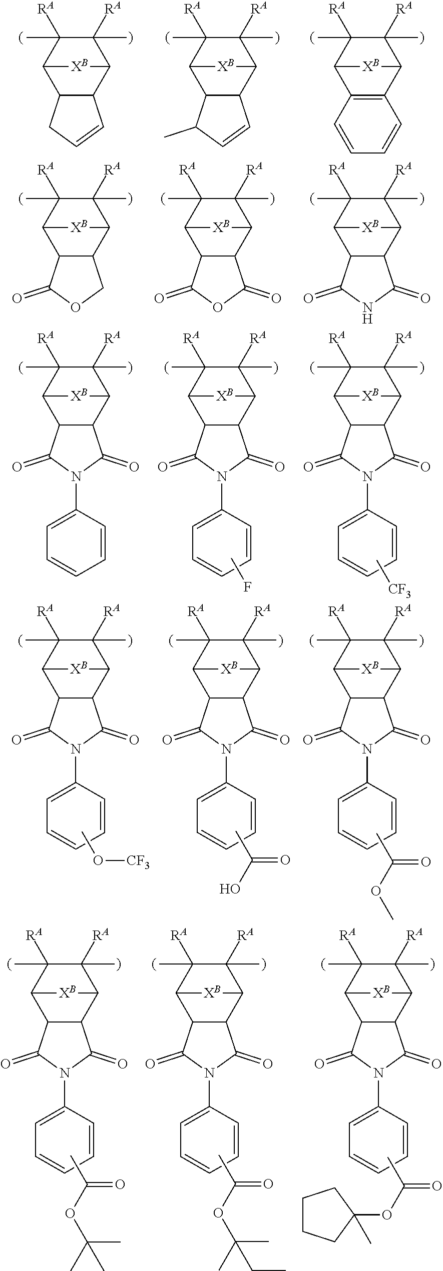

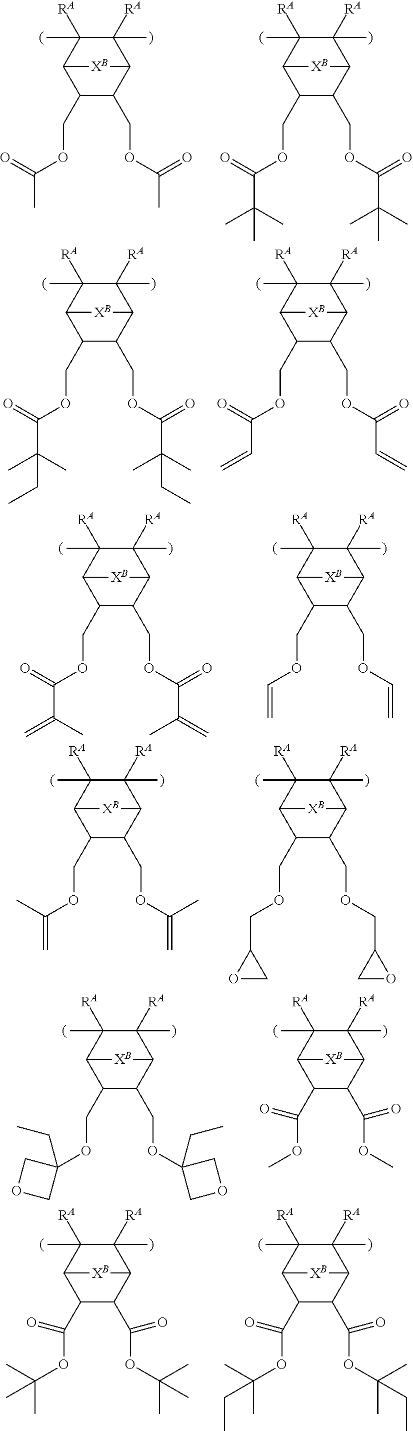

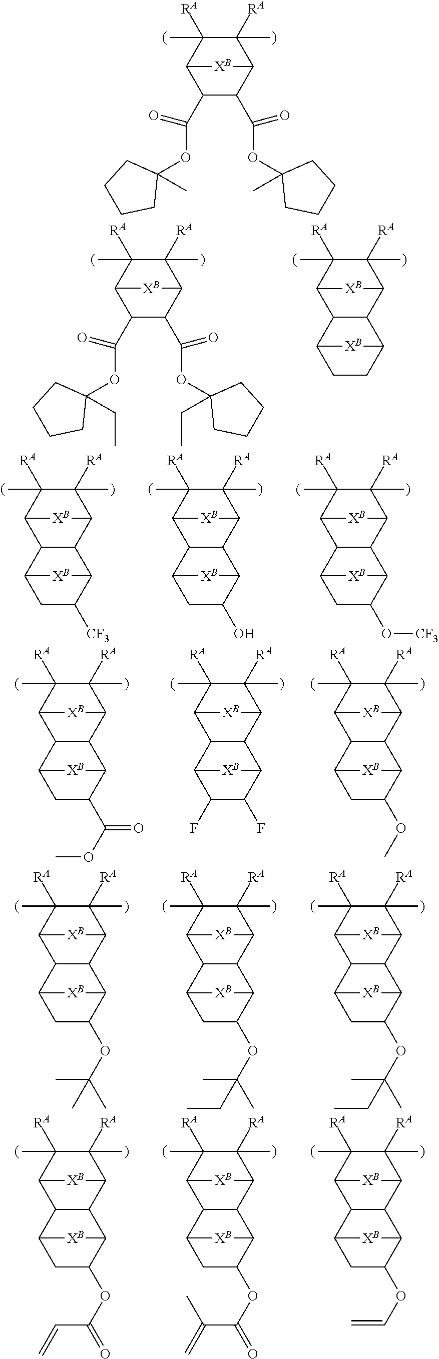

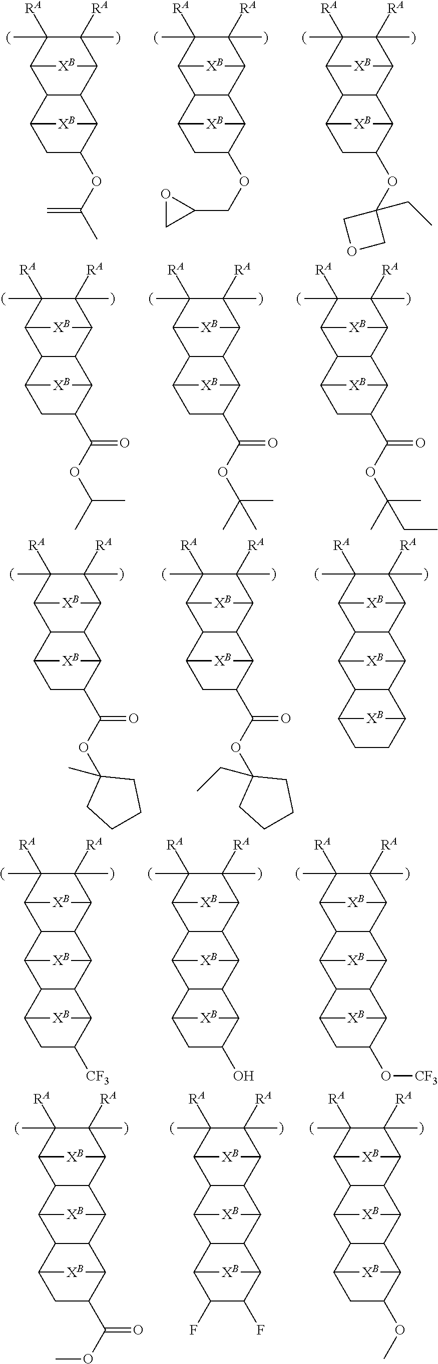

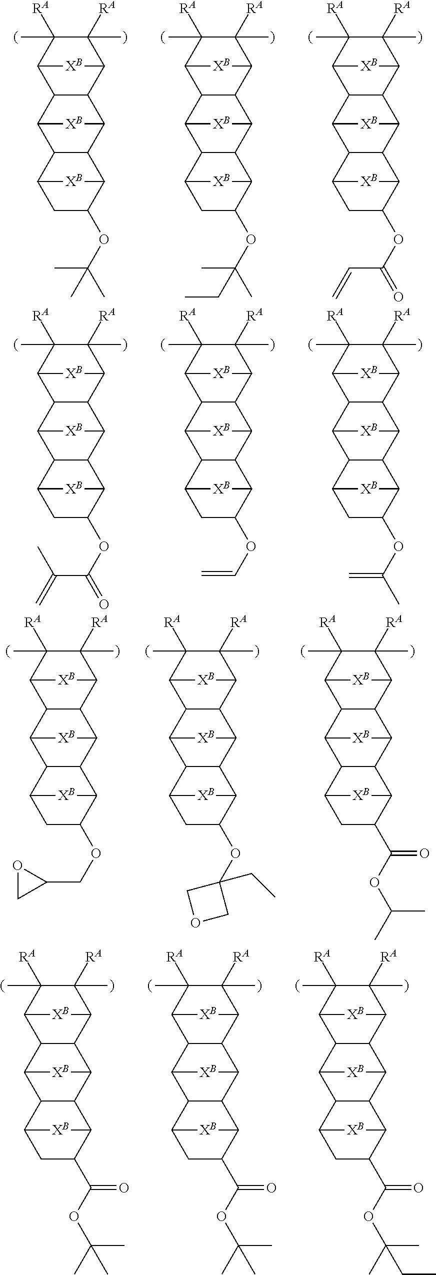

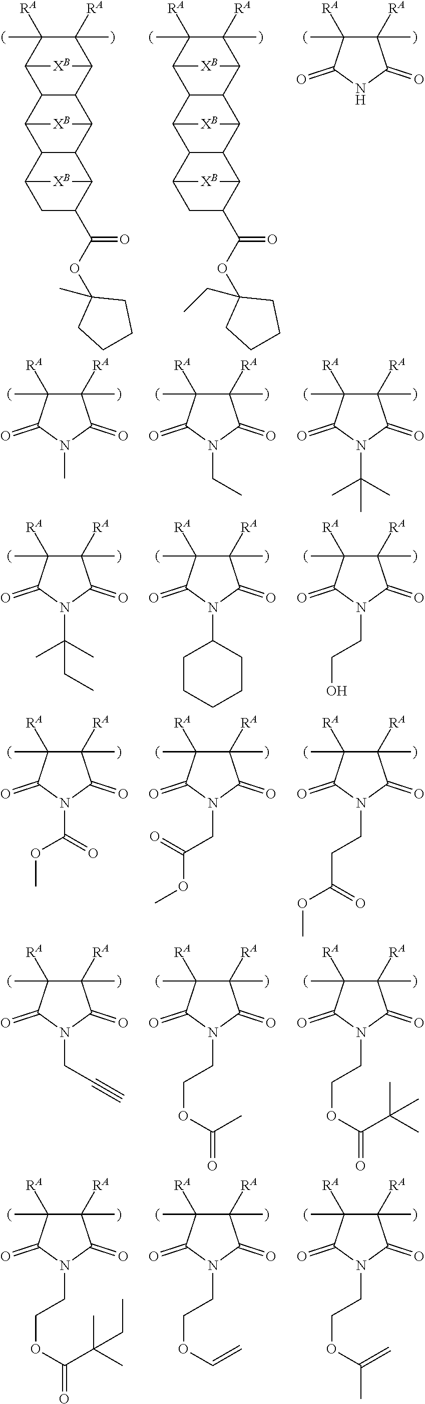

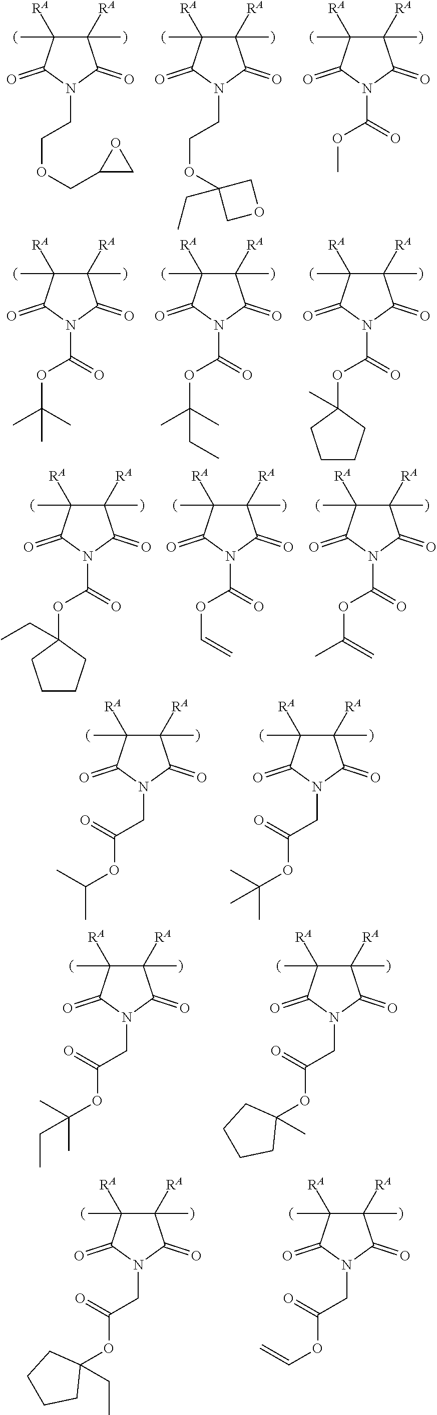

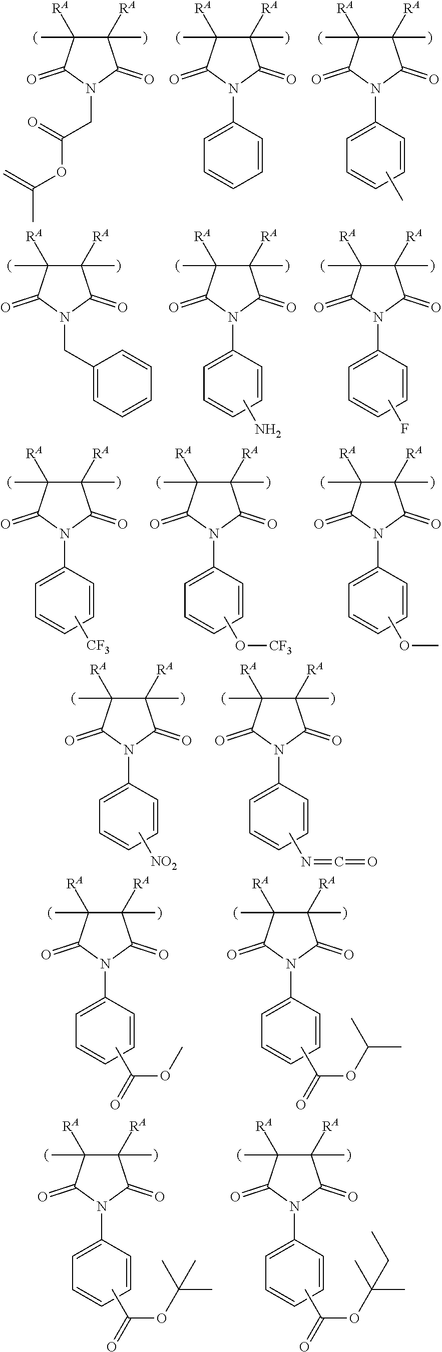

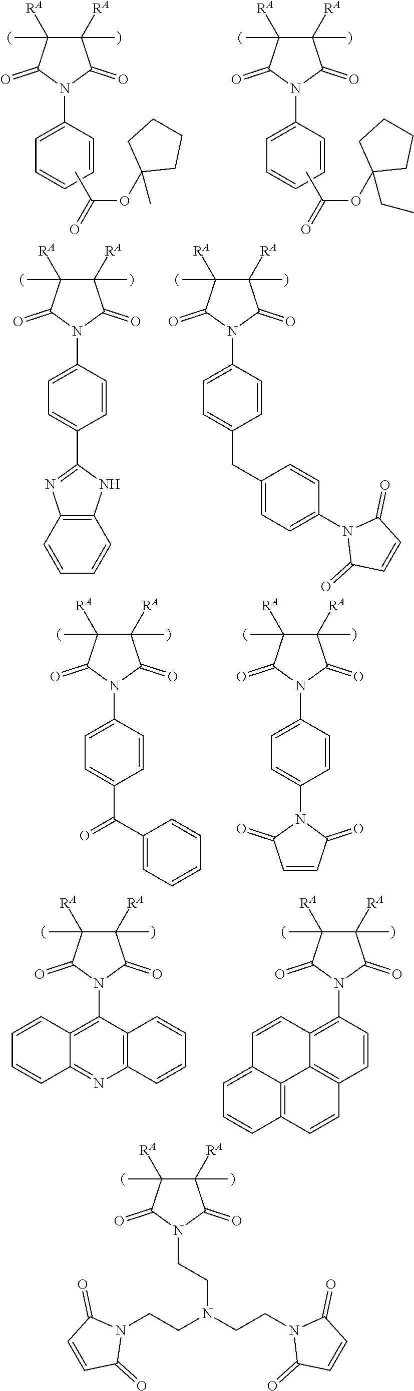

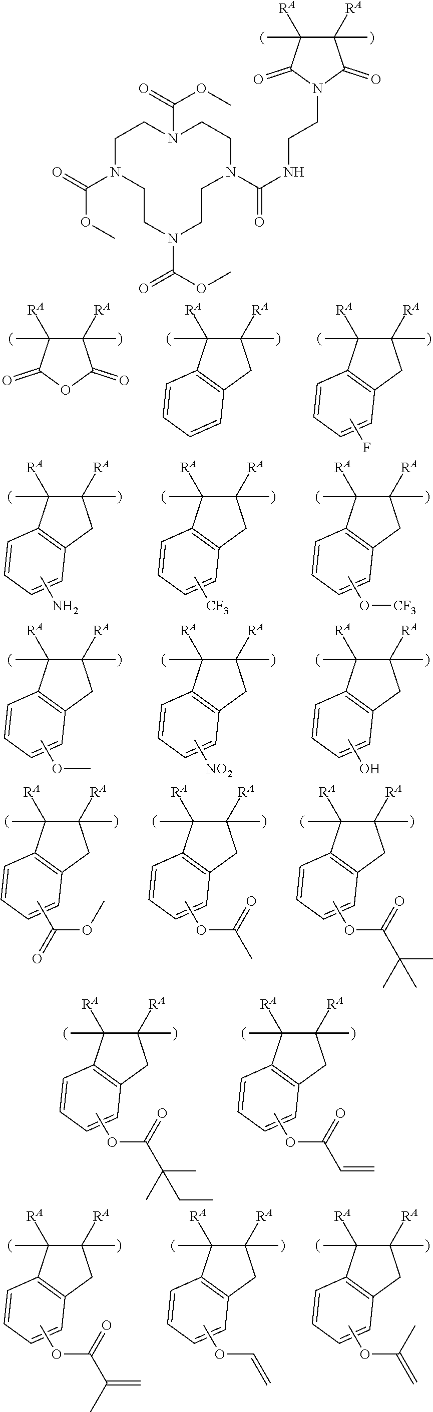

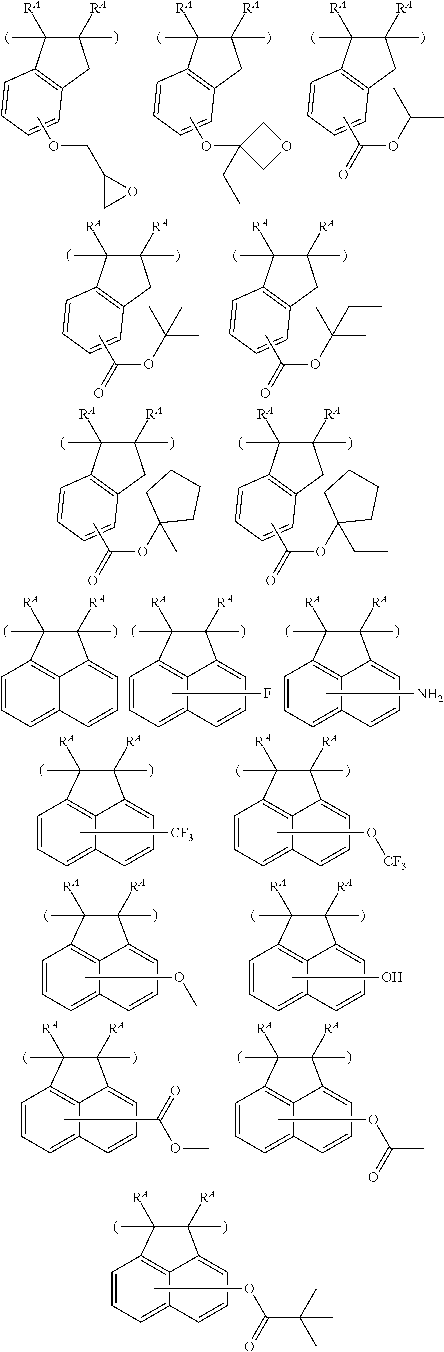

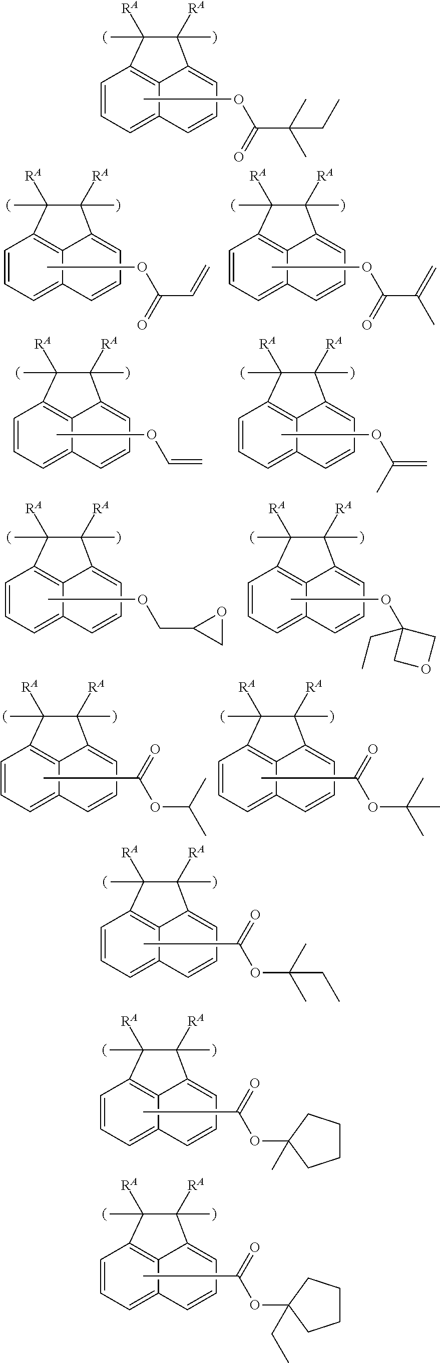

In the carboxylic acid derivative-containing polymer, the molar ratio of repeat units having formula (6) to other repeat units ranges preferably from 10:90 to 90:10, more preferably from 15:85 to 85:15, even more preferably from 20:80 to 80:20.

The carboxylic acid derivative-containing polymer should preferably have a weight average molecular weight (Mw) in the range of 1,000 to 500,000, and more preferably 3,000 to 100,000, as measured by GPC versus polystyrene standards using tetrahydrofuran (THF) solvent.

If a polymer has a wide molecular weight distribution or dispersity (Mw/Mn), which indicates the presence of lower and higher molecular weight polymer fractions, there is a possibility that foreign matter is left on the pattern or the pattern profile is degraded. The influences of Mw and Mw/Mn become stronger as the pattern rule becomes finer. Therefore, the carboxylic acid derivative-containing polymer should preferably have a narrow dispersity (Mw/Mn) of 1.0 to 2.0 in order to provide a resist composition suitable for micropatterning to a small feature size.

The carboxylic acid derivative-containing polymer may be synthesized by any desired methods, for example, by dissolving one or more monomers selected from the monomers corresponding to the foregoing repeat units in an organic solvent, adding a radical polymerization initiator thereto, and heating for polymerization. Examples of the organic solvent which can be used for polymerization include toluene, benzene, tetrahydrofuran (THF), diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and y-butyrolactone (GBL). Examples of the polymerization initiator used herein include 2,2′-azobisisobutyronitrile (AIBN), 2,2′-azobis(2,4-dimethylvaleronitrile), dimethyl 2,2-azobis(2-methylpropionate), 1,1′-azobis(1-acetoxy-1-phenylethane), benzoyl peroxide, and lauroyl peroxide. The amount of the initiator added is preferably 0.01 to 25 mol % of the total of monomers to be polymerized. The reaction temperature is preferably 50 to 150° C., more preferably 60 to 100° C. The reaction time is preferably 2 to 24 hours, more preferably 2 to 12 hours in view of production efficiency.

The polymerization initiator may be added to the monomer solution, which is fed to the reactor. Alternatively, a solution of the polymerization initiator is prepared separately from the monomer solution, and the monomer and initiator solutions are independently fed to the reactor. Since there is a possibility that the initiator generates a radical in the standby time, by which polymerization reaction takes place to form a ultrahigh molecular weight compound, it is preferred from the standpoint of quality control that the monomer solution and the initiator solution be independently prepared and added dropwise. Any of well-known chain transfer agents such as dodecylmercaptan and 2-mercaptoethanol may be used for the purpose of adjusting molecular weight. An appropriate amount of the chain transfer agent is 0.01 to 20 mol % based on the total of monomers to be polymerized.

The amount of each monomer in the monomer solution is set such that the content of the corresponding repeat unit may fall in the preferred range.

In the resist composition, the hypervalent iodine compound and the carboxylic acid derivative (or when the carboxylic acid derivative is a carboxylic acid derivative-containing polymer, the carboxylic acid derivative repeat units in the polymer) are preferably present such that the molar ratio of the hypervalent iodine compound to the carboxylic acid derivative (or carboxylic acid derivative repeat unit) may range from 10:90 to 90:10, more preferably from 20:80 to 80:20, even more preferably from 30:70 to 70:30. The hypervalent iodine compound may be used alone or in admixture. The carboxylic acid derivative-containing polymer may be used alone or as a mixture of two or more polymers having different compositional ratio, Mw and/or Mw/Mn.

### [Solvent]

The resist composition further contains a solvent. The solvent is not particularly limited as long as the hypervalent iodine compound, the carboxylic acid derivative and other components are dissolvable therein and a film can be formed from the resulting solution. Organic solvents are preferred. Suitable organic solvents include ketones such as cyclohexanone, methyl 2-n-pentyl ketone, and methyl isoamyl ketone; alcohols such as 3-methoxybutanol, 3-methyl-3-methoxybutanol, 1-methoxy-2-propanol, 1-ethoxy-2-propanol, diacetone alcohol, and 4-methyl-2-pentanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, methyl 2-hydroxyisobutyrate and propylene glycol mono-tert-butyl ether acetate; carboxylic acids such as formic acid, acetic acid, and propionic acid; lactones such as y-butyrolactone, and mixtures thereof.

The solvent is preferably present in such amounts that the resist composition may have a solids concentration of 0.1 to 20% by weight, more preferably 0.1 to 15% by weight, even more preferably 0.1 to 10% by weight. As used herein, the term solids is a general term for all components in the resist composition excluding the solvent.

### [Other Components]

The resist composition may further contain a surfactant. The surfactant is preferably selected from fluorochemical and silicone surfactants. Exemplary surfactants are described, for example, in US 2008/0248425, paragraph [0276]. Also useful are surfactants other than the fluorochemical and silicone surfactants, as described, for example, in US 2008/0248425, paragraph [0280].

When used, the surfactant is preferably present in an amount of 0.0001 to 2% by weight based on the overall solids. The surfactant may be used alone or in admixture.

The resist composition may further contain a radical scavenger (or radical trapping agent). The radical scavenger is effective for controlling photo-reaction and adjusting sensitivity during photolithography.

Suitable radical scavengers include hindered phenols, quinones, hindered amines, and thiol compounds. Exemplary hindered phenols include dibutylhydroxytoluene (BHT) and 2,2′-methylenebis(4-methyl-6-tert-butylphenol). Exemplary quinones include 4-methoxyphenol (or methoquinone) and hydroquinone. Exemplary hindered amines include 2,2,6,6-tetramethylpyperidine and 2,2,6,6-tetramethylpyperidine-N-oxy radical. Exemplary thiol compounds include dodecanethiol and hexadecanethiol.

When used, the radical scavenger is preferably present in an amount of 0.01 to 10% by weight based on the overall solids. The radical scavenger may be used alone or in admixture.

The resist composition may further contain a crosslinker. Since the crosslinker functions to promote crosslinking reaction during photolithography, a pattern having a higher glass transition temperature and a better resolution in fine line formation is obtained.

Suitable crosslinkers include compounds having a carbon-carbon unsaturated bond such as vinyl, (meth)acryloyl, allyl, alkynyl and aromatic ring as a functional group. Specifically, suitable vinyl-containing compounds include optionally substituted straight-chain alkenes, branched alkenes, and cyclic alkenes. Suitable (meth)acryloyl-containing compounds include optionally substituted acrylic acid, methacrylic acid, acrylates, and methacrylates. Suitable allyl-containing compounds include optionally substituted allyl alcohols, allyl ethers, allyl esters, allyl amides, allyl amines, allyl-containing isocyanurates. Suitable alkynyl-containing compounds include optionally substituted straight-chain alkynes, branched alkynes, cyclic alkynes, alkynyl alcohols, alkynyl ethers, alkynyl esters, alkynyl amides, alkynyl amines, and alkynyl-containing isocyanurates. Suitable aromatic ring-containing compounds include optionally substituted arenes, heteroarenes, styrene, stilbene, phenylacetylene, acenaphthylene, and chalcone. The crosslinker may contain only one of the foregoing functional groups or two or more functional groups. The number of functional groups in the crosslinker is preferably from 1 to 10, more preferably from 2 to 8.

When the resist composition contains the crosslinker, the amount of the crosslinker is preferably 0.01 to 50% by weight of the overall solids. The crosslinker may be used alone or in admixture.

When the resist composition contains the crosslinker, it may further contain a photopolymerization initiator. Upon receipt of high-energy radiation, the photopolymerization initiator generates radicals to promote crosslinking reaction of the crosslinker.

Examples of the photopolymerization initiator include benzophenone derivatives such as benzophenone, methyl O-benzoylbenzoate, 4-benzyol-4′-methyl diphenyl ketone, dibenzyl ketone, and fluorenone; acetophenone derivatives such as 2,2′-diethoxyacetophenone, 2-hydroxy-2-methylpropiophenone, 2,2-dimethoxy-1,2-diphenylethan-1-one, 1-hydroxycyclohexyl phenyl ketone, 2-methyl-1-[4-(methylthio)phenyl]-2-morpholinopropan-1-one, 2-hydroxy-1-{4-[4-(2-hydroxy-2-methylpropionyl)benzyl]phenyl}-2-methylpropan-1-one, and methyl phenylglyoxylate; thioxanthone derivatives such as thioxanthone, 2-methylthioxanthone, 2-isopropylthioxanthone, 4-isopropylthioxanthone, 2-chlorothioxanthone, and diethylthioxanthone; benzyl derivatives such as benzyl, benzyl dimethyl ketal, and benzyl-β-methoxyethylacetal; benzoin derivatives such as benzoin, benzoin methyl ether, and 2-hydroxy-2-methyl-1-phenylpropan-1-one; oxime compounds such as 1-phenyl-1,2-butanedione-2-(O-methoxycarbonyl)oxime, 1-phenyl-1,2-propanedione-2-(O-methoxycarbonyl)oxime, 1-phenyl-1,2-propanedione-2-(O-ethoxycarbonyl)oxime, 1-phenyl-1,2-propanedione-2-(O-benzoyl)oxime, 1,3-diphenylpropanetrione-2-(O-ethoxycarbonyl)oxime, 1-phenyl-3-ethoxypropanetrione-2-(O-benzoyl)oxime 1,2-octanedione, 1-{4-(phenylthio)-2-(O-benzoyl)oxime ethanone, and 1-[9-ethyl-6-(2-methylbenzoyl)-9H-carbazol-3-yl]-1-(O-acetyloxime); α-hydroxyketone compounds such as 2-hydroxy-2-methyl-1-phenylpropan-1-one, 1-[4-(2-hydroxyethoxy)phenyl]-2-hydroxy-2-methyl-1-propan-1-one, and 2-hydroxy-1-{4-[4-(2-hydroxy-2-methylpropionyl)benzyl]phenyl}-2-methylpropane; α-aminoalkylphenone compounds such as 2-benzyl-2-dimethylamino-1-(4-morpholinophenyl)butanone-1 and 2-dimethylamino-2-(4-methylbenzyl)-1-(4-morpholin-4-ylphenyl)butan-1-one; phosphine oxide compounds such as bis(2,4,6-trimethylbenzoyl)phenylphosphine oxide, bis(2,6-dimethoxybenzoyl)-2,4,4-trimethylpentylphosphine oxide, and 2,4,6-trimethylbenzoyl diphenylphosphine oxide; and titanocene compounds such as bis(η5-2,4-cyclopentadien-1-yl)-bis(2,6-difluoro-3-(1H-pyrrol-1-yl)phenyl)titanium.

When the resist composition contains the photopolymerization initiator, the amount of the initiator is preferably 0.1 to 10% by weight, more preferably 0.1 to 5% by weight, even more preferably 0.1 to 1% by weight of the overall solids. A sufficient effect is available as long as the amount is 0.1% by weight or more.

The resist composition contains the hypervalent iodine compound and the carboxylic acid derivative as main components and works such as to form a positive tone pattern in which the exposed region becomes soluble in the developer or a negative tone pattern in which the exposed region becomes insoluble in the developer. Although its mechanism is not well understood, the following mechanism is presumed.

When the resist composition is coated and prebaked to form a resist film, the carboxylic acid derivative is thermally decomposed to a carboxylic acid. The hypervalent iodine compound having formula (1), (2), (3) or (4) is a three-coordinate compound having aryl and carboxylate ligands. When such a three-coordinate iodine compound is mixed with a carboxylic acid, replacement of carboxylate ligands takes place as equilibration reaction. If the original carboxylate ligands are removed by any suitable means, a hypervalent iodine compound having new ligands is created. For example, if 1-iodonaphthylene diacetate as a hypervalent iodine compound is mixed with a carboxylic acid derivative, the carboxylic acid derivative is thermally decomposed into a carboxylic acid during the prebake step, and the low-boiling acetic acid resulting from ligand exchange reaction between carboxylic acid and hypervalent iodine compound is removed, then ligand exchange is completed. There is obtained a polymer in which the carboxylic acid is crosslinked with the hypervalent iodine compound.

When it is attempted to form a resist solution by directly adding a carboxylic acid compound and a hypervalent iodine compound to a solvent, there arises a problem that a carboxy-containing solvent must be used before the carboxylic acid compound can be dissolved because the carboxylic acid compound has a low solvent solubility, i.e., is insoluble in most solvents. The problem is solved by protecting the carboxylic acid compound with an organic group to form a carboxylic acid derivative, which is soluble in most solvents.

As compared with a carboxylic acid compound used as such, a carboxylic acid derivative provides some advantages that the agglomeration of carboxy groups in the film is prevented, the distribution of components after film formation becomes more uniform, and the roughness during patterning is reduced.

The polymer crosslinked with the hypervalent iodine compound is formed during film preparation. The reason is that even when such a crosslinked polymer is previously synthesized, the polymer is not soluble in most organic solvents so that a solution may not be prepared. If the hypervalent iodine compound having a low solvent solubility because of inherently strong polarization has taken therein a carboxylic acid compound as a ligand, then the hypervalent iodine compound suffers from a further loss of solubility. It is thus desirable that a resist film be formed while ligand exchange reaction be completed by converting the carboxylic acid derivative to a carboxylic acid compound and removing the original low-molecular-weight carboxylic acid component during film formation and subsequent bake steps.

When the carboxylic acid derivative is thermally converted to a carboxylic acid compound, the bake temperature may be adjusted in accordance with the type of organic group with which the carboxylic acid derivative is protected.

The resist composition may further comprise an acid generator. It may be any of thermal acid generators which are thermally decomposed to generate acids and photoacid generators which are photo-decomposed to generate acids. Exemplary acid generators are described in JP-A 2007-199653, paragraphs [0061]-[0085]. Upon receipt of heat or light, the acid generator generates an acid, which reacts with the carboxylic acid derivative to convert the carboxylic acid derivative to a carboxylic acid. The inclusion of the acid generator assists in completing the generation of carboxylic acid at low temperature, as compared with the use of only heat to drive reaction to carboxylic acid, that is, achieving a process temperature-lowering effect.

On use of a thermal acid generator, it generates an acid in the prebake step after coating of the resist composition, which reacts with the carboxylic acid derivative to convert it to a carboxylic acid.

On use of a photoacid generator, it generates an acid when a resist film formed by coating and prebaking the resist composition is subjected to flood exposure, which acid reacts with the carboxylic acid derivative to convert it to a carboxylic acid. In this case, the process should involve, after flood exposure, the step of baking the resist film for inducing ligand exchange reaction between the hypervalent iodine compound and the carboxylic acid compound.

When the resist composition contains the acid generator, its amount is preferably 0.05 to 20 parts by weight, more preferably 0.1 to 10 parts by weight per 100 parts by weight of the carboxylic acid derivative. The acid generator may be used alone or in admixture.

After a resist film is formed from the resist composition, the hypervalent iodine compound as the main component is photo-decomposed in the exposure step to bring about a polarity switch, and a pattern is formed in the subsequent development step. Although its mechanism is not well understood, the following mechanism is presumed.

The resist composition may take either positive or negative tone by a choice of components. In the case of positive tone, the resist film contains the polymer having the hypervalent iodine compound bonded thereto during film formation. Upon receipt of light, the hypervalent iodine compound is decomposed into a monovalent iodine compound.

At the same time, the crosslink between the hypervalent iodine compound and the carboxylic acid is canceled, resulting in lower molecular weights. As a result, the resist film in the exposed region is dissolved away in the organic solvent, yielding a pattern of positive tone.

In the case of negative tone, the resist film contains the polymer crosslinked with the hypervalent iodine compound, which is created during film formation. Upon receipt of light, the crosslinked polymer is decomposed, and replacement of crosslinks or bonds takes place to induce a molecular weight buildup or polarity switch. As a result, the resist film in the unexposed region is dissolved away in the alkaline aqueous solution, yielding a pattern of negative tone.

The hypervalent iodine compound should preferably have such a robust skeleton with a high molecular weight that the compound may volatilize little even under vacuum conditions during EB or EUV exposure. If a hypervalent iodine compound with a low molecular weight is used, the compound resulting from decomposition upon light exposure will volatilize under vacuum whereby the resist film undergoes substantial exposure shrinkage, resulting in contamination of the exposure tool with volatile components or dimensional changes of resist pattern by shrinkage. The problems are thus overcome by using a hypervalent iodine compound of robust skeleton having a high molecular weight enough to prevent substantial volatilization. The hypervalent iodine compound of robust skeleton having a high molecular weight assists in forming a resist pattern having an elevated glass transition temperature and improved resolution and etch resistance, while preventing the pattern from wrinkling.

Also preferably, the hypervalent iodine compound contains a plurality of hypervalent iodine bonds in the molecule. In either of positive and negative tones, it assists in forming a resist pattern having an increased crosslinking density and improved etch resistance and resolution, while preventing the pattern from wrinkling.

From the foregoing presumption, the inventive resist composition is regarded as falling in the concept of non-chemically-amplified resist composition. While the resist composition contains the carboxylic acid derivative in which the carboxy group is substituted with an acid labile group, elimination of the acid labile group occurs during bake prior to patternwise exposure, and the reaction of eliminating the acid labile group does not occur during patternwise exposure. In conventional chemically amplified resist compositions, the acid labile group is eliminated during patternwise exposure or subsequent bake. Then the inventive resist composition can form a small-size pattern with high resolution without any adverse effect (e.g., image blur) due to acid diffusion.

The inventive resist composition is quite effective in the EUV lithography. This is because an iodine atom having a high absorptivity to EUV radiation is included. That is, shot noise is reduced, and higher resolution and lower LWR are achievable.

As the EUV lithography resist composition capable of forming a small-size pattern, a metal resist composition based on a metal (specifically tin) compound having a high absorptivity to EUV radiation like iodine atom is known, for example, from Patent Document 2. However, the metal resist composition suffers from many problems including a lack of solvent solubility, poor shelf stability, and defects in the form of post-etching residues due to the containment of metal elements, as discussed previously. In contrast, the inventive resist composition which does not resort to metal elements is advantageous in defectiveness over the metal resist and eliminates the problem of solvent solubility. The inventive resist composition is applicable to either positive or negative tone, finding a wide variety of use. In the step of forming contact holes, for example, although a metal resist composition subject to negative tone development requires the reversal processing step after pillar pattern formation, the positive resist composition does not require the reversal step. From the aspect of process simplicity, the inventive resist composition is regarded more useful than the metal resist composition.

JP-A 2015-180928 and JP-A 2018-095853 describe a resist composition comprising a hypervalent iodine compound as an additive and a resist composition comprising a base polymer having a hypervalent iodine compound incorporated in its framework. The resist compositions described therein are successful in improving only line edge roughness. The patent documents refer nowhere to a possibility of photo-decomposition of the hypervalent iodine compound and an ability to function as a non-chemically-amplified resist. In these resist compositions, the hypervalent iodine compound is not a main component as understood from the addition amount and examples described therein. It is then believed that a material capable of reducing shot noise during the EUV lithography and forming a small-size pattern as the non-chemically-amplified resist is not conceivable from these patent documents. That is, the present invention provides a definitely novel resist composition and pattern forming process.

### [Pattern Forming Process]

When the resist composition is used in the fabrication of various integrated circuits, any well-known lithography techniques are applicable. For example, the invention provides a pattern forming process comprising the steps of applying the resist composition onto a substrate or a substrate having an underlying film thereon to form a resist film on the substrate or underlying film, exposing the resist film to high-energy radiation, and optionally developing the exposed resist film in a developer.

First, the resist composition is applied onto a substrate for integrated circuit fabrication (e.g., Si, SiO₂, SiN, SiON, TiN, WSi, BPSG, SOG, or organic antireflective coating) or a substrate having an underlying film thereon, or a substrate for mask circuit fabrication (e.g., Cr, CrO, CrON, MoSi₂, or SiO₂) or a substrate having an underlying film thereon by any suitable technique such as spin coating, roll coating, flow coating, dip coating, spray coating or doctor coating. The coating is prebaked (PAB) on a hot plate at a temperature of preferably 60 to 250° C. for 10 seconds to 30 minutes, more preferably at 80 to 220° C. for 30 seconds to 20 minutes to form a resist film having a thickness of 0.01 to 2 μm. Notably, the underlying film refers to a film formed between a substrate and a resist film in the multilayer resist process. The underlying film is not particularly limited and any of well-known films may be used.

Next the resist film is exposed to high-energy radiation. The radiation is selected from among UV, deep UV, EB, EUV, X-ray, soft X-ray, excimer laser radiation, γ-ray, and synchrotron radiation. On use of UV, deep UV, EUV, X-ray, soft X-ray, excimer laser radiation, γ-ray, and synchrotron radiation as the high-energy radiation, the resist film is exposed thereto directly or through a mask having the desired pattern so as to reach a dose of preferably about 1 to 300 mJ/cm², more preferably about 10 to 200 mJ/cm². On use of EB as the high-energy radiation, imagewise writing is performed directly or through a mask having the desired pattern so as to reach a dose of preferably about 0.1 to 8,000 μC/cm², more preferably about 0.5 to 5,000 μC/cm². The resist composition is best suited in micropatterning using EB or EUV as the high-energy radiation.

If necessary, the resist film is post-exposure baked (PEB). Preferably PEB is performed on a hot plate or in an oven at 30 to 200° C. for 10 seconds to 30 minutes, more preferably at 60 to 120° C. for 30 seconds to 20 minutes.

After the exposure or PEB, the resist film is developed in a developer to form a pattern, if necessary. Typical of the developer are alkaline aqueous solutions such as aqueous solutions of tetramethylammonium hydroxide and tetrabutylammonium hydroxide; and organic solvents such as 2-octanone, 2-nonanone, 2-heptanone, 3-heptanone, 4-heptanone, 2-hexanone, 3-hexanone, diisobutyl ketone, 5-methyl-2-hexanone, methylcyclohexanone, acetophenone, methylacetophenone, isopropyl alcohol, n-butanol, tert-butyl alcohol, isoamyl alcohol, tert-pentyl alcohol, n-pentanol, cyclohexanol, formic acid, acetic acid, propionic acid, propyl acetate, butyl acetate, isobutyl acetate, pentyl acetate, isopentyl acetate, butenyl acetate, cyclohexyl acetate, 4-tert-butylcyclohexyl acetate, octyl acetate, isobornyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, 3-methyl-1-butanol, diacetone alcohol, 4-methyl-2-pentanol, 3-methylcyclohexanol, 3,5,5-trimethylhexyl alcohol, 2,6-dimethyl-4-heptanol, toluene, anisole and ε-caprolactone. These organic solvents may be used alone or in admixture of two or more.

At the end of development, the resist film is rinsed if necessary. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents.

Rinsing is effective for preventing the resist pattern from collapse or reducing defect formation. Rinsing is not essential. By omitting rinsing, the amount of the solvent used is saved.

### EXAMPLES

Examples of the invention are given below by way of illustration and not by way of limitation. The abbreviation “pbw” is parts by weight.

### [1] Synthesis of Carboxylic Acid Derivatives

### Synthesis Example 1-1

### Synthesis of Carboxylic Acid Derivative m-1

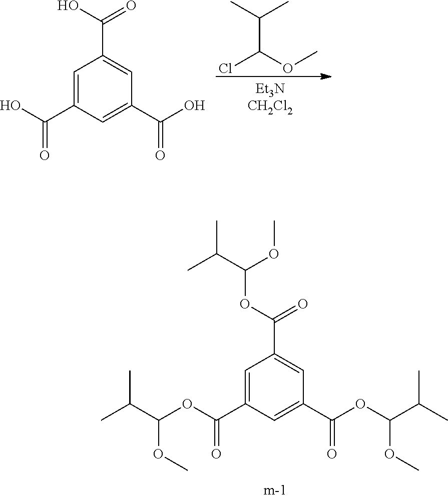

A 200-ml flask was charged with 4.2 g of 1,3,5-benzenetricarboxylic acid, 7.9 g of triethylamine, and 60 g of methylene chloride, which were stirred in an ice bath. Then, 9.6 g of 1-chloro-1-methoxy-2-methylpropane was added dropwise to the charge, which was stirred at room temperature for 8 hours. 60 ml of water was added to the reaction solution. The organic layer was extracted, washed twice with 30 ml of water, and concentrated at 40° C. There was obtained the target compound m-1 as oily matter (amount 18 g, yield 86%).

Compound m-1 was analyzed by NMR spectroscopy, with the results shown below.

¹H-NMR (500 MHz, DMSO-d₆):

δ 0.95 (d, 18H), 3.41 (s, 9H), 4.92 (m, 3H), 5.82 (s, 3H), 8.78 (s, 3H)

### Synthesis Examples 1-2 to 1-6

### Synthesis of Carboxylic Acid Derivatives m-2 to m-6

Derivatives m-2 to m-6 were synthesized by the same procedure as in Synthesis Example 1-1 aside from changing the type of reactant.

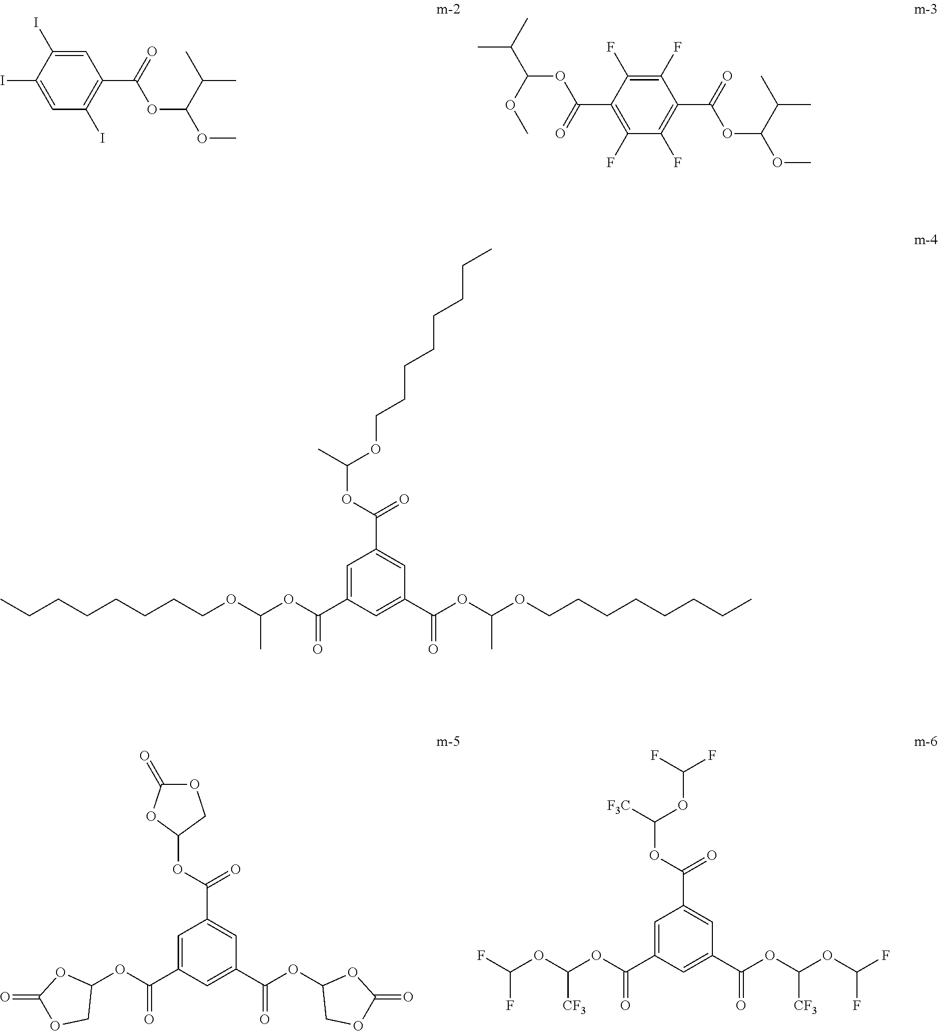 [SMILES: COC(OC(=O)c1cc(I)c(I)cc1I)C(C)C ; COC(OC(=O)c1c(F)c(F)c(C(=O)OC(OC)C(C)C)c(F)c1F)C(C)C ; CCCCCCCCOC(C)OC(=O)c1cc(C(=O)OC(C)OCCCCCCCC)cc(C(=O)OC(C)OCCCCCCCC)c1 ; O=C1OCC(OC(=O)c2cc(C(=O)OC3COC(=O)O3)cc(C(=O)OC3COC(=O)O3)c2)O1 ; O=C(OC(OC(F)F)C(F)(F)F)c1cc(C(=O)OC(OC(F)F)C(F)(F)F)cc(C(=O)OC(OC(F)F)C(F)(F)F)c1]

### [2] Synthesis of Carboxylic Acid Derivative-Containing Polymers

Carboxylic acid derivative-containing polymers P-1 to P-10 were synthesized using the monomers shown below.

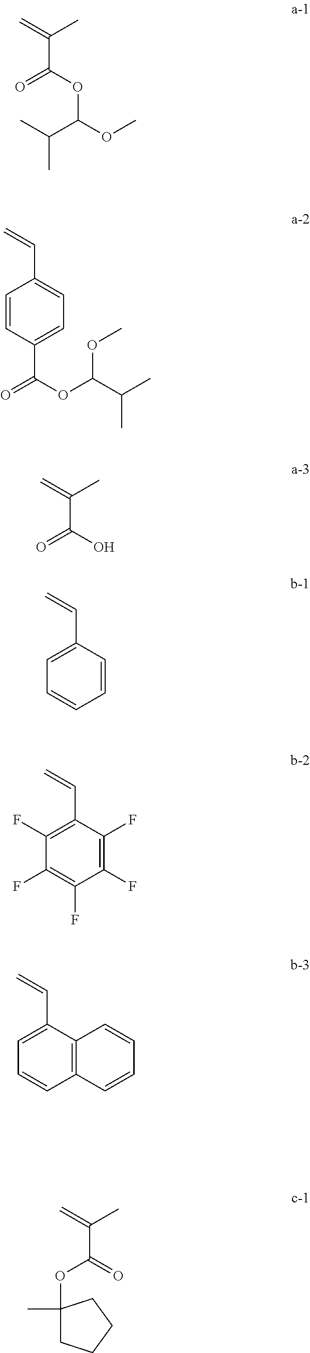

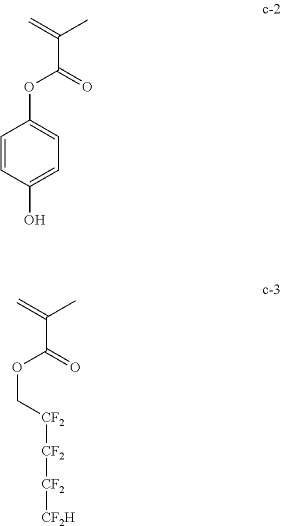 [SMILES: C=C(C)C(=O)Oc1ccc(O)cc1 ; C=C(C)C(=O)OCC(F)(F)C(F)(F)C(F)(F)C(F)F]

### Synthesis Example 2-1

### Synthesis of Polymer P-1

In nitrogen atmosphere, a flask was charged with 70 g of Monomer a-1, 11 g of Monomer b-1, 4.6 g of dimethyl 2,2′-azobis(isobutyrate) (V-601, FUJIFILM Wako Pure Chemical Corp.), and 124 g of methyl ethyl ketone (MEK) to form a monomer/initiator solution. Another flask in nitrogen atmosphere was charged with 62 g of MEK and heated at 80° C. with stirring, after which the monomer/initiator solution was added dropwise over 4 hours. After the completion of dropwise addition, the polymerization solution was continuously stirred for 2 hours while keeping the temperature of 80° C. It was then cooled to room temperature. With vigorous stirring, the polymerization solution was added dropwise to 4,000 g of hexane whereupon a polymer precipitated. The polymer was collected by filtration, washed twice with 1,200 g of hexane, and vacuum dried at 50° C. for 20 hours, obtaining Polymer P-1 in white powder form. Amount 78 g and yield 98%. Polymer P-1 had a Mw of 8,000 and a Mw/Mn of 1.44 as measured by GPC versus polystyrene standards using THF solvent.

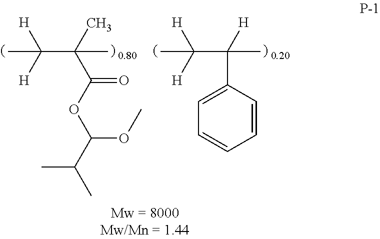

### Synthesis Examples 2-2 to 2-10

### Synthesis of Polymers P-2 to P-10]

Polymers P-2 to P-10 shown in Table 1 were prepared by the same procedure as in Synthesis Example 2-1 except that the type and amount of monomers used were changed.

TABLE 1

| | | Incorpora- | | Incorpora- | | |
|---|---|---|---|---|---|---|
| Poly- | Unit | tion ratio | Unit | tion ratio | | Mw/ |
| mer | 1 | (mol %) | 2 | (mol %) | Mw | Mn |
| P-1 | a-1 | 80 | b-1 | 20 | 8,000 | 1.44 |
| P-2 | a-1 | 50 | b-2 | 50 | 8,400 | 1.51 |
| P-3 | a-1 | 60 | b-3 | 40 | 8,100 | 1.42 |
| P-4 | a-1 | 60 | c-3 | 40 | 8,100 | 1.42 |
| P-5 | a-2 | 80 | b-1 | 20 | 8,000 | 1.44 |
| P-6 | a-2 | 50 | b-2 | 50 | 8,400 | 1.44 |
| P-7 | a-2 | 60 | b-3 | 40 | 8,400 | 1.42 |
| P-8 | a-2 | 60 | c-3 | 40 | 8,600 | 1.44 |
| P-9 | a-3 | 80 | b-1 | 20 | 8,000 | 1.44 |
| P-10 | c-1 | 65 | c-2 | 35 | 8,100 | 1.45 |

### [3] Preparation of Resist Composition

### Examples 1-1 to 1-20 and Comparative Examples 1-1 to 1-4

Resist compositions (R-01 to R-20, CR-01 and CR-02) were prepared by dissolving a hypervalent iodine compound, a carboxylic acid derivative or a carboxylic acid compound and a photoacid generator in a solvent containing 0.01 wt % of a surfactant (PF-636, Omnova Solutions, Inc.) in accordance with the recipe shown in Table 2, and filtering the solution through a Teflon® filter having a pore size of 0.2 μm. Also, resist compositions (CR-03 and CR-04) were prepared by dissolving a polymer, a photoacid generator, and a sensitivity modifier in a solvent containing 0.01 wt % of a surfactant (PF-636) in accordance with the recipe shown in Table 3, and filtering the solution through a Teflon® filter having a pore size of 0.2 μm.

TABLE 2

| | | | Hyper- | Hyper- | Carboxylic acid | | | |
|---|---|---|---|---|---|---|---|---|
| | | | valent | valent | derivative or | | | |
| | | Resist | iodine | iodine | carboxylic acid | Acid | | |
| | | compo- | compound | compound | compound | generator | Solvent 1 | Solvent 2 |
| | | sition | 1 (pbw) | 2 (pbw) | (pbw) | (pbw) | (pbw) | (pbw) |
| Example | 1-1 | R-01 | I-1 | — | P-1 | — | PGMEA | — |
| | | | (12) | | (9) | | (1000) | |
| | 1-2 | R-02 | I-2 | — | P-1 | — | PGMEA | — |
| | | | (10) | | (9) | | (1000) | |
| | 1-3 | R-03 | I-3 | — | P-1 | — | PGMEA | — |
| | | | (19) | | (9) | | (1000) | |
| | 1-4 | R-04 | I-1 | — | P-1 | TAG-1 | PGMEA | — |
| | | | (12) | | (9) | (1) | (1000) | |
| | 1-5 | R-05 | I-2 | — | P-1 | TAG-2 | PGMEA | — |
| | | | (10) | | (9) | (1) | (1000) | |
| | 1-6 | R-06 | I-3 | — | P-1 | TAG-3 | PGMEA | — |
| | | | (19) | | (9) | (1) | (1000) | |
| | 1-7 | R-07 | I-1 | I-2 | P-1 | — | PGMEA | — |
| | | | (6) | (5) | (9) | | (1000) | |
| | 1-8 | R-08 | I-2 | — | P-2 | — | PGMEA | — |
| | | | (10) | | (17) | | (1000) | |
| | 1-9 | R-09 | I-2 | — | P-3 | — | PGMEA | — |
| | | | (10) | | (11) | | (1000) | |
| | 1-10 | R-10 | I-2 | — | P-4 | — | PGMEA | — |
| | | | (10) | | (17) | | (1000) | |
| | 1-11 | R-11 | I-2 | — | P-5 | — | PGMEA | — |
| | | | (10) | | (19) | | (1000) | |
| | 1-12 | R-12 | I-2 | — | P-6 | — | PGMEA | — |
| | | | (10) | | (28) | | (1000) | |
| | 1-13 | R-13 | I-2 | — | P-7 | — | PGMEA | — |
| | | | (10) | | (22) | | (1000) | |
| | 1-14 | R-14 | I-2 | — | P-8 | — | PGMEA | — |
| | | | (10) | | (26) | | (1000) | |
| | 1-15 | R-15 | I-2 | — | m-1 | — | PGMEA | — |
| | | | (10) | | (9) | | (1000) | |
| | 1-16 | R-16 | I-2 | — | m-2 | — | PGMEA | — |
| | | | (10) | | (35) | | (1000) | |
| | 1-17 | R-17 | I-2 | — | m-3 | — | PGMEA | — |
| | | | (10) | | (12) | | (1000) | |
| | 1-18 | R-18 | I-2 | — | m-4 | — | PGMEA | — |
| | | | (10) | | (13) | | (1000) | |
| | 1-19 | R-19 | I-2 | — | m-5 | — | PGMEA | — |
| | | | (10) | | (9) | | (1000) | |
| | 1-20 | R-20 | I-2 | — | m-6 | — | PGMEA | — |
| | | | (10) | | (13) | | (1000) | |
| Comparative | 1-1 | CR-01 | I-3 | — | P-9 | — | PGMEA | AcOH |
| Example | | | (19) | | (12) | | (800) | (200) |
| | 1-2 | CR-02 | I-2 | — | d-1 | — | PGMEA | AcOH |
| | | | (10) | | (4) | | (800) | (200) |

TABLE 3

| | | Resist | | Photoacid | Sensitivity | | |
|---|---|---|---|---|---|---|---|
| | | compo- | Polymer | generator | modifier | Solvent 1 | Solvent 2 |
| | | sition | (pbw) | (pbw) | (pbw) | (pbw) | (pbw) |
| Comparative | 1-3 | CR-03 | P-10 (80) | PAG-1 (19) | Q-1 (6) | PGMEA (1890) | GBL (210) |
| Example | 1-4 | CR-04 | P-10 (80) | PAG-1 (19) | I-1 (5) | PGMEA (1890) | GBL (210) |

In Tables 2 and 3, the hypervalent iodine compound (I-1 to I-3), carboxylic acid compound (d-1), thermal acid generator (TAG-1 to TAG-3), photoacid generator (PAG-1), sensitivity modifier (Q-1), and solvent are identified below.

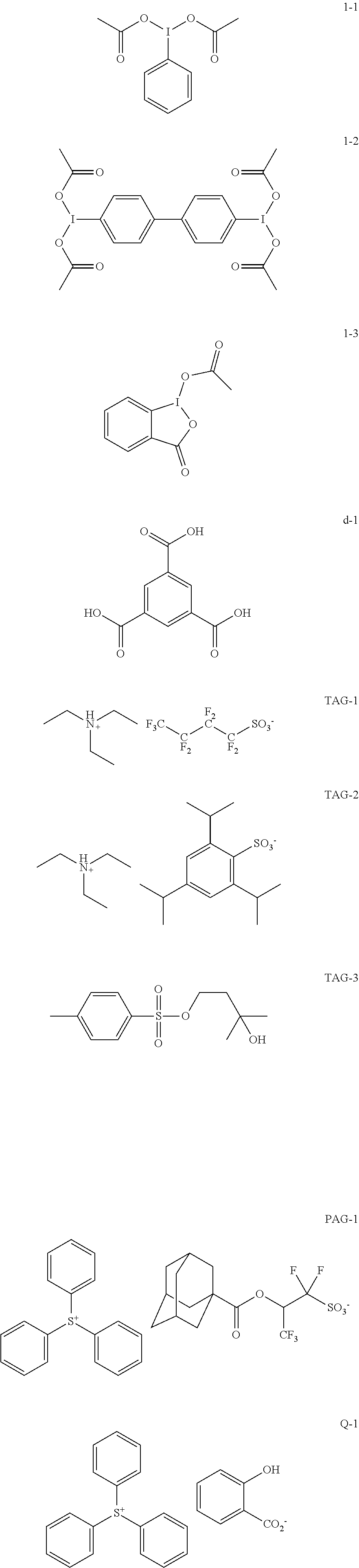

### Solvent:

PGMEA (propylene glycol monomethyl ether acetate)
AcOH (acetic acid)
GBL (γ-butyrolactone)

The carboxylic acid derivatives of Examples 1-1 to 1-20 were soluble in PGMEA alone. The carboxylic acid compounds of Comparative Examples 1-1 and 1-2 could not be dissolved unless acetic acid was added. It is thus demonstrated that after carboxylic acids are protected into carboxylic acid derivatives, the resulting carboxylic acid derivatives are soluble in most solvents.

### [4] EUV Lithography Test (Line-and-Space Pattern)

### Examples 2-1 to 2-20 and Comparative Examples 2-1 to 2-4

Each of the resist compositions (R-01 to R-20, CR-01 to CR-04) was spin coated on a silicon substrate having a 20-nm coating of silicon-containing spin-on hard mask SHB-A940 (Shin-Etsu Chemical Co., Ltd., silicon content 43 wt %) and baked (PAB) on a hotplate at the temperature shown in Table 4 for 60 seconds to form a resist film of 40 nm thick. Using an EUV scanner NXE3400 (ASML, NA 0.33, σ 0.9, 900 dipole illumination), the resist film was exposed to EUV through a mask bearing a 36-nm 1:1 line-and-space (LS) pattern. The resist film was baked (PEB) on a hotplate at the temperature shown in Table 4 for 60 seconds and developed in the developer shown in Table 4 for 30 seconds to form a LS pattern having a space width of 18 nm and a pitch of 36 nm.

The LS pattern was observed under CD-SEM (CG-6300, Hitachi High-Technologies Corp.) and evaluated for sensitivity, LWR and maximum resolution by the following methods. The results are shown in Table 4.

### [Evaluation of Sensitivity]

The optimum dose Eop (mJ/cm²) which provided an LS pattern with a space width of 18 nm and a pitch of 36 nm was determined and reported as sensitivity.

### [Evaluation of LWR]

An LS pattern was formed by exposure in the optimum dose (Eop). The space width was measured at longitudinally spaced apart 10 points, from which a 3-fold value (3σ) of the standard deviation (σ) was determined and reported as LWR. A smaller value indicates a pattern having a lower roughness and more uniform space width.

### [Evaluation of Maximum Resolution]

An LS pattern was formed while increasing the exposure dose little by little from the optimum dose (Eop). The line width (nm) which could be resolved was determined and reported as maximum resolution. A smaller value indicates a pattern having a better maximum resolution and smaller feature size.

TABLE 4

| | | Resist | PAB/PEB | | | | | Maximum |
|---|---|---|---|---|---|---|---|---|
| | | compo- | temp. | Devel- | Pattern | Eop | LWR | resolution |
| | | sition | (° C.) | oper | tone | (mJ/cm²) | (nm) | (nm) |
| Example | 2-1 | R-01 | 180/90 | nBA | positive | 40 | 3.4 | 16 |
| | 2-2 | R-02 | 180/90 | nBA | positive | 42 | 3.5 | 14 |
| | 2-3 | R-03 | 200/90 | nBA | positive | 36 | 3.2 | 14 |
| | 2-4 | R-04 | 160/90 | nBA | positive | 40 | 3.4 | 15 |
| | 2-5 | R-05 | 160/90 | nBA | positive | 42 | 3.5 | 14 |
| | 2-6 | R-06 | 140/90 | nBA | positive | 36 | 3.2 | 14 |
| | 2-7 | R-07 | 180/90 | nBA | positive | 41 | 3.5 | 15 |
| | 2-8 | R-08 | 180/90 | nBA | positive | 39 | 3.4 | 14 |
| | 2-9 | R-09 | 180/90 | nBA | positive | 38 | 3.7 | 14 |
| | 2-10 | R-10 | 180/90 | nBA | positive | 46 | 3.2 | 14 |
| | 2-11 | R-11 | 180/90 | TMAH | negative | 45 | 3.6 | 15 |
| | 2-12 | R-12 | 180/90 | TMAH | negative | 42 | 3.4 | 15 |
| | 2-13 | R-13 | 180/90 | TMAH | negative | 47 | 3.7 | 15 |
| | 2-14 | R-14 | 180/90 | TMAH | negative | 40 | 3.2 | 15 |
| | 2-15 | R-15 | 180/90 | TMAH | negative | 44 | 3.5 | 14 |
| | 2-16 | R-16 | 180/90 | nBA | positive | 44 | 3.4 | 14 |
| | 2-17 | R-17 | 180/90 | nBA | positive | 42 | 3.8 | 14 |
| | 2-18 | R-18 | 170/90 | TMAH | negative | 44 | 3.4 | 14 |
| | 2-19 | R-19 | 170/90 | TMAH | negative | 44 | 3.5 | 14 |
| | 2-20 | R-20 | 140/90 | TMAH | negative | 44 | 3.5 | 14 |
| Comparative | 2-1 | CR-01 | 110/90 | nBA | positive | 40 | 3.9 | 16 |
| Example | 2-2 | CR-02 | 110/90 | nBA | positive | 44 | 4.0 | 16 |
| | 2-3 | CR-03 | 105/90 | TMAH | positive | 85 | 4.4 | 18 |
| | 2-4 | CR-04 | 105/90 | TMAH | positive | 85 | 4.4 | 18 |

Developer: nBA (n-butyl acetate)
TMAH (2.38 wt % tetramethylammonium hydroxide aqueous solution)

As is evident from Table 4, a comparison of Examples 2-1 to 2-3 with Examples 2-4 to 2-6 reveals that the addition of a thermal acid generator ensures to convert the carboxylic acid derivative to a carboxylic acid via prebake at lower temperature and to form a pattern. A comparison of Examples 2-17 to 2-20 reveals that the prebake temperature can be adjusted depending on the type of substituent on the carboxylic acid derivative. A comparison of Examples 2-1 to 2-20 with Comparative Examples 2-1 and 2-2 reveals that using the carboxylic acid derivative, a resist pattern with improved LWR can be formed. A comparison of resist compositions within the scope of the invention with chemically amplified resist compositions of Comparative Examples 2-3 and 2-4 using acid catalyst reaction reveals better sensitivity, resolution and LWR.

### [5] EUV Lithography Test (Contact Hole Pattern)

### Examples 3-1 to 3-20 and Comparative Examples 3-1 to 3-4

Each of the resist compositions (R-01 to R-20, CR-01 to CR-04) was spin coated on a silicon substrate having a 20-nm coating of silicon-containing spin-on hard mask SHB-A940 (Shin-Etsu Chemical Co., Ltd., silicon content 43 wt %) and baked (PAB) on a hotplate at the temperature shown in Table 5 for 60 seconds to form a resist film of 50 nm thick. Using an EUV scanner NXE3400 (ASML, NA 0.33, σ 0.9/0.6, quadrupole illumination), the resist film was exposed to EUV through a mask bearing a hole pattern with a pitch of 64 nm+20% bias (on-wafer size). After exposure, the resist film was baked (PEB) on a hotplate at the temperature shown in Table 5 for 60 seconds and developed in the developer shown in Table 5 for 30 seconds to form a hole pattern having a size of 32 nm.

The hole pattern was observed under CD-SEM (CG-6300, Hitachi High-Technologies Corp.) and evaluated for sensitivity, CDU and maximum resolution by the following methods. The results are shown in Table 5.

### [Evaluation of Sensitivity]

The optimum dose Eop (mJ/cm²) which provided a contact hole pattern with a size of 32 nm was determined and reported as sensitivity.

### [Evaluation of CDU]

The size of 50 holes which were printed at Eop was measured, from which a 3-fold value (3σ) of the standard deviation (σ) was computed and reported as CDU. A smaller value of CDU indicates a hole pattern with more uniform hole diameter.

### [Evaluation of Maximum Resolution]

A hole pattern was formed while reducing the exposure dose little by little from the optimum dose (Eop). The hole diameter (nm) which could be resolved was determined and reported as maximum resolution. A smaller value indicates a pattern having a better maximum resolution and smaller hole diameter.

TABLE 5

| | | Resist | PAB/PEB | | | | | Maximum |
|---|---|---|---|---|---|---|---|---|
| | | compo- | temp. | Devel- | Pattern | Eop | CDU | resolution |
| | | sition | (° C.) | oper | tone | (mJ/cm²) | (nm) | (nm) |
| Example | 3-1 | R-01 | 180/90 | nBA | positive | 41 | 2.7 | 28 |
| | 3-2 | R-02 | 180/90 | nBA | positive | 43 | 2.3 | 26 |
| | 3-3 | R-03 | 200/90 | nBA | positive | 38 | 3.4 | 26 |
| | 3-4 | R-04 | 160/90 | nBA | positive | 41 | 2.5 | 26 |
| | 3-5 | R-05 | 160/90 | BA | positive | 42 | 2.9 | 26 |
| | 3-6 | R-06 | 140/90 | nBA | positive | 38 | 3.2 | 26 |
| | 3-7 | R-07 | 180/90 | nBA | positive | 41 | 3.0 | 26 |
| | 3-8 | R-08 | 180/90 | nBA | positive | 40 | 2.4 | 28 |
| | 3-9 | R-09 | 180/90 | nBA | positive | 39 | 3.2 | 26 |
| | 3-10 | R-10 | 180/90 | nBA | positive | 42 | 3.5 | 26 |
| | 3-11 | R-11 | 180/90 | TMAH | negative | 43 | 2.9 | 26 |
| | 3-12 | R-12 | 180/90 | TMAH | negative | 43 | 2.4 | 26 |
| | 3-13 | R-13 | 180/90 | TMAH | negative | 44 | 2.4 | 26 |
| | 3-14 | R-14 | 180/90 | TMAH | negative | 41 | 2.2 | 26 |
| | 3-15 | R-15 | 180/90 | TMAH | negative | 43 | 2.4 | 28 |
| | 3-16 | R-16 | 180/90 | nBA | positive | 43 | 2.9 | 26 |
| | 3-17 | R-17 | 180/90 | nBA | positive | 41 | 2.5 | 26 |
| | 3-18 | R-18 | 170/90 | TMAH | negative | 43 | 2.5 | 28 |
| | 3-19 | R-19 | 170/90 | TMAH | negative | 43 | 2.1 | 28 |
| | 3-20 | R-20 | 140/90 | TMAH | negative | 43 | 2.5 | 26 |
| Comparative | 3-1 | CR-01 | 110/90 | nBA | positive | 40 | 3.8 | 28 |
| Example | 3-2 | CR-02 | 110/90 | nBA | positive | 45 | 3.8 | 28 |
| | 3-3 | CR-03 | 105/90 | TMAH | positive | 50 | 4.2 | 32 |
| | 3-4 | CR-04 | 105/90 | TMAH | positive | 50 | 4.2 | 32 |

Developer: nBA (n-butyl acetate)
TMAH (2.38 wt % tetramethylammonium hydroxide aqueous solution)

As is evident from Table 5, a comparison of Examples 3-1 to 3-3 with Examples 3-4 to 3-6 reveals that the addition of a thermal acid generator ensures to convert the carboxylic acid derivative to a carboxylic acid via prebake at lower temperature and to form a pattern. A comparison of Examples 3-17 to 3-20 reveals that the prebake temperature can be adjusted depending on the type of substituent on the carboxylic acid derivative. A comparison of Examples 3-1 to 3-20 with Comparative Examples 3-1 and 3-2 reveals that using the carboxylic acid derivative, a resist pattern with improved CDU can be formed. A comparison of resist compositions within the scope of the invention with chemically amplified resist compositions of Comparative Examples 3-3 and 3-4 using acid catalyst reaction reveals better sensitivity, resolution and CDU.

Japanese Patent Application No. 2024-140591 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a hypervalent iodine compound, a carboxylic acid derivative, and a solvent,
said hypervalent iodine compound is at least one compound selected from hypervalent iodine compounds having the formulae (1) to (4): 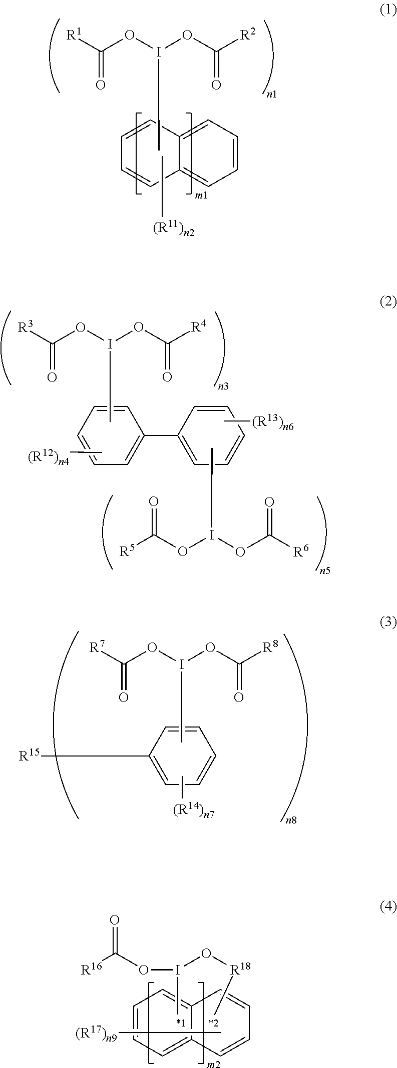
wherein m1 is 0, 1 or 2; when m1=0, n1 is 1, 2 or 3, n2 is 0, 1, 2, 3, 4 or 5 and 1 n1+n2≤6; when m1=1, n1 is 1, 2 or 3, n2 is 0, 1, 2, 3, 4, 5, 6 or 7 and 1≤n1+n2≤8; when m1=2, n1 is 1, 2 or 3, n2 is 0, 1, 2, 3, 4, 5, 6, 7, 8 or 9 and 1 n1+n2≤10;
n3 is 1 or 2, n4 is 0, 1, 2, 3 or 4, 1≤n3+n4≤5, n5 is 1 or 2, n6 is 0, 1, 2, 3 or 4, 1≤n5+n6≤5, n7 is 0, 1, 2, 3 or 4, n8 is 1, 2, 3 or 4,
m2 is 0, 1 or 2; when m2=0, n9 is 0, 1, 2, 3 or 4; when m2=1, n9 is 0, 1, 2, 3, 4, 5 or 6;
R¹ to R⁸ are each independently halogen or a C₁-C₁₀ hydrocarbyl group which may contain a heteroatom, R¹ and R², R³ and R⁴, R⁵ and R⁶, or R⁷ and R⁸ may bond together to form a ring with the carbon atoms to which they are attached and the intervenient atoms,
R¹¹ to R¹⁴ are each independently halogen or a C₁-C₄₀ hydrocarbyl group which may contain a heteroatom; when n2 is 2 or more, a plurality of R¹¹ may be identical or different and a plurality of R¹¹ may bond together to form a ring with the carbon atoms on the aromatic ring to which they are attached; when n4 is 2 or more, a plurality of R¹² may be identical or different and a plurality of R¹² may bond together to form a ring with the carbon atoms on the aromatic ring to which they are attached; when n6 is 2 or more, a plurality of R¹³ may be identical or different and a plurality of R¹³ may bond together to form a ring with the carbon atoms on the aromatic ring to which they are attached; when n7 is 2 or more, a plurality of R¹⁴ may be identical or different and a plurality of R¹⁴ may bond together to form a ring with the carbon atoms on the aromatic ring to which they are attached;
R¹⁵ is a C₁-C₄₀ (n8)-valent hydrocarbon group or C₂-C₄₀ (n8)-valent heterocyclic group; when n8=2, R¹⁵ may also be an ether bond, carbonyl group, azo group, thioether bond, carbonate bond, carbamate bond, sulfinyl group, sulfonyl group or thioketone bond; some or all of the hydrogen atoms in the (n8)-valent hydrocarbon group or (n8)-valent heterocyclic group may be substituted by a heteroatom-containing moiety, some —CH₂— in the (n8)-valent hydrocarbon group may be replaced by a heteroatom-containing moiety, R¹⁴ and R¹⁵ may bond together to form a ring with the carbon atoms to which they are attached and the intervenient atoms,
R¹⁶ is halogen or a C₁-C₁₀ hydrocarbyl group which may contain a heteroatom,
R¹⁷ is halogen or a C₁-C₄₀ hydrocarbyl group which may contain a heteroatom, when n9 is 2 or more, a plurality of R¹⁷ may be identical or different and a plurality of R¹⁷ may bond together to form a ring with the carbon atoms on the aromatic ring to which they are attached;
R¹⁸ is carbonyl or a C₁-C₁₀ hydrocarbylene group which may contain a heteroatom,
*1 and *2 each designate a point of attachment to a carbon atom on the aromatic ring in the formula, *1 and *2 being attached to adjoining carbon atoms on the aromatic ring,
said carboxylic acid derivative is a carboxylic acid derivative having the formula (5) or a polymer comprising carboxylic acid derivative repeat units having the formula (6): 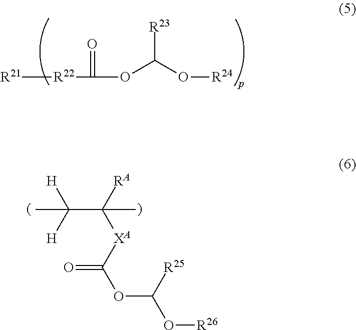
wherein p is 1, 2, 3 or 4,
R²¹ is a C₁-C₄₀ p-valent hydrocarbon group or C₂-C₄₀ p-valent heterocyclic group; when p=2, R²¹ may also be an ether bond, carbonyl group, azo group, thioether bond, carbonate bond, carbamate bond, sulfinyl group or sulfonyl group; some or all of the hydrogen atoms in the p-valent hydrocarbon group or p-valent heterocyclic group may be substituted by a heteroatom-containing moiety, some —CH₂— in the p-valent hydrocarbon group may be replaced by a heteroatom-containing moiety,
R²² is a single bond or C₁-C₁₀ hydrocarbylene group, some or all of the hydrogen atoms in the hydrocarbylene group may be substituted by a heteroatom-containing moiety, some —CH₂— in the hydrocarbylene group may be replaced by a heteroatom-containing moiety; when p is 2, 3 or 4, a plurality of R²² may be identical or different,
R²³ to R²⁶ are each independently halogen or a C₁-C₄₀ hydrocarbyl group which may contain a heteroatom, R²³ and R²⁴ may bond together to form a ring with the carbon and oxygen atoms to which they are attached, R²¹ and R²⁶ may bond together to form a ring with the carbon and oxygen atoms to which they are attached,
R^{A} is hydrogen, halogen, methyl or trifluoromethyl,
X^{A} is a single bond, phenylene, naphthylene, or *—C(═O)—O—X^{A1}—, X^{A1} is a C₁-C₁₀ saturated hydrocarbylene group, phenylene group or naphthylene group, the saturated hydrocarbylene group may contain a hydroxy moiety, ether bond, ester bond or lactone ring, * designates a point of attachment to the carbon atom in the backbone.

2. The resist composition of claim 1 wherein the polymer comprising carboxylic acid derivative repeat units is free of acid labile group-containing repeat units other than the repeat units having formula (6).

3. A laminate comprising a substrate and a resist film formed thereon from the resist composition of claim 1.

4. The laminate of claim 3, further comprising an underlying film between the substrate and the resist film.

5. The laminate of claim 3 wherein the resist film is formed by a ligand exchange between the hypervalent iodine compound and the carboxylic acid derivative.

6. A pattern forming process comprising the steps of applying the resist composition of claim 1 onto a substrate or a substrate having an underlying film deposited thereon to form a resist film thereon, exposing the resist film to i-line, KrF excimer laser, ArF excimer laser, EB or EUV, and developing the exposed resist film in a developer.
